(19) United States
(12) Patent Application Publication
(10) Pub. No.: US 2016/0147156 A1
(43) Pub. Date: May 26, 2016

(54) PATTERN FORMATION METHOD, ACTIVE-LIGHT-SENSITIVE OR RADIATION-SENSITIVE RESIN COMPOSITION, RESIST FILM, METHOD FOR MANUFACTURING ELECTRONIC DEVICE, AND ELECTRONIC DEVICE

(71) Applicant: FUJIFILM Corporation, Tokyo (JP)

(72) Inventor: Fumihiro YOSHINO, Haibara-gun (JP)

(73) Assignee: FUJIFILM Corporation, Tokyo (JP)

(21) Appl. No.: 15/011,870

(22) Filed: Feb. 1, 2016

Related U.S. Application Data
(63) Continuation of application No. PCT/JP2014/069867, filed on Jul. 28, 2014.

(30) Foreign Application Priority Data
Aug. 2, 2013 (JP) 2013-161643

(51) Int. Cl. G03F 7/32; G03F 7/20; G03F 7/038

(52) U.S. Cl. CPC G03F 7/325; G03F 7/038; G03F 7/20; G03F 7/2041

(57) ABSTRACT

The pattern formation method includes the following steps (i) to (iii): (i) a step in which an active-light-sensitive or radiation-sensitive resin composition is used to form a film whose solubility in a developer increases as the exposure dose increases from an unexposed state but then decreases once a predetermined exposure dose has been reached; (ii) a step in which the film is exposed; and (iii) a step in which a developer containing an organic solvent in the amount of 80% by mass or more with respect to the total amount of the developer is used to develop the exposed film.

### CROSS REFERENCE TO RELATED APPLICATION

This is a continuation of International Application No. PCT/JP2014/069867 filed on Jul. 28, 2014, and claims priority from Japanese Patent Application No. 2013-161643 filed on Aug. 2, 2013, the entire disclosures of which are incorporated herein by reference.

### BACKGROUND OF THE INVENTION

1. Field of the Invention

The present invention relates to a pattern formation method, an active-light-sensitive or radiation-sensitive resin composition, a resist film, a method for manufacturing an electronic device, and an electronic device. More specifically, the present invention relates to a pattern formation method which is suitably used for a process for manufacturing a semiconductor such as an IC, for the manufacture of liquid crystals, and a circuit board for a thermal head or the like, and for lithographic processes in photofabrication in addition to these, an active-light-sensitive or radiation-sensitive resin composition used for the pattern formation method, a method for manufacturing an electronic device, and an electronic device. In particular, the present invention relates to a pattern formation method which is suitable for exposure by an KrF exposure device, an ArF exposure device, and an ArF liquid immersion-type projection exposure device, each of which uses far ultraviolet rays at a wavelength of 300 nm or less as a light source, or an EUV exposure device which uses extreme ultraviolet rays (EUV light) as a light source, an active-light-sensitive or radiation-sensitive resin composition used for the pattern formation method, a resist film, a method for manufacturing an electronic device, and an electronic device.

2. Description of the Related Art

Since the advent of a resist for a KrF excimer laser (248 nm), an image formation method called chemical amplification has been used as an image formation method for a resist in order to compensate for sensitivity reduction due to light absorption. For example, in an image formation method for positive-type chemical amplification, an acid generator in exposed areas formed by exposure decomposes to generate an acid, the generated acid is used as a catalyst for a reaction through baking after the exposure (PEB: Post Exposure Bake) to change an alkali-insoluble group into an alkali-soluble group, and the exposed areas are removed by alkali development to form an image.

At present, ArF liquid immersion lithography is used in pattern formation at edges, but the resolution which can be obtained with a maximum NA of water immersion lithography using a lens with NA 1.35 is 40 nm to 38 nm. Thus, for the pattern formation after a 30-nm node, a double patterning process (see JP2008-292975A) is used, and as the pattern formation method, many processes have been proposed.

Furthermore, there has been a demand for a higher level of fineness of patterns, and recently, technology in which a resist film obtained by positive-type and negative-type chemical amplification resist compositions in the current mainstream is resolved using an organic developer is also known (see, for example, JP2008-292975A).

In addition, various attempts in view of obtaining high resolution in pattern formation have been made (see, for example, Sen Liu et al., “Development of KrF Hybrid Resist for a Dual Isolation Application”, Proc. of SPIE, 2013, Vol. 8682, 86820T).

### SUMMARY OF THE INVENTION

The pattern formation method described in JP2008-292975A as a double patterning method for forming a fine pitch (interval) of patterns is a so-called multiple developing method, for which at least two developing steps are required. Further, as a double patterning method for forming a fine pitch of patterns, an approach referred to as a so-called double exposure method, for which two exposing steps are required, is also known.

It is an object of the present invention to provide a novel pattern formation method, completely different from the double patterning methods in the related art, which can provide a fine pattern pitch using a single exposing step and a single developing step; an active-light-sensitive or radiation-sensitive resin composition used for the pattern formation method; a resist film; a method for manufacturing an electronic device; and an electronic device.

In particular, in the case of using a mask, it is an object of the present invention to provide a pattern formation method, by which a pattern having a pitch which is half the pitch of the mask or less can be formed; an active-light-sensitive or radiation-sensitive resin composition used for the pattern formation method; a resist film; a method for manufacturing an electronic device; and an electronic device.

The present invention has the following configurations, whereby the above objects of the present invention are accomplished.

[1] A pattern formation method including the following steps (i) to (iii):

(i) a step of forming a film whose solubility in a developer increases as the exposure dose increases from an unexposed state but then decreases once a predetermined exposure dose has been reached by using an active-light-sensitive or radiation-sensitive resin composition;

(ii) a step of exposing the film; and

(iii) a step of developing the exposed film by using a developer containing an organic solvent in the amount of 80% by mass or more with respect to the total amount of the developer.

[2] The pattern formation method as described in [1], in which the exposure is carried out through a mask to form a pattern having a narrower pitch than the pitch of the mask.

[3] The pattern formation method as described in [2], in which the pitch of the pattern is half the pitch of the mask or less.

[4] The pattern formation method as described in any one of [1] to [3], in which the active-light-sensitive or radiation-sensitive resin composition includes a resin (A) having a repeating unit (P1) containing a group capable of decomposing by an action of an acid to generate a polar group, and a compound (B) capable of generating an acid upon irradiation with active light or radiation.

[5] The pattern formation method as described in [4], in which the active-light-sensitive or radiation-sensitive resin composition further includes an ionic compound (S) containing an anionic moiety having a pKa of 0.0 to 10.0.

[6] The pattern formation method as described in [5], in which the resin (A) is a resin further having a repeating unit (P2) containing an acid group.

[7] The pattern formation method as described in [6], in which the pKa of the repeating unit (P2) is 0.0 to 10.0, and when the pKa of the repeating unit (P2) is higher than the pKa of the anionic moiety of the ionic compound (S), the difference between the pKa of the repeating unit (P2) and the pKa of the anionic moiety of the ionic compound (S) is 2.0 or less.

[8] The pattern formation method as described in [4],in which the resin (A) is a resin further having a repeating unit (P3) containing an ionic group obtained by forming a salt with an acid group.

[9] The pattern formation method as described in [5], in which the anionic moiety is represented by any one of the following General Formulae (a1) to (a5).

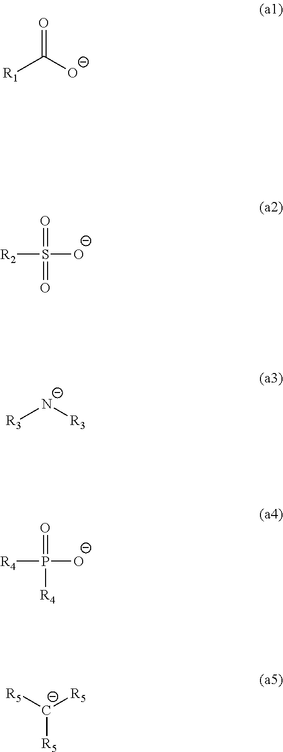

In the general formulae,

R₁, R₂, R₃, R₄, and R₅ each independently represent a hydrogen atom or an organic group,

R₃'s, which are present in plural numbers, may be the same as or different from each other and R₃'s may be bonded to each other to form a ring.

R₄'s, which are present in plural numbers, may be the same as or different from each other and R₄'s may be bonded to each other to form a ring, and

R₅'s, which are present in plural numbers, may be the same as or different from each other and R₅'s may be bonded to each other to form a ring.

[10] The pattern formation method as described in [5], in which the cationic moiety contained in the ionic compound (S) is represented by any one of the following General Formulae (b1) to (b7).

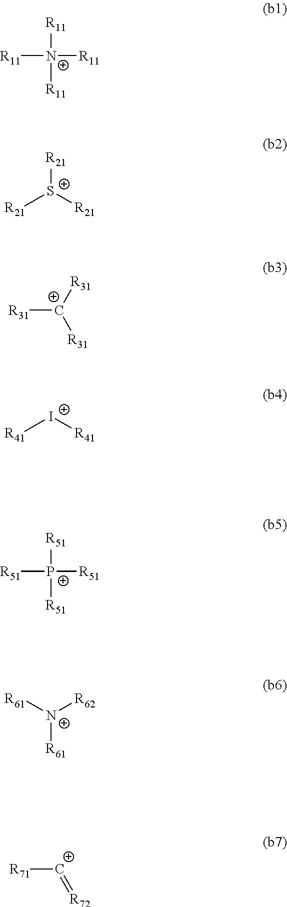

In the general formulae,

R₁₁, R₂₁, R₃₁, R₄₁, R₅₁, R₆₁, R₆₂, R₇₁, and R₇₂ each independently represent a hydrogen atom or an organic group,

R₁₁'s, which are present in plural numbers, may be the same as or different from each other and R₁₁'s may be bonded to each other to form a ring,

R₂₁'s, which are present in plural numbers, may be the same as or different from each other and R₂₁'s may be bonded to each other to form a ring,

R₃₁'s, which are present in plural numbers, may be the same as or different from each other and R₃₁'s may be bonded to each other to form a ring,

R₄₁'s, which are present in plural numbers, may be the same as or different from each other and R₄₁'s may be bonded to each other to form a ring,

R₅₁'s, which are present in plural numbers, may be the same as or different from each other and R₅₁'s may be bonded to each other to form a ring, and

R₆₁'s, which are present in plural numbers, may be the same as or different from each other and R₆₁'s may be bonded to each other to form a ring.

[11] The pattern formation method as described in any one of [1] to [10], in which the exposure is liquid immersion exposure.

[12] An active-light-sensitive or radiation-sensitive resin composition, which forms a film whose solubility in a developer increases as the exposure dose increases from an unexposed state but then decreases once a predetermined exposure dose has been reached.

[13] The active-light-sensitive or radiation-sensitive resin composition as described in [12], including a resin (A) having a repeating unit (P1) containing a group capable of decomposing by an action of an acid to generate a polar group, and a compound (B) capable of generating an acid upon irradiation with active light or radiation.

[14] The active-light-sensitive or radiation-sensitive resin composition as described in [13], further including an ionic compound (S) containing an anionic moiety having a pKa of 0.0 to 10.0.

[15] The active-light-sensitive or radiation-sensitive resin composition as described in [13] or [14], in which the resin (A) is a resin further having a repeating unit (P2) containing an acid group.

[16] The active-light-sensitive or radiation-sensitive resin composition as described in [15], in which the pKa of the repeating unit (P2) is 0.0 to 10.0, and when the pKa of the repeating unit (P2) is higher than the pKa of the anionic moiety of the ionic compound (S), the difference between the pKa of the repeating unit (P2) and the pKa of the anionic moiety of the ionic compound (S) is 2.0 or less.

[17] The active-light-sensitive or radiation-sensitive resin composition as described in [13], in which the resin (A) is a resin further having a repeating unit (P3) containing an ionic group obtained by forming a salt with an acid group.

[18] A resist film formed by using the active-light-sensitive or radiation-sensitive resin composition as described in any one of [12] to [17].

[19] A method for manufacturing an electronic device, including the pattern formation method as described in any one of [1] to [11].

[20] An electronic device manufactured by the method for manufacturing an electronic device as described in [19].

According to the present invention, it is possible to provide a novel pattern formation method, completely different from the double patterning methods in the related art, which can provide a fine pattern pitch using a single exposing step and a single developing step; an active-light-sensitive or radiation-sensitive resin composition used for the pattern formation method; a resist film; a method for manufacturing an electronic device; and an electronic device. In particular, in the case of using a mask, it is possible to provide a pattern formation method capable of forming a pattern having a pitch which is half the pitch of the mask or less; an active-light-sensitive or radiation-sensitive resin composition used for the pattern formation method; a resist film; a method for manufacturing an electronic device; and an electronic device.

### BRIEF DESCRIPTION OF THE DRAWINGS

FIG. 1 is a schematic explanatory view of a pattern formation method of the present invention.

FIG. 2 is a view showing a graph of the results of the residual film test of the resist film using the resist composition of Example 3.

FIG. 3 is a view showing a graph of the dissolution rate relative to the exposure dose (nm/sec, solubility) of the resist film using the resist composition of Example 3.

FIG. 4 is a view showing a graph of the results of the residual film test of the resist film using the resist composition of Example 25.

FIG. 5 is a view showing a graph of the dissolution rate relative to the exposure dose (nm/sec, solubility) of the resist film using the resist composition of Example 25.

FIG. 6 is a view showing a graph of the results of the residual film test of the resist film using the resist composition of Comparative Example 1.

FIG. 7 is a view showing a graph of the dissolution rate relative to the exposure dose (nm/sec, solubility) of the resist film using the resist composition of Comparative Example 1.

FIG. 8 is a view showing the results of observation of a pattern using the resist composition of Example 3 by means of a scanning electron microscopic image (SEM image).

FIG. 9 is a partially enlarged view within a range shown by white solid lines in FIG. 8.

FIG. 10A is a schematic view showing a mask used in dot pattern formation in Examples. FIG. 10B is a schematic view showing a dot pattern obtained by using the mask shown in FIG. 10A.

FIG. 11 is a schematic explanatory view showing a negative-type pattern formation method in the related art.

### DESCRIPTION OF THE PREFERRED EMBODIMENTS

Hereinafter, the embodiments of the present invention will be described in detail.

In citations for a group (atomic group) in the present specification, when the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

Furthermore, “active light” or “radiation” in the present specification means, for example, a bright line spectrum of a mercury lamp, far ultraviolet rays represented by an excimer laser, extreme ultraviolet rays (EUV light), X-rays, electron beams (EB), or the like. In addition, in the present invention, light means active light or radiation.

“Exposure” in the present specification includes, unless otherwise specified, not only exposure by a mercury lamp, far ultraviolet rays represented by an excimer laser, extreme ultraviolet rays, X-rays, EUV light, or the like, but also writing by particle rays such as electron beams and ion beams.

The pattern formation method of the present invention includes the following steps to (iii):

(i) a step of forming a film whose solubility in a developer increases as the exposure dose increases from an unexposed state but then decreases once a predetermined exposure dose has been reached by using an active-light-sensitive or radiation-sensitive resin composition;

(ii) a step of exposing the film; and

(iii) a step of developing the exposed film by using a developer (hereinafter also referred to as an organic developer) containing an organic solvent in the amount of 80% by mass or more with respect to the total amount of the developer.

The “predetermined exposure dose” in the present invention means an exposure dose at an inflection point in a solubility curve of the film with respect to the developer. The “predetermined exposure dose” may be any exposure dose, and is an exposure dose which can vary depending on the conditions of the respective steps of the pattern formation method of the present invention, such as the composition of the active-light-sensitive or radiation-sensitive resin composition, the materials, the film thickness of the resist film, and the like.

First, the pattern formation method of the present invention will be described with reference to FIGS. 1 and 11.

FIG. 1 is a schematic explanatory view of the pattern formation method of the present invention.

FIG. 11 is a schematic explanatory view of a negative-type pattern formation method in the related art.

As clearly seen from FIG. 11, in the negative-type pattern formation method in the related art, after exposure through a mask 11, a resist film (not shown) of an unexposed area which is light-shielded by the mask 11 and a resist film 12 of an exposed area which is not light-shielded are generated. When these resist film are developed, the resist film in the unexposed area is removed by development and the resist film 12 of the exposed area remains, whereby patterns of the pitch 14 which is the same as the pitch (interval) 13 of the mask is formed. For example, when the pitch 13 of the mask is 240 nm, the pitch 14 of the pattern of about 240 nm is formed.

Incidentally, as apparent from FIG. 11, it can be seen that only one pattern derived from the resist film of the exposed area per mask pitch is formed.

Meanwhile, as shown in FIG. 1, according to the pattern formation method of the present invention, for example, when exposure is carried out through the mask 1, a resist film 2 (hereinafter also simply referred to as an “unexposed area 2”) of an unexposed area which is light-shielded by a mask 1, and a resist film 3 (hereinafter also simply referred to as an “exposed area 3”) of an exposed area which is not light-shielded and sufficiently exposed can be generated. Here, in the present invention, the solubility in an organic developer increases as the exposure dose increases from an unexposed state, and thus, the solubility decreases in an unexposed state. Accordingly, the unexposed area 2 cannot be removed by development, which is different from the aforementioned pattern formation method in the related art. Further, the solubility in the exposed area 3 also reaches an inflection point at a predetermined exposure dose, which corresponds to a resist film whose solubility decreases once the exposure dose has been reached, and thus, the exposed area 3 cannot be removed by development.

Furthermore, in the present invention, a part 4 (hereinafter also simply referred to as a “semi-exposed area 4”) which is approximately the center between the exposure dose in the unexposed area 2 and the exposure dose in the exposed area 3 can be generated. The solubility of the semi-exposed area 4 increases as the exposure dose increases, and the semi-exposed area 4 can correspond to a film having the solubility reaching an inflection point at a predetermined exposure dose and a film having the solubility around the inflection point, and can be removed by development by an organic developer.

Therefore, a part (hereinafter also simply referred to as a “a semi-exposed area”) 4 which is approximately the center between the exposure dose in the unexposed area and the exposure dose in the exposed area can be removed by development by an organic developer, and the resist films of the unexposed area 2 and the exposed area 3 can be left as a pattern.

As a result, according to the pattern formation method of the present invention, as shown in FIG. 1, a pattern pitch 6 having a narrower pitch than the pitch 5 of the mask can be formed by a single developing step, and moreover, a pattern pitch 6 having a half (or less) of the pitch 5 of the mask can be suitably formed by a single developing step. For example, when the pitch 5 of the mask is 240 nm, a pattern pitch 6 of 120 nm can also be formed.

Furthermore, as apparent from FIG. 1, it can be seen that two patterns derived from the resist films in the unexposed area 2 and the exposed area 3 per mask pitch can be formed through a single exposing step and a single developing step by a method which is completely different from the double patterning methods in the related art.

Thus, according to the present invention, a pattern with a line width, which has been considered to be hardly formed in the pattern formation method in the related art, can be formed.

In the present invention, the pitch of the mask means an arrangement pitch of a light-shielded or transmitted pattern in a mask formed by arrangement of a plurality of light-shielded or transmitted patterns at constant intervals.

Furthermore, the pattern pitch means an arrangement pitch of the pattern in a plurality of patterns formed by arrangement at a constant interval. For example, in the case of a line-and-space pattern, the pattern pitch means a sum of the length in the width direction of one line pattern and the length in the width direction of one space pattern adjacent to the line pattern in the width direction.

Moreover, in the case of a dot pattern, the pattern pitch means a sum of the diameter of one dot pattern and the interval between the dot pattern and the dot pattern adjacent thereto.

Next, the active-light-sensitive or radiation-sensitive resin composition which can be used in the present invention will be described.

In addition, the present invention also relates to an active-light-sensitive or radiation-sensitive resin composition which will be described later.

The active-light-sensitive or radiation-sensitive resin composition according to the present invention can be used as an active-light-sensitive or radiation-sensitive resin composition for organic solvent development, which is employed in the development using a developer containing art organic solvent in the amount of 80% or more with respect to the total amount of the developer. Here, the use for organic solvent development means the application for use in a step for development using a developer including at least an organic solvent.

The active-light-sensitive or radiation-sensitive resin composition of the present invention is typically a resist composition., and preferably a resist composition for organic solvent development, in view of obtaining particularly superior effects. In addition, the composition according to the present invention is typically a chemical amplification type resist composition.

The active-light-sensitive or radiation-sensitive resin composition of the present invention can form a film whose solubility in a developer increases as the exposure dose increases from an unexposed state but then decreases once a predetermined exposure dose has been reached.

It is preferable that the active-light-sensitive or radiation-sensitive resin composition of the present invention includes a resin (A) having a repeating unit (P1) containing a group (hereinafter also simply referred to as an “acid-decomposable group”) capable of decomposing by an action of an acid to generate a polar group, which will be described later and a compound (B) (hereinafter also simply referred to as an “acid generator”) capable of generating an acid upon irradiation with active light or radiation, which will be described later.

### First to Third Embodiments of the Invention

The present invention preferably encompasses the following first to third embodiments.

Hereinafter, the following first to third embodiments may be collectively called the present invention in some cases.

In the first and third embodiments of the present invention, it is preferable that the active-light-sensitive or radiation-sensitive resin composition includes an ionic compound (S) containing an anionic moiety having a pKa of 0.0 to 10.0. Here, “the pKa of the anionic moiety” represents a pKa in a reaction of XH→X⁻+H⁺ when an anion of the ionic compound (S) is defined as X⁻.

The ionic compound (S) is a compound which is different from the compound (B) capable of generating an acid upon irradiation with active light or radiation, which will be described later.

By setting the pKa of the anionic moiety to 0.0 to 10.0, it is possible to inhibit the occurrence of acid decomposition of an acid-decomposable group of the repeating unit (P1) of the resin (A).

Furthermore, in the following first embodiment of the present invention, an exchange between a proton contained in an acid group of the following repeating unit (P2) and a cationic moiety of the ionic compound (S) can be allowed, and thus, a salt of the acid group with the cationic moiety can be formed. That is, a repeating unit (P3) containing an ionic group obtained by forming a salt with an acid group can be formed. The ionic group obtained by forming a salt with an acid group can cause the solubility of the film in an organic developer to decrease.

Furthermore, in the following third embodiment of the present invention, when an acid derived from the compound (B) capable of generating an acid upon irradiation with active light or radiation, which will be described later, is generated, the pKa of the anionic moiety of the ionic compound (S) is 0.0 to 10.0, and thus the proton can be suitably captured.

From the above viewpoint, the pKa of the anionic moiety of the ionic compound (S) is preferably 2.0 to 8.0, and the pKa of the anionic moiety of the ionic compound (S) is more preferably 3.0 to 7.0.

In the present invention, the “pKa” indicates pKa in an aqueous solution and is described, for example, in Chemical Handbook (II) (Revised 4^{th} Edition, 1993, compiled by the Chemical Society of Japan, Maruzen Company, Ltd.), and a lower value thereof indicates higher acid strength. Specifically, the pKa in an aqueous solution may be measured by using an infinite-dilution aqueous solution and measuring the acid dissociation constant at 25° C., or a value based on the Hammett substituent constants and the database of publicly known literature data may also be obtained by computation using the following software package 1. All the values of pKa described in the present specification indicate values determined by computation using this software package.

Software package 1: ACD/ChemSketch (manufactured by Advanced Chemistry Development Inc.; ACD/Labs ver. 8.08).

### First Embodiment

In the first embodiment of the present invention, it is more preferable that a resin (A) having a repeating unit (P1) containing an acid-decomposable group further has a repeating unit (P2) containing an acid group.

That is, the first embodiment of the present invention is an embodiment in which the active-light-sensitive or radiation-sensitive resin composition includes an ionic compound (S) containing an anionic moiety having a pKa of 0.0 to 10.0, and the resin (A) contains a repeating unit (P1) containing an acid-decomposable group and a repeating unit (P2) containing an acid group.

It is more preferable that the pKa of the repeating unit (P2) containing an acid group is 0.0 to 10.0.

The pKa in this range is suitable for exchange (neutralization) between a proton contained in an acid group of the repeating unit (P2) and a cationic moiety of the ionic compound (S), and suitable for formation of an ionic group obtained by forming a salt with an acid group.

In the present invention, the pKa of the repeating unit (P2) means the pKa of a monomer (monomer material) corresponding to the repeating unit (P2).

It is most preferable that the pKa of the repeating unit (P2) is lower than the pKa of the anionic moiety of the ionic compound (S). When the pKa of the repeating unit (P2) is higher than the pKa of the anionic moiety of the ionic compound (S), the difference between the pKa of the repeating unit (P2) and the pKa of the anionic moiety of the ionic compound (S) is preferably 2.0 or less, and particularly preferably 1.0 or less.

The pKa in this range is particularly suitable for exchange (neutralization) between a proton contained in an acid group of the repeating unit (P2) and a cationic moiety of the ionic compound (S), and particularly suitable for formation of an ionic group obtained by forming a salt with an acid group.

First, in the active-light-sensitive or radiation-sensitive resin composition in the first embodiment of the present invention, a salt can be formed by the exchange of a cationic moiety of the ionic compound (S) with a proton contained in an acid group of the repeating unit (P2). That is, a repeating unit (P3) containing an ionic group obtained by forming a salt with an acid group can be formed.

Since the ionic group which the resulting repeating unit (P3) has can reduce the solubility of the film in an organic developer, a film having the reduced solubility in the organic developer in an unexposed state can be formed.

Next, as the exposure dose increases, an acid derived from the compound (B) (acid generator) capable of generating an acid upon irradiation with active light or radiation, which will be described later, can be generated, the protonation (capture of protons) of an anionic moiety of the ionic group obtained by forming a salt with an acid group contained in the repeating unit (P3) proceeds, and regeneration of the repeating unit (P2) containing an acid group can proceed. Thus, the ionic group obtained by forming a salt with an acid group is reduced, and the solubility of the film in the developer can increase as the exposure dose increases.

In addition, when the exposure dose increases, the generation of protons by the acid generator increases, and thus, the anionic moiety of the ionic group obtained by forming a salt with an acid group contained in the repeating unit (P3) cannot capture protons (all of the repeating units (P3) can be regenerated into the repeating units (P2)). Thus, the acid decomposition of the acid-decomposable group contained in the resin (A) proceeds, and once a predetermined exposure dose has been reached, the solubility in the organic developer can decrease. Further, the acid generation can be chemically amplified by the acid decomposition to accelerate the decrease in the solubility

### Second Embodiment

In the second embodiment of the present invention, it is more preferable that the resin (A) having a repeating unit (P1) containing an acid-decomposable group further has a repeating unit (P3) containing an ionic group obtained by forming a salt with an acid group.

That is, the second embodiment of the present invention is an embodiment in which the resin (A) contains a repeating unit (P1) containing an acid-decomposable group and a repeating unit (P3) containing an ionic group obtained by forming a salt with an acid group.

It is preferable that the resin (A) having a repeating unit (P3) containing an ionic group obtained by forming a salt with an acid group is prepared by neutralizing the resin (A) having the repeating unit (P1) containing an acid-decomposable group and the repeating unit (P2) containing an acid group by using the aforementioned ionic compound (S) containing an anionic moiety having a pKa of 0.0 to 10.0, and exchanging a cationic moiety of the ionic compound (S) with a proton contained in an acid group of the repeating unit (P2).

Furthermore, as a method for producing the resin (A) having a repeating unit (P3), production as in (1) and (2) below is also preferable.

(1) A monomer corresponding to the repeating unit (P3) can be formed by subjecting an acid group contained in a monomer corresponding to the repeating unit (P2) to a neutralization treatment with an ionic compound (S) to form a salt.

(2) The resin (A) having a repeating unit (P3) can be produced by subjecting a monomer corresponding to the obtained repeating unit (P3), a monomer corresponding to a repeating unit (P1) containing an acid-decomposable group, and the like to polymerization in accordance with an ordinary method (for example, radical polymerization, living radical polymerization, and anion polymerization).

First, in the second embodiment of the present invention, since the ionic group contained in the repeating unit (P3) can reduce the solubility of the film in an organic developer, a film whose solubility in the organic developer is reduced in an unexposed state can be formed.

Next, as the exposure dose increases, an acid derived from an acid generator can be generated, and protonation (capture of protons) of an anionic moiety contained in an ionic group obtained by forming a salt with an acid group contained in the repeating unit (P3) can proceed. Thus, the number of the ionic groups obtained by forming a salt with an acid group decreases, and the solubility of the film in the developer can increase as the exposure dose increases.

In addition, as the exposure dose increases, generation of protons by the acid generator increases, and thus, the anionic moieties of the ionic group obtained by forming a salt with an acid group contained in the repeating unit (P3) cannot capture the protons. Thus, the acid decomposition of the acid-decomposable group contained in the resin (A) proceeds, and once a predetermined exposure dose has been reached, the solubility in the organic developer can decrease. Further, the acid generation can be chemically amplified by the acid decomposition to accelerate the decrease in the solubility.

### Third Embodiment

The third embodiment of the present invention is an embodiment in which the active-light-sensitive or radiation-sensitive resin composition includes an ionic compound (S) containing an anionic moiety having a pKa of 0.0 to 10.0, and further, the resin (A) contains a repeating unit (P1) containing an acid-decomposable group. In the third embodiment of the present invention, it is preferable that the resin (A) does not have a repeating unit (P2) containing an acid group.

In the third embodiment of the present invention, from the viewpoint that the ionic compound (S) can reduce the solubility in the organic developer, when the active-light-sensitive or radiation-sensitive resin composition contains an ionic compound (S), a film whose solubility in the organic developer decreases in an unexposed state can be formed.

Next, as the exposure dose increases, an acid derived from an acid generator can be generated, and protonation (capture of protons) of an anionic moiety having a pKa of 0.0 to 10.0, contained in the ionic compound (S), can proceed. Thus, salt exchange (anion exchange) of the anion derived from the acid generator with the anionic moiety derived from the ionic compound (S) can proceed. By the salt exchange, an ionic compound having an improved solubility in the organic developer can be generated, and the solubility of the film in the developer can increase as the exposure dose increases.

In addition, as the exposure dose increases, generation of protons by the acid generator increases, and thus, the anionic moiety of the ionic compound (S) cannot capture the protons. Thus, the acid decomposition of the acid-decomposable group contained in the resin (A) proceeds, and the solubility in the organic developer can decrease once a predetermined exposure dose has been reached. Further, the acid generation can be chemically amplified by the acid decomposition to accelerate the decrease in the solubility.

The respective components which can be included in the active-light-sensitive or radiation-sensitive resin composition according to the present invention will be described.

[1] Ionic Compound (S) Containing Anionic Moiety Having pKa of 0.0 to 10.0

First, the ionic compound (S) containing an anionic moiety having a pKa of 0.0 to 10.0, which is preferably used in the first and third embodiments of the present invention, will be described.

Furthermore, as described above, the ionic compound (S) containing an anionic moiety having a pKa of 0.0 to 10.0 is suitably used in the production of the resin (A) having a repeating unit (P3) containing an ionic group obtained by forming a salt with an acid group in the second embodiment of the present invention.

The ionic compound (S) is preferably a salt including an anionic moiety and a cationic moiety.

The ionic compound (S) is preferably a low molecular compound having a molecular weight of 2,000 or less, more preferably a low molecular compound having a molecular weight of 1,500 or less, and still more preferably a low molecular compound having a molecular weight of 900 or less. Herein, the low molecular compound in the present invention is a compound having a constant molecular weight, in which the molecular weight is 2,000 or less (more preferably 1,500 or less, and still more preferably 900 or less) (a compound substantially not having a molecular weight distribution), not a so-called polymer or oligomer, which is obtained by growing bonds in chain by opening the unsaturated bonds of a compound (a so-called polymerizable monomer) having an unsaturated bond with a use of an initiator. Further, the molecular weight is usually 100 or more.

The anionic moiety having a pKa of 0.0 to 10.0 in the ionic compound (S) is preferably an anion represented by any one of the following General Formulae (a1) to (a5).

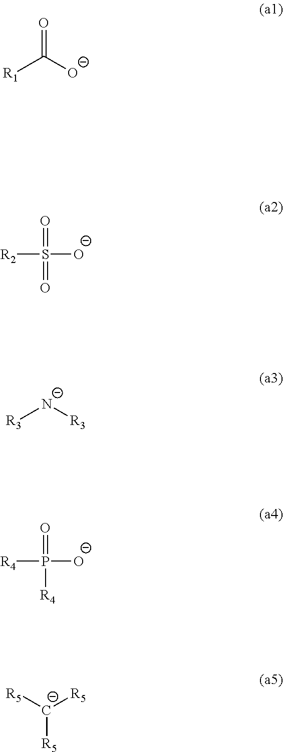

In the general formulae,

R₁, R₂, R₃, R₄, and R₅ each independently represent a hydrogen atom or an organic group.

R₃'s, which are present in plural numbers, may be the same as or different from each other and R₃'s may be bonded to each other to form a ring.

R₄'s, which are present in plural numbers, may be the same as or different from each other and R₄'s may be bonded to each other to form a ring.

R₅'s, which are present in plural numbers, may be the same as or different from each other and R₅'s may be bonded to each other to form a ring.

The organic group for R₁, R₂, and R₄ may be, for example, any one of an alkyl group (an alkyl group which may be linear or branched and preferably has 1 to 20 carbon atoms), a cycloalkyl group (preferably a cycloalkyl group having 3 to 20 carbon atoms), an alkenyl group (preferably an alkenyl group having 2 to 20 carbon atoms), an alkynyl group (preferably an alkynyl group having 2 to 20 carbon atoms), and an aryl group (preferably an aryl group having 6 to 30 carbon atoms).

The organic group for R₃ and R₅ may be, for example, any one of an alkyl group (an alkyl group which may be linear or branched, and preferably has 1 to 20 carbon atoms), a cycloalkyl group (a cycloalkyl group which may be monocyclic or polycyclic, and preferably has 3 to 20 carbon atoms an alkylsulfonyl group (an alkyl group which may be linear or branched, and preferably has 1 to 20 carbon atoms), a cycloalkylsulfonyl group (preferably a cycloalkyl group having 3 to 20 carbon atoms), an alkenyl group (preferably an alkenyl group having 2 to 20 carbon atoms), an alkynyl group (preferably an alkynyl group having 2 to 20 carbon atoms), and an aryl group (preferably an aryl group having 6 to 30 carbon atoms).

Specific examples of the alkyl group for R₁, R₂, R₃, R₄, and R₅ include a methyl group, an ethyl group, a propyl group, an isopropyl group, an n-butyl group, a sec-butyl group, a t-butyl group, a hexyl group, and an octyl group.

Examples of the alkyl moiety of the alkylsulfonyl group for R₃ and R₅ include the same groups as the aforementioned alkyl groups.

The cycloalkyl group for R₁, R₂, R₃, R₄, and R₅ may be a monocyclic cycloalkyl group or a polycyclic cycloalkyl group. Examples of the monocyclic cycloalkyl group include a cyclopropyl group, a cyclobutyl group, a cyclopentyl group, a cyclohexyl group, a cycloheptyl group, and a cyclooctyl group. Examples of the polycyclic cycloalkyl group include an adamantyl group, a norbornyl group, a bornyl group, a camphenyl group, a decahydronaphthyl group, a tricyclodecanyl group, a tetracyclodecanyl group, a camphoryl group, a dicyclohexyl group, and a pinenyl group.

Examples of the cycloalkyl moiety of the cycloalkylsulfonyl group for R₃ and R₅ include the same groups as the aforementioned cycloalkyl groups.

Examples of the alkenyl group for R₁, R₂, R₃, R₄, and R₅ include a vinyl group, a propenyl group, and a hexenyl group.

Examples of the alkynyl group for R₁, R₂, R₃, R₄, and R₅ include a propanyl group and a hexanyl group.

Examples of the aryl group for R₁, R₂, R₃, and R₅ include a phenyl group and a p-tolyl group.

The alkyl group, the cycloalkyl group, the alkylsulfonyl group, the cycloalkylsulfonyl group, the alkenyl group, the alkynyl group, or the aryl group for R₁, R₂, R₃, R₄, and R₅ may have a substituent. Examples of the substituent include the following. That is, the examples of the substituent include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkylthioxy groups such as a methylthioxy group, an ethylthioxy group, and a tert-butylthioxy group; arylthioxy groups such as a phenylthioxy group and a p-tolylthioxy group; alkoxycarbonyl groups such as a methoxycarbonyl group, a butoxycarbonyl group, and a phenoxycarbonyl group; acetoxy groups; linear alkyl groups such as a methyl group, an ethyl group, a propyl group, a butyl group, a heptyl group, a hexyl group, a dodecyl group, and a 2-ethylhexyl group; branched alkyl groups; cycloalkyl groups such as a 7,7-dimethylbicyclo[2.2.1]heptanone group and a cyclohexyl group; alkenyl groups such as a vinyl group, a propenyl group, and a hexenyl group; acetylene groups; alkynyl groups such as a propanyl group and a hexanyl group; aryl groups such as a phenyl group and a tolyl group; a hydroxyl group; a carboxyl group; a sulfonic acid group; and a carbonyl group.

Specific examples of the anionic moiety having a pKa of 0.0 to 10.0 in the ionic compound (S) are shown below, but the present invention is not limited thereto.

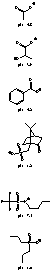

The cationic moiety contained in the ionic compound (S) is preferably a cation represented by any one of the following General Formulae (b1) to (b7).

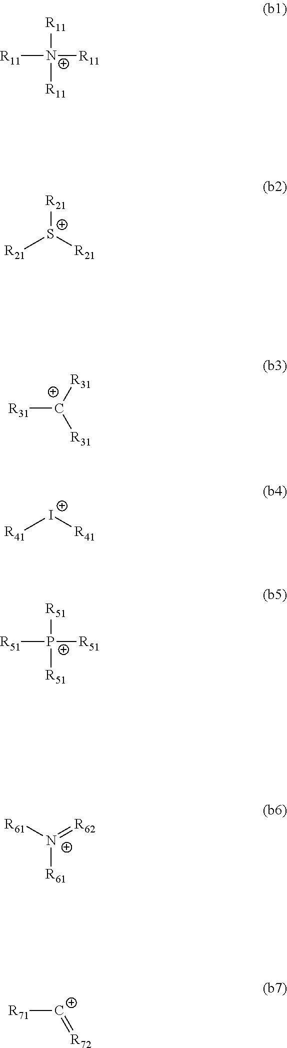

In the general formulae,

R₁₁, R₂₁, R₃₁, R₄₁, R₅₁, R₆₁, R_{71,} and R₇₂ each independently represent a hydrogen atom or an organic group.

R₁₁'s, which are present in plural numbers, may be the same as or different from each other and R₁₁'s may be bonded to each other to form a ring.

R₂₁'s, which are present in plural numbers, may be the same as or different from each other and R₂₁'s may be bonded to each other to form a ring.

R₃₁'s, which are present in plural numbers, may be the same as or different from each other and R₃₁'s may be bonded to each other to form a ring.

R₄₁'s, which are present in plural numbers, may be the same as or different from each other and R₄₁'s may be bonded to each other to form a ring.

R₅₁'s, which are present in plural numbers, may be the same as or different from each other and R₅₁'s may be bonded to each other to form a ring.

R₆₁'s, which are present in plural numbers, may be same as or different from each other and R₆₁'s may be bonded to each other to form a ring.

Examples of the organic group for R₁₁, R₂₁, R₃₁, R₄₁, R₅₁, R₆₁, and R₇₁ include an alkyl group (an alkyl group which may be linear or branched, and preferably has 1 to 20 carbon atoms), a cycloalkyl group (preferably a cycloalkyl group having 3 to 20 carbon atoms, an alkenyl group (preferably an alkenyl group having 2 to 20 carbon atoms), an alkynyl group (preferably an alkynyl group having 2 to 20 carbon atoms), and an aryl group (preferably an aryl group having 6 to 30 carbon atoms).

Examples of the organic group for R₆₂ and R₇₂ include a hydrocarbon group, with a hydrocarbon group having 1 to 10 carbon atoms being preferable and a hydrocarbon group having 1 to 6 carbon atoms being more preferable.

R₆₂ is preferably a group which is bonded to at least one of R₆₁'s to form a ring, and more preferably a group capable of forming a nitrogen atom-containing aromatic ring.

R₇₂ is preferably a group which is bonded to R₇₁ to form a ring, and more preferably a group capable of forming an aromatic ring.

Specific examples of the alkyl group for R₁₁, R₂₁, R₃₁, R₄₁, R₅₁, R₆₁, and R₇₁ include a methyl group, an ethyl group, a propyl group, an isopropyl group, an n-butyl group, a sec-butyl group, a t-butyl group, a hexyl group, and an octyl group.

The cycloalkyl group for R₁₁, R₂₁, R₃₁, R₄₁, R₅₁, R₆₁, and R₇₁ may be a monocyclic cycloalkyl group or a polycyclic cycloalkyl group. Examples of the monocyclic cycloalkyl group include a cyclopropyl group, a cyclobutyl group, a cyclopentyl group, a cyclohexyl group, a cycloheptyl group, and a cyclooctyl group. Examples of the polycyclic cycloalkyl group include an adamantyl group, a norbonyl group, a bornyl group, a camphenyl group, a decahydronaphthyl group, a tricyclodecanyl group, a tetracyclodecanyl group, a camphoroyl group, a dicyclohexyl group, and a pinenyl group.

Examples of the alkenyl group for R₁₁, R₂₁, R₃₁, R₄₁, R₅₁, R₆₁, and R₇₁ include a vinyl group, a propenyl group, and a hexenyl group.

Examples of the alkynyl group for R₁₁, R₂₁, R₃₁, R₄₁, R₅₁, R₆₁, and R₇₁ include a propanyl group and a hexanyl group.

Examples of the aryl group for R₁₁, R₂₁, R₃₁, R₄₁, R₅₁, R₆₁, and R₇₁ include a phenyl group and a p-tolyl group.

The alkyl group, the cycloalkyl group, the alkylsulfonyl group, the cycloalkylsulfonyl group, the alkenyl group, the alkynyl group, or the aryl group for R₁₁, R₂₁, R₃₁, R₄₁, R₅₁, R₆₁, and R₇₁ may have a substituent. Examples of the substituent include the following. That is, examples of the substituent include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkylthioxy groups such as a methylthioxy group, an ethylthioxy group, and a tert-butylthioxy group; arylthioxy groups such as a phenylthioxy group and a p-tolylthioxy group; alkoxycarbonyl groups such as a methoxycarbonyl group, a butoxycarbonyl group, and a phenoxycarbonyl group; acetoxy groups; linear alkyl groups such as a methyl group, an ethyl group, a propyl group, a butyl group, a heptyl group, a hexyl group, a dodecyl group, and a 2-ethylhexyl group; branched alkyl groups; cycloalkyl groups such as a 7,7-dimethylbicyclo[2.2.1]heptanone group and a cyclohexyl group; alkenyl groups such as a vinyl group, a propenyl group, and a hexenyl group; acetylene groups; alkynyl groups such as a propenyl group and a hexanyl group; aryl groups such as a phenyl group and a tolyl group; a hydroxyl group; a carboxyl group; a sulfonic acid group; and a carbonyl group.

Specific examples of the cationic moiety in the ionic compound (S) are shown below, but the present invention is not limited thereto.

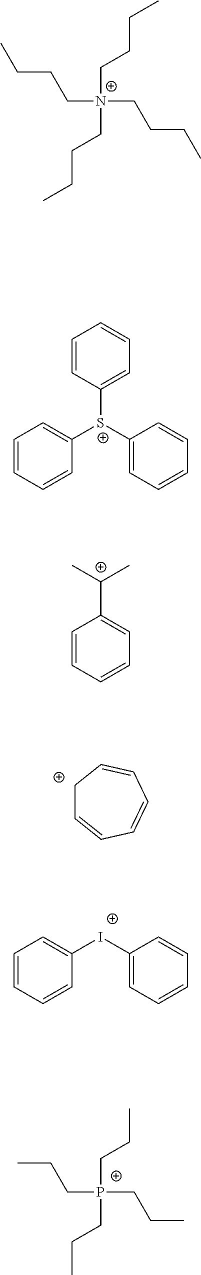

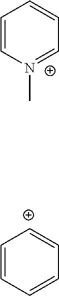

Specific examples of the ionic compound (S) in the present invention are shown below, but the present invention is not limited thereto.

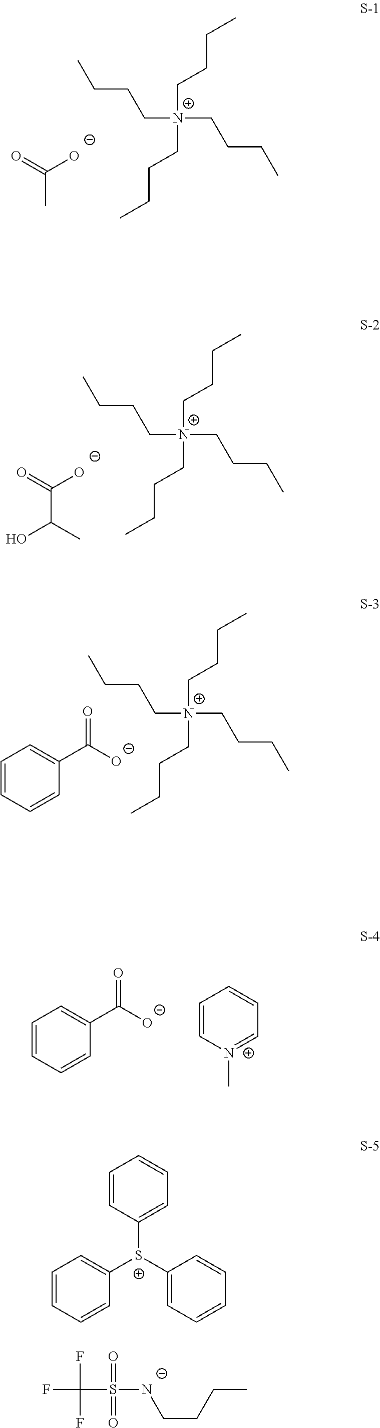

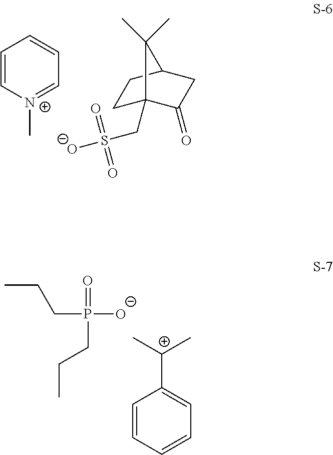

The ionic compound (S) containing an anionic moiety having a pKa of 0.0 to 10.0 can be synthesized by a known method, and ones available from Aldrich may be used.

The ionic compound (S) containing an anionic moiety having a pKa of 0.0 to 10.0 may be used alone or in combination of two or more kinds thereof.

In the present invention, the content of the ionic compound (S) in the composition is preferably 0.01% by millimole to 1.5% by millimole, more preferably 0.03% by millimole to 1.0% by millimole, and still more preferably 0.05% by millimole to 0.8% by millimole, with respect to the mass of the total solid contents of the active-light-sensitive or radiation-sensitive resin composition.

In the present invention, the content of the ionic compound (S) in the composition is expressed in % by mass, and is preferably 0.1% by mass to 60% by mass, more preferably 0.3% by mass to 40% by mass, and still more preferably 0.5% by mass to 32% by mass, based on the total solid contents of the active-light-sensitive or radiation-sensitive resin composition.

In the first embodiment of the present invention (an embodiment in which the active-light-sensitive or radiation-sensitive resin composition contains an ionic compound (S), and further, the resin (A) contains a repeating unit (P 1) containing an acid-decomposable group and a repeating unit (P2) containing an acid group), the content of the ionic compound (S) in the composition is preferably 0.01% by millimole to 0.8% by millimole, more preferably 0.03% by millimole to 0.5% by millimole, and still more preferably 0.05% by millimole to 0.3% by millimole, with respect to the mass of the total solid contents of the active-light-sensitive or radiation-sensitive resin composition.

In the first embodiment of the present invention, when the content of the ionic compound (S) in the composition is expressed in % by mass, it is preferably 0.1% by mass to 30% by mass, more preferably 0.3% by mass to 25% by mass, still more preferably 0.5% by mass to 20% by mass, based on the total solid contents of the active-light-sensitive or radiation-sensitive resin composition.

In the third embodiment of the present invention (an embodiment in which the active-light-sensitive or radiation-sensitive resin composition contains an ionic compound (S), and further, the resin (A) contains a repeating unit (P1) containing an acid-decomposable group), the content of the ionic compound (S) in the composition is preferably 0.1% by millimole to 1.5% by millimole, more preferably 0.2% by millimole to 1.0% by millimole, and still more preferably 0.3% by millimole to 0.8% by millimole, with respect to the mass of the total solid contents of the active-light-sensitive or radiation-sensitive resin composition.

In the third embodiment of the present invention, when the content of the ionic compound (S) in the composition is expressed in % by mass, it is preferably 1% by mass to 30% by mass, more preferably 3% by mass to 25% by mass, still more preferably 5% by mass to 20% by mass, based on the total solid contents of the active-light-sensitive or radiation-sensitive resin composition.

[2] Resin (A) Having Repeating Unit (P1) Having Acid-Decomposable Group (Hereinafter also Referred to as an “Acid-Cecomposable Resin” or a “Resin (A)”)

[Repeating Unit (P1) Having Acid-Decomposable Group]

The acid-decomposable group preferably has a structure in which a polar group is protected with a group capable of decomposing by an action of an acid to leave.

The polar group is not particularly limited as long as it is a group sparingly soluble or insoluble in the developer including an organic solvent, and examples thereof include a phenolic hydroxyl group, a carboxyl group, a fluorinated alcohol group (preferably a hexafluoroisopropanol group), an acidic group (a group which dissociates in a 2.38%-by-mass aqueous tetramethylammonium hydroxide solution, which is used as a developer of a resist in the prior art), such as a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Further, the alcoholic hydroxyl group refers to a hydroxyl group bonded to a hydrocarbon group, which is other than a hydroxyl group (a phenolic hydroxyl group) directly bonded on an aromatic ring, and excludes an aliphatic alcohol (for example, a fluorinated alcohol group (a hexafluoroisopropanol group or the like)), of which the α-position is substituted with an electron withdrawing group such as a fluorine atom as a hydroxyl group. As the alcoholic hydroxyl group, a hydroxyl group having a pKa ranging from 12 to 20 is preferable.

Preferred examples of the polar group include a carboxyl group, a fluorinated alcohol group (preferably a hexafluoroisopropanol group), and a sulfonic acid group.

The group preferable as the acid-decomposable group is a group in which hydrogen atoms of these groups are substituted with a group which leaves by an acid.

Examples of the group capable of leaving by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ to R₀₂ each independently represent a hydrogen atom, an alkyl group, a cycloalkyl group, an aryl group, an aralkyl group, or an alkenyl group.

The alkyl group of R₃₆ to R₃₉, R₀₁, and R₀₂ is preferably an alkyl group having 1 to 8 carbon atoms.

The cycloalkyl group of R₃₆ to R₃₉, R₀₁, and R₀₂ may be monocyclic or polycyclic. As the monocyclic cycloalkyl group, a cycloalkyl group having 3 to 8 carbon atoms is preferable, and as the polycyclic cycloalkyl group, a cycloalkyl group having 6 to 20 carbon atoms is preferable. Incidentally, at least one of the carbon atoms in the cycloalkyl group may be substituted with a heteroatom such as an oxygen atom.

The aryl group of R₃₆ to R₃₉, R₀₁, and R₀₂ is preferably an aryl group having 6 to 10 carbon atoms, and examples thereof include a phenyl group, a naphthyl group, and an anthryl group.

The aralkyl group of R₃₆ to R₃₉, R₀₁, and R₀₂ is preferably an aralkyl group having 7 to 12 carbon atoms, and examples thereof include a benzyl group, a phenethyl group, and a naphthylmethyl group.

The alkenyl group of R₃₆ to R₃₉, R₀₁, and R₀₂ is preferably an alkenyl group having 2 to 8 carbon atoms, and examples thereof include a vinyl group, an allyl group, a butenyl group, and a cyclohexenyl group.

As the ring formed by the mutual bonding of R₃₆ and R₃₇, a monocyclic cycloalkyl group or a polycyclic cycloalkyl group is preferable. A monocyclic cycloalkyl group having 5 or 6 carbon atoms is more preferable and a monocyclic cycloalkyl group having 5 carbon atoms is particularly preferable.

The acid-decomposable group is preferably a cumyl ester group, an enol ester group, an acetal ester group, a tertiary alkyl ester group, or the like, and more preferably a tertiary alkyl ester group.

Further, the resin (A) is preferably one having a repeating unit represented by the following General Formula (AI) or (AI′) as the repeating unit (P1) containing an acid-decomposable group.

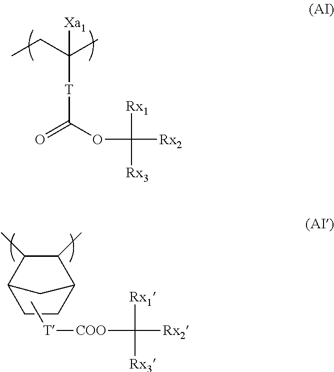

In General Formula (AI),
Xa₁ represents a hydrogen atom, an alkyl group, a cyano group, or a halogen atom,
T represents a single bond or a divalent linking group,
Rx₁ to Rx₃ each independently represent an alkyl group or a cycloalkyl group, and two members out of Rx₁ to Rx₃ may be bonded to each other to form a ring structure.

In General Formula (AI′).
T′ represents a single bond or a divalent linking group,
Rx₁′ to Rx₃′ each independently represent an alkyl group or a cycloalkyl group, and two members out of Rx₁′ to Rx₃′ may be bonded to each other to form a ring structure.

Examples of the divalent linking group of T include an alkylene group, a —COO—Rt- group, an —O—Rt- group, and a phenylene group. In the formula, Rt represents an alkylene group or a cycloalkylene group.

T is preferably a single bond or a —COO—Rt- group. Rt is preferably an alkylene group having 1 to 5 carbon atoms, more preferably a —CH₂— group, a —(CH₂)₂— group, or a —(CH₂)₃— group, and still more preferably a single bond.

The alkyl group of Xa₁ may have a substituent, and examples of the substituent include a hydroxyl group and a halogen atom (preferably a fluorine atom).

The alkyl group of Xa₁ is preferably an alkyl group having 1 to 4 carbon atoms, and examples thereof include a methyl group, an ethyl group, a propyl group, a hydroxymethyl group, and a trifluoromethyl group, with the methyl group being preferable.

Xa₁ is preferably a hydrogen atom or a methyl group.

The alkyl group of Rx₁, Rx₂, and Rx₃ may be linear or branched, and it is preferably an alkyl group having 1 to 4 carbon atoms, such as a methyl group, an ethyl group, an n-propyl group, an isopropyl group, an n-butyl group, an isobutyl group, and a t-butyl group.

The cycloalkyl group of Rx₁, Rx₂, and Rx₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

As the ring structure formed by the mutual bonding of two members out of Rx₁, Rx₂, and Rx₃, a monocyclic cycloalkane ring such as a cyclopentyl ring and a cyclohexyl ring, or a polycyclic cycloalkyl group such as a norbornyl ring, a tetracyclodecanyl ring, a tetracyclododecanyl ring, and an adamantyl ring is preferable, and a monocyclic cycloalkane ring having 5 or 6 carbon atoms is particularly preferable.

Rx₁, Rx₂, and Rx₃ are each independently preferably an alkyl group, and more preferably a linear or branched alkyl group having 1 to 4 carbon atoms.

Specific and preferred examples of T′, Rx₁′ to Rx₃′, and the ring structure which is formed by the mutual bonding of two members out of Rx₁′ to Rx₃′ include the same as those mentioned as the specific and preferred examples of T, Rx₁ to Rx₃, and the ring structure which is formed by the mutual bonding of two members out of Rx₁ to Rx₃.

Each of the above groups may have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, and an alkoxycarbonyl group (having 2 to 6 carbon atoms), and the number of carbon atoms is preferably 8 or less. Among these, a substituent which does not have a heteroatom such as an oxygen atom, a nitrogen atom, and a sulfur atom is more preferable (still more preferably, for example, a group which is not an alkyl group substituted with a hydroxyl group or the like), from the viewpoint of further improving dissolution contrast for a developer including an organic solvent before and after acid-decomposition, a group formed only of hydrogen atoms and carbon atoms is still more preferable, and a linear or branched alkyl group, or a cycloalkyl group is particularly preferable.

Specific examples of the repeating unit (P 1) containing an acid-decomposable group are shown below, but the present invention is not limited to these specific examples.

In the specific examples, Rx represents a hydrogen atom, CH₃, CF₃, or CH₂OH. Rxa and Rxb each represent an alkyl group having 1 to 4 carbon atoms. Xa₁ represents a hydrogen atom, CH₃, CF₃, or CH₂OH. Z represents a substituent, and in the case of being present in plural numbers, plural numbers of Z's may be the same as or different from each other. p represents 0 or a positive integer. Specific examples and preferred examples of Z are the same as the specific examples and the preferred examples of the substituents that each group such as Rx₁ to Rx₃ may have.

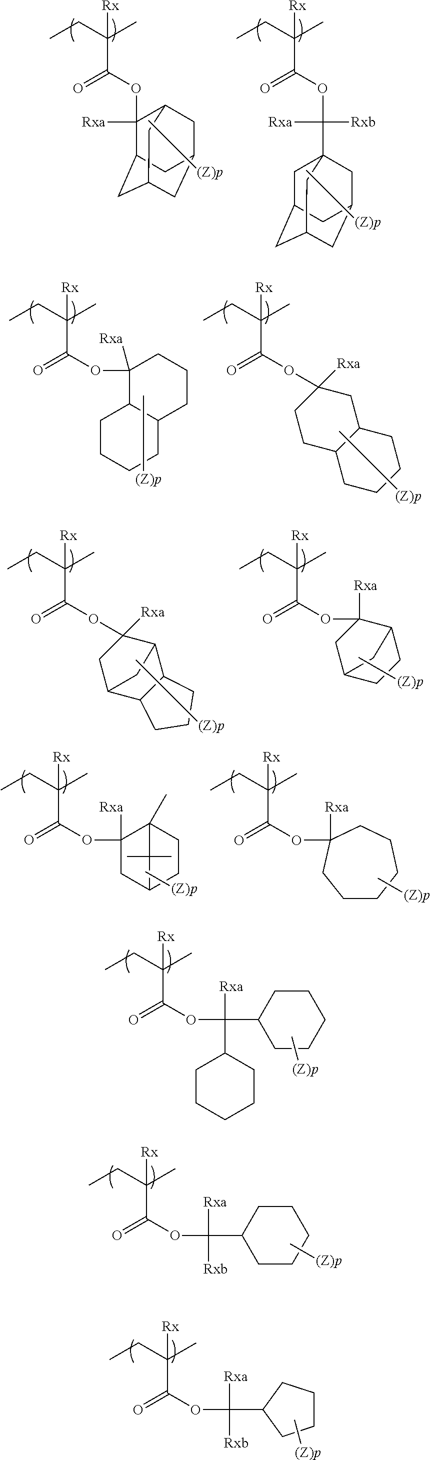

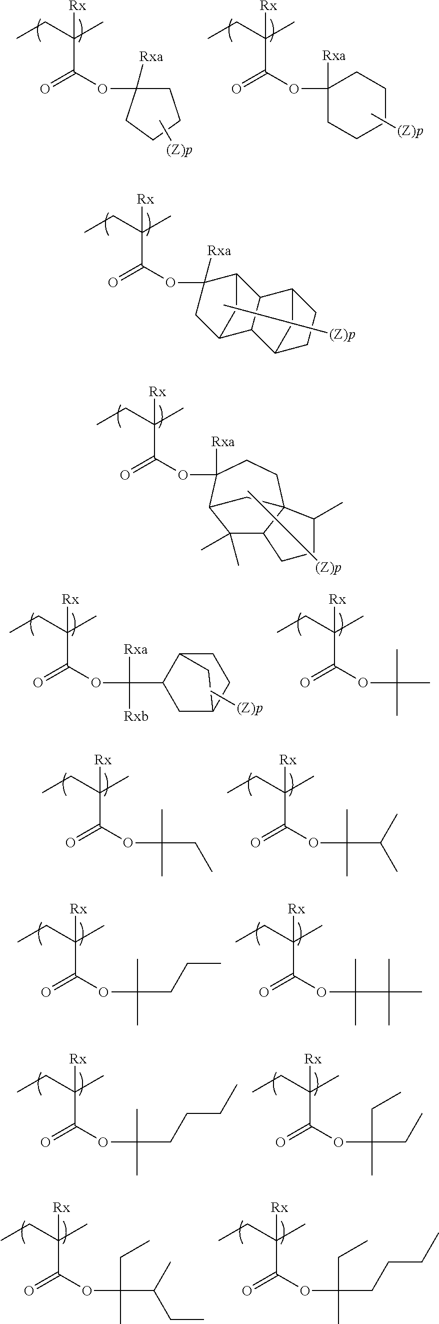

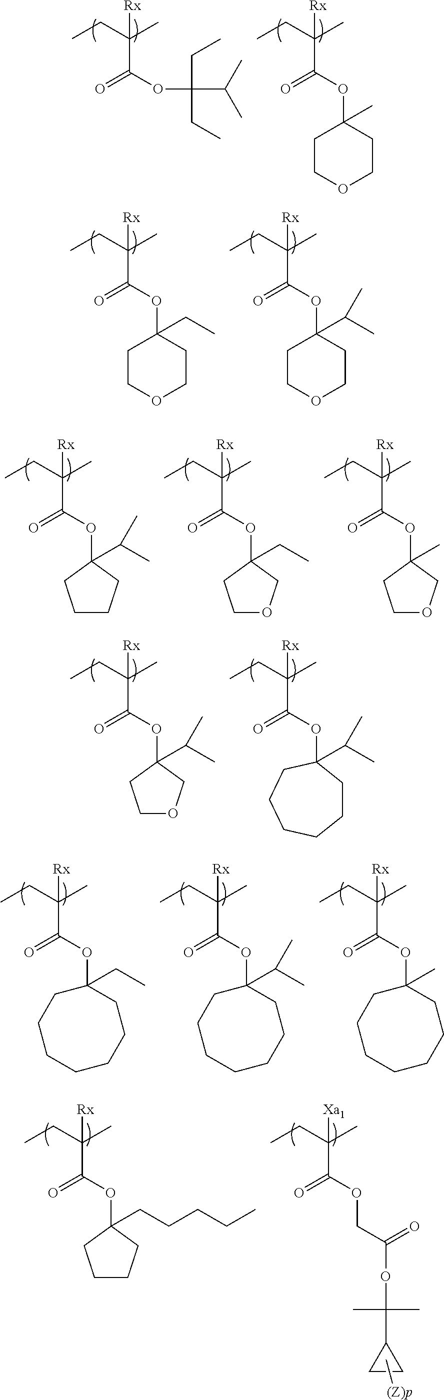

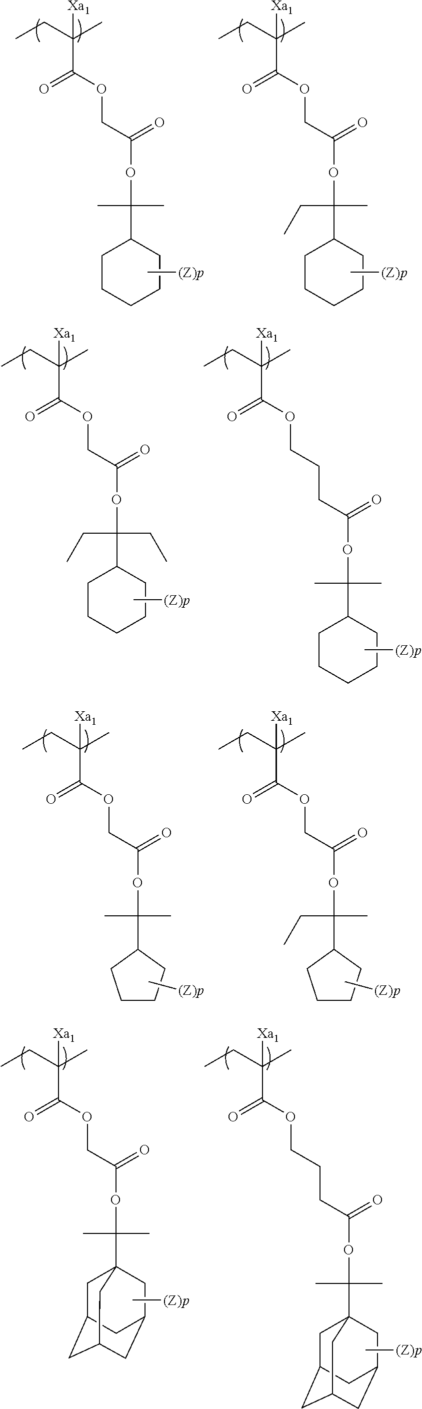

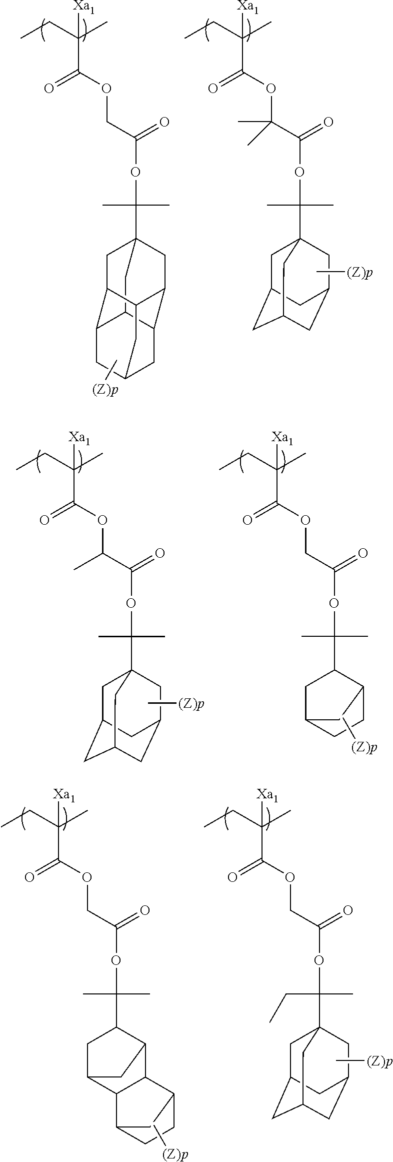

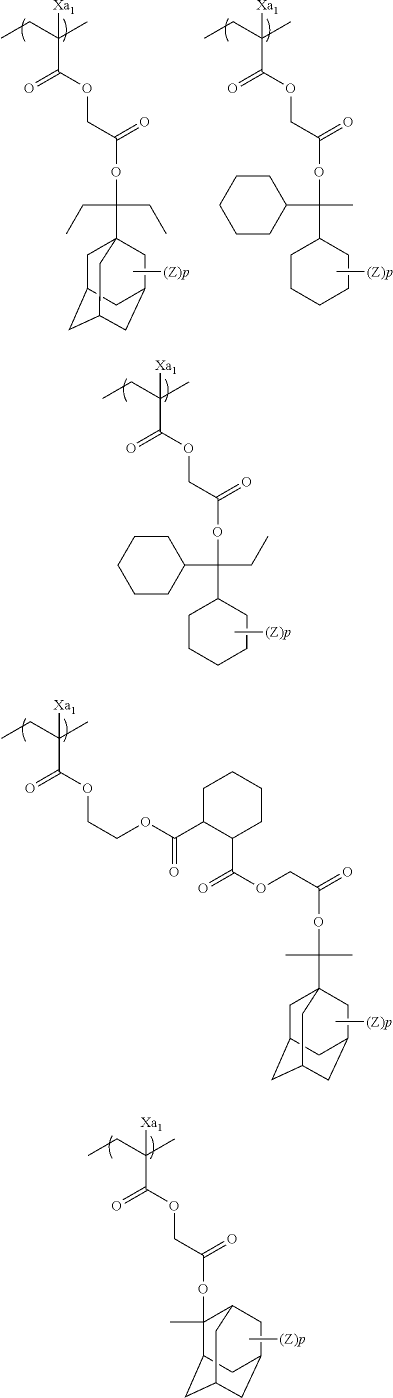

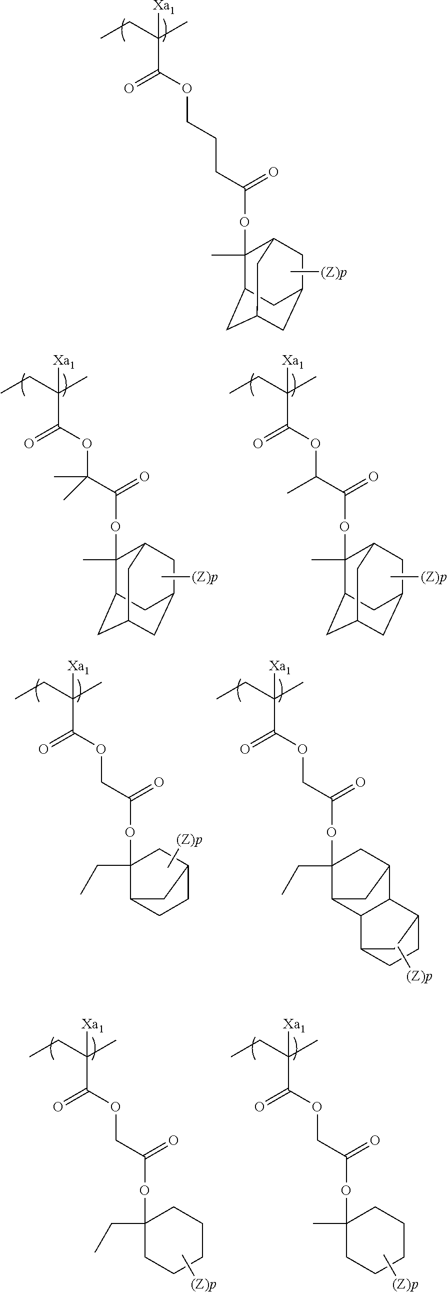

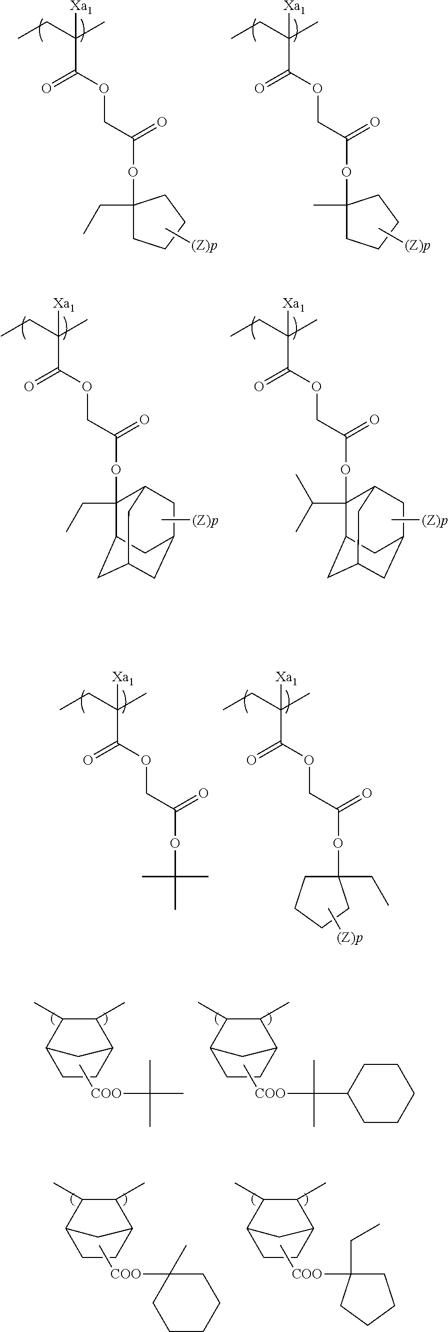

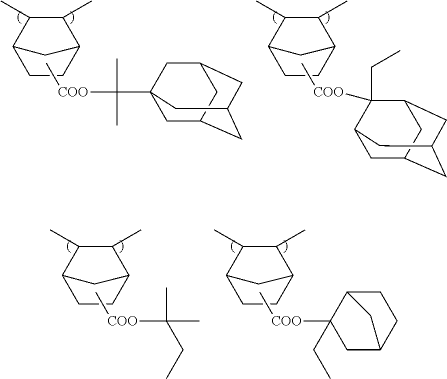

In addition, it is also preferable that the resin (A) has a repeating unit represented by following General Formula (IV) as the repeating unit containing an acid-decomposable group.

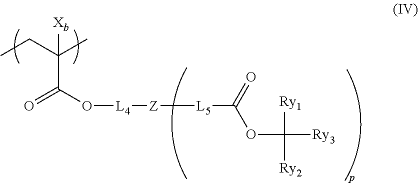

In General Formula (IV), X_{b} represents a hydrogen atom, an alkyl group, a cyano group, or a halogen atom.

Ry₁ to Ry₃ each independently represent an alkyl group or a cycloalkyl group, and two members out of Ry₁ to Ry₃ may be bonded to each other to form a ring.

Z represents a (p+1)-valent linking group having a polycyclic hydrocarbon structure, which may have a heteroatom as a ring member thereof. It is preferable that Z contains no ester bond in an atomic group constituting the polycyclic ring (or equivalently, it is preferable that Z contains no lactone ring as a ring constituting the polycyclic ring).

L₄ and L₅ each independently represent a single bond or a divalent linking group.

p represents an integer of 1 to 3.

When p is 2 or 3, a plurality of L₅'s, a plurality of Ry₁'s, a plurality of Ry₂'s, and a plurality of Ry₃'s may be the same as or different from each other.

The alkyl group of X_{b} may have a substituent, and examples of the substituent include a hydroxyl group and a halogen atom (preferably a fluorine atom).

The alkyl group of X_{b} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b} is preferably a hydrogen atom or a methyl group.

Specific examples and preferred examples of the alkyl group and the cycloalkyl group of Ry₁ to Ry₃ are the same as the specific examples and the preferred examples of the alkyl group and the cycloalkyl group of Rx₁ to Rx₃ in General Formula (AI).

Specific examples and preferred examples of the ring structure formed by the mutual bonding of two members of Ry₁ to Ry₃ are the same as the specific examples and the preferred examples of the ring structure formed by the mutual bonding of two members of Rx₁ to Rx₃ in General Formula (AI).

Ry₁ to Ry₃ are each independently preferably an alkyl group, and more preferably a linear or branched alkyl group having 1 to 4 carbon atoms. Further, the total number of carbon atoms in the chained or branched alkyl group as Ry₁ to Ry₃ is preferably 5 or less.

Ry₁ to Ry₃ may further have a substituent, and examples of the substituent are the same ones as the above-described substituents, which each of Rx₁ to Rx₃ in General Formula (AI) may further have.

Examples of the linking group having a polycyclic hydrocarbon structure of Z include a ring-assembly hydrocarbon ring group and a crosslinked cyclic hydrocarbon ring, and may further include a group formed by removing (p+1) arbitrary hydrogen atoms from a ring-assembly hydrocarbon ring group and a group formed by removing (p+1) arbitrary hydrogen atoms from a crosslinked cyclic hydrocarbon ring.

The linking group having a polycyclic hydrocarbon structure, represented by Z, may have a substituent. Examples of the substituent that Z may have include a substituent such as an alkyl group, a hydroxyl group, a cyano group, a keto group (an alkylcarbonyl group or the like), an acyloxy group, —COOR, —CON(R)₂, —SO₂R, —SO₃R, and —SO₂N(R)₂. Here, R represents a hydrogen atom, an alkyl group, a cycloalkyl group, or an aryl group.

The alkyl group, the alkylcarbonyl group, the acyloxy group, —COOR, —CON(R)₂, —SO₂R, —SO₃R, and —SO₂N(R)₂ as the substituent that Z may have may further have a substituent. Examples of such a substituent include a halogen atom (preferably a fluorine atom).

In the linking group having a polycyclic hydrocarbon structure, represented by Z, carbon constituting the polycyclic ring (carbon contributing to ring formation) may be carbonyl carbon. Further, the polycyclic ring may contain, as mentioned above, a heteroatom such as an oxygen atom and a sulfur atom as a ring member. However, as mentioned above, Z contains no ester bond as an atomic group constituting the polycyclic ring.

Examples of the linking groups represented by L₄ and L₅ include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), and a linking group formed by combination of a plurality of these groups. The linking groups having a total number of carbon atoms of 12 or less is preferable.

L₄ is preferably a single bond, an alkylene group, —COO—, —OCO—, —CONH—, —NHCO—,-alkylene group-COO—, -alkylene group-OCO—, -alkylene group-CONH—, -alkylene group—NHCO—, —CO—, —O—, —SO₂—, or -alkylene group-O—, and more preferably a single bond, an alkylene group, -alkylene group-COO— or -alkylene group-O—.

L₅ is preferably a single bond, an alkylene group, —COO—, —OCO—, —CONH—, —NHCO—, —COO-alkylene group-, —OCO-alkylene group-, —CONH-alkylene group-, —NHCO-alkylene group-, —CO—, —O—, —SO₂—, —O-alkylene group-, or —O-cycloalkylene group-, and more preferably a single bond, an alkylene group, —COO-alkylene group-, —O-alkylene group-, or —O-cycloalkylene group-.

In the description method above, the bonding arm “-” at the left end means to be bonded to an ester bond on the main chain side in L₄ and bonded to Z in L₅, while the bonding arm “-” at the right end means to be bonded to Z in L₄and an ester bond connected to a group represented by (Ry₁)(Ry₂)(Ry₃)C— in L₅.

Incidentally, L₄ and L₅ may be bonded to the same atom constituting the polycyclic ring in Z.

p is preferably 1 or 2, and more preferably 1.

Specific examples of the repeating unit represented by General Formula (IV) are shown below, but the present invention is not limited thereto. In specific examples below, Xₐ represents a hydrogen atom, an alkyl group, a cyano group, or a halogen atom.

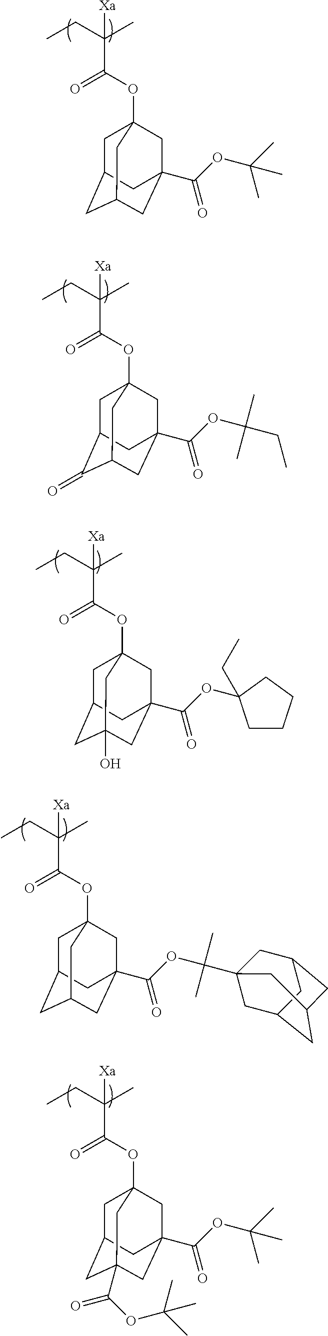

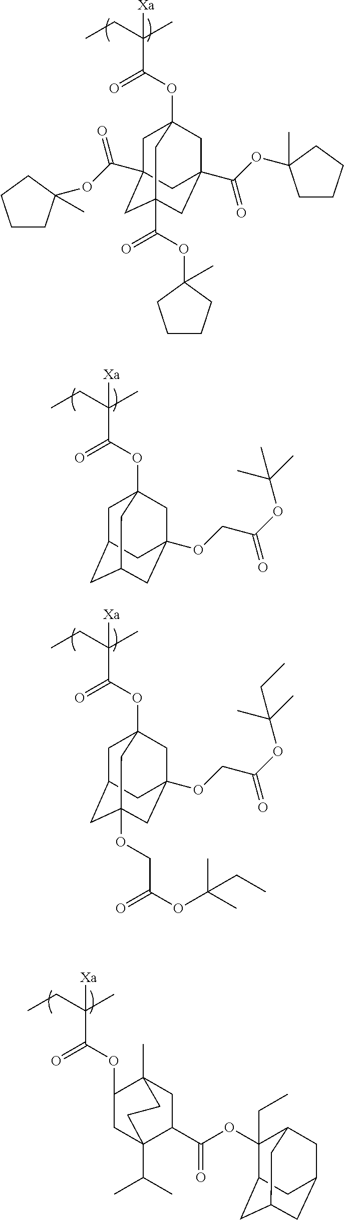

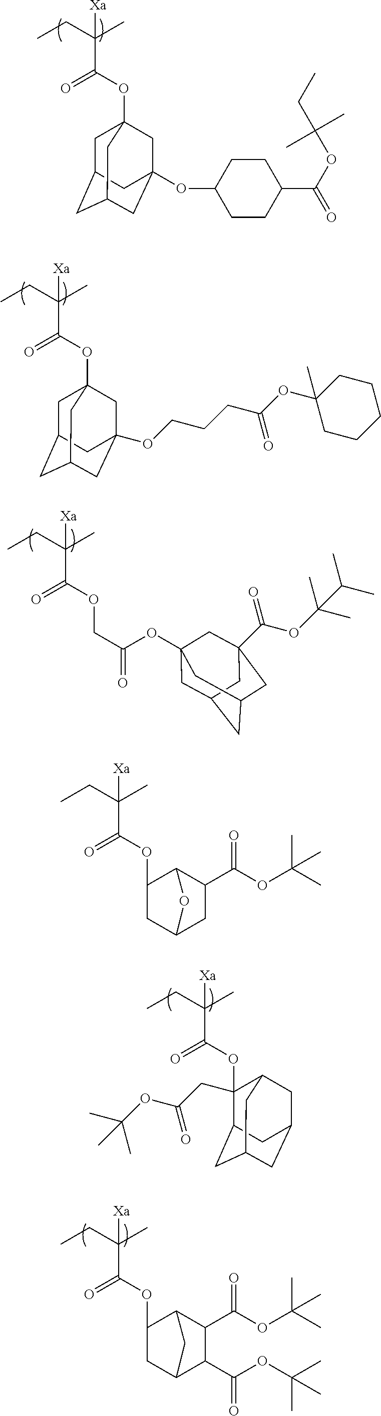

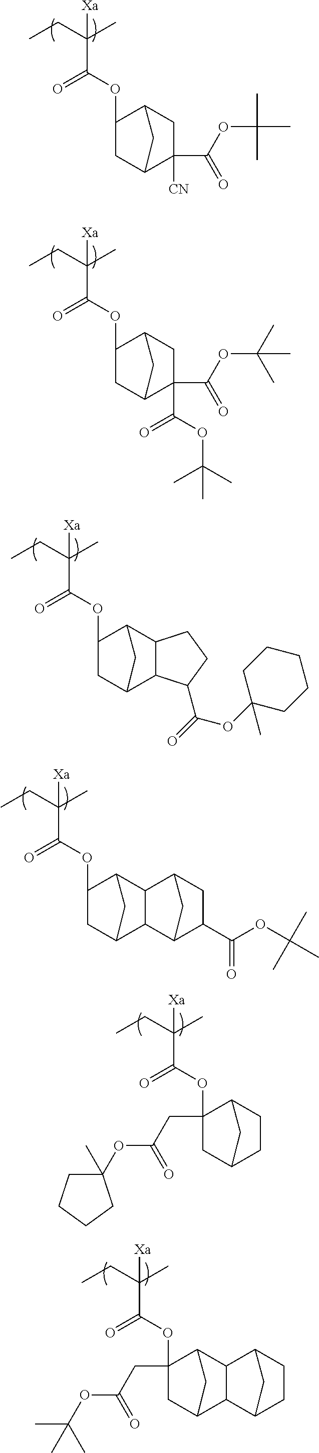

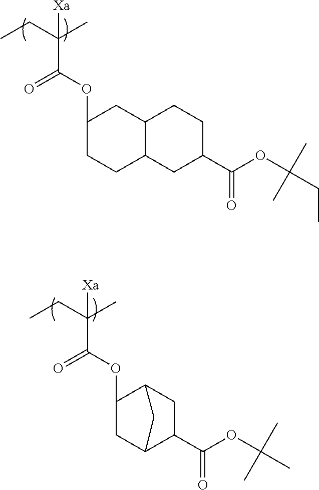

Furthermore, the resin (A) may contain a repeating unit capable of decomposing by the action of an acid to generate an alcoholic hydroxyl group as shown below, as the repeating unit containing an acid-decomposable group.

In the following specific examples, Xa₁ represents a hydrogen atom, CH₃, CF₃, or CH₂OH.

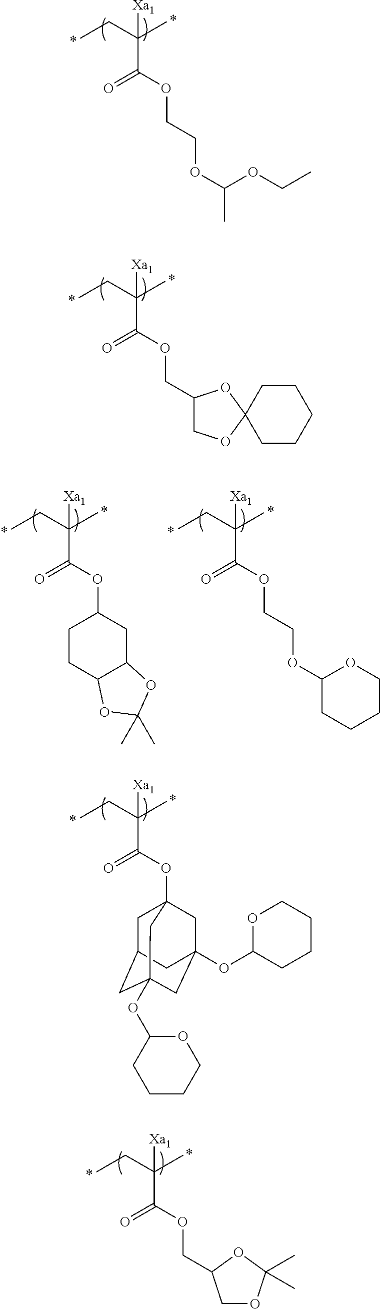

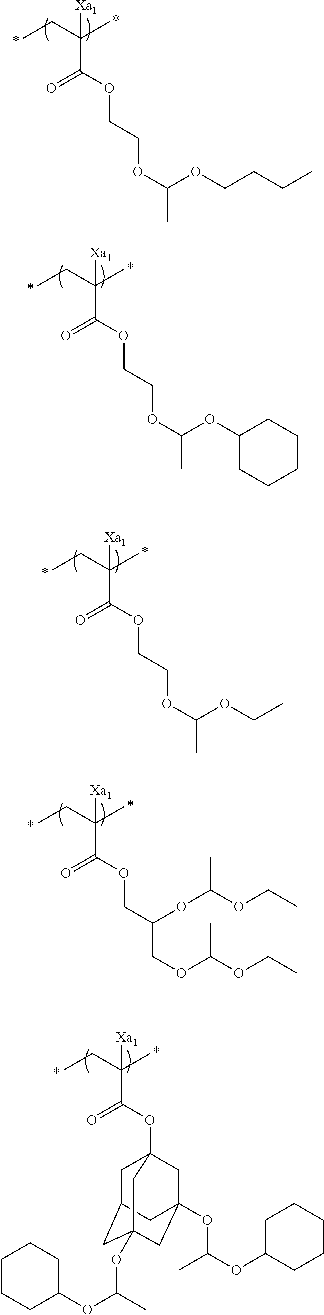

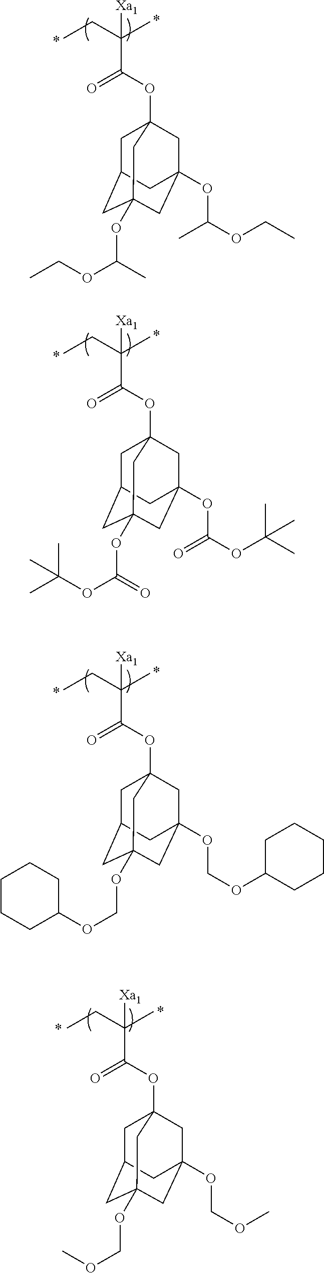

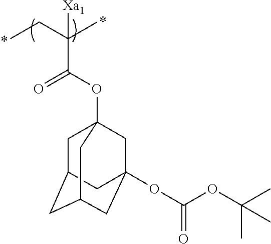

The repeating units containing an acid-decomposable group can be used alone or in combination of two or more kinds thereof.

The combination in the case where the resin (A) includes two or more kinds of repeating units containing an acid-decomposable group is not particularly limited in the present invention, and examples thereof are shown below.

In the following specific examples, R represents a hydrogen atom, CH₃, CF₃, or CH₂OH.

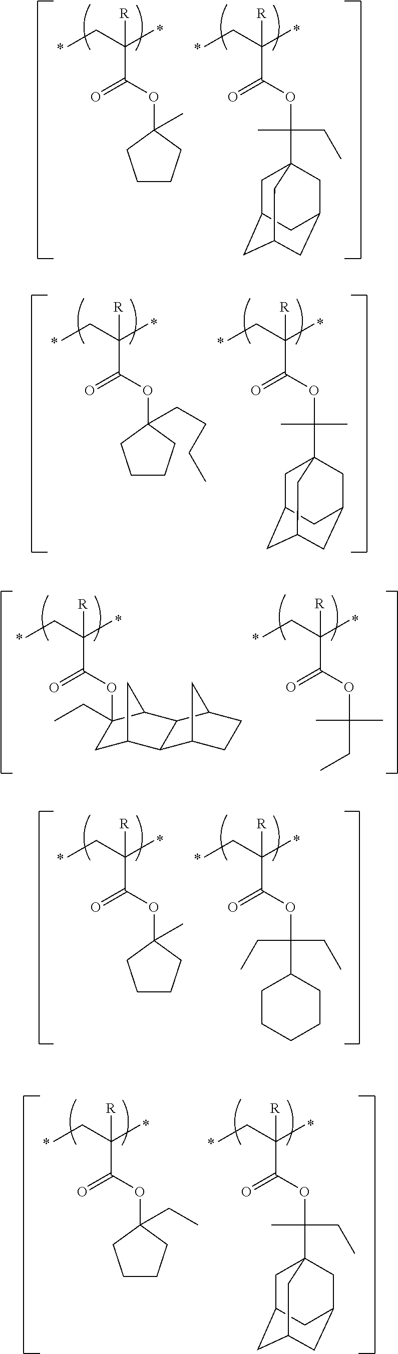

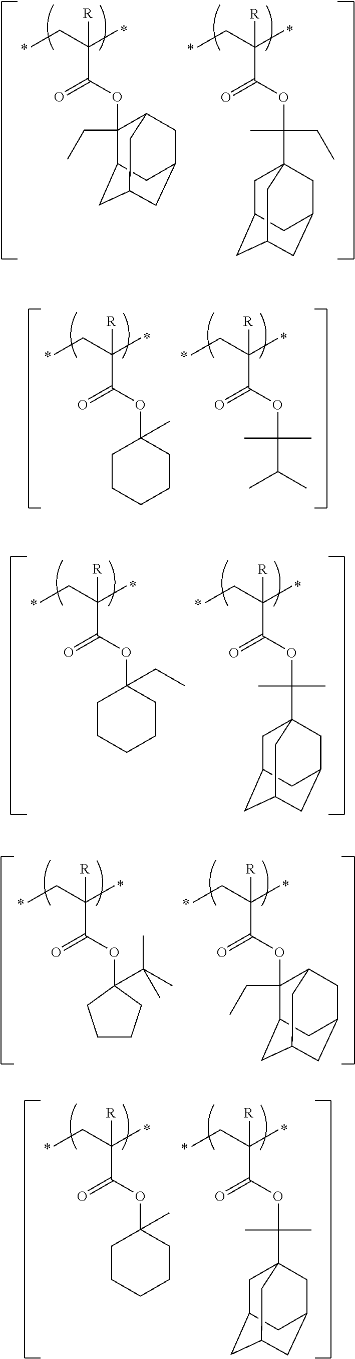

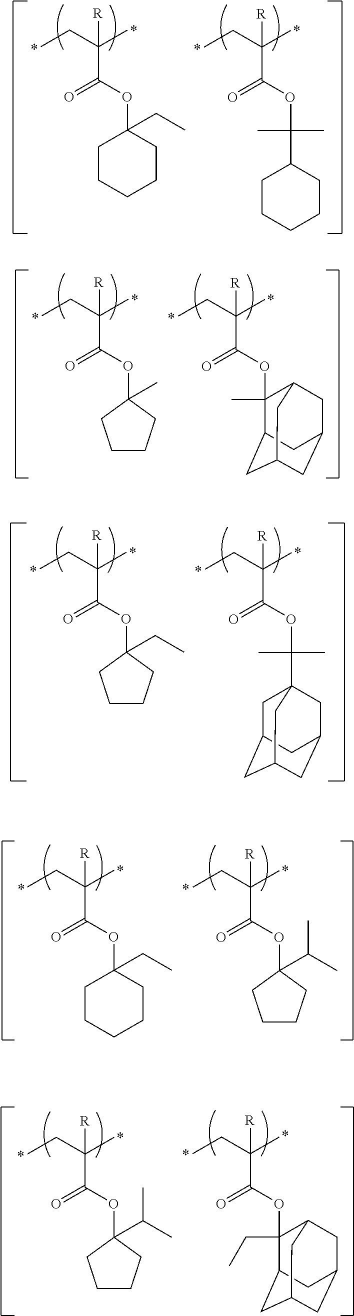

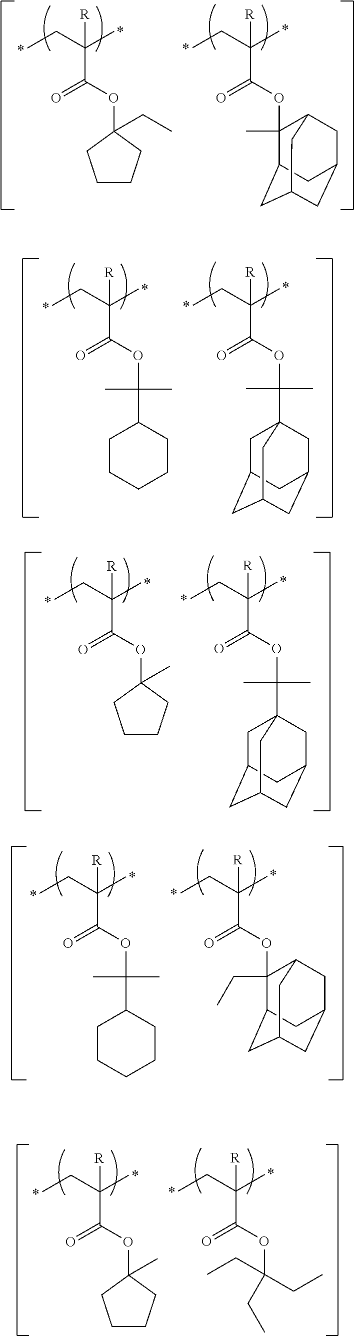

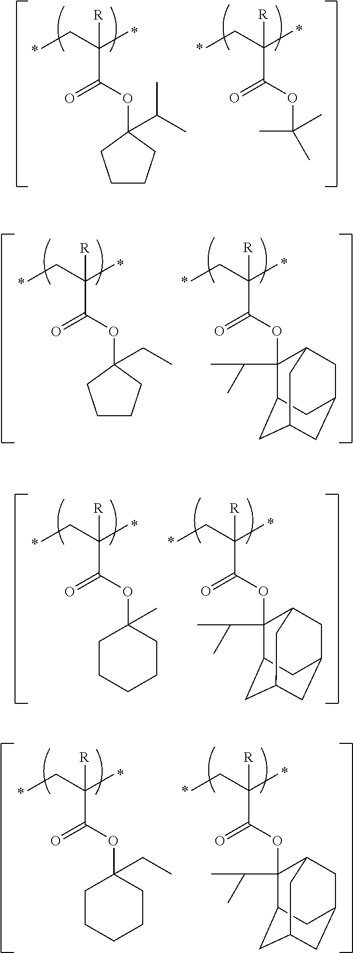

The content of the repeating units containing an acid-decomposable group contained in the resin (A) (the total thereof in the case where a plurality of repeating units having acid-decomposable groups are present) is preferably 15% by mole or more, more preferably 20% by mole or more, still more preferably 25% by mole or more, and particularly preferably 40% by mole or more, with respect to all the repeating units in the resin (A). Among these, it is preferable that the resin (A) has the repeating units represented by General Formula (AI) and the content of the repeating units represented by General Formula (AI) is 40% by mole or more with respect to all the repeating units in the resin (A).

In addition, the content of the repeating units containing an acid-decomposable group is preferably 80% by mole or less, more preferably 70% by mole or less, and still more preferably 65% by mole or less, with respect to all the repeating units in the resin (A)

[Repeating Unit (P2) Having Acid Group]

In the first embodiment of the present invention, it is preferable that the resin (A) has a repeating unit (P2) containing an acid group as described above.

Examples of the acid group include a carboxyl group, a sulfonamido group, a sulfonylimido group, a bissulfonylimido group, a naphthol structure, and an aliphatic alcohol group (for example, a hexafluoroisopropanol group), of which the α-position is substituted with an electron withdrawing group, it is more preferable that the resin (A) has a repeating unit having a carboxyl group or a sulfonic acid group, and it is still more preferable that the resin (A) has a repeating unit having a carboxyl group. As the repeating unit containing an acid group, any of the repeating units in which the acid group is bonded directly to the main chain of the resin such as a repeating unit consisting of an acrylic acid or a methacrylic acid, a repeating unit in which the acid group is bonded to the main chain of the resin through a linking group, or introducing the repeating unit to the end of the polymer chain using a polymerization initiator or a chain transfer agent containing an acid group at the time of polymerization is preferable, and the linking group may have a monocyclic or polycyclic cyclic hydrocarbon structure. A repeating structure consisting of an acrylic acid or a methacrylic acid is particularly preferable.

Furthermore, by treating the repeating unit (P2) containing an acid group with an ionic compound (S), a resin (A) having a repeating unit (P3), containing an acid group which forms a salt capable of decreasing the solubility in the developer as described above, can be preferably produced.

The repeating unit (P2) containing an acid group preferably has a pKa of 0.0 to 10.0, more preferably has a pKa of 2.0 to 9.0, and still more preferably has a pKa of 3.0 to 8.0.

These pKa ranges are suitable for exchange (neutralization) between a proton contained in an acid group of the repeating unit (P2) and a cationic moiety of the ionic compound (S), for which the ranges are suitable for formation of an ionic group obtained by forming a salt with an acid group.

In the present invention, the pKa of the repeating unit (P2) means a pKa which is calculated for the monomeric material (monomer) corresponding to the repeating unit (P2).

In the present invention, the acid group is not particularly limited, and examples thereof include a carboxylic acid group and a sulfonic acid group, with the carboxylic acid group being preferable.

The content of the repeating unit (P2) containing an acid group is preferably 25% by mole or less, more preferably 20% by mole or less, and still more preferably 15% by mole or less, with respect to all the repeating units in the resin (A). In the case where the resin (A) contains a repeating unit containing an acid group, the content of the repeating unit containing an acid group in the resin (A) is preferably 1% by mole or more, more preferably 3% by mole or more, and still more preferably 5% by mole or more.

Specific examples of the repeating unit (P2) containing an acid group will be shown below, but the present invention is not limited to these. The pKa in the following specific examples is a value calculated from the corresponding monomers.

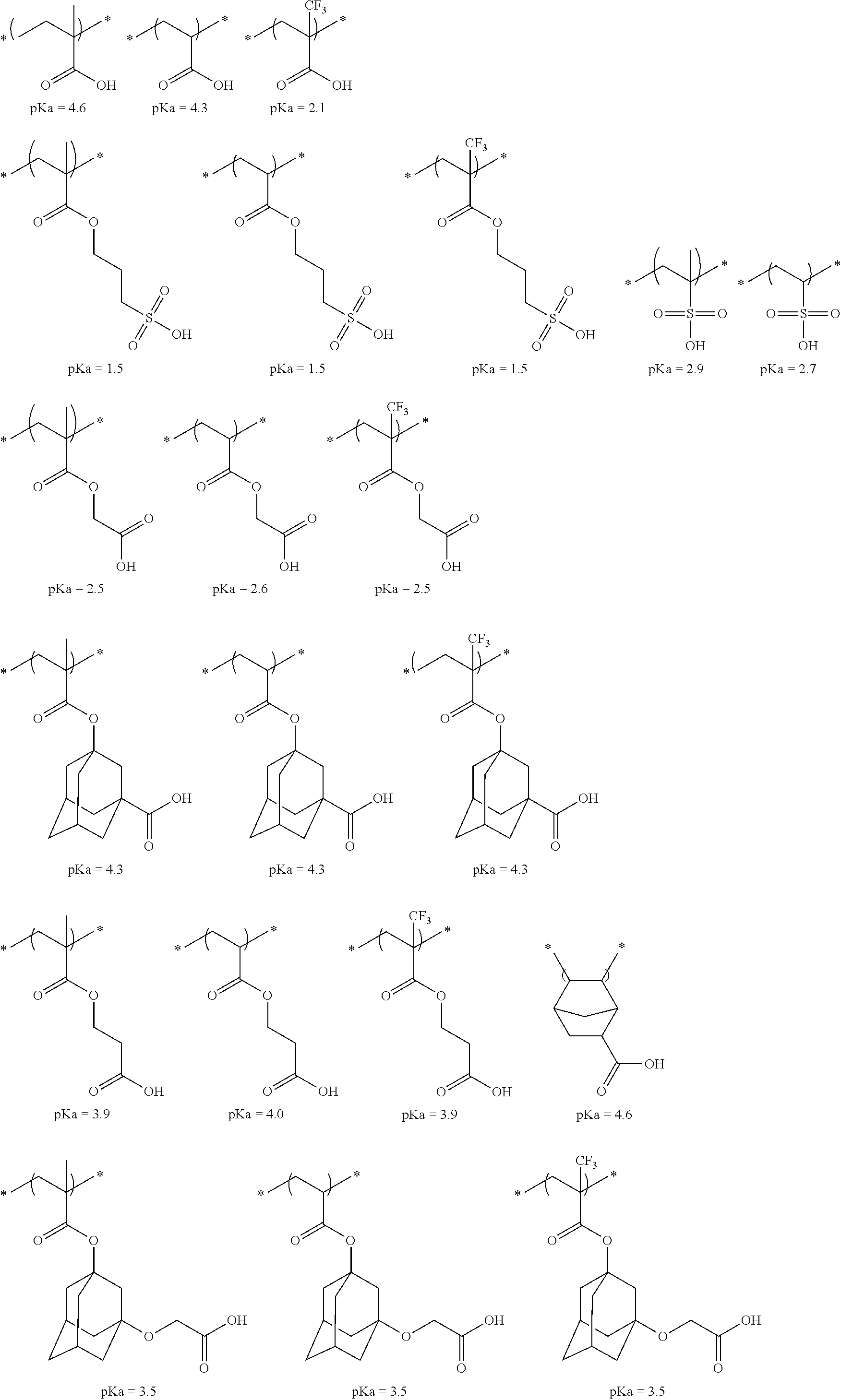

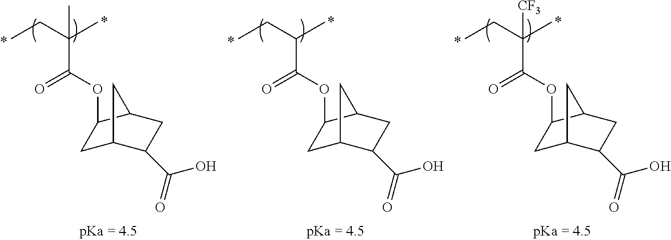

[Repeating Unit (P3) Having Ionic Group Obtained by Forming Salt with Acid Group]

In the second embodiment of the present invention, it is preferable that the resin (A) has a repeating unit (P3) containing an ionic group obtained by forming a salt with an acid group as described above.

The ionic group obtained by forming a salt with an acid group in the repeating unit (P3) is more preferably a salt formed of an anion (conjugated base) derived from an acid group of the aforementioned repeating unit (P2) and a cationic moiety in the aforementioned ionic compound (S).

The content of the repeating unit (P3) containing an ionic group obtained by forming a salt with an acid group is preferably 25% by mole or less, more preferably 20% by mole or less, and still more preferably 15% by mole or less, with respect to all the repeating units in the resin (A). In the case where the resin (A) contains a repeating unit containing an acid. group, the content of the repeating unit (P3) in the resin (A) is preferably 1% by mole or more, more preferably 3% by mole or more, and still more preferably 5% by mole or more.

Specific examples of the repeating unit (P3) containing an ionic group obtained by forming a salt with an acid group are shown below, but the present invention is not limited thereto.

In the specific examples, Rx represents H, CH₃, CH₂OH, or CF₃.

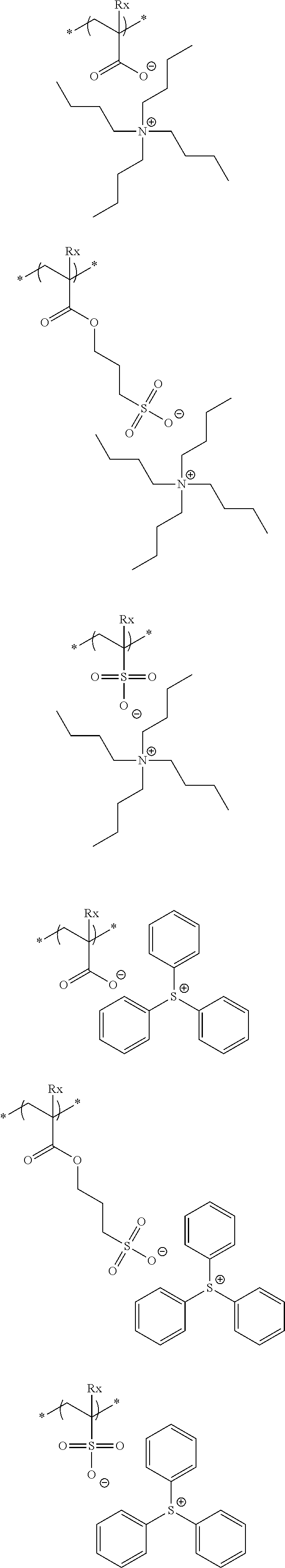

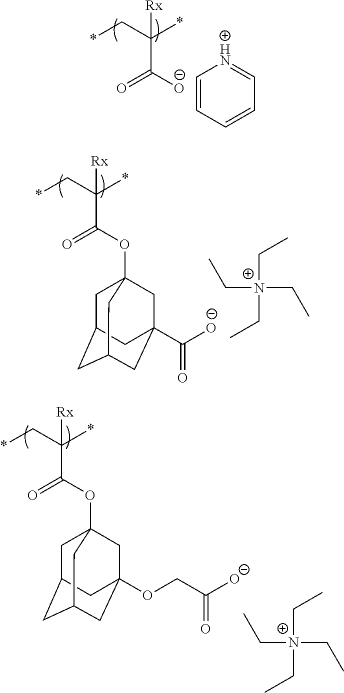

[Other Repeating Units]

The resin (A) may contain a repeating unit having a lactone structure or a sultone structure.

As the lactone structure or the sultone structure, any structure may be used as long as it has a lactone structure or a sultone structure, but the structure is preferably a 5- to 7-membered ring lactone structure or a 5- to 7-membered ring sultone structure, and more preferably a 5- to 7-membered ring lactone structure to which another ring structure is fused in the form of forming a bicyclo or spiro structure, or a 5- to 7-membered ring sultone structure to which another ring structure is fused in the form of forming a bicyclo or spiro structure. The resin still more preferably has a repeating unit having a lactone structure represented by any one of the following General Formulae (LC1-1) to (LC1-21) or a sultone structure represented by any one of the following General Formulae (SL1-1) to (SL1-3). The intone structure or sultone structure may be bonded directly to the main chain. Preferred lactone structures are (LC1-1), (LC1-4), (LC1-5), (LC1-6), (LC1-13), (LC1-14), and (LC1-17), with the lactone structure of (LC1-4) being particularly preferable. By using such a specific lactone structure, LER and development defects are relieved.

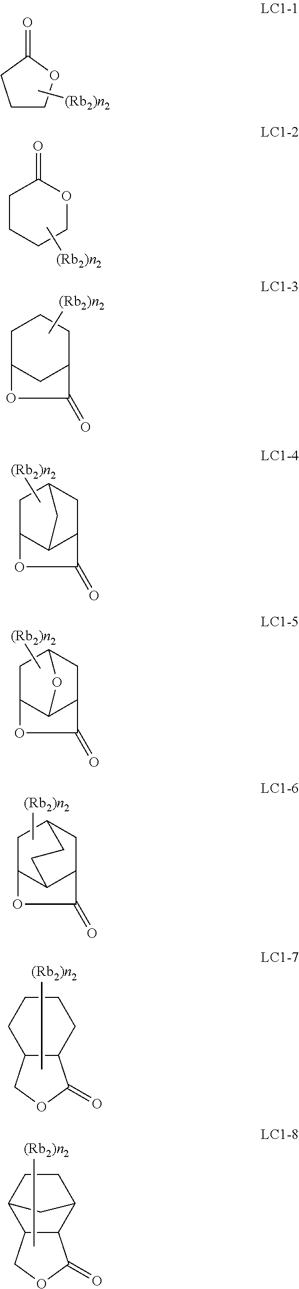

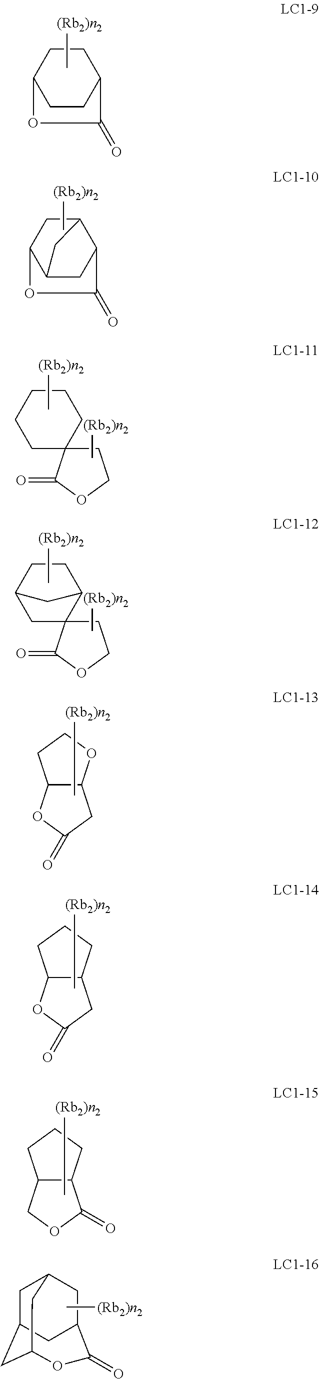

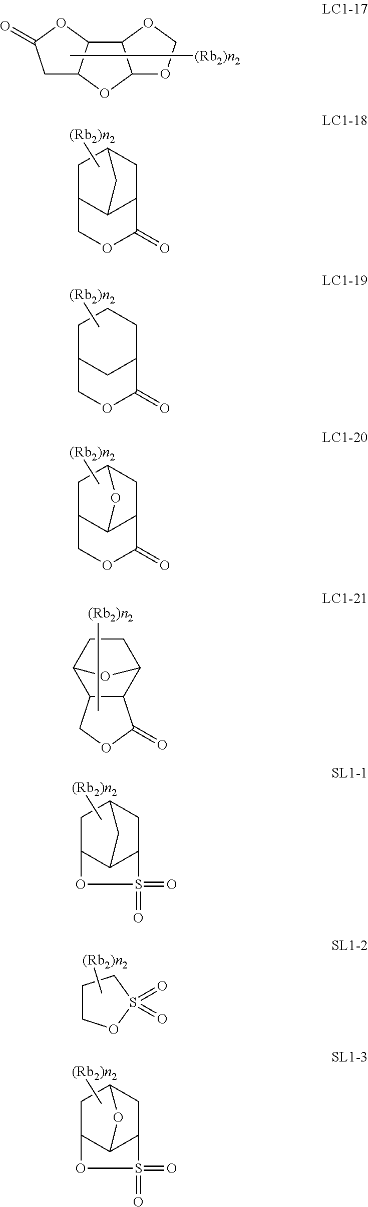

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferable. n₂ represents an integer of 0 to 4. When n₂ is an integer of 2 or more, a plurality of the substituents (Rb₂) which are present may be the same as or different from each other. Further, a plurality of the substituents (Rb₂) may be bonded to each other to form a ring.

The repeating unit having a lactone structure or a sultone structure usually has an optical isomer, and any optical isomer may be used. Further, one kind of optical isomer may be used alone or a plurality of optical isomers may be mixed and used. In the case of mainly using one kind of optical isomer, the optical purity (ee) thereof is preferably 90% or more, and more preferably 95% or more.

The repeating unit having a lactone structure or a sultone structure is preferably a repeating unit represented by the following General Formula (III).

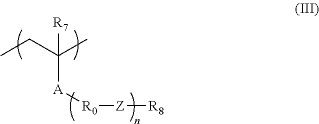

In General Formula (III),

A represents an ester bond (a group represented by —COO—) or an amide bond (a group represented by —CONH—),

in the case where a plurality of R₀'s are present, R₀'s each independently represent an alkylene group, a cycloalkylene group, or a combination thereof, and

in the case where a plurality of Z's are present, Z's each independently represent a single bond, an ether bond, an ester bond, an amide bond, a urethane bond, a group represented by the following General Formula:

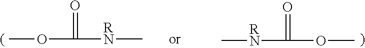

an urea bond, or a group represented by the following General Formula:

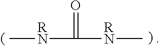

Here, R's each independently represent a hydrogen atom, an alkyl group, a cycloalkyl group, or an aryl group,

R₈ represents a monovalent organic group having a lactone structure or a sultone structure,

n is the repetition number of the structure represented by —R₀—Z—, and represents an integer of 0 to 5, preferably 0 or 1, and more preferably 0, and in the case where n is 0, —R₀—Z— is not present and a single bond is formed, and

R₇ represents a hydrogen atom, a halogen atom, or an alkyl group.

The alkylene group and the cycloalkylene group of R₀ may have a substituent.

Z is preferably an ether bond or an ester bond, and more preferably an ester bond.

The alkyl group of R₇ is preferably an alkyl group having 1 to 4 carbon atoms, more preferably a methyl group or an ethyl group, and particularly preferably a methyl group.

The alkylene group and the cycloalkylene group of R₀, and the alkyl group in R₇ may be each substituted, and examples of the substituent include a halogen atom such as a fluorine atom, a chlorine atom; and a bromine atom, a mercapto group, a hydroxyl group, an alkoxy group, and an acyloxy group.

R₇ is preferably a hydrogen atom, a methyl group, a trifluoromethyl group, or a hydroxymethyl group.

The preferred chained alkylene group in R₀ is chained alkylene, preferably having 1 to 10 carbon atoms, and more preferably having 1 to 5 carbon atoms. Preferred examples of the cycloalkylene group include a cycloalkylene group having 3 to 20 carbon atoms. In order to express the effects of the present invention, a chained alkylene group is more preferable, and a methylene group is particularly preferable.

The monovalent organic group having a lactone structure or a sultone structure represented by R₈ is not limited as long as it has a lactone structure or a sultone structure. Specific examples thereof include ones having a lactone structure or a sultone structure represented by any one of General Formulae (LC1-1) to (LC1-21) and (SL1-1) to (SL1-3), with the structure represented by (LC1-4) being particularly preferable. In (LC1-1) to (LC1-21), n₂ is preferably 2 or less.

Furthermore, R₈ is preferably a monovalent organic group having an unsubstituted lactone structure or sultone structure, or a monovalent organic group having a lactone structure or a sultone structure having a methyl group, a cyano group, or an alkoxycarbonyl group as a substituent, and more preferably a monovalent organic group having a lactone structure having a cyano group as a substituent (cyanolactone).

Specific examples of the repeating unit having a group having a lactone structure or a sultone structure are shown below, but the present invention is not limited thereto.

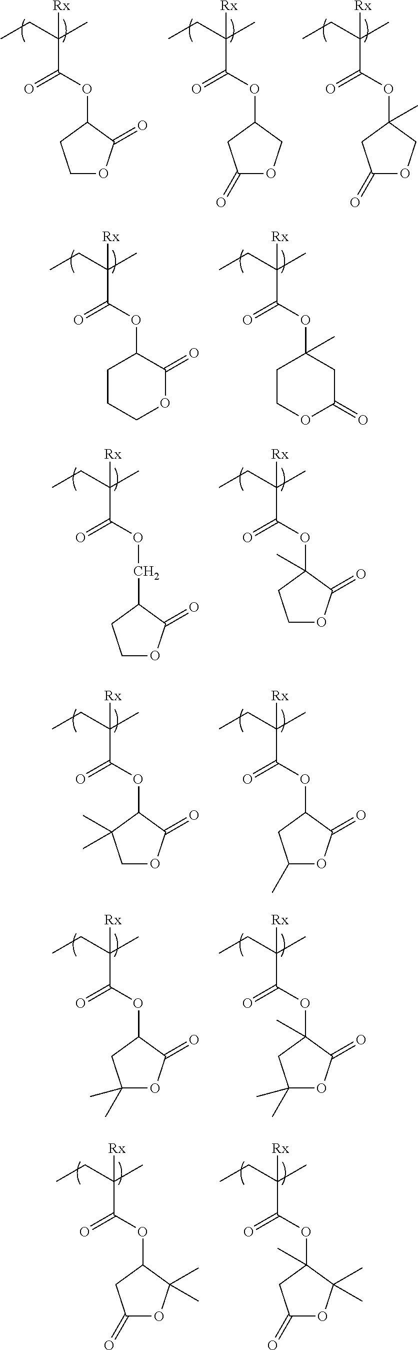

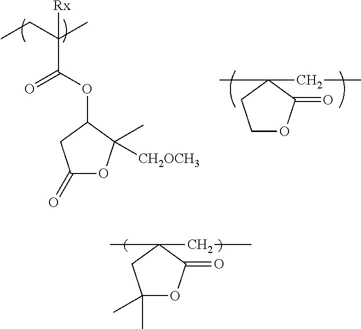

(in the formulae, Rx represents H, CH₃, CH₂H, or CF₃)

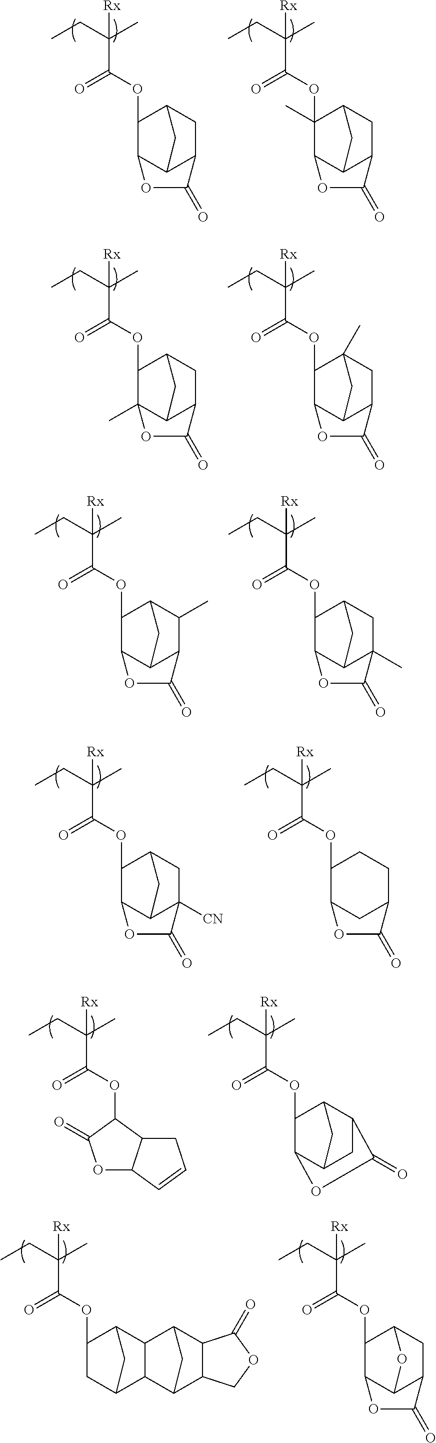

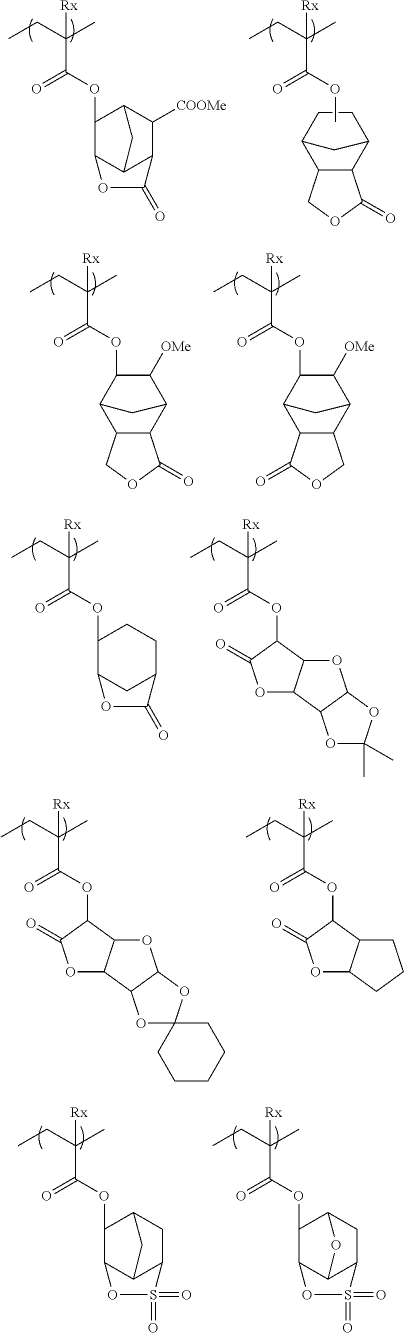

(in the formulae, Rx represents H, CH₃, CH₂OH, or CF₃)

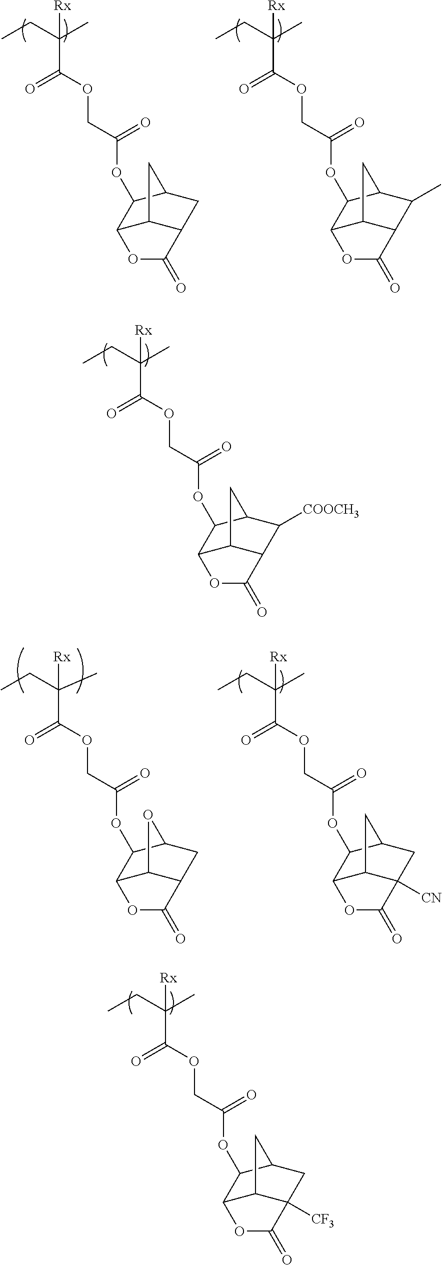

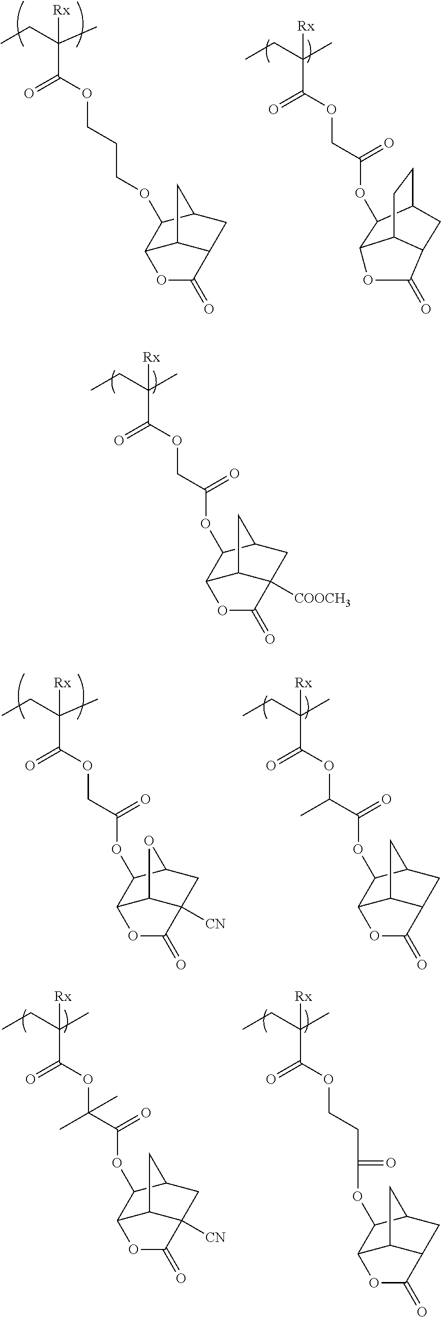

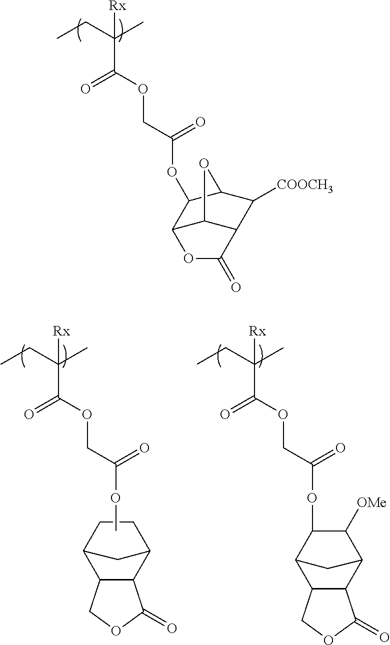

(in the formulae, Rx represents H, CH₃, CH₂OH, or CF₃)

In order to enhance the effects of the present invention, it is also possible to use two or more kinds of repeating units having a lactone structure or a sultone structure in combination.

In the case where the resin (A) contains the repeating units having a lactone structure or a sultone structure, the content of the repeating units having a lactone structure or a sultone structure is preferably 5% by mole to 60% by mole, more preferably 5% by mole to 55% by mole, and still more preferably 10% by mole to 50% by mole, with respect to all the repeating units in the resin (A).

Furthermore, the resin (A) may have a repeating unit having a cyclic carbonic ester structure.

The repeating unit having a cyclic carbonic ester structure is preferably a repeating unit represented by the following General Formula (A-1).

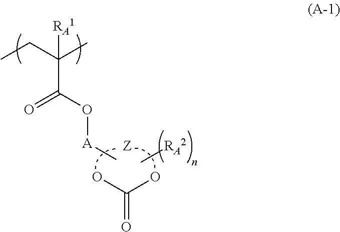

In General Formula (A-1),

R_{A}¹ represents a hydrogen atom or an alkyl group,

in the case where n is 2 or more, R_{A}²'s each independently represent a substituent,

A represents a single bond or a divalent linking group,

Z represents an atomic group which forms a monocyclic or polycyclic structure together with a group represented by —O—C(═O)—O— in the formula, and

n represents an integer of 0 or more.

General Formula (A-1) will be described in detail.

The alkyl group represented by R_{A}¹ may have a substituent such as a fluorine atom. R_{A}¹ preferably represents a hydrogen atom, a methyl group, or a trifluoromethyl group, and more preferably represents a methyl group.

The substituent represented by R_{A}² is, for example, an alkyl group, a cycloalkyl group, a hydroxyl group, an alkoxy group, an amino group, or an alkoxycarbonylamino group, and preferably an alkyl group having 1 to 5 carbon atoms. The alkyl group may have a substituent such as a hydroxyl group.

n represents the number of substituents and is an integer of 0 or more. n is, for example, preferably 0 to 4, and more preferably 0.

Examples of the divalent linking group represented by A include an alkylene group, a cycloalkylene group, an ester bond, an amide bond, an ether bond, a urethane bond, a urea bond, and a combination thereof. The alkylene group is preferably an alkylene group having 1 to 10 carbon atoms, and more preferably an alkylene group having 1 to 5 carbon atoms, and examples thereof include a methylene group, an ethylene group, and a propylene group.

In one embodiment of the present invention, A is preferably a single bond or an alkylene group.

Examples of the monocyclic ring containing —O—C(═O)—O— represented by Z include a 5- to 7-membered ring in which in a cyclic carbonic ester represented by the following General Formula (a), n_{A} is 2 to 4, and is preferably a 5- or 6-membered ring (n_{A} is 2 or 3), and more preferably a 5-membered ring (n_{A}=2).

Examples of the polycyclic ring containing —O—C(═O)—O— represented by Z include a structure in which a cyclic carbonic ester represented by the following General Formula (a) forms a fused ring together with another ring structure or two or more other ring structures, and a structure in which a spiro ring is formed. The “other ring structure” capable of forming a fused ring or a spiro ring may be any one of an alicyclic hydrocarbon group, an aromatic hydrocarbon group, and a heterocycle.

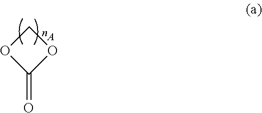

The monomer corresponding to the repeating unit represented by General Formula (A-1) can be synthesized by, for example, methods known in the related art, described in Tetrahedron Letters, Vol. 27, No. 32, p. 3741 (1986), Organic Letters, Vol. 4, No. 15, p. 2561 (2002), or the like.

The resin (A) may contain one kind of repeating units represented by General Formula (A-1) alone, or two or more kinds thereof.

In the resin (A), the content of the repeating unit having a cyclic carbonic ester structure (preferably the repeating units represented by General Formula (A-1)) is preferably 3% by mole to 80% by mole, more preferably 3% by mole to 60% by mole, particularly preferably 3% by mole to 30% by mole, and most preferably 10% by mole to 15% by mole, with respect to all the repeating units constituting the resin (A). By setting the content to such a range, the developability, low defect rates, low LWR, low PEB temperature dependency, profiles, and the like for the resist can be improved.

Specific examples (repeating units (A-1a) to (A-1w)) of the repeating unit represented by General Formula (A-1) are shown below, but the present invention is not limited thereto.

Moreover, in the following specific examples, R_{A}¹ has the same meaning as R_{A}¹ in General Formula (A-1).

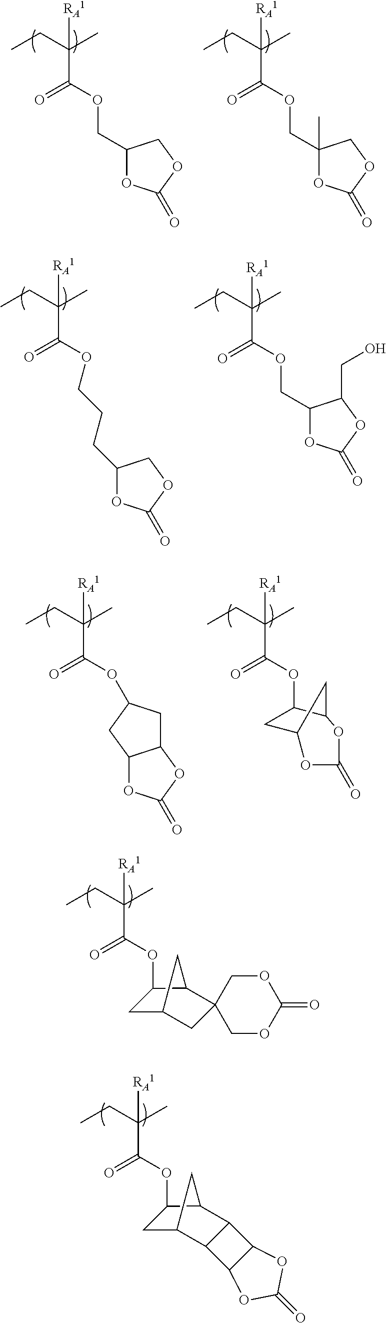

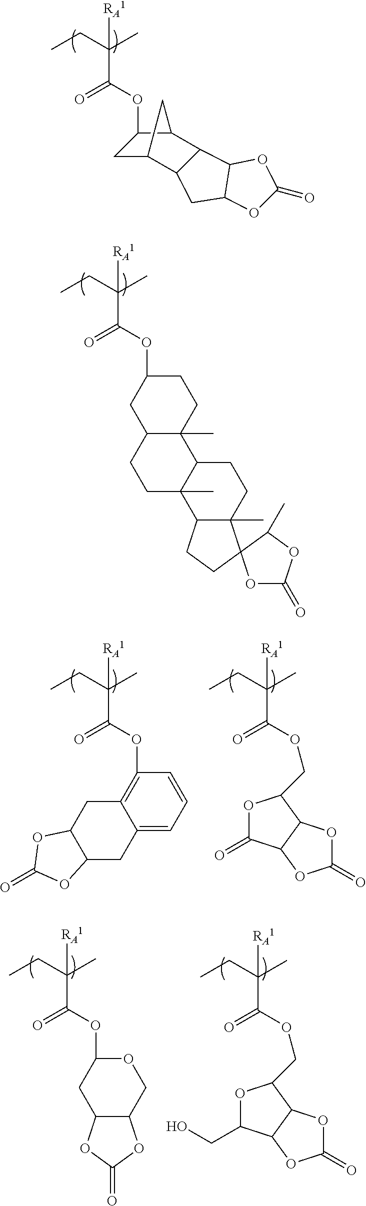

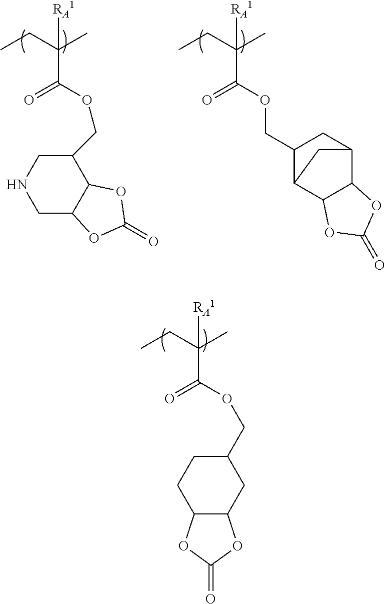

The resin (A) may contain a repeating unit having a hydroxyl group or a cyano group. With the repeating unit, the adhesion to a substrate and the affinity for developer are enhanced. The repeating unit having a hydroxyl group or a cyano group is preferably a repeating unit having an alicyclic hydrocarbon structure substituted with a hydroxyl group or a cyano group, and preferably has no acid-decomposable group.

Incidentally, the repeating unit having an alicyclic hydrocarbon structure substituted with a hydroxyl group or a cyano group is preferably different from the repeating unit containing an acid-decomposable group (that is, preferably a repeating unit which is stable against an acid).

The alicyclic hydrocarbon structure in the alicyclic hydrocarbon structure substituted with a hydroxyl group or a cyano group is preferably an adamantyl group, a diamantyl group, or a norbornane group.

More preferred examples of the repeating unit include a repeating unit represented by any one of the following General Formulae (AIIa) to (AIIe).

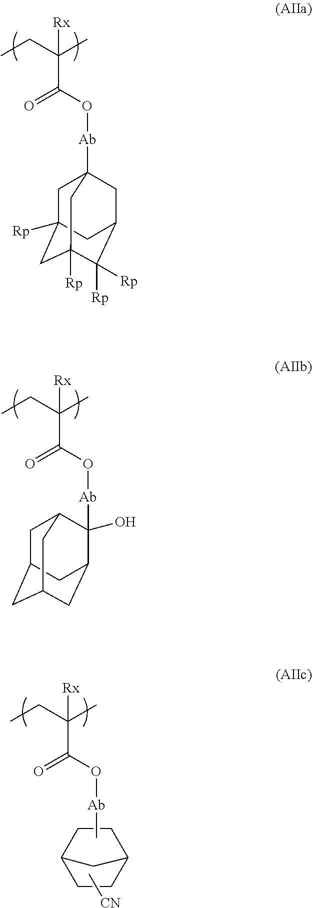

In the formulae, Rx represents a hydrogen atom, a methyl group, a hydroxymethyl group, or a trifluoromethyl group.

Ab represents a single bond or a divalent linking group.

Examples of the divalent linking group represented by Ab include an alkylene group, a cycloalkylene group, an ester bond, an amide bond, an ether bond, a urethane bond, a urea bond, and a combination thereof. The alkylene group is preferably an alkylene group having 1 to 10 carbon atoms, and more preferably an alkylene group having 1 to 5 carbon atoms, and examples thereof include a methylene group, an ethylene group, and a propylene group.

In one embodiment of the present invention, Ab is preferably a single bond or an alkylene group.

Rp represents a hydrogen atom, a hydroxyl group, or a hydroxyalkyl group. A plurality of Rp's may be the same as or different from each other, but at least one of a plurality of Rp's represents a hydroxyl group or a hydroxyalkyl group.

The resin (A) may or may not contain a repeating unit having a hydroxyl group or a cyano group, but in the case where the resin (A) contains a repeating unit having a hydroxyl group or a cyano group, the content of the repeating units having a hydroxyl group or a cyano group is preferably 1% by mole to 40% by mole, more preferably 3% by mole to 30% by mole, and still more preferably 5% by mole to 25% by mole, with respect to all the repeating units in the resin (A).

Specific examples of the repeating unit having a hydroxyl group or a cyano group are shown below, but the present invention is not limited thereto.

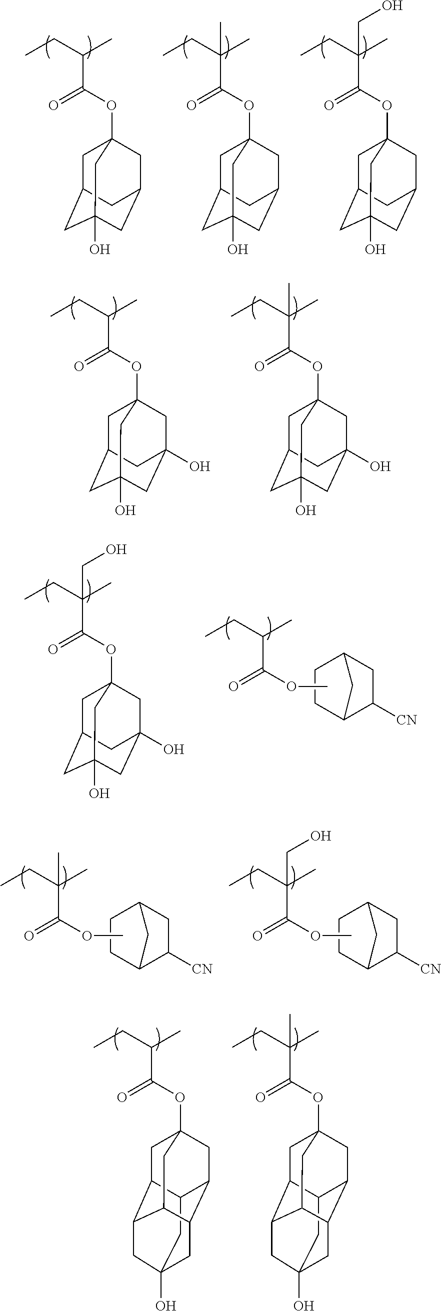

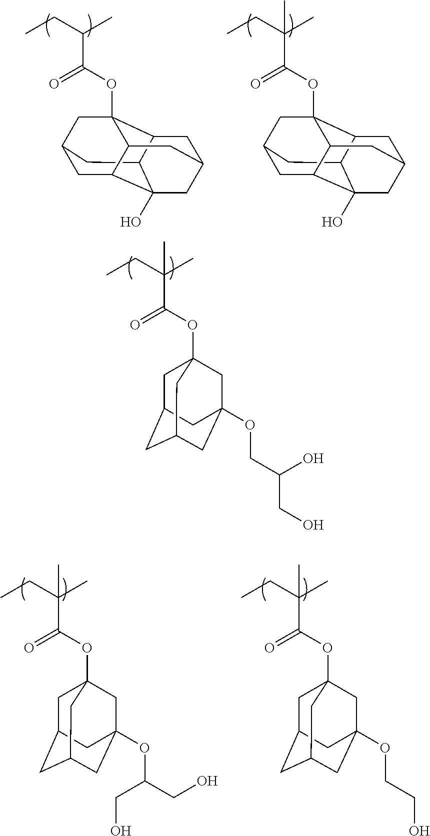

In addition, the monomers described in paragraph “0011” of WO2011/122336A, or the repeating units corresponding thereto can also be suitably used.

The resin (A) in the present invention may further contain a repeating unit having an alicyclic hydrocarbon structure having no polar group (for example, the acid groups, a hydroxyl group, and a cyano group) and not exhibiting acid-decomposability. With this repeating unit, elution of a low molecular component from the resist film to the immersion liquid can be reduced during the liquid immersion exposure and in addition, the solubility of the resin at the development using a developer including an organic solvent can be appropriately adjusted. Such a repeating unit contains a repeating unit represented by General Formula (IV).

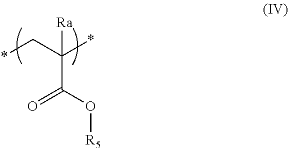

In General Formula (IV), R₅ represents a hydrocarbon group having at least one cyclic structure and having no polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

The cyclic structure contained in includes a monocyclic hydrocarbon group and a polycyclic hydrocarbon group. Preferred examples of the monocyclic hydrocarbon group include a cyclopentyl group and a cyclohexyl group.

Examples of the polycyclic hydrocarbon group include a ring-assembly hydrocarbon group and a crosslinked cyclic hydrocarbon group. Examples of the ring-assembly hydrocarbon group include a bicyclohexyl group and a perhydronaphthalenyl group, and examples of the crosslinked cyclic hydrocarbon ring include bicyclic hydrocarbon rings such as a pinane ring, a bornane ring, a norpinane ring, a norbornane ring, and a bicyclooctane ring (a bicyclo[2.2.2]octane ring, a bicyclo[3.2.1]octane ring, or the like); tricyclic hydrocarbon rings such as a homobledane ring, an adamantane ring, a tricyclo[5.2.1.0^{2,6}]decane ring, and a tricyclo[4.3.1.1.^{2,5}]undecane ring; and tetracyclic hydrocarbon rings such as a tetracyclo[4.4.0.1^{2,5}.1^{7,10}]dodecane ring and a perhydro'1,4-methano-5,8-methanonaphthalene ring. Other examples of the crosslinked cyclic hydrocarbon ring include fused cyclic hydrocarbon rings, and more specifically, fused rings formed by fusing a plurality of 5- to 8-membered cycloalkane rings, such as a perhydronaphthalene(decalin) ring, a perhydroanthracene ring, a perhydrophenanthrene ring, a perhydroacenaphthene ring, a perhydrofluorene ring, a perhydroindene ring, and a perhydrophenalene ring.

Preferred examples of the crosslinked cyclic hydrocarbon ring include a norbornyl group, an adamantyl group, a bicyclooctanyl group, and a tricyclo[5.2.1.0^{2,6}]decanyl group. More preferred examples of the crosslinked cyclic hydrocarbon rings include a norbornyl group and an adamantyl group.

Such an alicyclic hydrocarbon group may have a substituent. Preferred examples of the substituent include a halogen atom, an alkyl group, a hydroxyl group substituted with a hydrogen atom, and an amino group substituted with a hydrogen atom.

The resin (A) may or may not contain a repeating unit having an alicyclic hydrocarbon structure having no polar group and not exhibiting acid-decomposability, but in the case where such a repeating unit is contained in the resin (A), the content thereof is preferably 1% by mole to 50% by mole, and more preferably 5% by mole to 50% by mole, with respect to all the repeating units in the resin (A).

Specific examples of the repeating unit having an alicyclic hydrocarbon structure having no polar group and not exhibiting acid-decomposability are shown below, but the present invention is not limited thereto. In the formulae, Ra represents H, CH₃, CH₂OH, or CF₃.

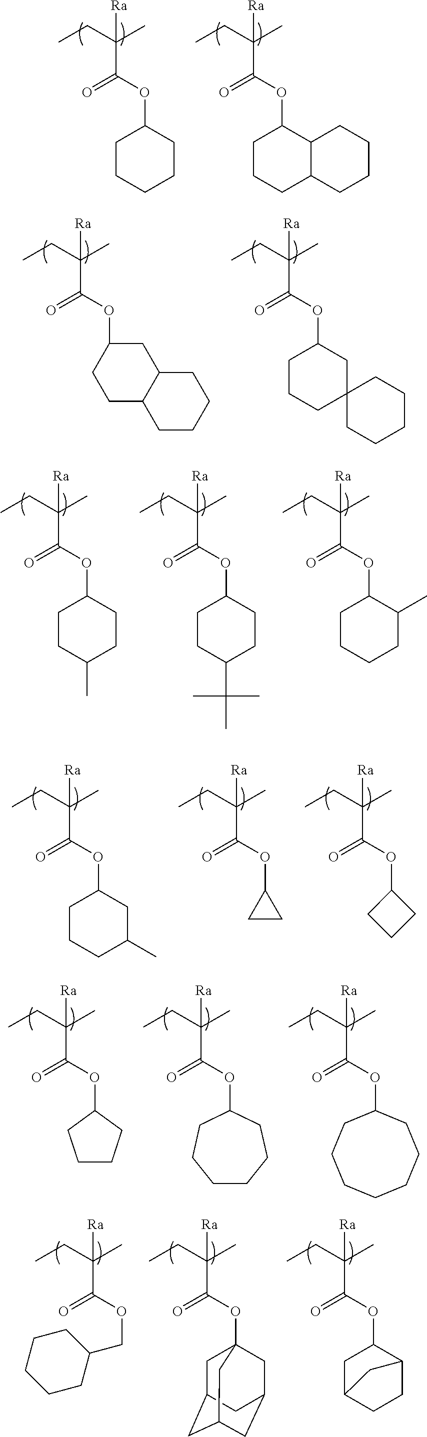

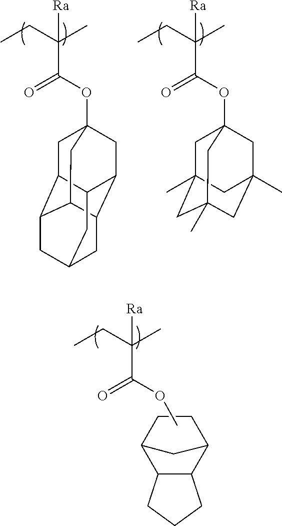

In addition to the repeating structural units as described above, the resin (A) used in the composition of the present invention can have a variety of repeating structural units for the purpose of adjusting dry etching resistance, suitability for a standard developer, adhesion to a substrate, and a resist profile, and in addition, resolving power, heat resistance, sensitivity, and the like, which are characteristics generally required for the active-light-sensitive or radiation-sensitive resin composition.

Examples of such repeating structural units include, but are not limited to, repeating structural units corresponding to the following monomers.

Thus, it becomes possible to perform fine adjustments to performance required for the resin used in the composition according to the present invention, in particular:

(1) solubility for a coating solvent,

(2) film-forming properties (glass transition point),

(3) alkali developability,

(4) film reduction (selection of hydrophilic, hydrophobic, or alkali-soluble groups),

(5) adhesion of an unexposed area to a substrate,

(6) dry etching resistance,

and the like.

Examples of such a monomer include a compound having one addition-polymerizable unsaturated bond selected from acrylic esters, methacrylic esters, acrylamides, methacrylamides, allyl compounds, vinyl ethers, and vinyl esters.

In addition to these, an addition-polymerizable unsaturated compound that is copolymerizable with the monomers corresponding to various repeating structural units as described above may be copolymerized.

In the resin (A) used in the composition of the present invention, the molar ratio of each repeating structural unit content is appropriately set in order to adjust dry etching resistance, suitability for a standard developer, adhesion to a substrate, and a resist profile of the active-light-sensitive or radiation-sensitive resin composition, and in addition, resolving power, heat resistance, sensitivity, and the like, each of which is performance generally required for the active-light-sensitive or radiation-sensitive resin composition.

The form of the resin (A) in the present invention may be any of random-type, block-type, comb-type, and star-type forms. The resin (A) can be synthesized by, for example, radical, cationic, or anionic polymerization of unsaturated monomers corresponding to respective structures. It is also possible to obtain a desired resin after polymerization using unsaturated monomers corresponding to precursors of respective structures, and then by carrying out a polymer reaction.

When the composition of the present invention is for ArF exposure, it is preferable that the resin (A) used in the composition of the present invention has substantially no aromatic rings (specifically, the proportion of repeating units having an aromatic group in the resin is preferably 5% by mole or less, more preferably 3% by mole or less, and ideally 0% by mole, that is, the resin does not have an aromatic group) in terms of transparency to ArF light. It is preferable that the resin (A) has a monocyclic or polycyclic alicyclic hydrocarbon structure.

In the case where the composition of the present invention contains a resin (D) as described later, it is preferable that the resin (A) contains neither a fluorine atom nor a silicon atom (specifically, the proportion of repeating units having fluorine atom or silicon atom in the resin is preferably 5% by mole or less, more preferably 3% by mole or less, and ideally 0% by mole) from the viewpoint of compatibility with the resin (D).

The resin (A) used in the composition of the present invention is preferably a resin in which all the repeating units are composed of (meth)acrylate-based repeating units. In this case, all the repeating units may be methacrylate-based repeating units, all the repeating units may be acrylate-based repeating units, or all the repeating units may be composed of methacrylate-based repeating units and acrylate-based repeating units, but the acrylate-based repeating units preferably accounts for 50% by mole or less with respect to all the repeating units.

In the case of irradiating the composition of the present invention with KrF excimer laser light, electron beams, X-rays, or high-energy beams at a wavelength of 50 nm or less (EUV or the like), the resin (A) preferably further contains a hydroxystyrene-based repeating unit. It is more preferable to contain a hydroxystyrene-based repeating unit, a hydroxystyrene-based repeating unit protected by an acid-decomposable group, and an acid-decomposable repeating unit such as tertiary alkyl ester(meth)acrylate.

Preferred examples of the hydroxystyrene-based repeating unit containing an acid-decomposable group include repeating units composed of t-butoxycarbonyloxystyrene, 1-alkoxyethoxystyrene, and tertiary alkyl ester(meth)acrylate. Repeating units composed of 2-alkyl-2-adamantyl(meth)acrylate and dialkyl(1-adamantyl)methyl(meth)acrylate are more preferable.

Specific examples of such resin include resins having a repeating unit represented by the following General Formula (A).

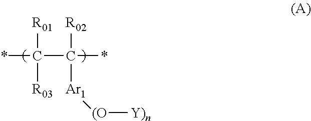

In the formula, R₀₁, R₀₂, and R₀₃ each independently represent a hydrogen atom, an alkyl group, a cycloalkyl group, a halogen atom, a cyano group, or an alkoxycarbonyl group. Ar₁ represents an aromatic ring group. Further, R₀₃ and Ar₁ are each an alkylene group, or both of them may be bonded to each other, together with a —C—C— chain, to form a 5- or 6-membered ring.

Y's in the number of n each independently represent a hydrogen atom or a group capable of leaving by an action of an acid, provided that at least one of Y's represents a group capable of leaving by an action of an acid.

n represents an integer of 1 to 4, and is preferably 1 or 2, and more preferably 1.

The alkyl group as R₀₁ to R₀₃ is, for example, preferably an alkyl group having 20 or less carbon atoms, preferably a methyl group, an ethyl group, a propyl group, an isopropyl group, an n-butyl group, a sec-butyl group, a hexyl group, a 2-ethylhexyl group, an octyl group, or a dodecyl group, and more preferably an alkyl group having 8 or less carbon atoms. Further, these alkyl groups may have substituents.

The alkyl group included in the alkoxycarbornyl group is preferably the same as the alkyl group in R₀₁ to R₀₃.

The cycloalkyl group may be a monocyclic cycloalkyl group or a polycyclic cycloalkyl group. Preferred examples thereof include a monocyclic cycloalkyl group having 3 to 8 carbon atoms, such as a cyclopropyl group, a cyclopentyl group, and a cyclohexyl group. Here, these cycloalkyl groups may have a substituent.

Examples of the halogen atom may include a fluorine atom, a chlorine atom, a bromine atom, and an iodine atom, and a fluorine atom is more preferable.

In the case where R₀₃ represents an alkylene group, preferred examples of the alkylene group include ones having 1 to 8 carbon atoms, such as a methylene group, an ethylene group, a propylene group, a butylene group, a hexylene group, and an octylene group.

The aromatic ring as Ar₁ is preferably one having 6 to 14 carbon atoms, and examples thereof include a benzene ring, a toluene ring, and a naphthalene ring. Here, these aromatic ring groups may have a substituent.

Examples of the group Y capable of leaving by an action of an acid include groups represented by —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), and —CH(R₃₆)(Ar).

In the formula, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

Ar represents an aryl group.

As the alkyl group as R₃₆ to R₃₉, R₀₁, or R₀₂, an alkyl group having 1 to 8 carbon atoms is preferable and examples thereof include a methyl group, an ethyl group, a propyl group, an n-butyl group, a sec-butyl group, a hexyl group, and an octyl group.

A cycloalkyl group as R₃₆ to R₃₉, R₀₁, or R₀₂ may be either a monocyclic cycloalkyl group or a polycyclic cycloalkyl group. As the monocyclic cycloalkyl group, a cycloalkyl group having 3 to 8 carbon atoms is preferable. As the polycyclic cycloalkyl group, a cycloalkyl group having 6 to 20 carbon atoms is preferable. Further, some of the carbon atoms in the cycloalkyl group may be substituted with hetero atoms such as an oxygen atom.

An aryl group as R₃₆ to R₃₉, R₀₁, R₀₂, or Ar is preferably an aryl group with 6 to 10 carbon atoms and examples thereof include a phenyl group, a naphthyl group, and an anthryl group.

An aralkyl group as R₃₆ to R₃₉, R₀₁, or R₀₂ is preferably an aralkyl group with 7 to 12 carbon atoms and, for example, a benzyl group, a phenethyl group, and a naphthylmethyl group are preferable.

An alkenyl group as R₃₆ to R₃₉, R₀₁, or R₀₂ is preferably an alkenyl group with 2 to 8 carbon atoms and examples thereof include a vinyl group, an allyl group, a butenyl group, and a cyclohexenyl group.

A ring formed by R₃₆ and R₃₇ bonded to each other may be monocyclic or may be polycyclic. As a monocyclic type, a cycloalkane structure with 3 to 8 carbon atoms is preferable. As a polycyclic type, a cycloalkane structure with 6 to 20 carbon atoms is preferable. Here, some of the carbon atoms in the ring structure may be substituted with hetero atoms such as an oxygen atom.

Each of the groups described above may have a substituent. Examples of the substituent include an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, a cyano group, and a nitro group. The substituents preferably have 8 or less carbon atoms.

As a group Y capable of leaving by an action of an acid, a structure represented by the following General Formula (B) is more preferable.

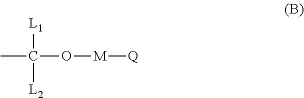

In the formula, L₁ and L₂ each independently represent a hydrogen atom, an alkyl group, a cycloalkyl group, an aryl group, or an aralkyl group.

M represents a single bond or a divalent bonding group.

Q represents an alkyl group, a cycloalkyl group, a cyclic aliphatic group, an aromatic ring group, an amino group, an ammonium group, a mercapto group, a cyano group, or an aldehyde group. Here, the cyclic aliphatic group and an aromatic ring group may include a hetero atom.

Here, a 5- or 6-membered ring may be formed by at least two of Q, M, and L₁ being bonded to each other.

An alkyl group as L₁ and L₂ is, for example, an alkyl group with 1 to 8 carbon atoms.

A cycloalkyl group as L₁ and L₂ is, for example, a cycloalkyl group with 3 to 15 carbon atoms.

An aryl group as L₁ and L₂ is, for example, an aryl group with 6 to 15 carbon atoms.

An aralkyl group as L₁ and L₂ is, for example, an aralkyl group with 6 to 20 carbon atoms.

A divalent bonding group as M is, for example, an alkylene group, a cycloalkylene group, an alkenylene group, an arylene group, —S—, —O—, —CO—, —SO₂—, —N(R₀)—, or a combination of two or more thereof. Here, R₀ is a hydrogen atom or an alkyl group.

An alkyl group and a cycloalkyl group as Q are the same as each of the groups as L₁ and L₂ described above.

Examples of a cyclic aliphatic group or an aromatic ring group as Q include the cycloalkyl group and the aryl group as L₁ and L₂ described above. The cycloalkyl group and the aryl group are preferably groups with 3 to 15 carbon atoms.

Examples of a cyclic aliphatic group or an aromatic ring group which contains hetero atoms as Q include groups such as thiirane, cyclothiolane, thiophene, furan, pyrrole, benzothiophene, benzofuran, benzopyrrole, triazinc, imidazole, benzimidazole, triazole, thiadiazole, thiazole, pyrrolidone, and the like which have a heterocyclic structure. However, the cyclic aliphatic group or the aromatic ring group is not limited thereto as long as it is a ring which is formed by carbon and hetero atoms or a ring which is formed by only hetero atoms.

Examples of a ring structure which at least two of Q, M, and L₁ may form by being bonded to each other include a 5- or 6-membered ring structure which is formed by these forming a propylene group or a butylene group. Here, the 5- or 6-membered ring structure contains oxygen atoms.

Each of the groups which are represented by L₁, L₂, M, and Q in General Formula (2) may have a substituent. Examples of the substituent include an alkyl group, a cycloalkyl group, an aryl group, an amino group, an amido group, a ureide group, a urethane group, a hydroxyl group, a carboxyl group, a halogen atom, an alkoxy group, a thioether group, an acyl group, an acyloxy group, an alkoxycarbonyl group, a cyano group, and a nitro group. The substituents preferably have 8 or less carbon atoms.

As a group represented by -(M-Q), a group having 1 to 20 carbon atoms is preferable, a group having 1 to 10 carbon atoms is more preferable, and a group having 1 to 8 carbon atoms is still more preferable.

Specific examples of a resin having a hydroxystyrene repeating unit will be shown below, but the present invention is not limited thereto.

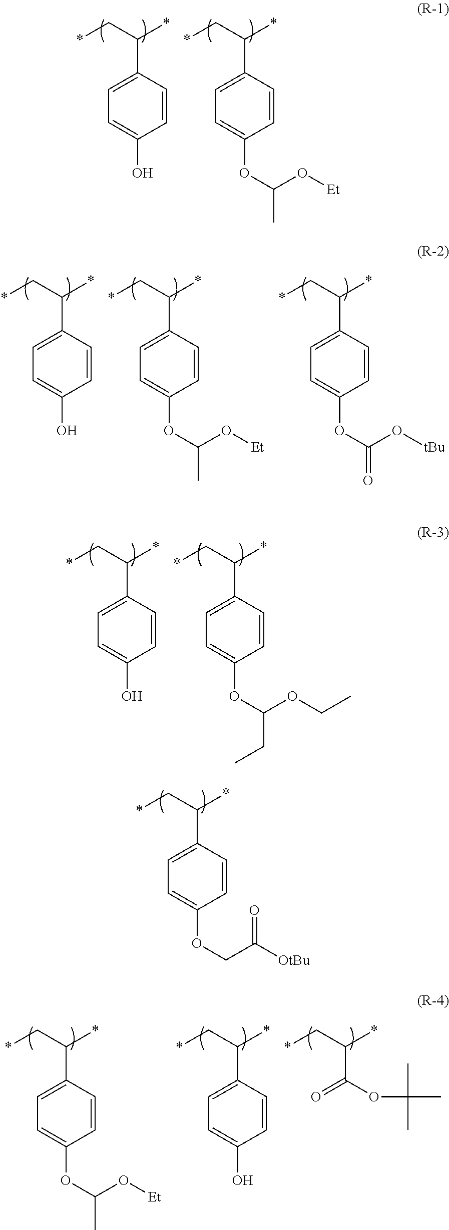

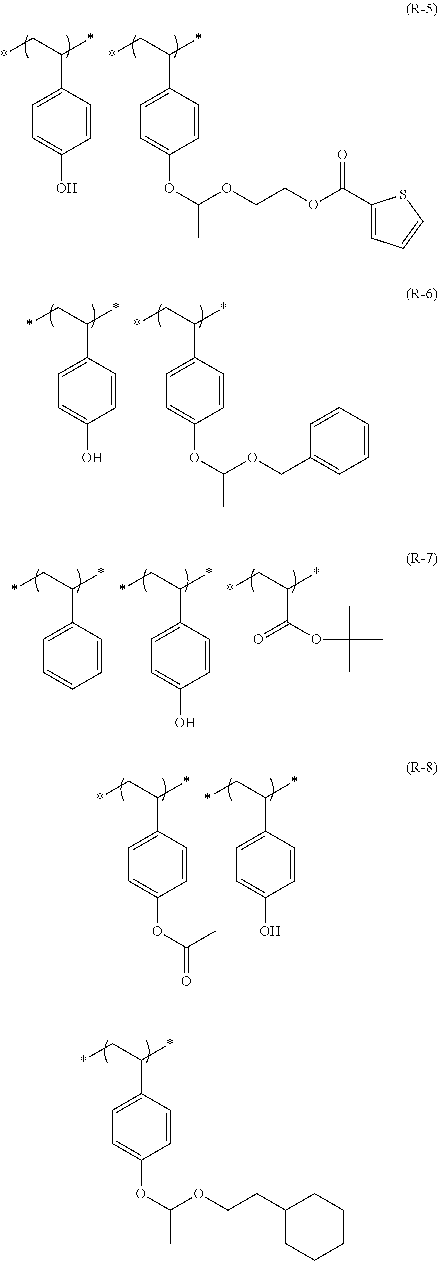

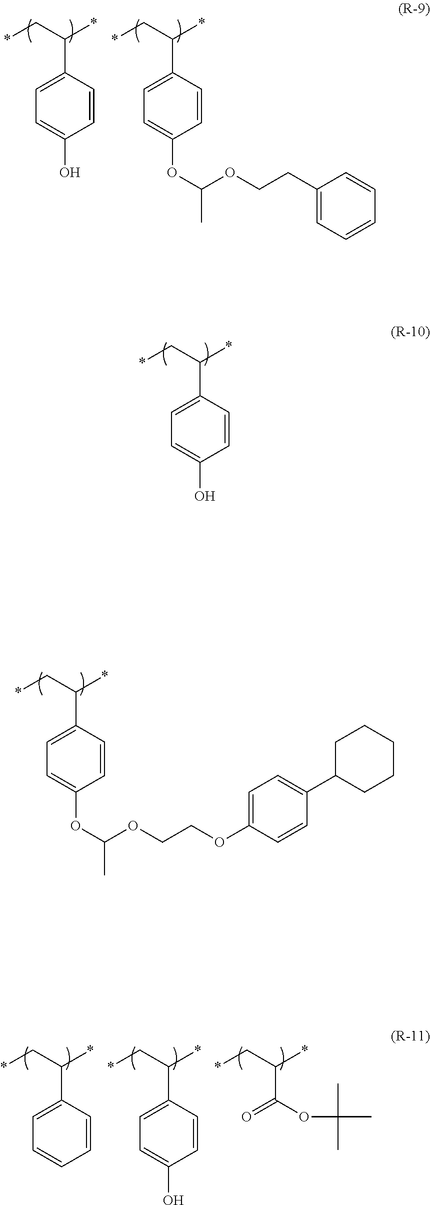

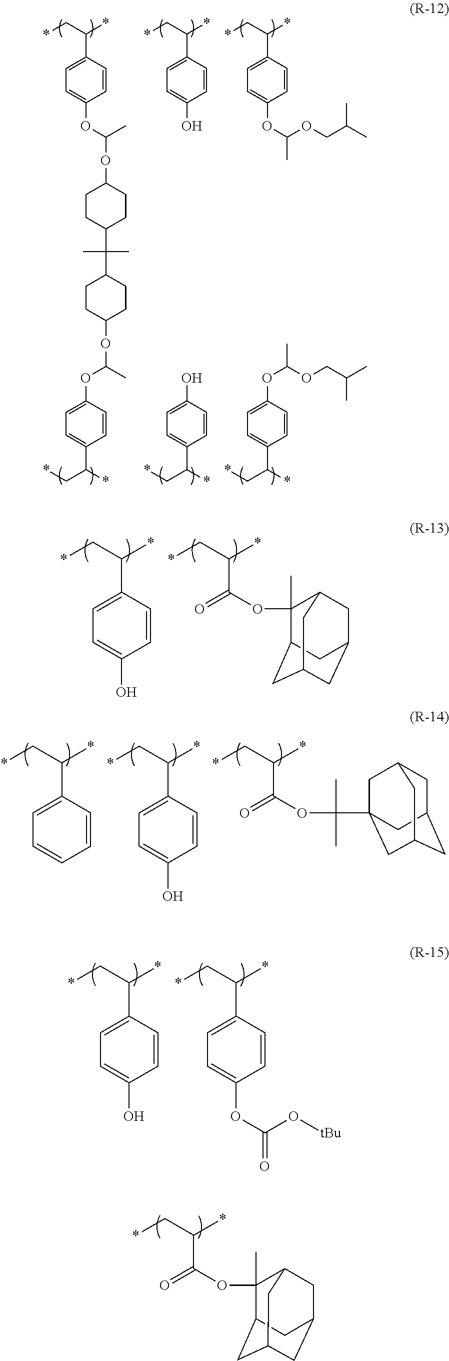

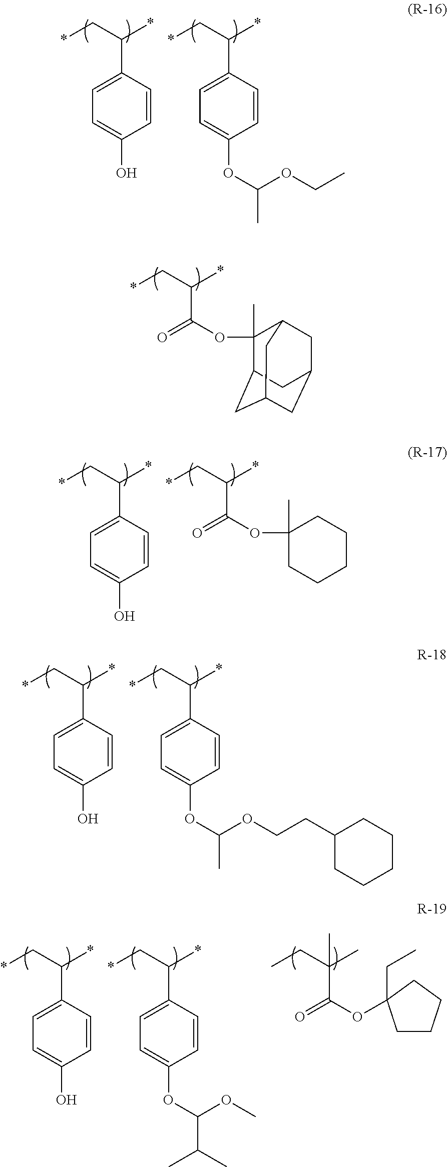

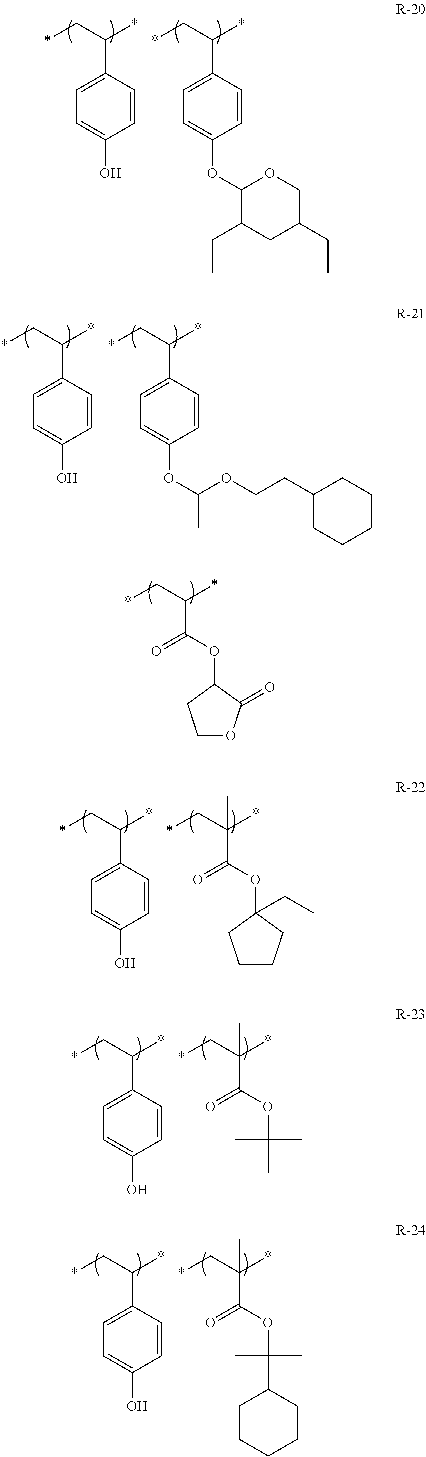

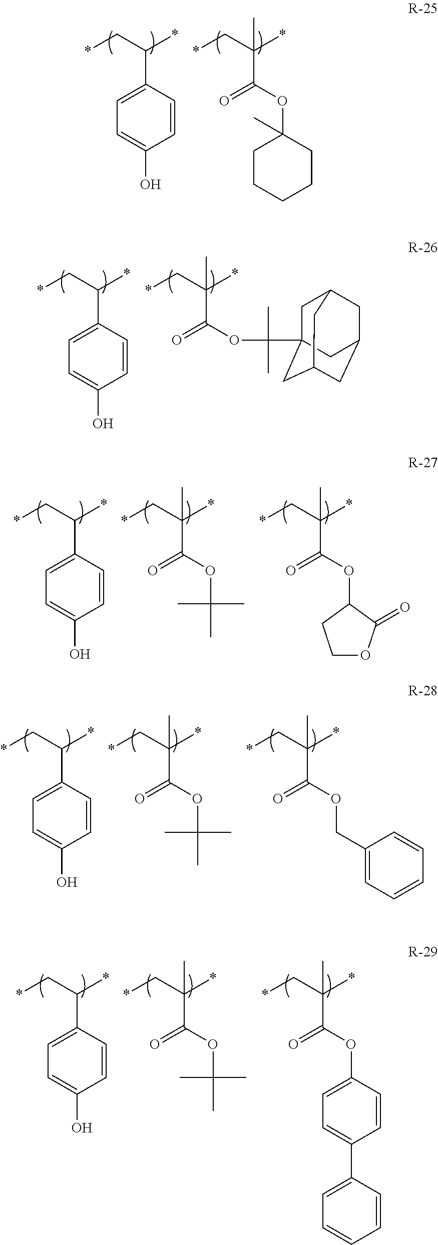

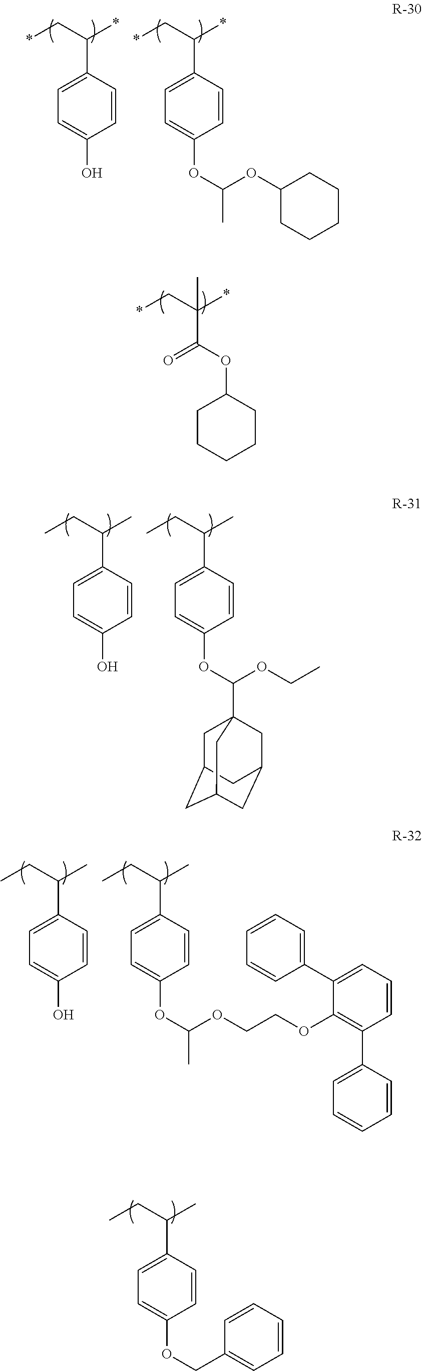

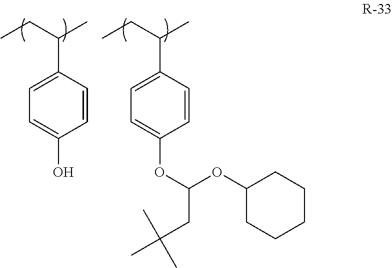

In these specific examples, tBu represents a t-butyl group.

The resin (A) in the present invention can be synthesized in accordance with an ordinary method (for example, radical polymerization, living radical polymerization, and anion polymerization). For example, as the general synthesis method, a bulk polymerization method in which polymerization is carried out by dissolving monomer species and an initiator in a solvent and heating the solution, a dropwise addition polymerization method in which a solution of monomer species and an initiator is added dropwise to a heating solvent over 1 hour to 10 hours, or the like may be included, and a dropwise addition polymerization method is preferable. Examples of the reaction solvent may include ethers such as tetrahydrofuran, 1,4-dioxane, and diisopropyl ether, ketones such as methyl ethyl ketone and methyl isobutyl ketone, ester solvents such as ethyl acetate, amide solvents such as dimethyl formamide and dimethyl acetamide, and a solvent which dissolves the composition of the present invention, such as propylene glycol monomethyl ether acetate, propylene glycol monomethyl ether, and cyclohexanone, as will be described later. It is more preferable to perform polymerization using the same solvent as the solvent used in the photosensitive composition of the present invention. Thereby, generation of the particles during storage can be suppressed.

It is preferable that the polymerization reaction is carried out in an inert gas atmosphere such as nitrogen or argon. As the polymerization initiator, commercially available radical initiators (an azo-based initiator, peroxide, or the like) are used to initiate the polymerization. As the radical initiator, an azo-based initiator is preferable, and the azo-based initiator having an ester group, a cyano group, or a carboxyl group is preferable. Preferable initiators may include azobisisobutyronitrile, azobisdimethylvaleronitrile, dimethyl 2,2′-azobis(2-methyl propionate), or the like. The initiator is added or added in installments, if necessary, and the desired polymer is recovered after the reaction is completed, the reaction mixture is poured into a solvent, and then a method such as powder or solid recovery is used. The concentration of the reaction is 5% by mass to 50% by mass and preferably 10% by mass to 30% by mass. The reaction temperature is normally 10° C. to 150° C., preferably 30° C. to 120° C., and more preferably 60° C. to 100° C.

After the reaction is completed, the resultant is allowed to be cooled to the room temperature and purified. Purification may be carried out using common methods such as a liquid-liquid extraction method in which residual monomers and oligomer components are removed by washing with water or combining appropriate solvents, a purification method in a solution state such as ultrafiltration in which only those with a specific molecular weight or less are extracted and removed, a reprecipitation method in which residual monomers and the like are removed by coagulating the resin in a poor solvent through dropwise addition of the resin solution to a poor solvent, and a purification method in a solid state in which separated resin slurry is washed with a poor solvent.

For example, the resin is precipitated as solids by contacting the resin with a sparingly soluble or insoluble solvent (a poor solvent) in 10 times or less the volume of the reaction solution, and preferably 5 times to 10 times the volume.

The solvent used during precipitation or reprecipitation from the polymer solution (precipitation or reprecipitation solvent) may be a poor solvent of the polymer, and may be appropriately selected and used from hydrocarbons, halogenated hydrocarbons, nitro compounds, ethers, ketones, esters, carbonates, alcohols, carboxylic acids, water, and a mixed solvent including these solvents, depending on the type of polymer. Among these, as the precipitation or reprecipitation solvent, a solvent containing at least alcohols (particularly, methanol or the like) or water is preferable.

The amount of precipitation or reprecipitation solvent to be used can be appropriately selected taking efficiency, a yield, or the like into account. Generally, the amount is in the range of 100 parts by mass to 10,000 parts by mass, preferably 200 parts by mass to 2,000 parts by mass, arid more preferably 300 parts by mass to 1,000 parts by mass, with respect to 100 parts by mass of polymer solution.

The precipitation or reprecipitation temperature may be appropriately selected considering efficiency and operability, but is normally 0° C. to 50° C., and preferably around room temperature (for example, approximately 20° C. to 35° C.). A precipitation or reprecipitation operation may be carried out by well-known methods of batch-type or continuous-type using a common mixing vessel such as a stirring tank.

The precipitated or reprecipitated polymer is generally provided for use after being subjected to common solid-liquid separation such as filtration and centrifugation, and then dried. Filtration is carried out using a filtration material with solvent resistance, preferably under pressure. Drying is carried out at a temperature of approximately 30° C. to 100° C., preferably approximately 30° C. to 50° C. under normal pressure or reduced pressure (preferably under reduced pressure).

In addition, in the present invention, after the resin is precipitated and separated once, the resin is dissolved in the solvent (C1) as described above and filtered using a filter, and the filtrate is brought into contact with a solvent in which the resin is sparingly soluble or insoluble (poor solvent) to perform re-precipitation. In other words, after the radical polymerization reaction is completed, a method may be used in which the polymer is brought into contact with a sparingly soluble or insoluble solvent and the resin is precipitated (step a), the resin is separated from the solution (step b), then the resin is dissolved, in the solvent (C1) to prepare a resin solution A (step c), the resin solution A is filtered using a filter (step d), then the resin solid is precipitated by contacting the filtrate in the step d with a solvent in which the resin is sparingly soluble or insoluble in 10 times or less volume of the resin solution A (preferably 5 times or less volume) (step d), and the precipitated resin is separated (step e).

In addition, as described above, in order to suppress aggregation of the resin after the composition is prepared, a step in which the resin solution A before being used in the step (d) is heated at approximately 30° C. to 90° C. for approximately 30 minutes to 12 hours may be added as described in, for example, JP2009-037108A.

The weight-average molecular weight of the resin (A) of the present invention is a value in terms of polystyrene as measured by GPC, and is 7,000 or less as described above, preferably 7,000 to 200,000, more preferably 7,000 to 50,000, still more preferably 7,000 to 40,000, and particularly preferably 7,000 to 30,000. In the case where the weight-average molecular weight is less than 7,000, the solubility in the organic developer is exceedingly increased and this causes a concern that an accurate pattern may not be formed.

The resin (A) having a dispersity (molecular weight distribution) which is in the range of usually 1.0 to 3.0, preferably 1.0 to 2.6, more preferably 1.0 to 2.0, and particularly preferably 1.4 to 2.0 is used. As the molecular weight distribution is smaller, the resolution and resist shape are superior, the side wall of the resist pattern is smoother, and the roughness is more improved.

In the active-light-sensitive or radiation-sensitive resin composition of the present invention, the blending ratio of the resin (A) in the entire composition is preferably 30% by mass to 99% by mass, and more preferably 60% by mass to 95% by mass, of the total solid content.

Furthermore, in the present invention, the resin (A) may be used alone or in combination of two or more kinds thereof. Here, in the case where a combination of two or more kinds of the resin (A) is used, a resin solution containing the resin (A) and the solvent (C1) is subjected to a step of filtration using a filter to obtain a filtrate, from which at least one of two or more kinds of the resin (A) is obtained.

Examples of the resin (A) which is preferably used in the present invention include those used in Examples which will be described later. In addition, the following resins are also exemplified. In the structures, the compositional ratios (molar ratios), the weight-average molecular weight (Mw), and the dispersity (Mw/Mn) are shown. In addition, such exemplary resins include both of those which can be applied to one embodiment and those which can be applied to a plurality of embodiments, among the aforementioned (first embodiment), (second embodiment), and (third embodiment).

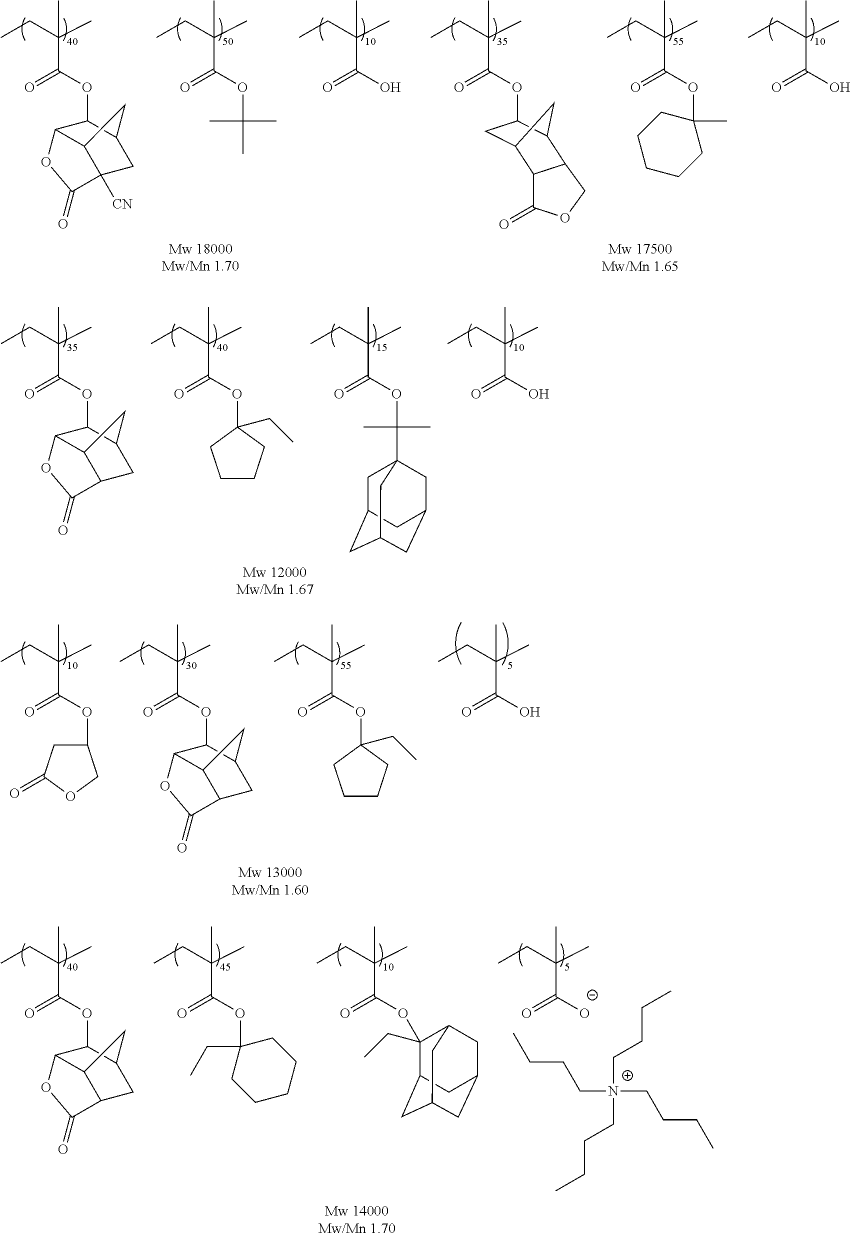

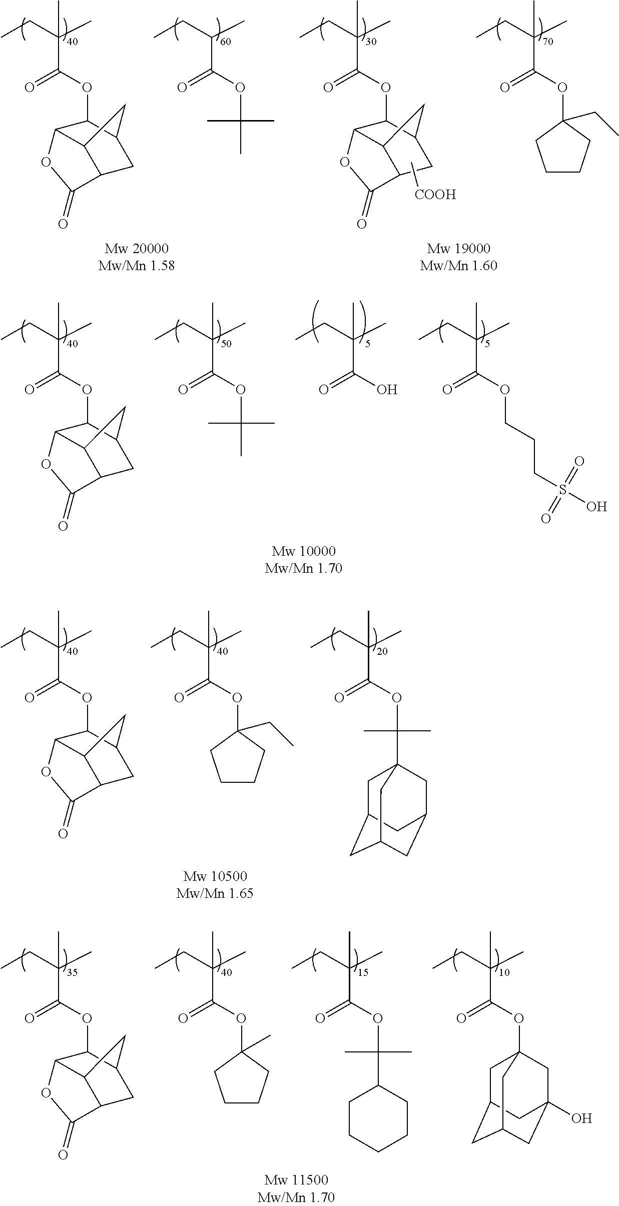

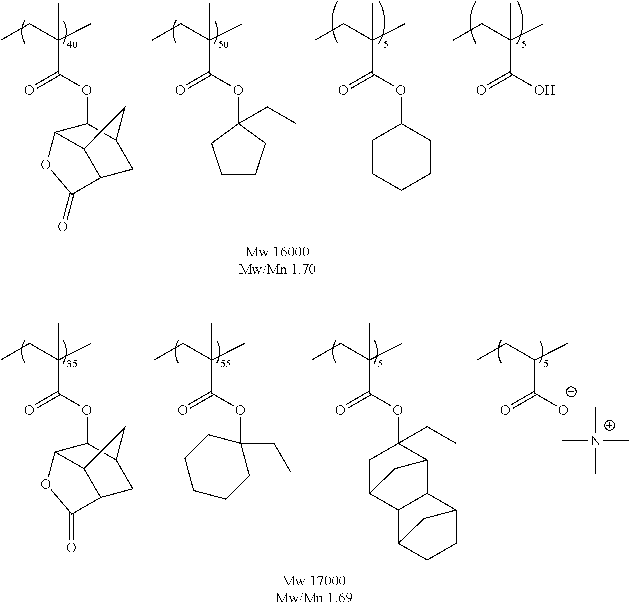

[3] Compound (B) Capable of Generating Acid upon Irradiation with Active Light or Radiation

The composition in the present invention preferably further contains a compound (B) capable of generating an acid upon irradiation with active light or radiation (hereinafter also referred to as an “acid generator”). As the compound (B) capable of generating an acid upon irradiation with active light or radiation, a compound capable of generating an organic acid upon irradiation with active light or radiation is preferable.

The pKa of the acid generated upon irradiation with active light or radiation is preferably in the range of −12 to 0, more preferably in the range of −10 to −1, and particularly preferably in the range of −8 to −1.

The compound (B) capable of generating an acid upon irradiation with active light or radiation is preferably capable of generating an acid having a fluorine atom or a group containing a fluorine atom.

The compound (B) capable of generating an acid upon irradiation with active light or radiation is a compound different from the aforementioned ionic compound (S).

The compound (B) capable of generating an acid upon irradiation with active light or radiation may be either a form of a low molecular compound or a form introduced into a part of a polymer. Further, a combination of the form of a low molecular compound and the form introduced into a part of a polymer may also be used.

Even in the case with the form introduced into a part of a polymer, the compound (B) capable of generating an acid upon irradiation with active light or radiation is different from the aforementioned repeating unit (P3).

In the case where the compound (B) capable of generating an acid upon irradiation with active light or radiation is in the form of a low molecular compound, the molecular weight is preferably 3,000 or less, more preferably 2,000 or less, and still more preferably 1,000 or less.

In the case where the compound (B) capable of generating an acid upon irradiation with active light or radiation is in the form introduced into a part of a polymer, it may be introduced into a part of the acid-decomposable resin as described above or into a resin other than the acid-decomposable resin.

In the present invention, the compound (B) capable of generating an acid upon irradiation with active light or radiation is preferably in the form of a low molecular compound.

The acid generator which can be used may be appropriately selected from a photoinitiator for cationic photopolymerization, a photoinitiator for radical photopolymerization, a photodecoloring agent for dyes, a photodiscoloring agent, a known compound capable of generating an acid upon irradiation with active light or radiation, which is used for a microresist or the like, and a mixture thereof.

Examples thereof include a diazonium salt, a phosphonium salt, a sulfonium salt, an iodonium salt, imidosulfonate, oxime sulfonate, diazodisulfone, disulfone, and o-nitrobenzyl sulfonate.

Preferred examples of the compounds among the acid generators include compounds represented by the following General Formulae (ZI), (ZII), and (ZIII).

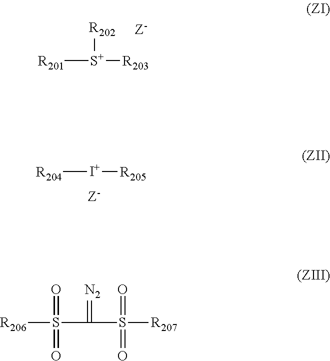

In General Formula (ZI),

R₂₀₁, R₂₀₂, and R₂₀₃ each independently represent an organic group,

the number of carbon atoms of the organic group as R₂₀₁, R₂₀₂, and R₂₀₃ is generally 1 to 30, and preferably 1 to 20,

two members out of R₂₀₁ to R₂₀₃ may be bonded to each other to form a ring structure, and the ring may contain an oxygen atom, a sulfur atom, an ester bond, an amide bond, or a carbonyl group, and examples of the group formed by the mutual bonding of two members out of R₂₀₁ to R₂₀₃ include an alkylene group (for example, a butylene group and a pentylene group), and

Z⁻ represents a non-nucleophilic anion.

Examples of the non-nucleophilic anion as Z⁻ include a sulfonic acid anion, a carboxylic acid anion, a sulfonylimide anion, a bis(alkylsulfonyl)imide anion, and a tris(alkylsulfonyl)methyl anion.

The non-nucleophilic anion is an anion having an extremely low ability of causing a nucleophilic reaction and this anion can suppress the decomposition with aging due to an intramolecular nucleophilic reaction. With this anion, the stability with aging of the active-light-sensitive or radiation-sensitive resin composition is improved.

Examples of the sulfonic acid anion include an aliphatic sulfonic acid anion, an aromatic sulfonic acid anion, and a camphorsulfonic acid anion.

Examples of the carboxylic acid anion include an aliphatic carboxylic acid anion, an aromatic carboxylic acid anion, and an aralkylcarboxylic acid anion.

The aliphatic moiety in the aliphatic sulfonic acid anion and aliphatic carboxylic acid anion may be an alkyl group, or a cycloalkyl group but is preferably an alkyl group having 1 to 30 carbon atoms or a cycloalkyl group having 3 to 30 carbon atoms.

Preferred examples of the aromatic group in the aromatic sulfonic acid anion and aromatic carboxylic acid anion include an aryl group having 6 to 14 carbon atoms, for example, a phenyl group, a tolyl group, and a naphthyl group.

The alkyl group, the cycloalkyl group, and the aryl group in the aliphatic sulfonic acid anion and the aromatic sulfonic acid anion may have a substituent. Examples of the substituent on the alkyl group, the cycloalkyl group, and the aryl group in the aliphatic sulfonic acid anion and the aromatic sulfonic acid anion include a nitro group, a halogen atom (a fluorine atom, a chlorine atom, a bromine atom, or an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). The aryl group and the ring structure contained in each group may further have, as the substituent, an alkyl group (preferably having 1 to 15 carbon atoms) or a cycloalkyl group (preferably having 3 to 15 carbon atoms).

Preferred examples of the aralkyl group in the aralkylcarboxylic acid anion include an aralkyl group having 7 to 12 carbon atoms, for example, a benzyl group, a phenethyl group, a naphthylmethyl group, a naphthylethyl group, and a naphthylbutyl group.

The alkyl group, the cycloalkyl group, the aryl group, and the aralkyl group in the aliphatic carboxylic acid anion, the aromatic carboxylic acid anion, and the aralkylcarboxylic acid anion may have a substituent. Examples of the substituent include a halogen atom, an alkyl group, a cycloalkyl group, an alkoxy group, and an alkylthio group, which are the same as those in the aromatic sulfonic acid anion.

Examples of the sulfonylimide anion include a saccharin anion.

Preferred examples of the alkyl group in the bis(alkylsulfonyl)imide anion and the tris(alkylsulfonyl)methide anion include an alkyl group having 1 to 5 carbon atoms, and examples thereof include a methyl group, an ethyl group, a propyl group, an isopropyl group, an n-butyl group, an isobutyl group, a sec-butyl group, a pentyl group, and a neopentyl group.

Two alkyl groups in the bis(alkylsulfonyl)imide anion may be linked to each other to constitute an alkylene group (preferably having 2 to 4 carbon atoms) and to form a ring together with an imido group and two sulfonyl groups. Examples of the substituent which such an alkyl group and an alkylene group formed by the mutual linking of the two alkyl groups in the bis(alkylsulfonyl)imide anion may have include a halogen atom, a halogen atom-substituted alkyl group, an alkoxy group, an alkylthio group, an alkyloxysulfonyl group, an aryloxysulfonyl group, and a cycloalkylaryloxysulfonyl group, with the fluorine atom-substituted alkyl group being preferable. Other examples of the non-nucleophilic anion include fluorinated phosphorus (for example, PF₆⁻), fluorinated boron (for example, BF₄⁻), and fluorinated antimony (for example, SbF₆⁻).

The non-nucleophilic anion of Z⁻ is preferably an aliphatic sulfonic acid anion substituted with a fluorine atom at least at the α-position of sulfonic acid, an aromatic sulfonic acid anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonic acid anion having 4 to 8 carbon atoms or a benzenesulfonic acid anion having a fluorine atom, still more preferably a nonafluorobutanesulfonic acid anion, a perfluorooctanesulfonic acid anion, a pentafluorobenzenesulfonic acid anion, or a 3,5-bis(trifluoromethyl)benzenesulfonic acid anion.

The acid generator is preferably a compound capable of generating an acid represented by the following General Formula (V) or (VI) upon irradiation with active light or radiation. The compound capable of generating an acid represented by the following General Formula (V) or (VI) has a cyclic organic group, so that the resolution and the roughness performance can be more improved.

The non-nucleophilic anion can be an anion capable of generating an organic acid represented by the following General Formula (V) or (VI).

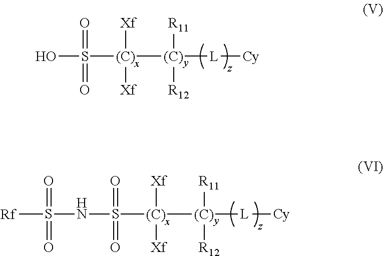

In the general formulae,

Xf's each independently represent a fluorine atom or an alkyl group substituted with at least one fluorine atom,

R₁₁ and R₁₂ each independently represent a hydrogen atom, a fluorine atom, or an alkyl group,

L's each independently represent a divalent linking group,

Cy represents a cyclic organic group,

Rf represents a group containing a fluorine atom,

x represents an integer of 1 to 20,

y represents an integer of 0 to 10, and

z represents an integer of 0 to 10.

Xf represents a fluorine atom or an alkyl group substituted with at least one fluorine atom. The number of carbon atoms of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. More specifically, Xf is more preferably a fluorine atom or CF₃. It is particularly preferable that both Xf's are fluorine atoms.

R₁₁ and R₁₂ each independently represent a hydrogen atom, a fluorine atom, or an alkyl group. The alkyl group may have a substituent (preferably a fluorine atom), and is preferably an alkyl group having 1 to 4 carbon atoms, and more preferably a perfluoroalkyl group having 1 to 4 carbon atoms. As a specific example of the alkyl group having the substituent of R₁₁ and R₁₂, CF₃ is preferable.

L represents a divalent linking group. Examples of the divalent linking group include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), and a divalent linking group formed by combination of a plurality of these members. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

Cy represents a cyclic organic group. Examples of the cyclic organic group include an alicyclic group, an aryl group, and a heterocyclic group.

The alicyclic group may be monocyclic or polycyclic. Among those, an alicyclic group with a bulky structure, having 7 or more carbon atoms, such as a norbornyl group, a tricyclodecanyl group, a tetracyclodecanyl group, a tetracyclododecanyl group, and an adamantyl group, is preferable from the viewpoints of inhibiting in-film diffusion in a post exposure bake (PEB) step and improving the Mask Error Enhancement Factor (MEEF).

The aryl group may be monocyclic or polycyclic. Examples of the aryl group include a phenyl group, a naphthyl group, a phenanthryl group, and an anthryl group. Among these, a naphthyl group having a relatively low light absorbance at 193 nm is preferable.

The heterocyclic group may be monocyclic or polycyclic, but with a polycyclic heterocyclic group, the diffusion of an acid can be more inhibited. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring or sultone ring, and a decahydroisoquinoline ring. The heterocycle in the heterocyclic group is particularly preferably a furan ring, a thiophene ring, a pyridine ring, or a decahydroisoquinoline ring. Examples of the lactone ring or sultone ring include lactone structures or sultones exemplified in the resin (A) as mentioned above.

The cyclic organic group as described above may have a substituent, and examples of the substituent include an alkyl group (may be linear or branched, preferably having 1 to 12 carbon atoms), a cycloalkyl group (may be monocyclic, polycyclic or spirocyclic, preferably having 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (the carbon contributing to ring formation) may be carbonyl carbon.

x is preferably 1 to 8, more preferably 1 to 4, and particularly preferably 1. y is preferably 0 to 4, and more preferably 0. z is preferably 0 to 8, and more preferably 0 to 4.

Examples of the group containing a fluorine atom, represented by Rf, include an alkyl group having at least one fluorine atom, a cycloalkyl group having at least one fluorine atom, and an aryl group having at least one fluorine atom.

The alkyl group, cycloalkyl group, and aryl group may be substituted with a fluorine atom or may be substituted with another substituent containing a fluorine atom. In the case where Rf is a cycloalkyl group having at least one fluorine atom or an aryl group having at least one fluorine atom, examples of other such substituents containing a fluorine atom include an alkyl group substituted with at least one fluorine atom.

Furthermore, the alkyl group, cycloalkyl group, and aryl group may be further substituted with a fluorine atom-free substituent. Examples of this substituent include ones not containing a fluorine atom out of those described above for Cy.

Examples of the alkyl group having at least one fluorine atom, represented by Rf, are the same as ones described above as the alkyl group substituted with at least one fluorine atom represented by Xf. Examples of the cycloalkyl group having at least one fluorine atom, represented by Rf, include a perfluorocyclopentyl group and a perfluorocyclohexyl group. Examples of the aryl group having at least one fluorine atom represented by Rf include a perfluorophenyl group.

Moreover, it is also preferable that the non-nucleophilic anion is an anion represented by any of the following General Formulae (B-1) to (B-3).

First, an anion represented by the following General Formula (B-1) will be described.

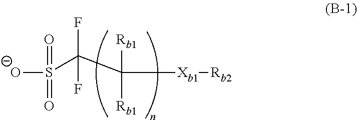

In General Formula (B-1),

R_{b1}'s each independently represent a hydrogen atom, a fluorine atom, or a trifluoromethyl group (CF₃),

n represents an integer of 1 to 4,

n is preferably an integer of 1 to 3, and more preferably 1 or 2,

X_{b1} represents a single bond, an ether bond, an ester bond (—OCO— or —COO—), or a sulfonic ester bond (—OSO₃— or —SO₃—),

X_{b1} is preferably an ester bond (—OCO— or —COO—) or a sulfonic acid ester bond (—OSO₂— or —SO₃—), and

R_{b2} represents a substituent having 6 or more carbon atoms.

The substituent having 6 or more carbon atoms with regard to R_{b2} is preferably a bulky group, and examples thereof include an alkyl group, an alicyclic group, an aryl group, and a heterocyclic group each having 6 or more carbon atoms.

As for R_{b2}, the alkyl group having 6 or more carbon atoms may be linear or branched, and a linear or branched alkyl group having 6 to 20 carbon atoms is preferable. Examples thereof include a linear or branched hexyl group, a linear or branched heptyl group, and a linear or branched octyl group. From the viewpoint of bulkiness, the branched alkyl group is preferable.

The alicyclic group having 6 or more carbon atoms for R_{b2} may be monocyclic or polycyclic. Examples of the monocyclic aliphatic group include a monocyclic cycloalkyl group such as a cyclohexyl group and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among these, alicyclic groups having a bulky structure with 7 or more carbon atoms, such as a norbornyl group, a tricyclodecanyl group, a tetracyclodecanyl group, a tetracyclododecanyl group, and an adamantyl group, are preferable from the viewpoints of inhibiting in-film diffusion in a post exposure bake (PEB) step and improving the Mask Error Enhancement Factor (MEEF).

The aryl group having 6 or more carbon atoms for R_{b2} may be monocyclic or polycyclic. Examples of the aryl group include a phenyl group, a naphthyl group, a phenanthryl group and an anthryl group. Among these, a naphthyl group having a relatively low light absorbance at 193 nm is preferable.

The heterocyclic group having 6 or more carbon atoms for R_{b2} may be monocyclic or polycyclic, but with a polycyclic heterocyclic group, the diffusion of an acid can be more inhibited. Further, the heterocyclic group may have aromaticity or may not have aromaticity Examples of the heterocycle having aromaticity include a benzofuran ring, a benzothiophene ring, a dibenzofuran ring, and a dibenzothiophene ring. Examples of the heterocycle not having aromaticity include a tetrahydropyran ring, a lactone ring, and a decahydroisoquinoline ring. The heterocycle in the heterocyclic group is particularly preferably a benzofuran ring or decahydroisoquinoline ring. Examples of the lactone ring include the lactone structures exemplified in the resin (A) as mentioned above.

The substituent having 6 or more carbon atoms for R_{b2} may further have a substituent. Examples of the further substituent include an alkyl group (which may be either linear or branched and preferably has 1 to 12 carbon atoms), a cycloalkyl group (which may be monocyclic, polycyclic, or spirocyclic, and preferably has 3 to 20 carbon atoms), an aryl group (which preferably has 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon atom constituting the alicyclic group, the aryl group, or the heterocyclic group as described above (the carbon contributing to ring formation) may be carbonyl carbon. Examples of the anion represented by General Formula (B-1) are shown below, but the present invention is not limited thereto.

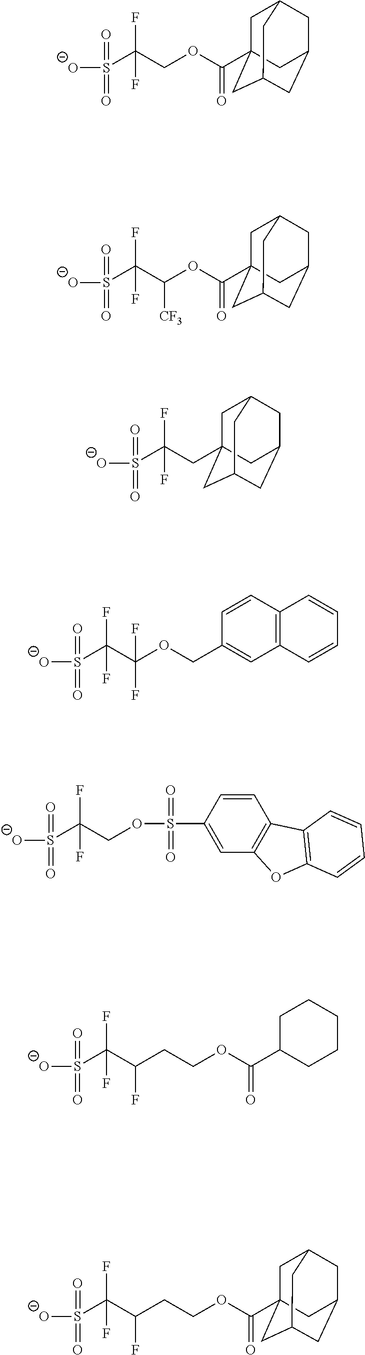

Next, an anion represented by the following General Formula (B-2) will be described.

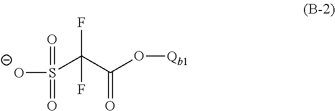

In General Formula (B-2),

Q_{b1} represents a group having a lactone structure, a group having a sultone structure, or a group having a cyclic carbonate structure.

Examples of the lactone structure or the sultone structure for Q_{b1} include the same lactone structures and the sultone structures as in the repeating units having lactone structures and the sultone structures as described earlier in the section of the resin (A). Specific examples thereof include the lactone structures represented by any of General Formulae (LC1-1) to (LC1-17) or the sultone structures represented by any of General Formulae (SL1-1) to (SL1-3).

The lactone structure or sultone structure as mentioned above may be in a state of binding directly to the oxygen atom in the ester group in General Formula (B-2) or in a state of binding to the oxygen atom in the ester group in General Formula (B-2) through an alkylene group (for example, a methylene group and an ethylene group). In this case, a group having the lactone structure or sultone structure can be referred to as an alkyl group having the lactone structure or sultone structure as a substituent.

The cyclic carbonate structure for Q_{b1} is preferably a 5- to 7-membered cyclic carbonate structure, and examples thereof include 1,3-dioxorane-2-one and 1,3-dioxane-2-one.

The cyclic carbonate structure may be in a state of binding directly to the oxygen atom in the ester group in General Formula (B-2) or in a state of binding to the oxygen atom in the ester group in General Formula (B-2) through an alkylene group (for example, a methylene group and an ethylene group). In this case, the group having the cyclic carbonate structure can be referred to as an alkyl group having the cyclic carbonate structure as a substituent.

Specific examples of the anion represented by the General Formula (B-2) will be shown below, but the present invention is not limited thereto.

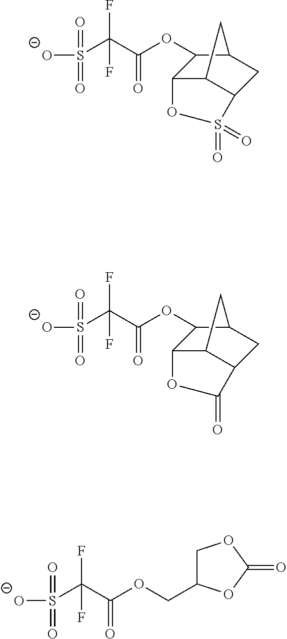

Next, the anion represented by the following General Formula (B-3) will be described.

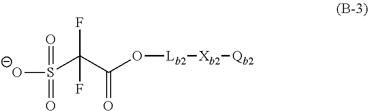

In General Formula (B-3),

L_{b2} represents an alkylene group having 1 to 6 carbon atoms, and examples thereof include a methylene group, an ethylene group, a propylene group, or a butylene group, and is preferably an alkylene group having 1 to 4 carbon atoms,

X_{b2} represents an ether bond or an ester bond (—OCO— or —COO—), and

Qb2 represents an alicyclic group, or a group containing an aromatic ring.

The alicyclic group with regard to Q_{b2} may be monocyclic or polycyclic. As the alicyclic group, an alicyclic group having a bulky structure having 7 or more carbon atoms, such as a norbornyl group, a tricyclodecanyl group, a tetracyclodecanyl group, a tetracyclodecanyl group, and an adamantyl group, is preferable.

The aromatic ring in the group containing an aromatic ring for Q_{b2} is preferably an aromatic ring having 6 to 20 carbon atoms, and examples thereof include a benzene ring, a naphthalene ring, a phenanthrene ring, and an anthracene ring, with the benzene ring and the naphthalene ring being more preferable. The aromatic ring may be substituted with at least one fluorine atom, and examples of the aromatic ring which is substituted with at least one fluorine atom include a perfluorophenyl group.

The aromatic ring may be in a state of binding directly to X_{b2}, or may be in a state of binding to X_{b2} through an alkylene group (for example, a methylene group and an ethylene group). In this case, the group containing the aromatic ring can be referred to as an alkyl group having the aromatic ring as a substituent.

Specific examples of the anion structure represented by General Formula (B-3) are shown below, but the present invention is not limited thereto.

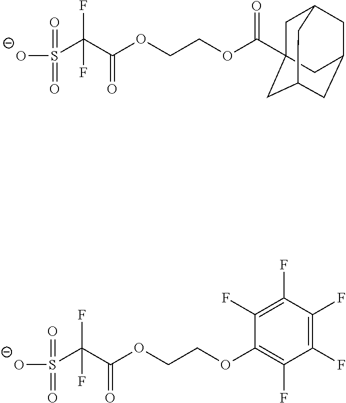

Examples of the organic group represented by R₂₀₁, R₂₀₂, and R₂₀₃ include corresponding groups in the compounds (ZI-1), (ZI-2), (ZI-3), and (ZI-4) as described later.

Incidentally, the compound may be a compound having a plurality of structures represented by General Formula (ZI). For example, the compound may be a compound having a structure in which at least one of R₂₀₁ to R₂₀₃ in a compound represented by General Formula (ZI) is bonded to at least one of R₂₀₁ to R₂₀₃ in another compound represented by General Formula (ZI) through a single bond or a linking group.

More preferred examples of the components (ZI) include the compounds (ZI-1), (ZI-2), (ZI-3), and (ZI-4) as described below.

The compound (ZI-1) is an arylsulfonium compound in which at least one of R₂₀₁ to R₂₀₃ in General Formula (ZI) is an aryl group, that is, a compound having arylsulfonium as the cation.

In the arylsulfonium compound, all of R₂₀₁ to R₂₀₃ may be an aryl group, or a part of R₂₀₁ to R₂₀₃ may be an aryl group, with the remainder being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, and more preferably a phenyl group. The aryl group may be an aryl group having a heterocyclic structure containing an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In the case where the arylsulfonium compound has two or more aryl groups, these two or more aryl groups may be the same as or different from each other.

The alkyl group or cycloalkyl group which is contained, if desired, in the arylsulfonium compound is preferably a linear or branched alkyl group having 1 to 15 carbon atoms or a cycloalkyl group having 3 to 15 carbon atoms.

The aryl group, the alkyl group, and the cycloalkyl group of R₂₀₁ to R₂₀₃ may have, as the substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group. The substituent is preferably a linear or branched alkyl group having 1 to 12 carbon atoms, a cycloalkyl group having 3 to 12 carbon atoms, or a linear, branched, or cyclic alkoxy group having 1 to 12 carbon atoms, more preferably an alkyl group having 1 to 4 carbon atoms, or an alkoxy group having 1 to 4 carbon atoms. The substituent may be substituted on any one of three members R₂₀₁ to R₂₀₃ or may be substituted on all of these three members. In the case where R₂₀₁ to R₂₀₃ are each an aryl group, the substituent is preferably substituted on the p-position of the aryl group.

Next, the compound (ZI-2) will be described.

The compound (ZI-2) is a compound in which R₂₀₁ to R₂₀₃ in Formula (ZI) each independently represent an organic group having no aromatic ring. The aromatic ring as used herein encompasses an aromatic ring containing a heteroatom.

The organic group having no aromatic ring as R₂₀₁ to R₂₀₃ has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

Preferred examples of the alkyl group and the cycloalkyl group of R₂₀₁ to R₂₀₃ include a linear or branched alkyl group having 1 to 10 carbon atoms, and a cycloalkyl group having 3 to 10 carbon atoms. More preferred examples of the alkyl group include a 2-oxoalkyl group and an alkoxycarbonylmethyl group. More preferred examples of the cycloalkyl group include a 2-oxocycloalkyl group.

The 2-oxoalkyl group may be linear or branched, and preferred examples thereof include a group having >C═O at the 2-position of the alkyl group.

Preferred examples of the 2-oxocycloalkyl group include a group having >C═O at the 2-position of the cycloalkyl group.

Preferred examples of the alkoxy group that may be mentioned as the alkoxycarbonylmethyl group include an alkoxy group having 1 to 5 carbon atoms (a methoxy group, an ethoxy group, a propoxy group, a butoxy group, and a pentoxy group).

R₂₀₁ to R₂₀₃ may be further substituted with a halogen atom, an alkoxy group (for example, having 1 to 5 carbon atoms), a hydroxyl group, a cyano group, and a nitro group.

Next, the compound (ZI-3) will be described.

The compound (ZI-3) is a compound represented by the following General Formula (ZI-3), which has a phenacylsulfonium salt structure.

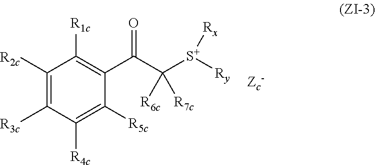

In General Formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,

R_{6c} and R_{7c} each independently represent a hydrogen atom, an alkyl group, a cycloalkyl group, a halogen atom, a cyano group, or an aryl group, and

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more members out of R_{1c} to R_{5c}, R_{5c} and R_{6c}, and R_{6c}and R_{7c}, R_{5c} and Rₓ, or Rₓ and R_{y} may be bonded to each other to form a ring structure. This ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocycle, and a polycyclic fused ring formed by combination of two or more members out of these rings. Examples of the ring structure include 3- to 10-membered rings, with 4- to 8-membered rings being preferable, and 5- or 6-membered rings being more preferable.

Examples of the group formed by combination of any two or more members out of R_{1c} to R_{5c}, a pair of and R_{6c} R_{7c} , or a pair of Rₓ and R_{y} include a butylene group, and a pentylene group.

The group formed by combination of a pair of R_{5c} and R_{6c}, or a pair of R_{5c} and Rₓ is preferably a single bond or an alkylene group, and examples of the alkylene group include a methylene group and an ethylene group.

Zₑ⁻ represents a non-nucleophilic anion, and examples thereof include the same ones as the non-nucleophilic anions of Z⁻ in General Formula (ZI).

The alkyl group as R_{1c} to R_{7c} may be linear or branched and examples thereof include an alkyl group having 1 to 20 carbon atoms, and preferably a linear or branched alkyl group having 1 to 12 carbon atoms. Examples of the cycloalkyl group include a cycloalkyl group having 3 to 10 carbon atoms.

The aryl group as R_{1c} to R_{5c} is preferably an aryl group having 5 to 15 carbon atoms, and examples thereof include a phenyl group and a naphthyl group.

The alkoxy group as R_{1c} to R_{5c} may be linear, branched, or cyclic, and examples thereof include an alkoxy group having 1 to 10 carbon atoms, and preferably a linear or branched alkoxy group having 1 to 5 carbon atoms, and acyclic alkoxy group having 3 to 10 carbon atoms.

Specific examples of the alkoxy group in the alkoxycarbonyl group as R_{1c} to R_{5c} are the same as the specific examples of the alkoxy group as R_{1c} to R_{5c} above.

Specific examples of the alkyl group in the alkylcarbonyloxy group and the alkylthio group as R_{1c} to R_{5c} are the same as the specific examples of the alkyl group as R_{1c} to R_{5c} above.

Specific examples of the cycloalkyl group in the cycloalkylcarbonyloxy group as R_{1c} to R_{5c} are the same as the specific examples of the cycloalkyl group as R_{1c} to R_{5c} above.

Specific examples of the aryl group in the aryloxy group and the arylthio group as R_{1c} to R_{5c} are the same as the specific examples of the aryl group as R_{1c} to R_{5c} above.

It is preferable that any one of R_{1c} to R_{5c} is a linear or branched alkyl group, a cycloalkyl group, or a linear, branched, or cyclic alkoxy group, and it is more preferable that the sum of number of carbon atoms of R_{1c} to R_{5c} is 2 to 15. With this, the solvent solubility is more enhanced, and generation of particles during storage can be inhibited.

Preferred examples of the ring structure which may be formed by the mutual bonding of any two or more members of R_{1c} to R_{5c} include 5- or 6-membered rings, and particularly preferred examples thereof include 6-membered rings (for example, a phenyl ring).

Examples of the ring structure which may be formed by the mutual bonding of R_{5c} and R_{6c} include a 4-membered or higher-membered ring (particularly preferably a 5- or 6-membered ring) formed together with the carbonyl carbon atom and the carbon atom in General Formula (ZI-3) by the mutual bonding of R_{5c} and R_{6c} to constitute a single bond or an alkylene group (a methylene group, an ethylene group, and the like).

The aryl group as R_{5c} and R_{7c} preferably has 5 to 15 carbon atoms, and examples thereof include a phenyl group and a naphthyl group.

As an embodiment of R_{6c} and R_{7c}, a case where both are each an alkyl group is preferable, and in particular, a case where R_{6c} and R_{7c} are each a linear or branched alkyl group having 1 to 4 carbon atoms is more preferable, and a case where both are a methyl group is particularly preferable.

In the case where R_{6c} and R_{7c} are bonded to each other to form a ring, the group formed by the mutual bonding of R_{6c} and R_{7c} is preferably an alkylene group having 2 to 10 carbon atoms, and examples thereof include an ethylene group, a propylene group, a butylene group, a pentylene group, and a hexylene group. Further, the ring formed by the mutual bonding of R_{6c} and R_{7c} may contain a heteroatom such as an oxygen atom in the ring.

Examples of the alkyl group and the cycloalkyl group as Rₓ and R_{y} include the same ones as the alkyl groups and the cycloalkyl groups with respect to R_{1c} to R_{7c}.

Examples of the 2-oxoalkyl group and the 2-oxocycloalkyl group as Rₓ and R_{y} include a group having >C═O at the 2-position of the alkyl group and the cycloalkyl group as R_{1c} to R_{7c}.

Examples of the alkoxy group in the alkoxycarbonylalkyl group as Rₓ and R_{y} include the same ones as the alkoxy groups with respect to R_{1c} to R_{5c}. Examples of the alkyl group include an alkyl group having 1 to 12 carbon atoms, and preferably a linear alkyl group having 1 to 5 carbon atoms (for example, a methyl group and an ethyl group).

The allyl group as Rₓ and R_{y} is not particularly limited but is preferably an unsubstituted allyl group or an allyl group substituted with a monocyclic or polycyclic cycloalkyl group (preferably a cycloalkyl group having 3 to 10 carbon atoms).

The vinyl group as Rₓ and R_{y} is not particularly limited, but is preferably an unsubstituted vinyl group or a vinyl group substituted with a monocyclic or polycyclic cycloalkyl group (preferably a cycloalkyl group having 3 to 10 carbon atoms).

Examples of the ring structure which may be formed by the mutual bonding of R_{5c} and Rₓ include a 5-membered or higher-membered ring (preferably a 5-membered ring) formed by the mutual bonding of R_{5c} and Rₓ to constitute a single bond or an alkylene group (for example, a methylene group and an ethylene group) together with the sulfur atom and carbonyl carbon atom in General Formula (ZI-3).

Examples of the ring structure which may be formed by the mutual bonding of Rₓ and R_{y} includes a 5- or 6-membered ring, and preferably a 5-membered ring (that is, a tetrahydrothiophene ring) formed by the mutual bonding of divalent Rₓ and R_{y} (for example, a methylene group, an ethylene group, and a propylene group) together with the sulfur atom in General Formula (ZI-3).

Rₓ and R_{y} are preferably an alkyl or cycloalkyl group having 4 or more carbon atoms, more preferably 6 or more carbon atoms, and still more preferably 8 or more carbon atoms.

R_{1c} to R_{7c}, and Rₓ, and R_{y} may further have a substituent, and examples of such a substituent include a halogen atom (for example, a fluorine atom), a hydroxyl group, a carboxyl group, a cyano group, a nitro group, an alkyl group, a cycloalkyl group, an aryl group, au alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyloxy group.

In General Formula (ZI-3), it is more preferable that R_{1c}, R_{2c}, R_{4c}, and R_{5c} each independently represent a hydrogen atom, and R_{3c} represents a group except for a hydrogen atom, that is, represents an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Examples of the cation in the compound represented by General Formula (ZI-2) or (ZI-3) in the present invention including the specific examples as follows.

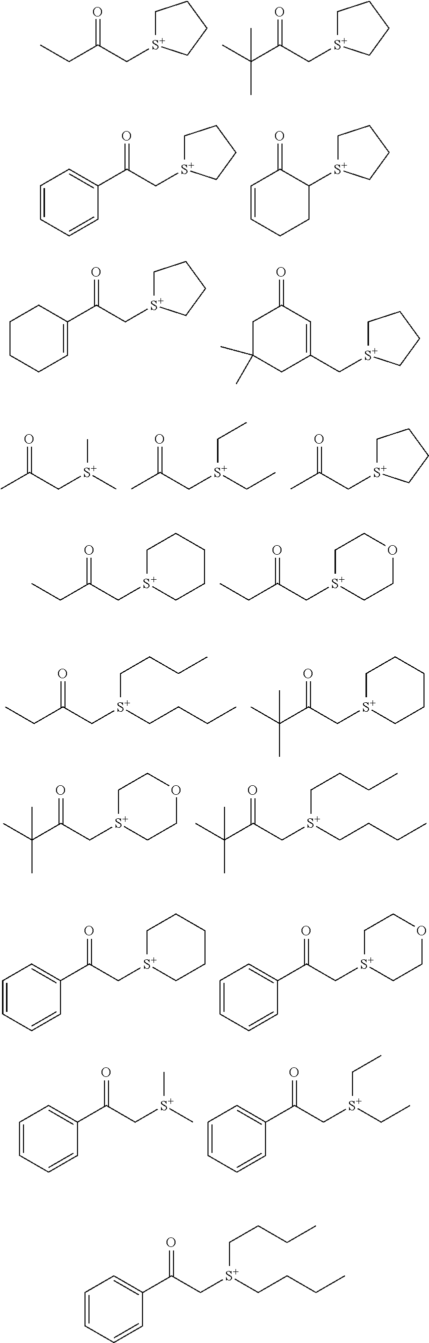

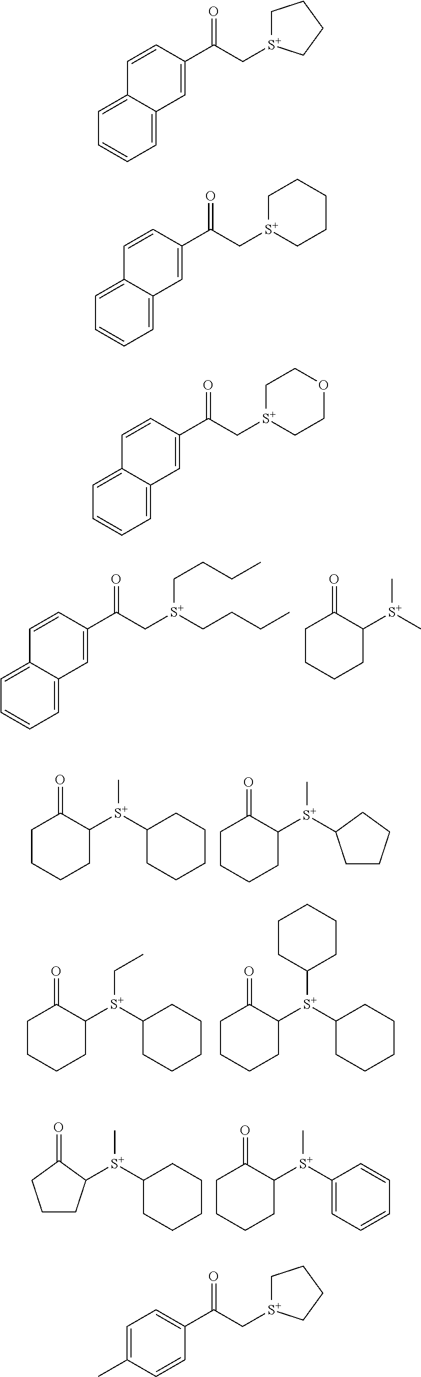

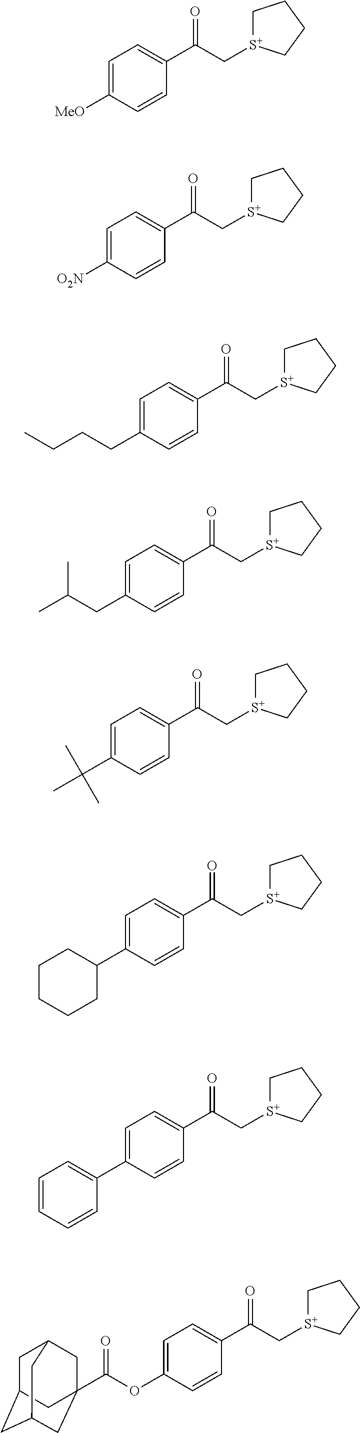

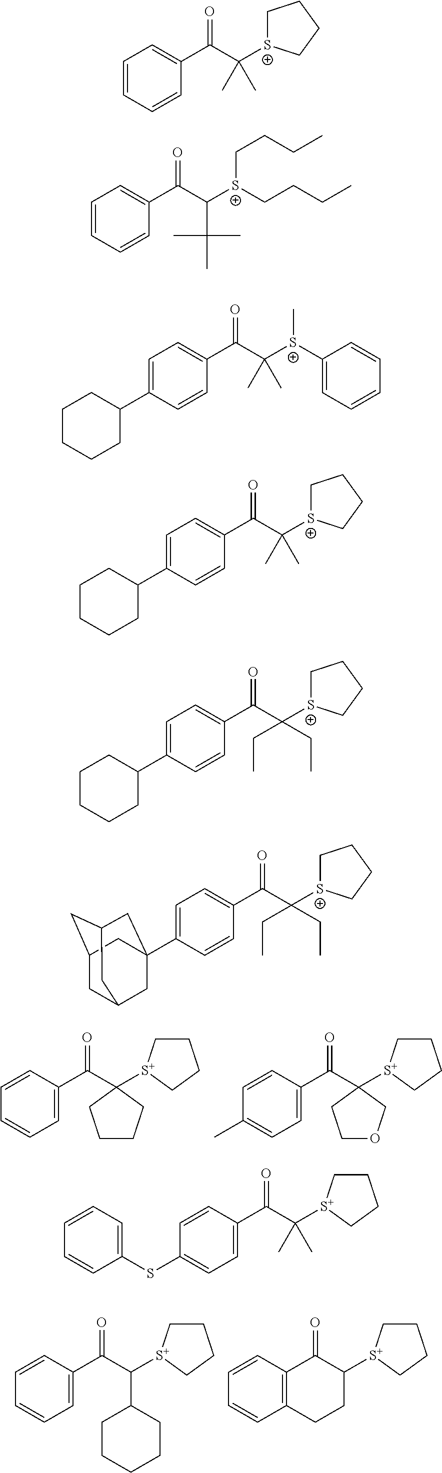

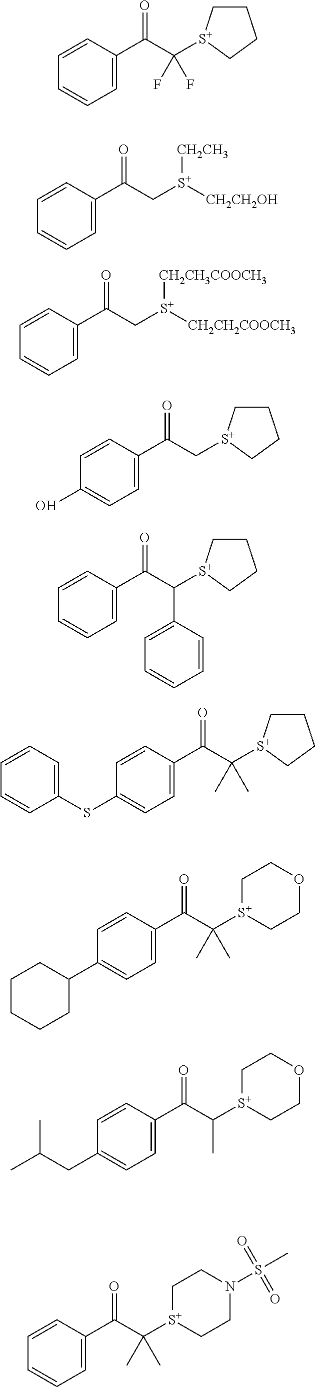

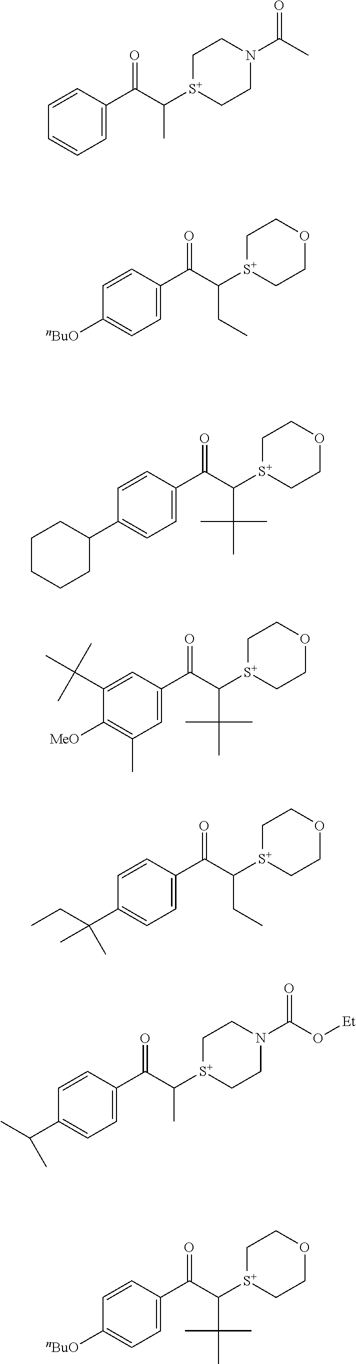

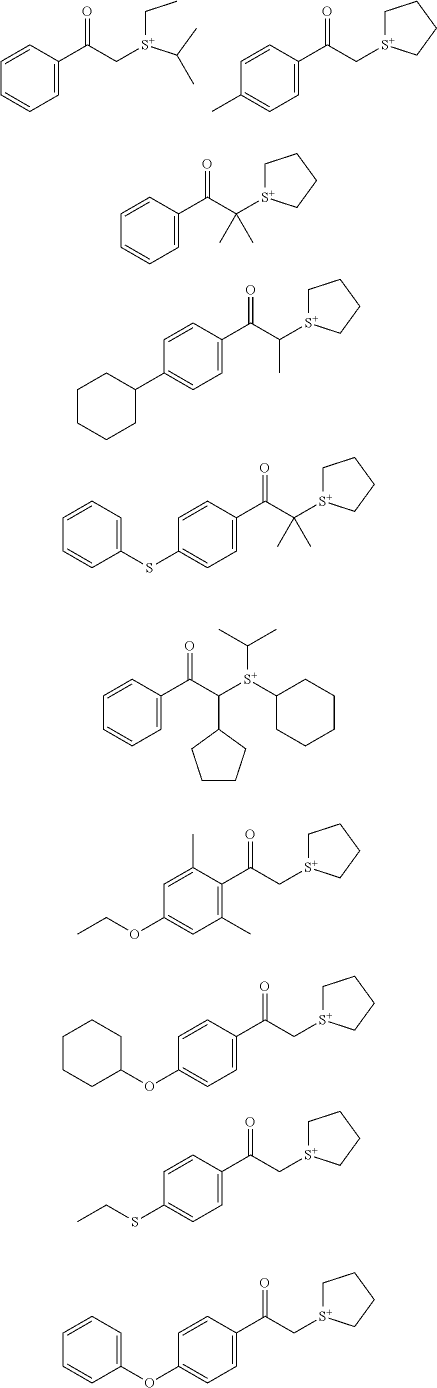

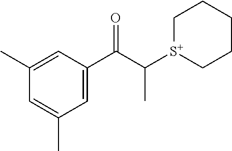

Next, the compound (ZI-4) will be described.

The compound (ZI-4) is represented by the following General Formula (ZI-4).

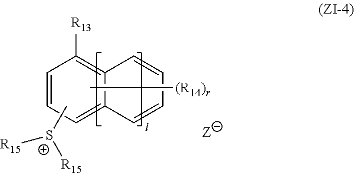

In General Formula (ZI-4),

R₁₃ represents a hydrogen atom, a fluorine atom, a hydroxyl group, an alkyl group, a cycloalkyl group, an alkoxy group, an alkoxycarbonyl group, or a group having a cycloalkyl group, and these groups may have a substituent,

in the case where a plurality of R¹⁴'s are present, R₁₄'s each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group, and these groups may have a substituent,

R₁₅'s each independently represent an alkyl group, a cycloalkyl group, or a naphthyl group, two R₁₅'s may be bonded to each other to form a ring, and these groups may have a substituent,

l represents an integer of 0 to 2,

r represents an integer of 0 to 8, and

Z⁻ represents a non-nucleophilic anion, and examples thereof include the same ones as the nucleophilic anions of Z⁻ in General Formula (ZI).

In General Formula (ZI-4), as the alkyl group of R₁₃, R₁₄, and R₁₅, a linear or branched alkyl group having 1 to 10 carbon atoms is preferable.

Examples of the cycloalkyl group of R₁₃, R₁₄, and R₁₅ include a monocyclic or polycyclic cycloalkyl group (preferably a cycloalkyl group having 3 to 20 carbon atoms), with cyclopropyl, cyclopentyl, cyclohexyl, cycloheptyl, and cyclooctyl being particularly preferable.

As the alkoxy group of R₁₃ and R₁₄, a linear or branched alkoxy group having 1 to 10 carbon atoms is preferable.

The alkoxycarbonyl group of R₁₃ and R₁₄ is preferably a linear or branched alkoxycarbonyl group having 2 to 11 carbon atoms, and preferred examples thereof include a methoxycarbonyl group, an ethoxycarbonyl group, and an n-butoxycarbonyl group.

Examples of the group having a cycloalkyl group of R₁₃ and R₁₄ include a monocyclic or polycyclic cycloalkyl group (preferably a cycloalkyl group having 3 to 20 carbon atoms), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ preferably has a total number of carbon atoms of 7 or more, and more preferably has a total number of carbon atoms of 7 to 15, and it is preferably a monocyclic cycloalkyl group. The monocyclic cycloalkyloxy group having a total number of carbon atoms of 7 or more refers to a monocyclic cycloalkyloxy group in which a cycloalkyloxy group such as a cyclopropyloxy group, a cyclobutyloxy group, a cyclopentyloxy group, a cyclohexyloxy group, a cycloheptyloxy group, a cyclooctyloxy group, and a cyclododecanyloxy group arbitrarily has a substituent such as an alkyl group, a hydroxyl group, a halogen atom (for example, fluorine, chlorine, bromine, and iodine), a nitro group, a cyano group, an amido group, a sulfonamido group, an alkoxy group, an alkoxycarbonyl group, an acyl group such as a formyl group, an acetyl group, and a benzoyl group, an acyloxy group, and a carboxyl group, and in which the total number of carbon atoms inclusive of the number of carbon atoms of an arbitrary substituent on the cycloalkyl group is 7 or more.

Furthermore, examples of the polycyclic cycloalkyloxy group having a total number of carbon atoms of 7 or more include a norbornyloxy group, a tricyclodecanyloxy group, a tetracyclodecanyloxy group, and an adamantyloxy group.

The alkoxy group having a monocyclic or polycyclic cycloalkyl group of R₁₃ and R₁₄ has a total number of carbon atoms of preferably 7 or more, and more preferably a total number of carbon atoms of 7 to 15, and is preferably an alkoxy group having a monocyclic cycloalkyl group. The alkoxy group having a total number of carbon atoms of 7 or more and having a monocyclic cycloalkyl group refers to an alkoxy group in which the above-described monocyclic cycloalkyl group which may have a substituent is substituted on an alkoxy group such as methoxy, ethoxy, propoxy, butoxy, pentyloxy, hexyloxy, heptoxy, octyloxy, dodecycloxy, 2-ethylhexyloxy, isopropoxy, sec-butoxy, t-butoxy, and isoamyloxy, in which the total number of carbon atoms inclusive of the number of carbon atoms of the substituent is 7 or more. Examples thereof include a cyclohexylinethoxy group, a cyclopentylethoxy group, and a cyclohexylethoxy group, with a cyclohexylmethoxy group being preferable.

Examples of the alkoxy group having a total number of carbon atoms of 7 or more and having a polycyclic cycloalkyl group include a norbonylmethoxy group, a norbonylethoxy group, a tricyclodecanylmethoxy group, a tricyclodecanylethoxy group, a tetracyclodecanylmethoxy group, a tetracyclodecanylethoxy group, an adamantylmethoxy group, and an adamantylethoxy group, with the norhomylmethoxy group and the norbornyledioxy group being preferable.

Examples of the alkyl group in the alkylcarbonyl group of R₁₄ include the same specific examples as the alkyl group of R₁₃ to R₁₅ as described above.

The alkylsulfonyl group and the cycloalkylsulfonyl group of R₁₄ are each a linear, branched, or cyclic alkylsulfonyl group preferably having 1 to 10 carbon atoms, and preferred examples thereof include a methanesulfonyl group, an ethanesulfonyl group, an n-propanesulfonyl group, an n-butanesulfonyl group, a cyclopentanesulfonyl group, and a cyclohexanesulfonyl group.

Examples of the substituent which may be substituted on each of the groups above include a halogen atom (for example, a fluorine atom), a hydroxyl group, a carboxyl group, a cyano group, a nitro group, an alkoxy group, an alkoxyalkyl group, an alkoxycarbonyl group, and an alkoxycarbonyloxy group.

Examples of the alkoxy group include a linear, branched, or cyclic alkoxy group having 1 to 20 carbon atoms.

Examples of the alkoxyalkyl group include a linear, branched, or cyclic alkoxyalkyl group having 2 to 21 carbon atoms.

Examples of the alkoxycarbornyl group include a linear, branched, or cyclic alkoxycarbornyl group having 2 to 21 carbon atoms.

Examples of the alkoxycarbonyloxy group include a linear, branched, or cyclic alkoxycarbonyloxy group having 2 to 21 carbon atoms.

The ring structure which may be formed by the mutual bonding of two R₁₅'s includes a 5- or 6-membered ring, preferably a 5-membered ring (that is, a tetrahydrothiophene ring), formed by two R₁₅'s together with the sulfur atom in General Formula (ZI-4) and may be fused with an aryl group or a cycloalkyl group. The two R₁₅'s may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, and an alkoxycarbonyloxy group. With regard to the substituent un the ring structure, a plurality of substituents may be present, and they may be bonded to each other to form a ring (an aromatic or non-aromatic hydrocarbon ring, an aromatic or non-aromatic heterocycle, or a polycyclic fused ring formed by combination of two or more of these rings).

R₁₅ in General Formula (ZI-4) is preferably, for example, a methyl group, an ethyl group, a naphthyl group, or a divalent group capable of forming a tetrahydrothiophene ring structure together with the sulfur atom when two R₁₅'s are bonded to each other.

The substituent which R₁₃ and R₁₄ may have is preferably a hydroxyl group, an alkoxy group, an alkoxycarbonyl group, or a halogen atom (in particular, a fluorine atom).

l is preferably 0 or 1, and more preferably 1.

r is preferably 0 to 2.

Examples of the cation in the compound represented by General Formula (ZI-4) in the present invention include the following specific examples.

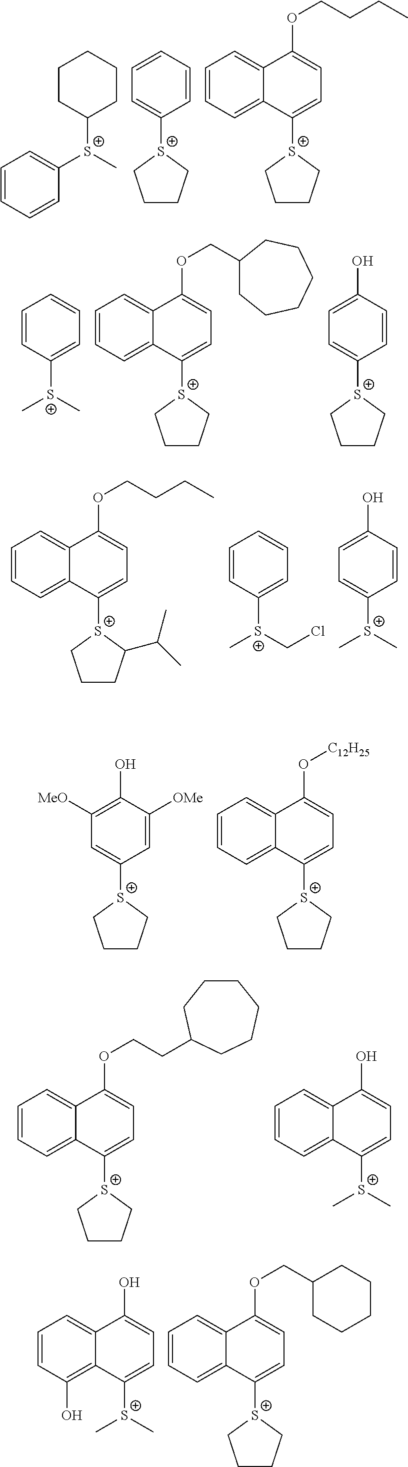

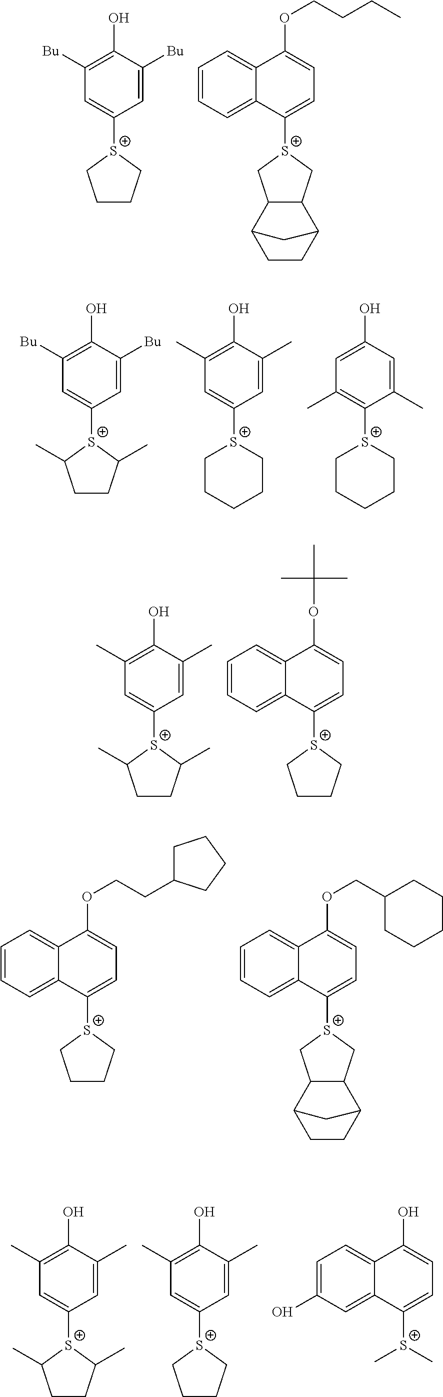

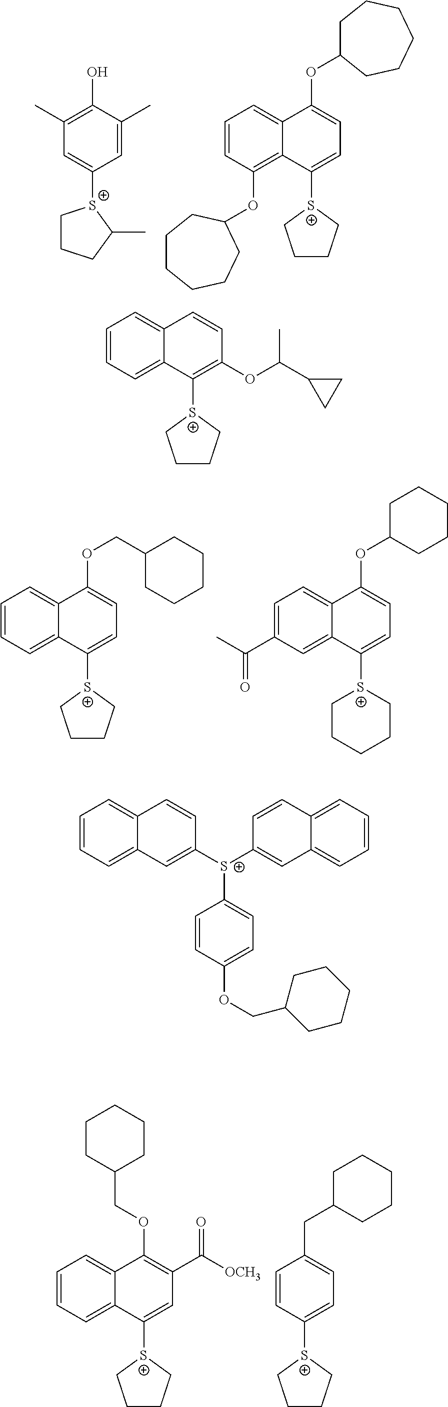

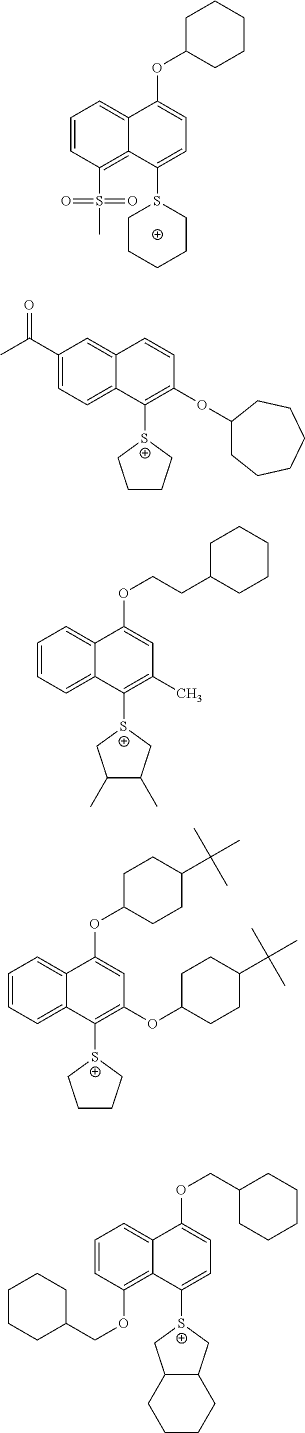

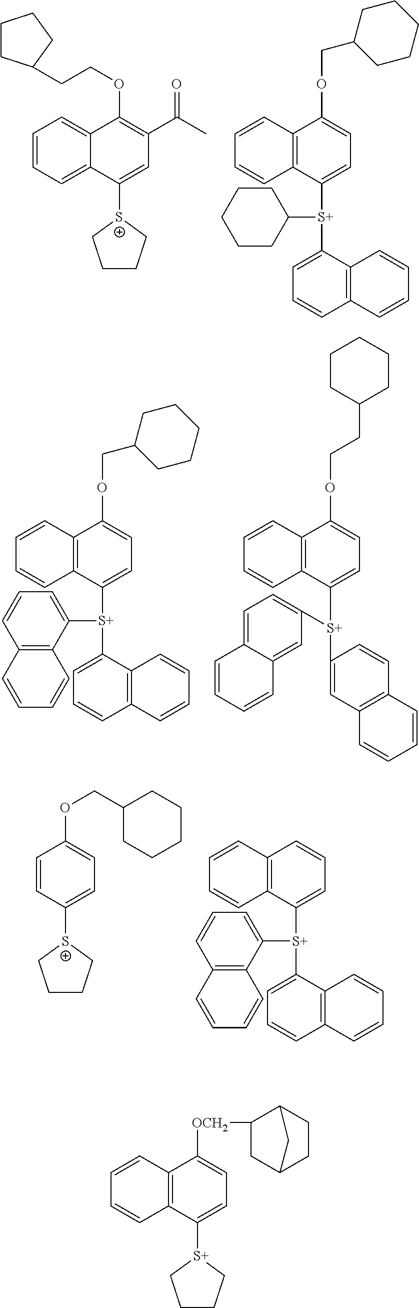

Next, General Formulae (ZII) and (ZIII) will be described.

In General Formulae (ZII) and (ZIII),

R₂₀₄ to R₂₀₇ independently represent an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure containing an oxygen atom, a nitrogen atom, a sulfur atom, or the like. Examples of the framework of the aryl group having a heterocyclic structure include pyrrole, furan, thiophene, indole, benzofuran, and benzothiophene.

The alkyl group and the cycloalkyl group with respect to R₂₀₄ to R₂₀₇ are preferably a linear or branched alkyl group having 1 to 10 carbon atoms (for example, a methyl group, an ethyl group, a propyl group, a butyl group, and a pentyl group) and a cycloalkyl group having 3 to 10 carbon atoms (for example, a cyclopentyl group, a cyclohexyl group, and a norbornyl group).

The aryl group, the alkyl group, and the cycloalkyl group of R₂₀₄ to R₂₀₇ may have a substituent, and examples of the substituent which the aryl group, an alkyl group and cycloalkyl group of R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents a non-nucleophilic anion, and examples thereof include the same ones as the non-nucleophilic anions of Z⁻ in General Formula (ZI).

Other examples of the acid generator include compounds represented by the following General Formulae (ZIV), (ZV), and (ZVI).

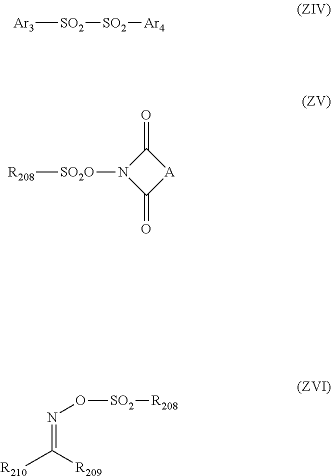

In General Formulae (ZIV) to (ZVI),

Ar₃ and Ar₄ each independently represent an aryl group, and R₂₀₈, R₂₀₉, and R₂₁₀ each independently represent an alkyl group, a cycloalkyl group, or an aryl group, and

A represents an alkylene group, an alkenylene group, or an arylene group.

Specific examples of the aryl group of Ar₃, Ar₄, R₂₀₈, R₂₀₉, and R₂₁₀ include the same ones as the specific examples of the aryl group of R₂₀₁, R₂₀₂, and R₂₀₃ in General Formula (ZI-1).

Specific examples of the alkyl group and the cycloalkyl group of R₂₀₈, R₂₀₉, and R₂₁₀ include the same ones as the specific examples of the alkyl group and the cycloalkyl group of R₂₀₁, R₂₀₂, and R₂₀₃ in General Formula (ZI-2).

Examples of the alkylene group of A include an alkylene group having 1 to 12 carbon atoms (for example, a methylene group, an ethylene group, a propylene group, an isopropylene group, a butylene group, and an isobutylene group); examples of the alkenylene group of A include an alkenylene group having 2 to 12 carbon atoms (for example, an ethenylene group, a propenylene group, and a butenylene group); and examples of the arylene group of A include an arylene group having 6 to 10 carbon atoms (for example, a phenylene group, a tolylene group, and a naphthylene group).

Among the acid generators, the compounds represented by General Formulae (ZI) to (ZIII) are more preferable.

Furthermore, the acid generator is preferably a compound capable of generating an acid having one sulfonic acid group, or imido group, more preferably a compound capable of generating a monovalent perfluoroalkanesulfonic acid, a compound capable of generating an aromatic sulfonic acid substituted with a monovalent fluorine atom or a group containing a fluorine atom, or a compound capable of generating an imide acid substituted with a monovalent fluorine atom or a group containing a fluorine atom, and still more preferably a sulfonium salt of a fluoro-substituted alkanesulfonic acid, a fluorine-substituted benzenesulfonic acid, a fluorine-substituted imide acid, or a fluorine-substituted methide acid. The acid generator which can be used is particularly preferably a compound capable of generating a fluoro-substituted alkanesulfonic acid, a fluoro-substituted benzenesulfonic acid, or a fluoro-substituted imide acid, in which pKa of the acid generated is or less, thereby enhancing the sensitivity.

Among the acid generators, particularly preferred examples are shown below.

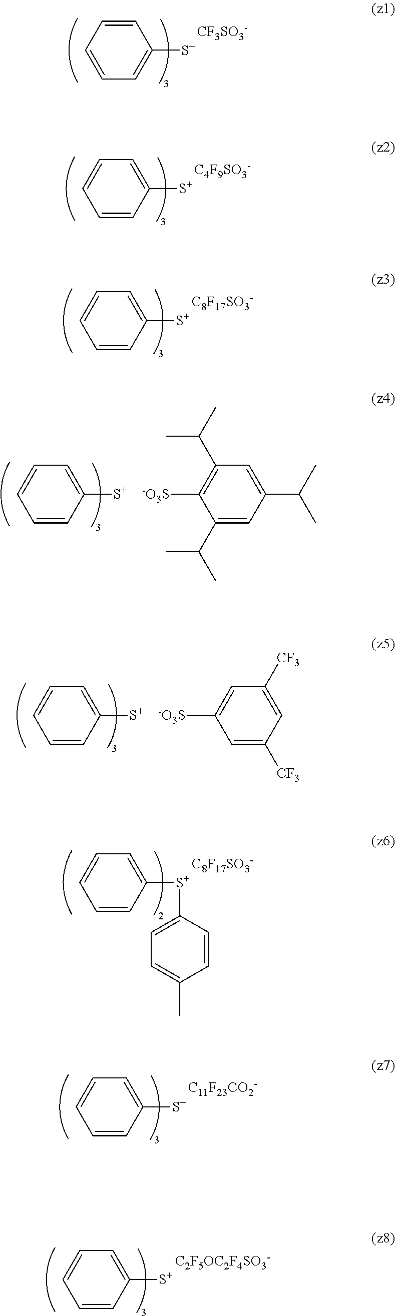

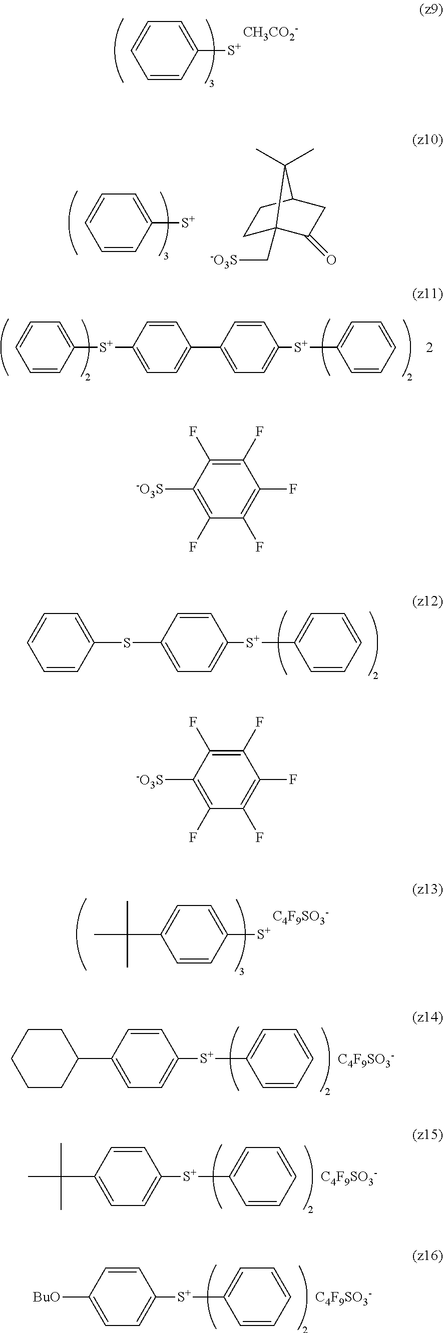

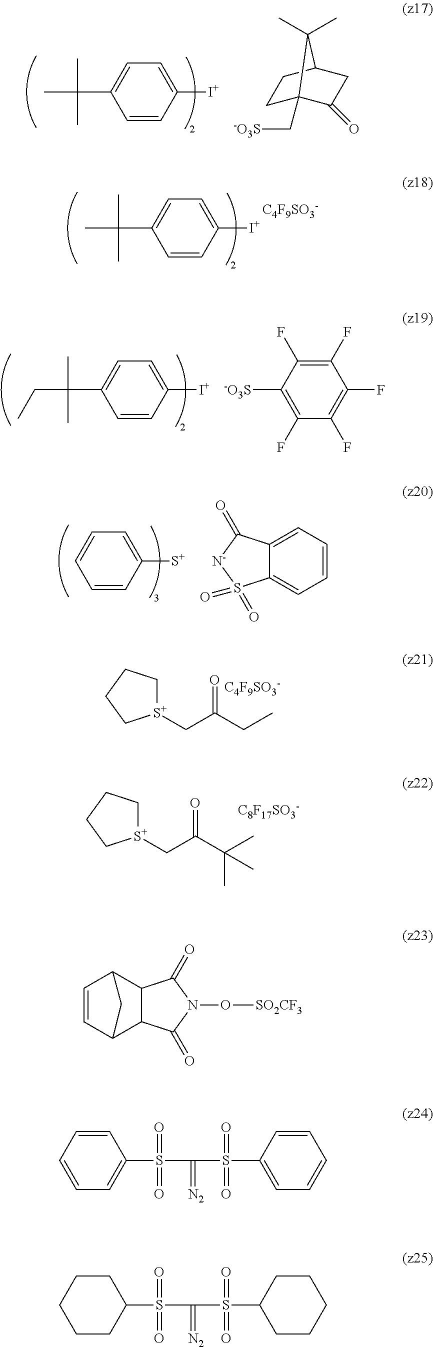

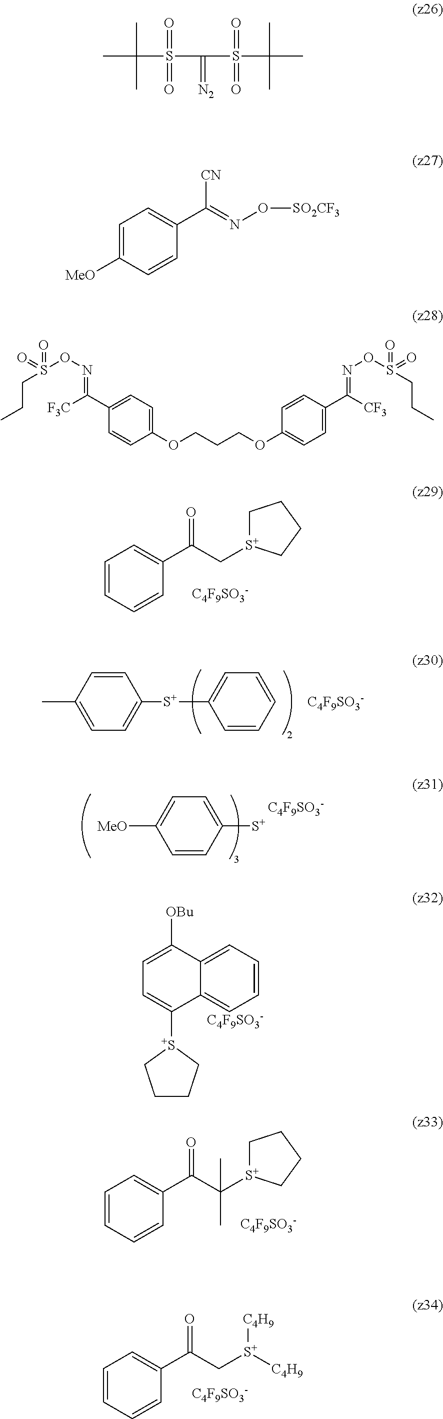

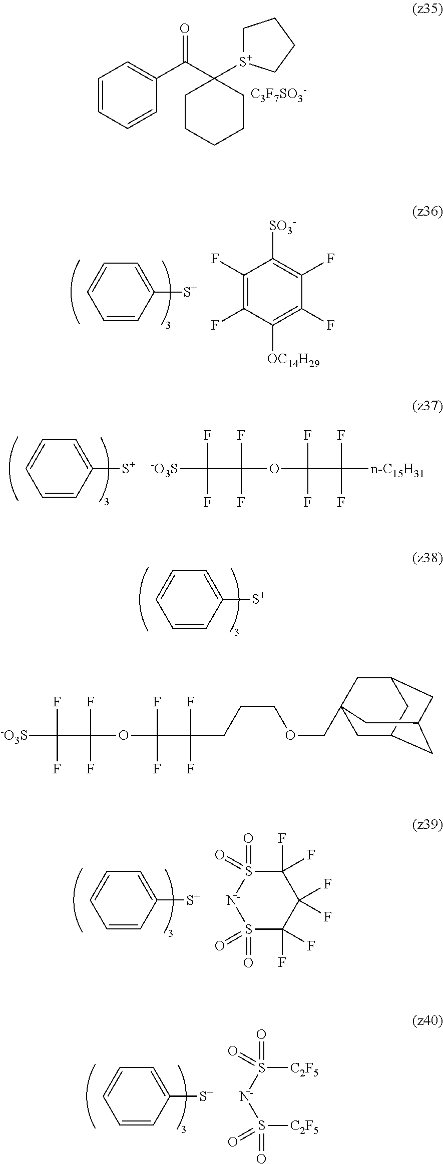

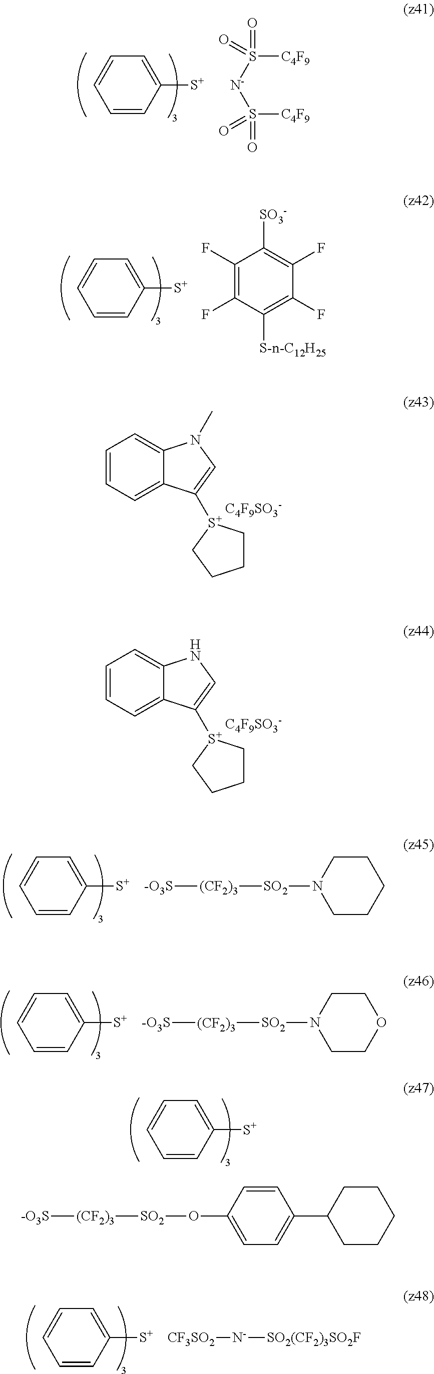

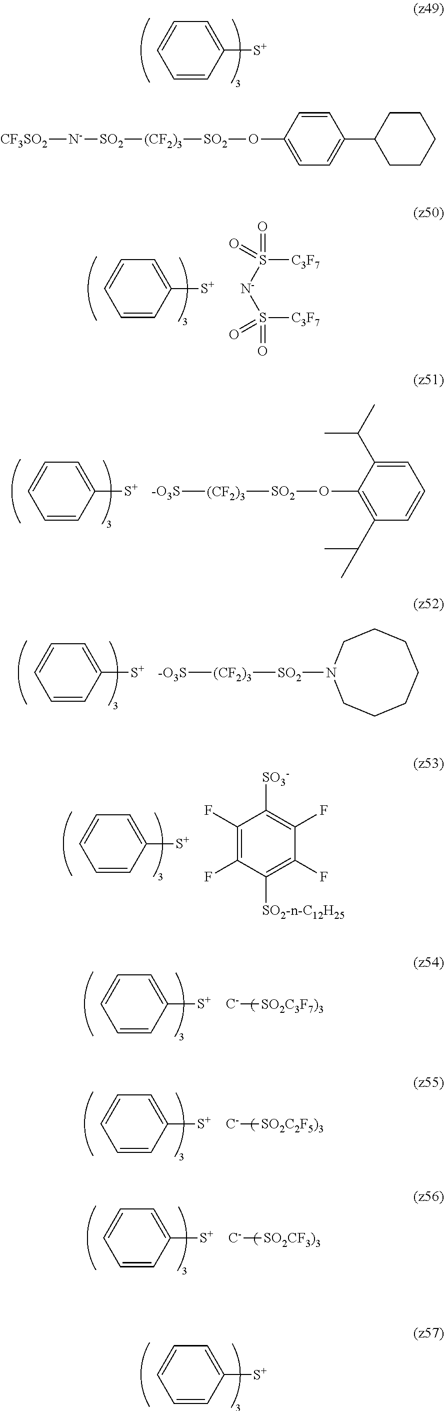

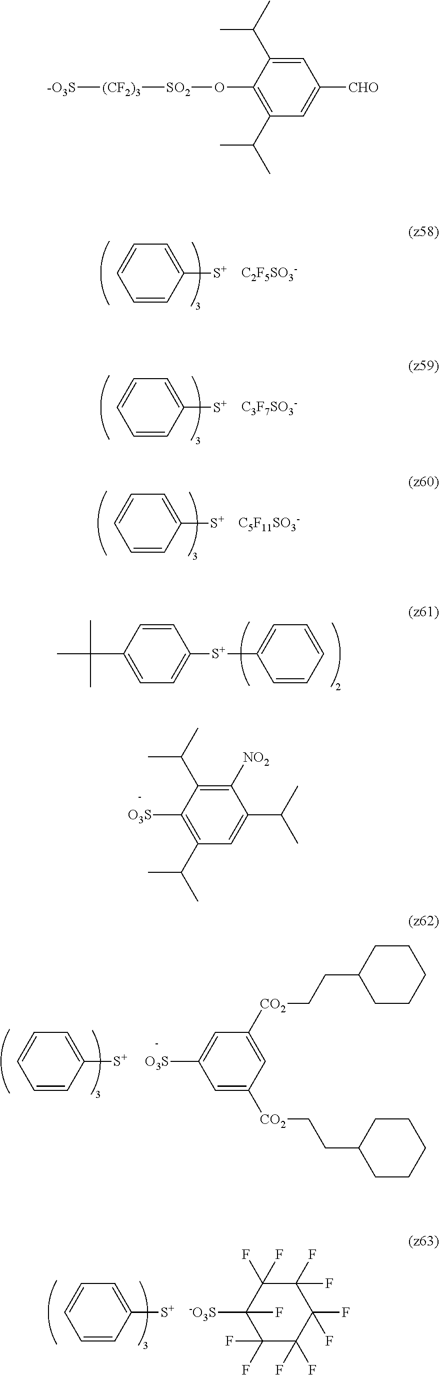

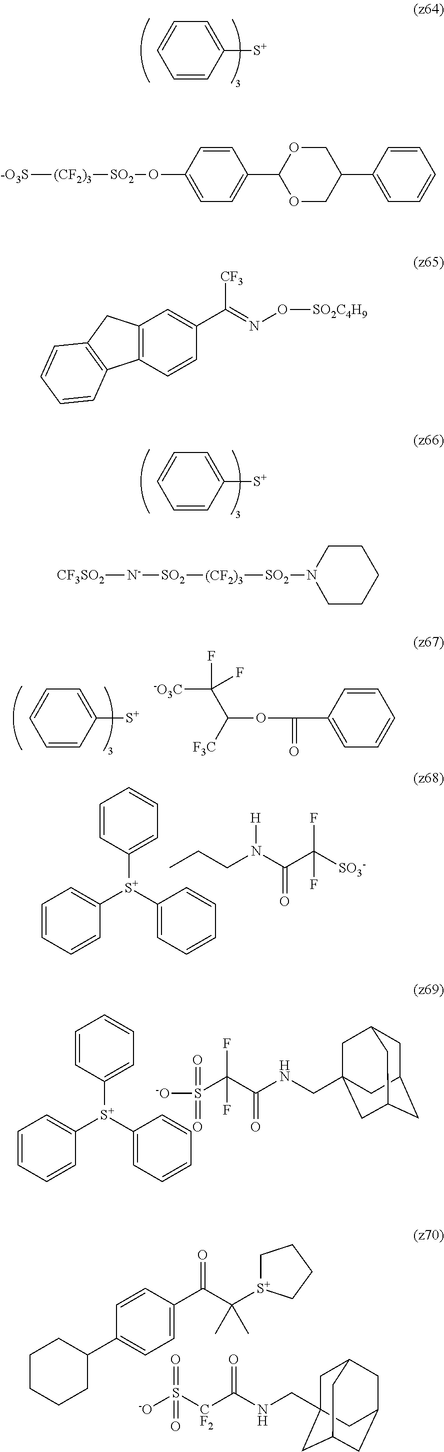

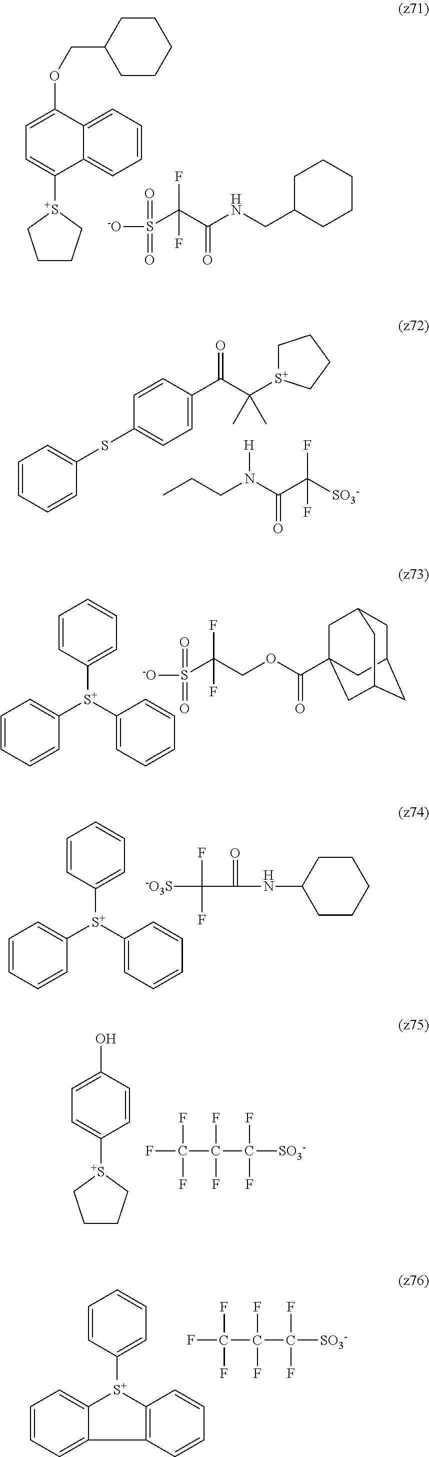

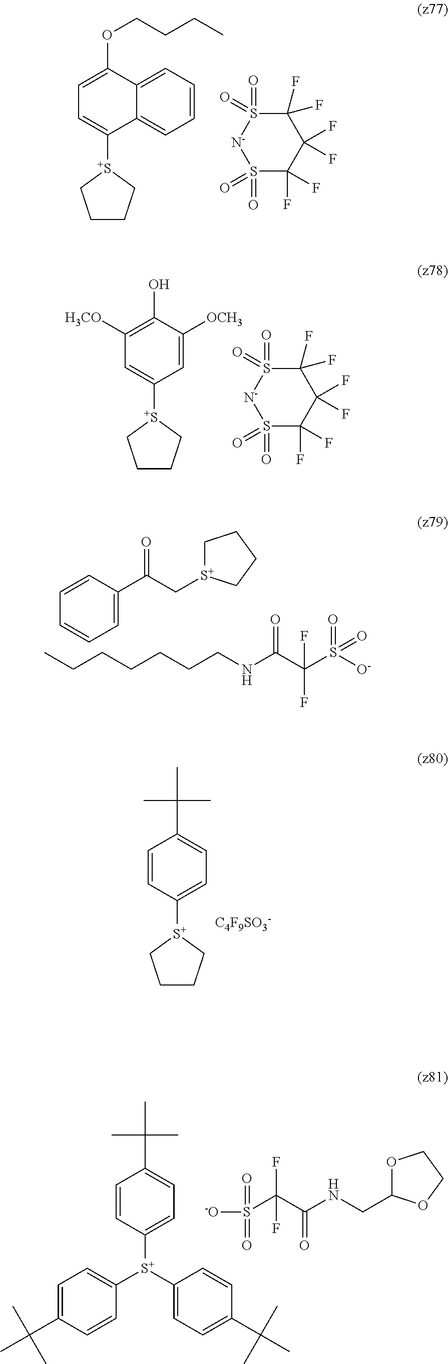

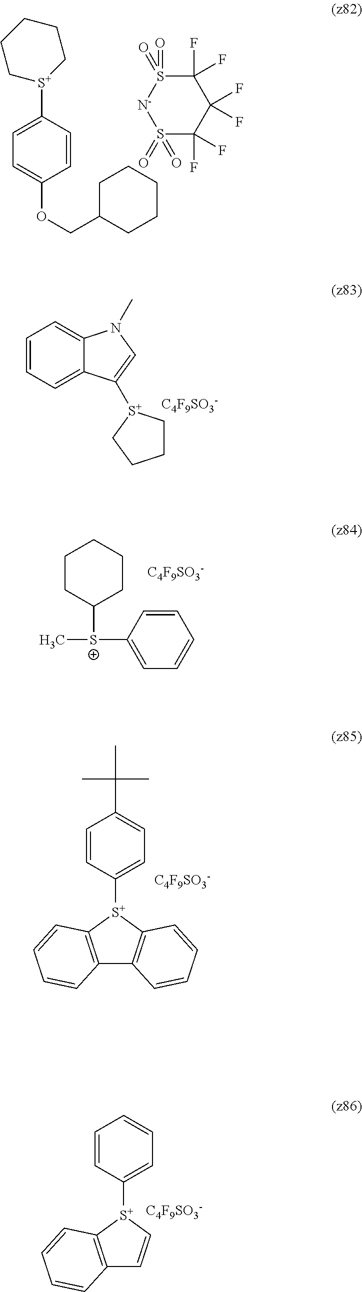

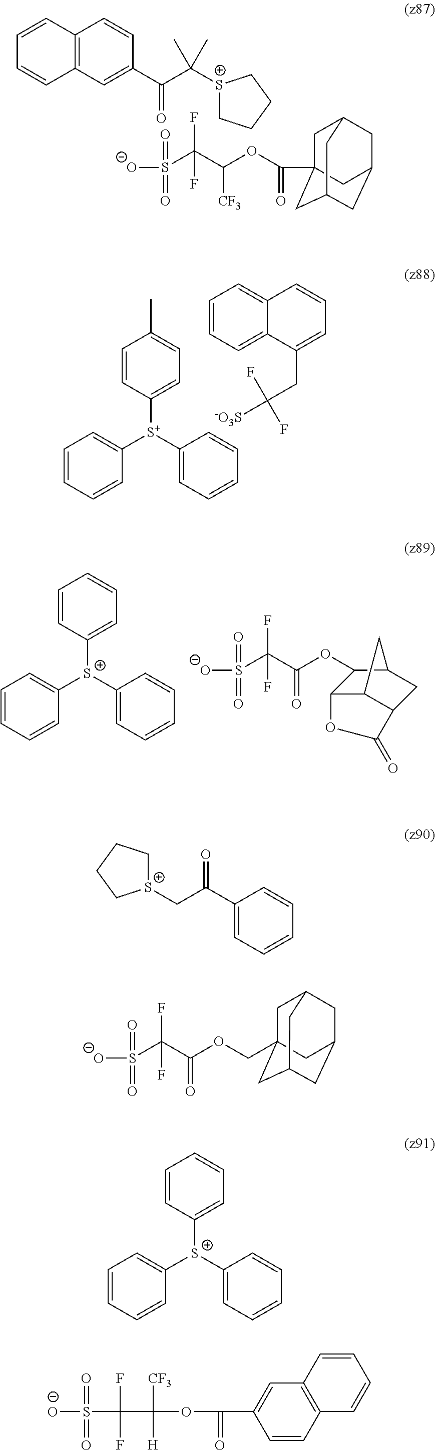

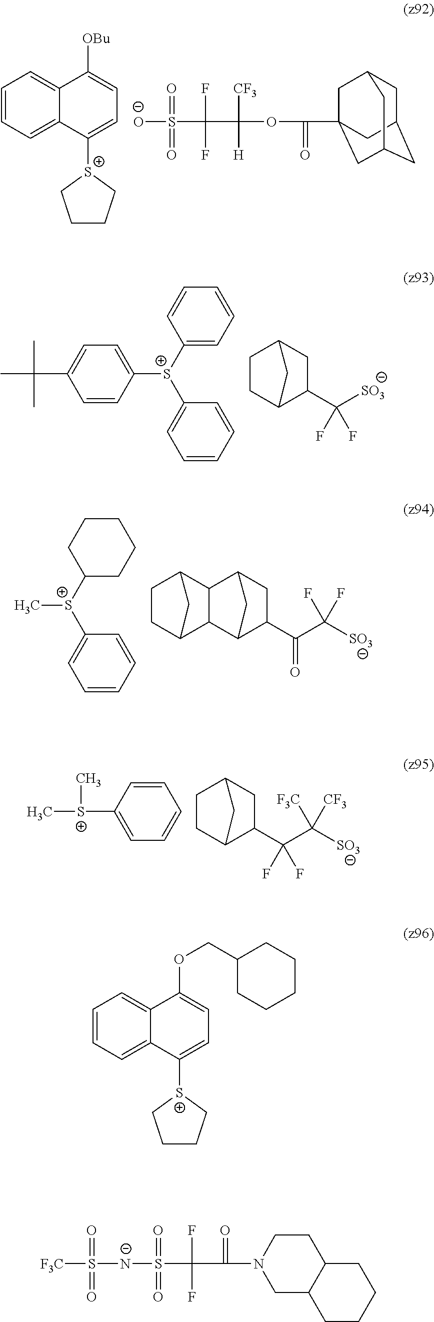

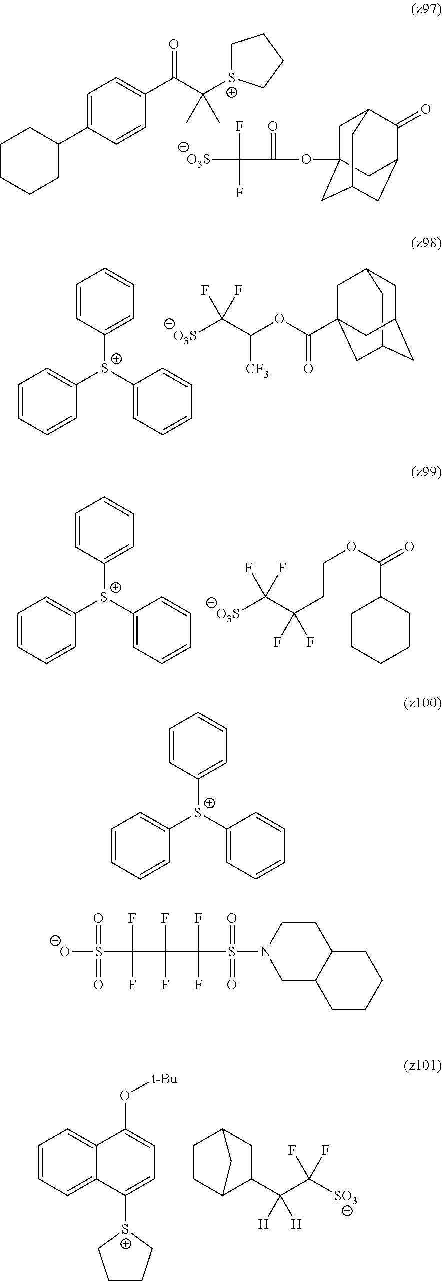

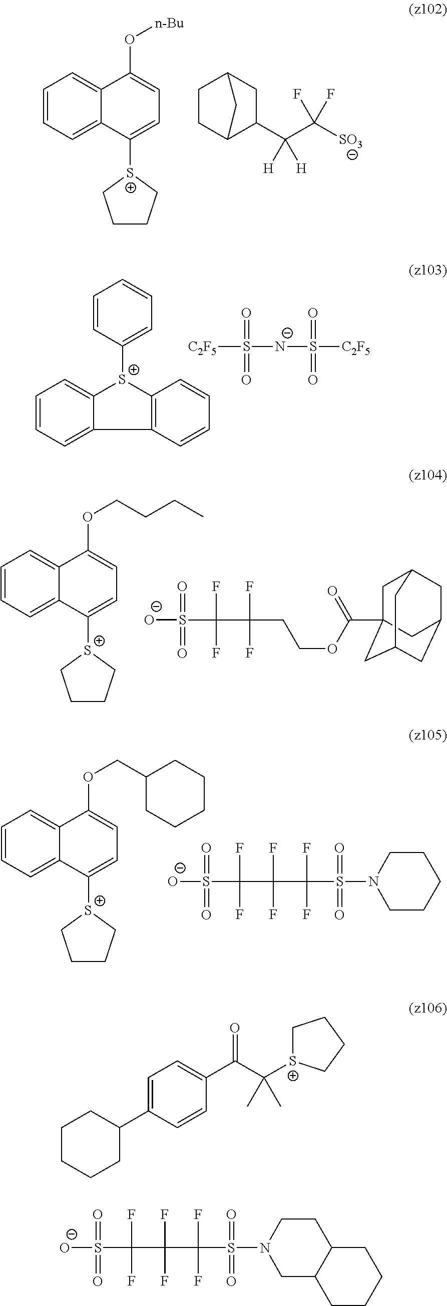

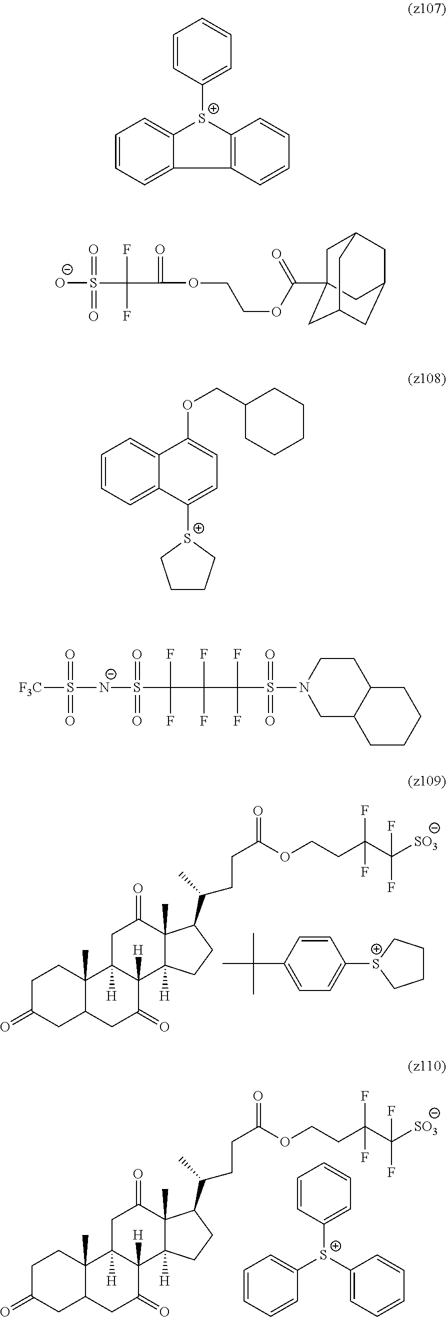

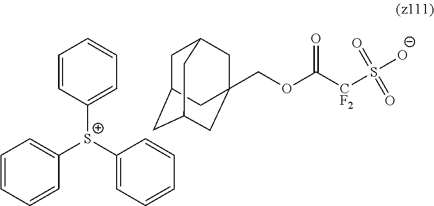 [SMILES: c1ccc([S+](c2ccccc2)c2ccccc2)cc1 ; O=C(OCC12CC3CC(CC(C3)C1)C2)C(F)(F)S(=O)(=O)[O-]]

Furthermore, particularly preferred examples of those having an anion represented by any one of General Formulae (B-1) to (B-3) among the compounds (B) are shown below, but the present invention is not limited thereto.

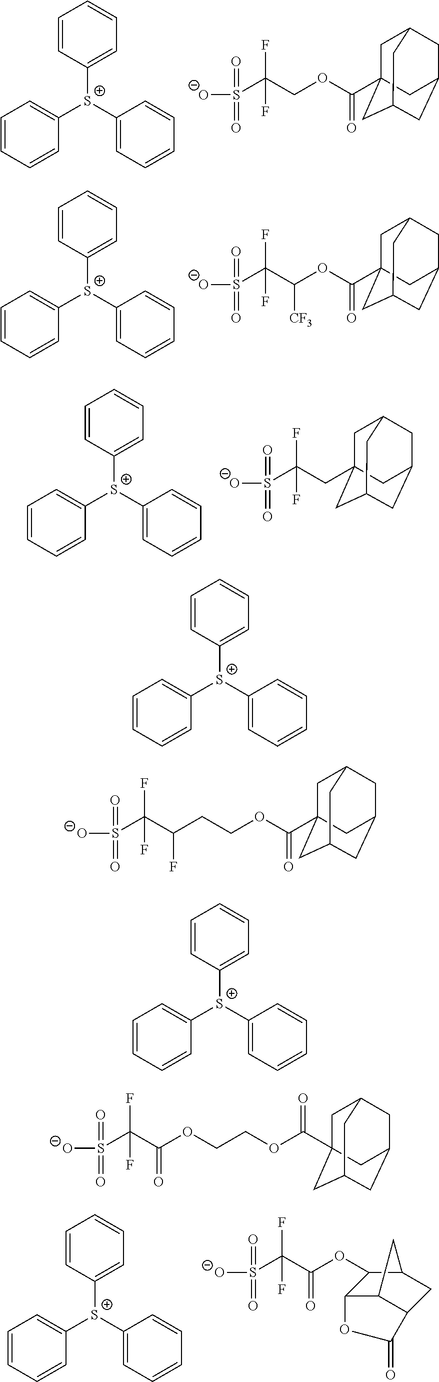

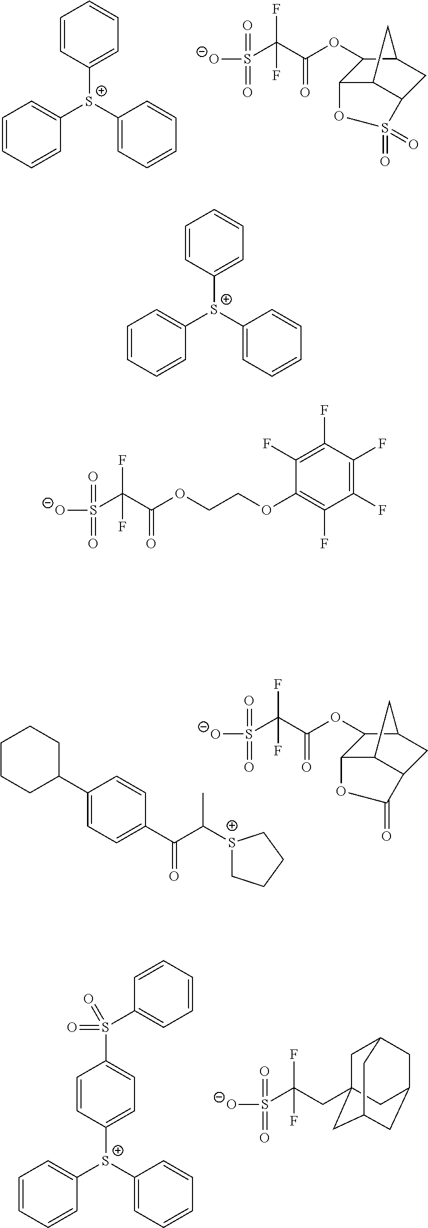

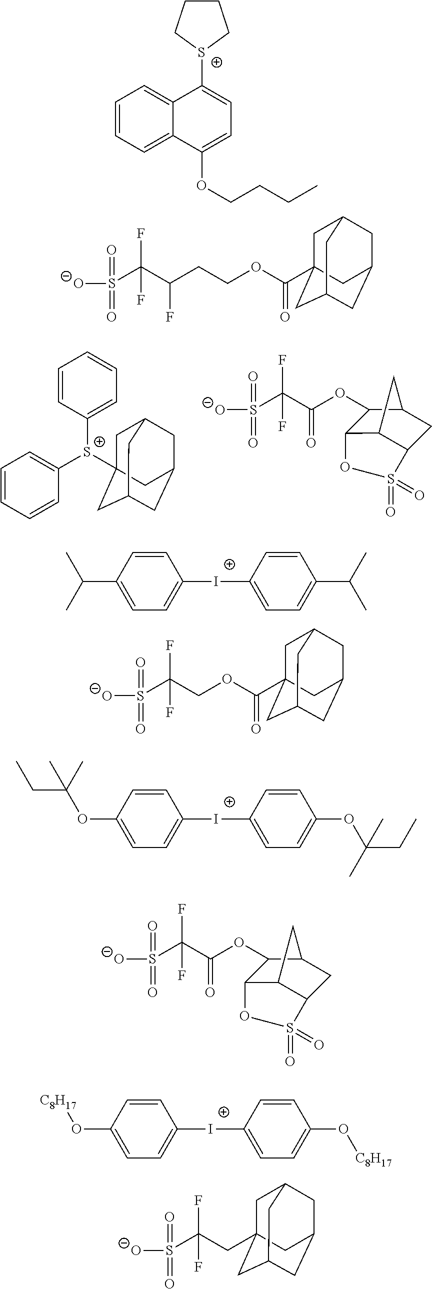

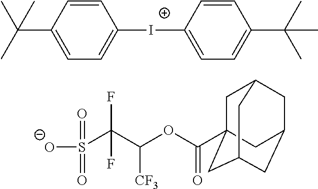

The acid generators can be synthesized by a known method, and can be synthesized in accordance with the methods described in, for example, JP2007-161707A, “0200” to “0210” of JP2010-100595A, “0051” to “0058” of WO2011/093280A, “0382” to “0385” of WO2008/153110A, JP2007-161707A, and the like.

The acid generators can be used alone or in combination of two or more kinds thereof.

The content of the compound capable of generating an acid upon irradiation with active light or radiation exclusive of the case where the compound is represented by General Formula (ZI-3) or (ZI-4)) in the composition is preferably 0.1% by mass to 30% by mass, more preferably 0.5% by mass to 25% by mass, still more preferably 3% by mass to 20% by mass, and particularly preferably 3% by mass to 15% by mass, with respect to the total solid content of the active-light-sensitive or radiation-sensitive resin composition.

In addition, in the case where the acid generator is represented by General Formula (ZI-3) or (ZI-4), the content thereof is preferably 5% by mass to 35% by mass, more preferably 6% by mass to 30% by mass, still more preferably 6% by mass to 30% by mass, and particularly preferably 6% by mass to 25% by mass, with respect to the total solid content of the composition.

[4] Solvent (C)

Examples of the solvent which can be used in the preparation of the active-light-sensitive or radiation-sensitive resin composition in the present invention include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include ones described in, for example, “0441” to “0455” of US2008/0187860A.

In the present invention, a mixed solvent obtained by mixing a solvent containing a hydroxyl group and a solvent containing no hydroxyl group in the structure may be used as the organic solvent.

As the solvent containing a hydroxyl group and the solvent containing no hydroxyl group, the aforementioned exemplary compounds can be appropriately selected and used, but as the solvent containing a hydroxyl group, alkylene glycol monoalkyl ether, alkyl lactate, and the like are preferable, and propylene glycol monomethyl ether (PGME, alternative name: 1-methoxy-2-propanol) and ethyl lactate are more preferable. Further, as the solvent containing no hydroxyl group, alkylene glycol monoalkyl ether acetate, alkyl alkoxy propionate, a monoketone compound which may contain a ring, cyclic lactone, alkyl acetate, and the like are preferable. Among these, propylene glycol monomethyl ether acetate (PGMEA, alternative name: 1-methoxy-2-acetoxypropane), ethyl ethoxypropionate, 2-heptanone, γ-butyrolactone, cyclohexanone, and butyl acetate are particularly preferable, and propylene glycol monomethyl ether acetate, ethyl ethoxypropionate, and 2-heptanone are most preferable.

The mixing ratio (based on mass) of the solvent containing a hydroxyl group and the solvent containing no hydroxyl group is 1/99 to 99/1, preferably 10/90 to 90/10, and more preferably 20/80 to 60/40. A mixed solvent whose proportion of the solvent containing no hydroxyl group is 50% by mass or more is particularly preferable from the viewpoint that coating evenness.

The solvent preferably contains propylene glycol monomethyl ether acetate, and is preferably a solvent composed of propylene glycol monomethyl ether acetate alone or a mixed solvent of two or more kinds of solvents including propylene glycol monomethyl ether acetate.

[5] Hydrophobic Resin (D)

The active-light-sensitive or radiation-sensitive resin composition according to the present invention may contain a hydrophobic resin (hereinafter also referred to as a “hydrophobic resin (D)” or simply a “resin (D)”), particularly when the composition is applied to immersion exposure. Further, it is preferable that the hydrophobic resin (D) is different from the resin (A).

With this, the hydrophobic resin (D) is unevenly distributed to the film surface layer, and in the case where a liquid immersion medium is water, the static/dynamic contact angle of the resist film surface with respect to water is improved, which can enhance the immersion liquid tracking properties. Further, in the case where the pattern formation method of the present invention is carried out by EUV exposure, it is also possible to apply the hydrophobic resin (D), from which so-called outgassing inhibition or the like can be expected.

It is preferable that the hydrophobic resin (D) is designed to be unevenly distributed to the interface as mentioned above, but in contrast to a surfactant, the resin (D) is not necessarily required to have a hydrophilic group in the molecule, and may not contribute to uniform mixing of polar/nonpolar materials.

From the viewpoint of uneven distribution to the film surface layer, it is preferable that the hydrophobic resin (D) contains any of at least one kind of a “fluorine atom”, a “silicon atom”, and a “CH₃ partial structure contained in the side chain portion of the resin”, and it is more preferable that the resin (D) contains two or more kinds thereof.

In the case where the hydrophobic resin (D) contains a fluorine atom and/or a silicon atom, the fluorine atom and/or the silicon atom in the hydrophobic resin (D) may be contained in the main chain of the resin or may be contained in the side chain.

In the case where the hydrophobic resin (D) contains a fluorine atom, the resin is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group such as a phenyl group and a naphthyl group, in which at least one hydrogen atom is substituted with a fluorine atom, and may further have a substituent other than a fluorine atom.

Preferred examples of the alkyl group having a fluorine atom, the cycloalkyl group having a fluorine atom, and the aryl group having a fluorine atom include groups represented by the following General Formulae (F2) to (F4), but the present invention is not limited thereto.

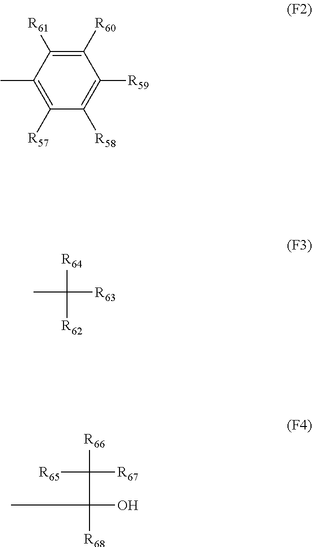

In General Formulae (F2) to (F4),

R₅₇ to R₆₈ each independently represent a hydrogen atom, a fluorine atom, or an (linear or branched) alkyl group, a provided that at least one of R₅₇ to R₆₁, at least one of R₆₂ to R₆₄, and at least one of R₆₅ to R₆₈ each independently represent a fluorine atom or an alkyl group (preferably having 1 to 4 carbon atoms) in which at least one hydrogen atom is substituted with a fluorine atom.

It is preferable that R₅₇ to R₆₁, and R₆₅ to R₆₇ are all fluorine atoms. R₆₂, R₆₃, and R₆₅ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group, with the hexafluoroisopropyl group, the heptafluoroisopropyl group, the hexafluoro(2-methyl)isopropyl group, the octafluoroisobutyl group, the nonafluoro-t-butyl group, and the perfluoroisopentyl group are preferable, and the hexafluoroisopropyl group and the heptafluoroisopropyl group being more preferable.

Specific examples of the group represented by General Formula (F4) include —C(CF₃)₂OH, —C(C₂F₅)₂OH, —C(CF₃)(CH₃)OH, and —CH(CF₃)OH, with —C(CF₃)₂OH being preferable.

The partial structure having a fluorine atom may be bonded directly to the main chain or may be bonded to the main chain through a group selected from the group consisting of an alkylene group, a phenylene group, an ether bond, a thioether bond, a carbonyl group, an ester bond, an amide bond, a urethane bond, and a ureylene bond, or a group formed by combination of two or more thereof.

Specific examples of the repeating unit having a fluorine atom are shown below, but the present invention is not limited to these.

In the specific examples, X₁ represents a hydrogen atom, —CH₃, —F, or —CF₃. represents —F or —CF₃.

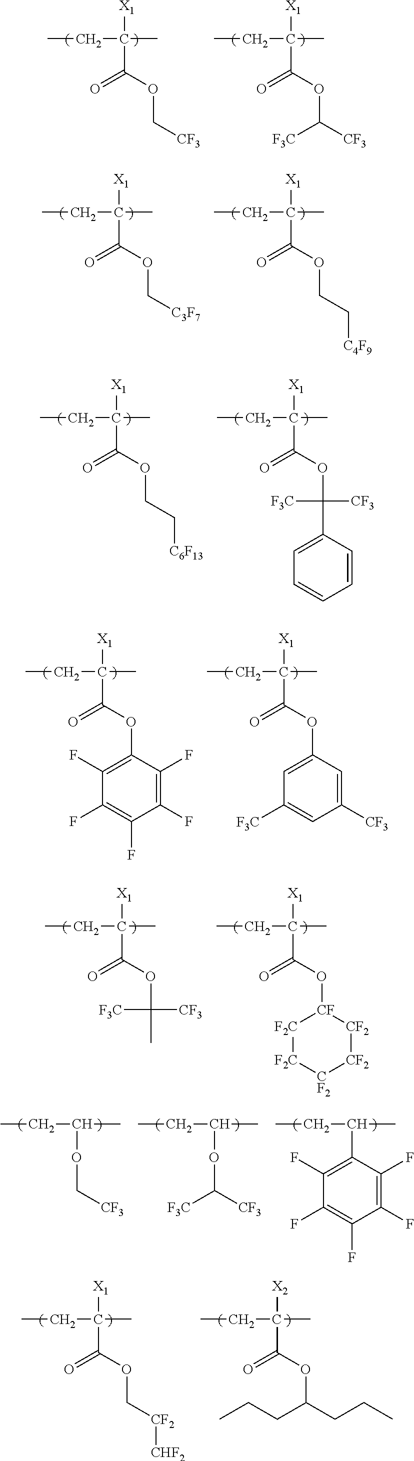

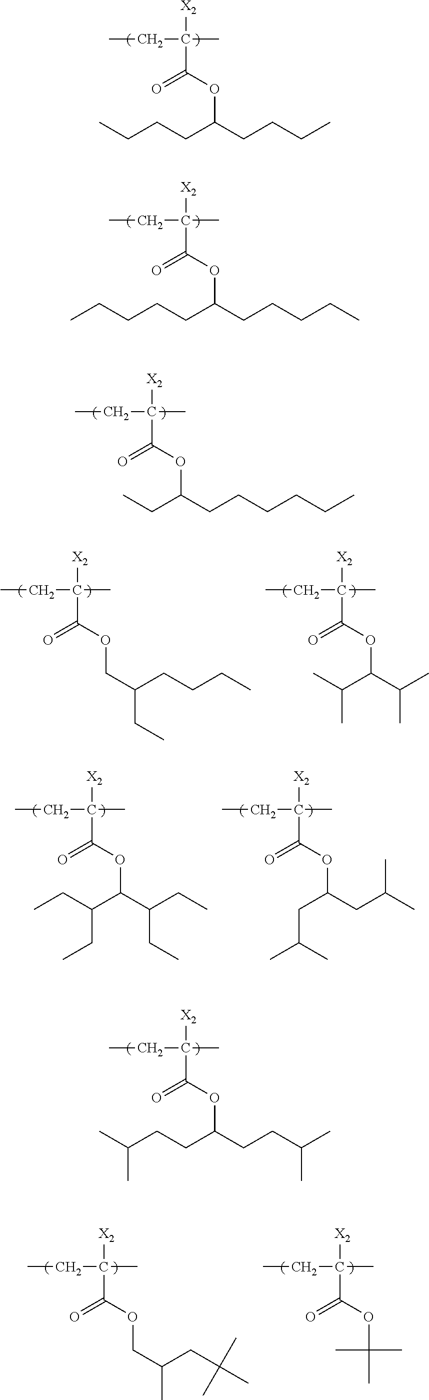

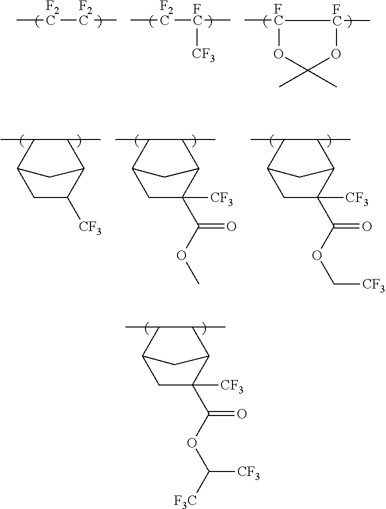

The hydrophobic resin (D) may contain a silicon atom. As a partial structure having a silicon atom, a resin having an alkylsilyl structure (preferably a trialkylsilyl group), or a cyclic siloxane structure is preferable.

The alkylsilyl structure or the cyclic siloxane structure may include, specifically, a group represented by the following the General Formulae (CS-1) to (CS-3).

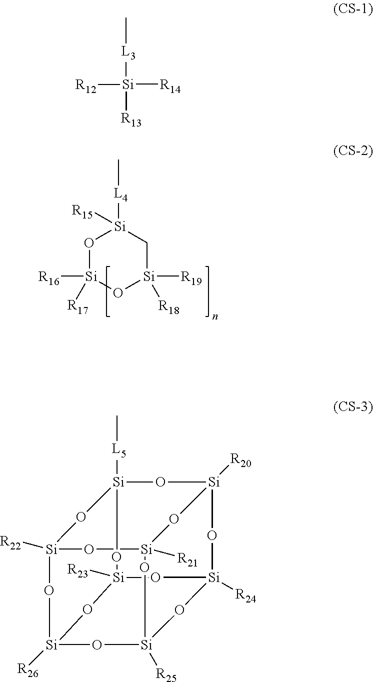

In General Formulae (CS-1) to (CS-3),

R₁₂ to R₂₆ each independently represent a linear or branched alkyl group (preferably 1 to 20 carbon atoms) or a cycloalkyl group (preferably 3 to 20 carbon atoms).

L₃ to L₅ represent a single bond or a divalent linking group. Examples of a divalent linking group include one, or a combination (the total number of carbon atoms is preferably 12 or less) of two or more, which are selected from a group formed of an alkylene group, a phenylene group, an ether bond, a thioether bond, a carbonyl group, an ester bond, an amide bond, a urethane bond, and a urea bond.

n represents an integer of 1 to 5. n is preferably an integer of 2 to 4.

Specific examples of the repeating units having a group represented by the General Formulae (CS-1) to (CS-3) are shown below, however, the present invention is not limited to these. Further, in the specific examples, X₁ represents a hydrogen atom, —F, or —CF₃.

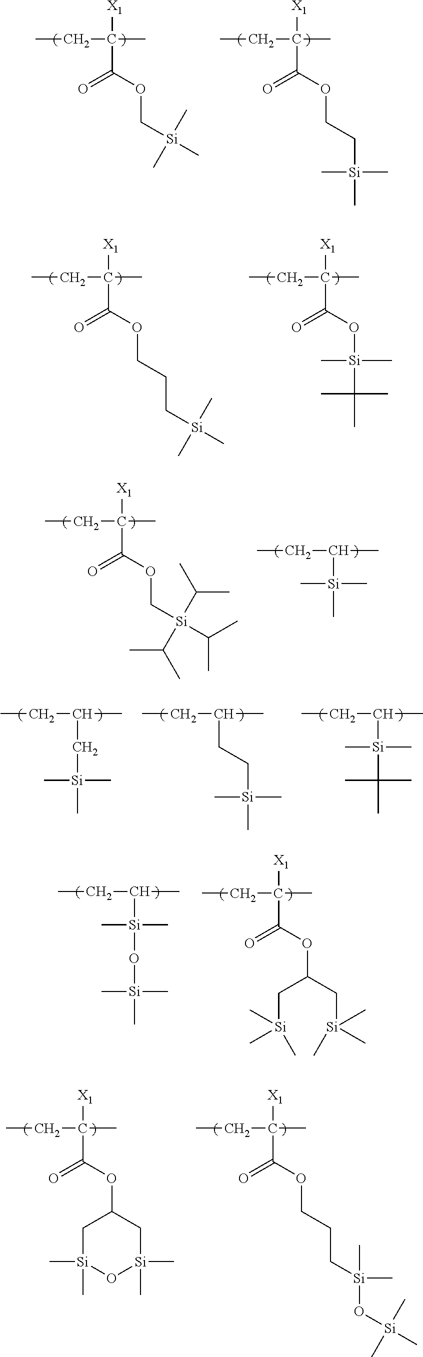

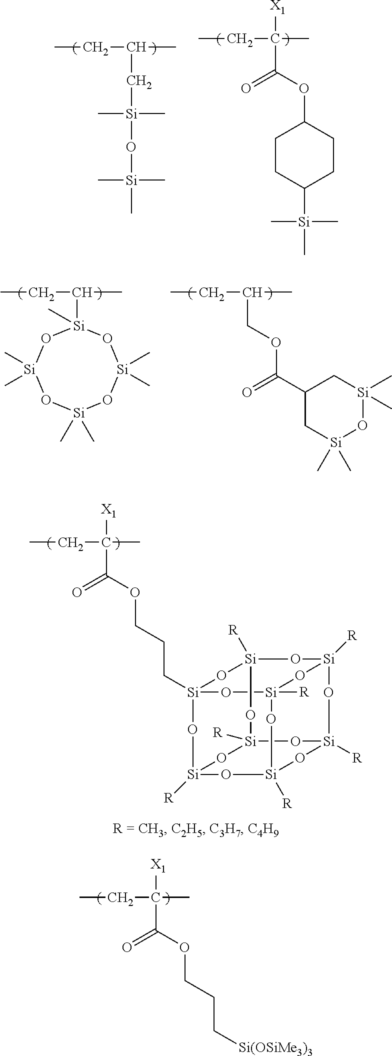

Furthermore, it is also preferable that the hydrophobic resin (D) contains a CH₃ partial. structure in the side chain portion as described above.

Here, the CH₃ partial structure contained in the side chain portion in the resin (D) (hereinafter also referred to as a “side chain CH₃ partial structure”) is intended to include CH₃ partial structures contained in an ethyl group, a propyl group, and the like.

On the other hand, a methyl group bonded directly to the main chain of the resin (D) (for example, an α-methyl group in the repeating unit having a methacrylic acid structure) makes only a small contribution of uneven distribution to the surface of the resin (D) due to the effect of the main chain, and it is therefore not included in the CH₃ partial structure in the present invention.

More specifically, in the case where the resin (D) contains a repeating unit derived from a monomer having a polymerizable moiety with a carbon-carbon double bond, such as a repeating unit represented by the following General Formula (M), and in addition, R₁₁ to R₁₄ are CH₃ “themselves”, such CH₃ is not included in the CH₃ partial structure contained in the side chain portion in the present invention.

On the other hand, a CH₃ partial structure which is present through sonic atom(s) from the C—C main chain is intended to correspond to the CH₃ partial structure in the present invention. For example, in the case where R₁₁ is an ethyl group (CH₂CH₃), it is intended that the repeating unit has “one” CH₃ partial structure in the present invention.

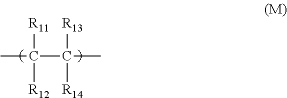

In General Formula (M),

R₁₁ to R₁₄ each independently represent a side chain portion.

Examples of R₁₁ to R₁₄ at the side chain portion include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

It is preferable that the hydrophobic resin (D) is a resin containing a repeating unit having the CH₃ partial structure in the side chain portion thereof. Further, it is more preferable that such a repeating unit has at least one repeating unit (x) selected from a repeating unit represented by the following General Formula (II) and a repeating unit represented by the following General Formula (III).

Hereinafter, the repeating unit represented by General Formula (II) will be described in detail.

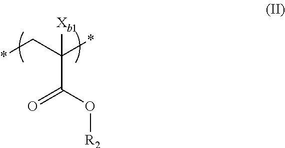

In General Formula (II), X_{b1} represents a hydrogen atom, an alkyl group, a cyano group, or a halogen atom, and R₂ represents an organic group which has one or more CH₃ partial structures and is stable against an acid. Here, more specifically, the organic group which is stable against an acid is preferably an organic group which does not have “the group capable of decomposing by the action of an acid to generate a polar group” as mentioned with respect to the resin (A).

The alkyl group of X_{b1} is preferably an alkyl group having 1 to 4 carbon atoms, and examples include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably 2 to 10, and more preferably 2 to 8.

The alkyl group having one or more CH₃ partial structures in R₂ is preferably a branched alkyl group having 3 to 20 carbon atoms.

The cycloalkyl group having one or more CH₃ partial structures in R₂ may be monocyclic or polycyclic. Specific examples thereof include a group having 5 or more carbon atoms, which has a monocyclic, bicyclic, tricyclic, or tetracyclic structure. The number of carbon atoms thereof is preferably 6 to 30, and more preferably 7 to 25.

The alkenyl group having one or more CH₃ partial structures in R₂ is preferably a linear or branched alkenyl group having 1 to 20 carbon atoms, and more preferably a branched alkenyl group.

The aryl group having one or more CH₃ partial structures in R₂ is preferably an aryl group having 6 to 20 carbon atoms, such as a phenyl group and a naphthyl group, and more preferably a phenyl group.

The aralkyl group having one or more CH₃ partial structures in R₂ is preferably an aralkyl group having 7 to 12 carbon atoms, such as a benzyl group, a phenethyl group, and a naphthylmethyl group.

Specific preferred examples of the repeating unit represented by General Formula (II) are shown below, but the present invention is not limited thereto.

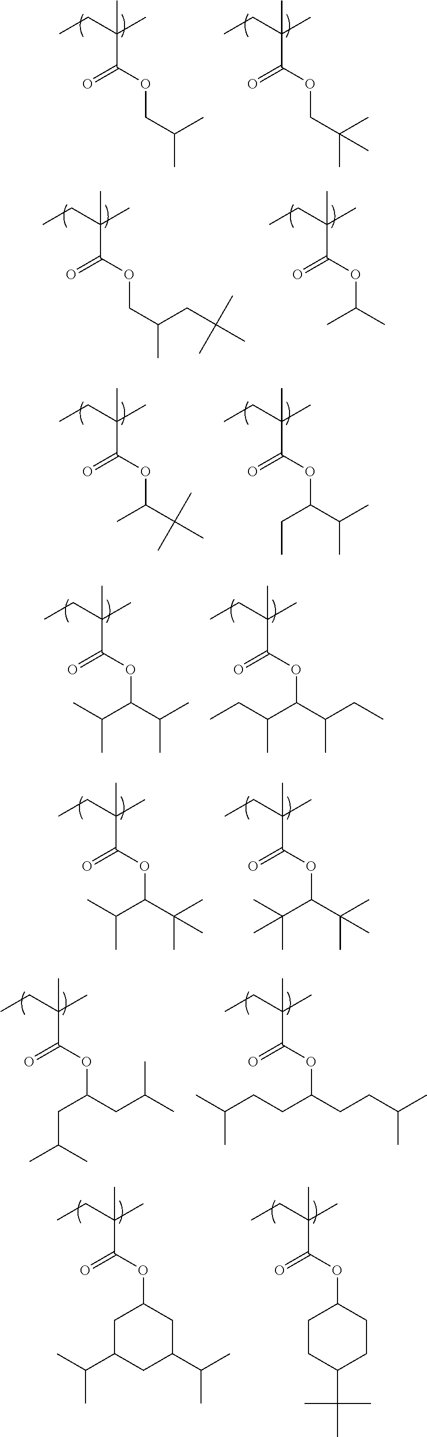

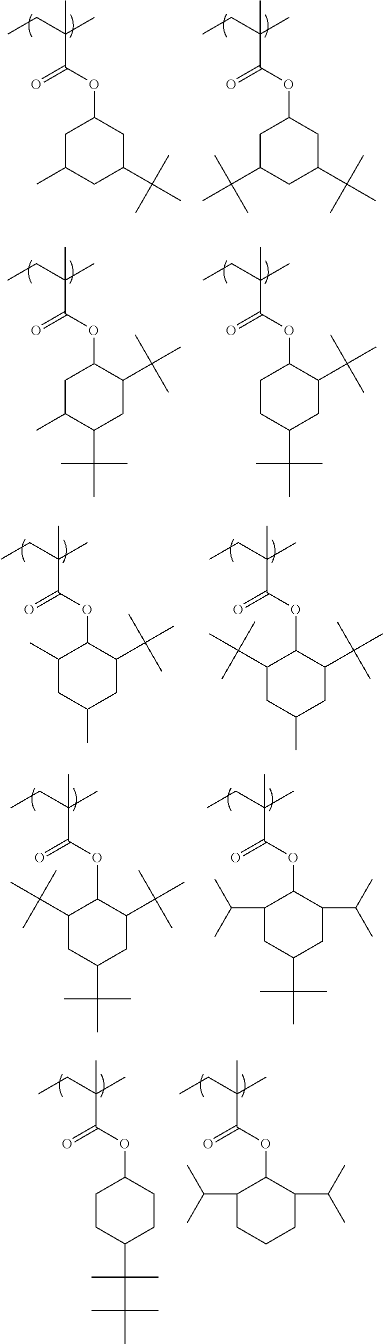

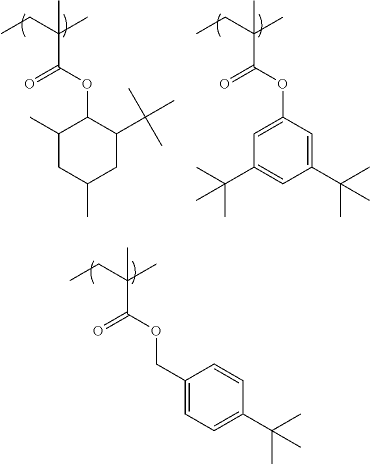

The repeating unit represented by General Formula (II) is preferably a repeating unit which is stable against an acid (acid-indecomposable), and specifically, it is preferably a repeating unit having no group capable of decomposing by the action of an acid to generate a polar group.

The repeating unit represented by the following General Formula (III) will be described in detail.

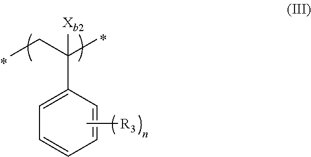

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, a but a hydrogen atom is preferable.

X_{b2} is preferably a hydrogen atom.

R₃ is an organic group which is stable against an acid. Therefore, to be more specific, R₃ is preferably an organic group which does not have “the group capable of decomposing by the action of an acid to generate a polar group” as mentioned in the resin (A).

Examples of R₃ include an alkyl group having one or more CH₃ partial structures.

The number of the CH₃ partial structures contained in the organic group which has one or more CH₃ partial structures and is stable against an acid as R₃ is preferably 1 to 10, more preferably 1 to 8, and still more preferably 1 to 4.

The alkyl group having one or more CH₃ partial structures in R₃ is preferably a branched alkyl group having 3 to 20 carbon atoms.

n represents an integer of 1 to 5, preferably 1 to 3, and more preferably 1 or 2.

Specific preferred examples of the repeating unit represented by General Formula (III) are shown below, but the present invention is not limited thereto.

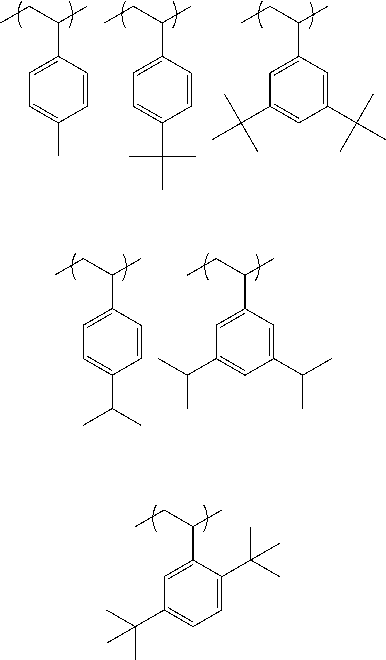

The repeating unit represented by General Formula (III) is preferably a repeating unit which is stable against an acid (acid-indecomposable), and specifically, it is a repeating unit which has no group capable of decomposing by the action of an acid to generate a polar group.

In the case where the resin (D) contains a CH₃ partial structure in the side chain portion thereof, and in particular, it has neither a fluorine atom nor a silicon atom, the content of at least one repeating unit (x) of the repeating unit represented by General Formula (II) and the repeating unit represented by General Formula (III) is preferably 90% by mole or more, and more preferably 95% by mole or more, with respect to all the repeating units of the resin (D). Further, the content is usually 100% by mole or less with respect to all the repeating units of the resin (D).

By incorporating at least one repeating unit (x) of the repeating unit represented by General Formula (II) and the repeating unit represented by General Formula (III) in a proportion of 90% by mole or more with respect to all the repeating units of the resin (D) into the resin (D), the surface free energy of the resin (D) is increased. As a result, it is difficult for the resin (D) to be unevenly distributed on the surface of the resist film and the static/dynamic contact angle of the resist film with respect to water can be securely increased, thereby enhancing the immersion liquid tracking properties.

In addition, the hydrophobic resin (D) may have at least one group selected from the following groups (x) to (z) in the case (i) of containing a fluorine atom and/or a silicon atom as well as in the case (ii) of containing a CH₃ partial structure in the side chain portion:

(x) an acid group,

(y) a group having a lactone structure, an acid anhydride group, or an acid imido group, and

(z) a group capable of decomposing by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the acid group include a fluorinated alcohol group (preferably hexafluoroisopropanol), sulfonimido group, and a bis(alkylcarbonyl)methylene group.

Examples of the repeating unit containing an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent containing an acid group during the polymerization. All of these cases are preferable. The repeating unit containing an acid group (x) may have at least one of a fluorine atom and a silicon atom.

The content of the repeating units containing an acid group (x) is preferably 1% by mole to 50% by mole, more preferably 3% by mole to 35% by mole, and still more preferably 5% by mole to 20% by mole, with respect to all the repeating units in the hydrophobic resin (D).

Specific preferred examples of the repeating unit containing an acid group (x) are shown below, but the present invention is not limited thereto. In the formulae, Rx represents a hydrogen atom, CH₃, CF₃, or, CH₂OH.

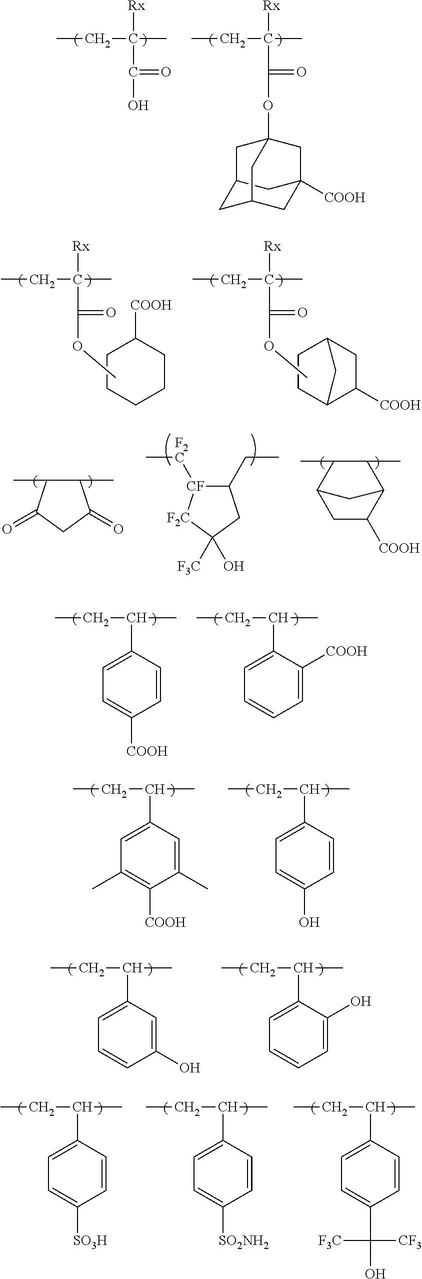

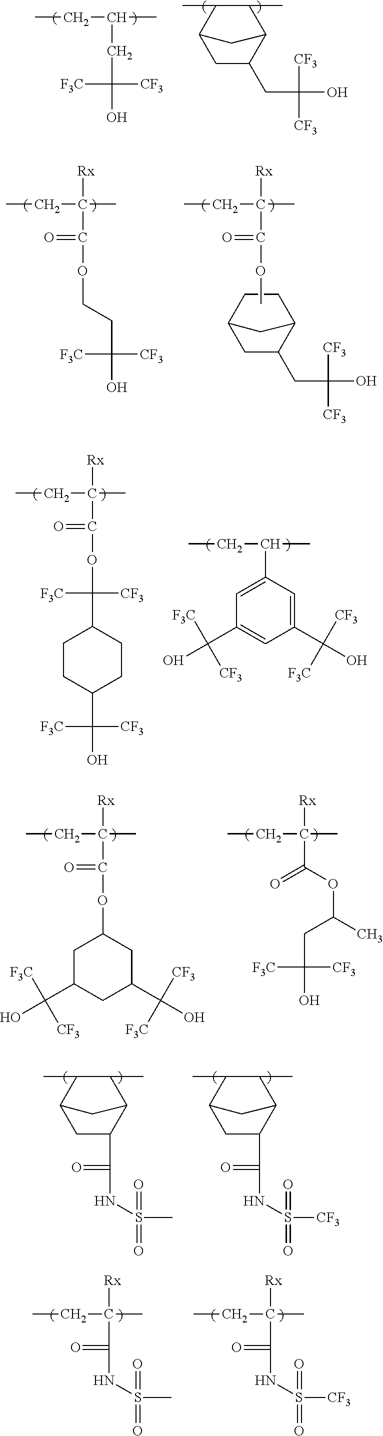

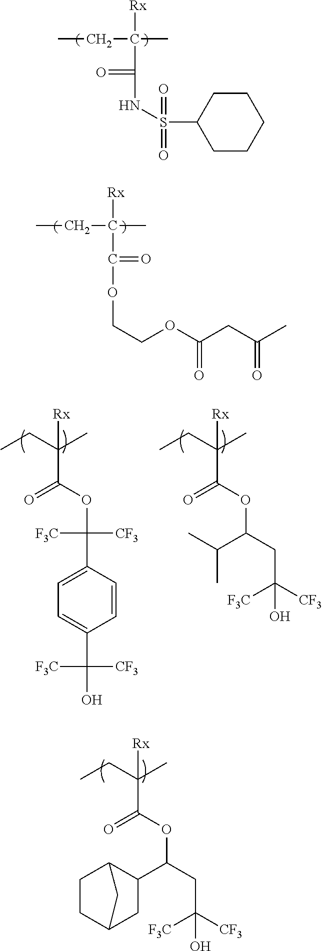

As the group having a lactone structure, the acid anhydride group, or the acid imido group (y), the group having a lactone structure is particularly preferable.

The repeating unit containing such a group is, for example, a repeating unit in which the group is directly bonded to the main chain of the resin, such as a repeating unit by an acrylic ester or a methacrylic ester. This repeating unit may be a repeating unit in which the group is bonded to the main chain of the resin through a linking group. Alternatively, this repeating unit may be introduced into the terminal of the resin by using a polymerization initiator or chain transfer agent containing the group during the polymerization.

Examples of the repeating unit containing a group having a lactone structure include the same ones as those of the repeating unit having a lactone structure as described earlier in the section of the acid-decomposable resin (A).

The content of the repeating units having a group having a lactone structure, an acid anhydride group, or an acid imido group is preferably 1% by mole to 100% by mole, more preferably 3% by mole to 98% by mole, and still more preferably 5% by mole to 95% by mole, with respect to all the repeating units in the hydrophobic resin (D).

With respect to the hydrophobic resin (D), examples of the repeating unit having a group (z) capable of decomposing by the action of an acid include the same ones as the repeating units containing an acid-decomposable group, as mentioned with respect to the resin (A). The repeating unit having a group (z) capable of decomposing by the action of an acid may contain at least one of a fluorine atom and a silicon atom. In the hydrophobic resin (D), the content of the repeating units having a group (z) capable of decomposing by the action of an acid is preferably 1% by mole to 80% by mole, more preferably 10% by mole to 80% by mole, and still more preferably 20% by mole to 60% by mole, with respect to all the repeating units in the resin (D).

The hydrophobic resin (D) may also have a repeating unit represented by the following General Formula (III).

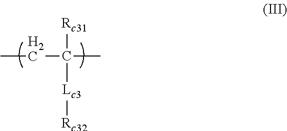

In General Formula (III),

R_{c31} represents a hydrogen atom, an alkyl group (which may be substituted with a fluorine atom or the like), a cyano group, or a —CH₂—O—R_{ac2} group, in which Rac₂ represents a hydrogen atom, an alkyl group, or an acyl group, and R_{c31} is preferably a hydrogen atom, a methyl group, a hydroxymethyl group, or a trifluoromethyl group, and more preferably a hydrogen atom or a methyl group,

R_{c32} represents a group having an alkyl group, a cycloalkyl group, an alkenyl group, a cycloalkenyl group, or an aryl group, each of which may be substituted with a group containing a fluorine atom or a silicon atom, and

L_{c3} represents a single bond or a divalent linking group.

In General Formula (III), the alkyl group of R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an ether bond, a phenylene group, or an ester bond (a group represented by —COO—).

The content of the repeating units represented by formula (III) is preferably 1% by mole to 100% by mole, more preferably 10% by mole to 90% by mole, and still more preferably 30% by mole to 70% by mole, with respect to all the repeating units in the hydrophobic resin.

It is also preferable that the hydrophobic resin (D) further has a repeating unit represented by the following General Formula (CII-AB).

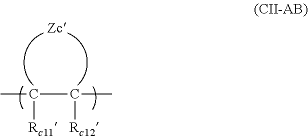

In Formula (CII-AB),

R_{c11}′ and R_{c12}′ each independently represent a hydrogen atom, a cyano group, a halogen atom, or an alkyl group, and

Z_{c}′ represents an atomic group for forming an alicyclic structure containing two carbon atoms (C—C) to which Z_{c}′ is bonded.

The content of the repeating units represented by General Formula (CII-AB) is preferably 1% by mole to 100% by mole, more preferably 10% by mole to 90% by mole, and still more preferably 30% by mole to 70% by mole, with respect to all the repeating units in the hydrophobic resin.

Specific examples of the repeating units represented by General Formulae (III) and (CII-AB) are shown below, but the present invention is not limited thereto. In the formulae, Ra represents H, CH₃, CH₂OH, CF₃, or CN.

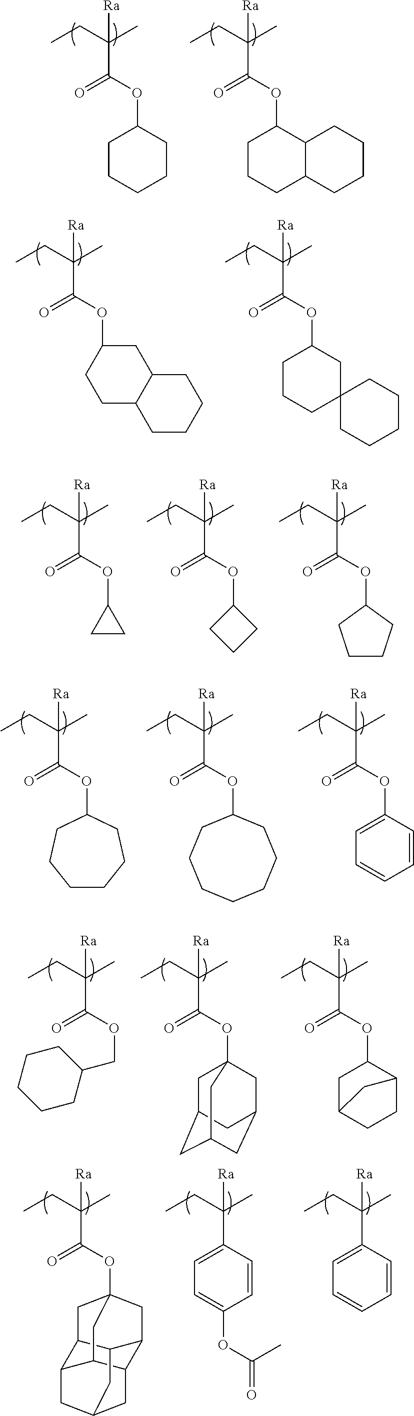

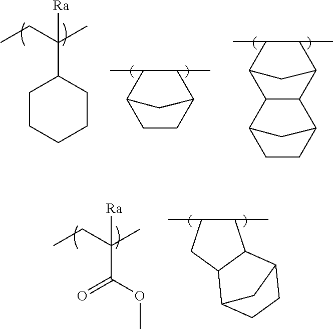

In the case where the hydrophobic resin (D) has a fluorine atom, the content of the fluorine atom is preferably 5% by mass to 80% by mass, and more preferably 10% by mass to 80% by mass, with respect to the weight-average molecular weight of the hydrophobic resin (D). Further, the proportion of the repeating units containing a fluorine atom is preferably 10% by mole to 100% by mole, and more preferably 30% by mole to 100% by mole, with respect to all the repeating units contained in the hydrophobic resin (D).

In the case where the hydrophobic resin (D) has a silicon atom, the content of the silicon atom is preferably 2% by mass to 50% by mass, and more preferably 2% by mass to 30% by mass, with respect to the weight-average molecular weight of the hydrophobic resin (D). Further, the proportion of the repeating unit containing a silicon atom is preferably 10% by mole to 100% by mole, and more preferably 20% by mole to 100% by mole, with respect to all the repeating units contained in the hydrophobic resin (D).

On the other hand, in particular, in the case where the resin (D) contains a CH₃ partial structure in the side chain portion thereof, it is also preferable that the resin (D) has a form having substantially neither a fluorine atom nor a silicon atom. In this case, specifically, the content of the repeating units containing a fluorine atom or a silicon atom is preferably 5% by mole or less, more preferably 3% by mole or less, still more preferably 1% by mole or less, and ideally 0% by mole, that is, containing neither a fluorine atom nor a silicon atom, with respect to all the repeating units in the resin (D). In addition, it is preferable that the resin (D) is composed substantially of a repeating unit constituted with only an atom selected from the group consisting of a carbon atom, an oxygen atom, a hydrogen atom, a nitrogen atom, and a sulfur atom. More specifically, the proportion of the repeating unit constituted with only an atom selected from the group consisting of a carbon atom, an oxygen atom, a hydrogen atom, a nitrogen atom, and a sulfur atom is preferably 95% by mole or more, more preferably 97% by mole or more, still more preferably 99% by mole or more, and ideally 100% by mole, of all the repeating units in the resin (D).

The weight-average molecular weight of the hydrophobic resin (D) in terms of standard polystyrene is preferably 1,000 to 100,000, more preferably 1,000 to 50,000, and still more preferably 2,000 to 15,000.

Furthermore, the hydrophobic resins (D) may be used alone or in combination of two or more kinds thereof.

The content of the hydrophobic resins (D) in the composition is preferably 0.01% by mass to 10% by mass, more preferably 0.05% by mass to 8% by mass, and still more preferably 0.1% by mass to 7% by mass, with respect to the total solid content of the composition of the present invention.

In the hydrophobic resin (D), similarly to the resin (A), it is certain that the content of impurities such as metal is small, but the content of residual monomers or oligomer components is also preferably 0.01% by mass to 5% by mass, more preferably 0.01% by mass to 3% by mass, and still more preferably 0.05% by mass to 1% by mass. Within these ranges, an active-light-sensitive or radiation-sensitive resin composition free from in-liquid extraneous materials and a change in sensitivity or the like with aging can be obtained. Further, from the viewpoints of a resolution, a resist profile, the side wall of a resist pattern, a roughness, and the like, the molecular weight distribution (Mw/Mn, also referred to as a dispersity) is preferably in the range of 1 to 5, more preferably 1 to 3, and still more preferably 1 to 2.

As the hydrophobic resin (D), various commercial products may be used, or the resin may be synthesized by an ordinary method (for example, radical polymerization). Examples of the general synthesis method include a batch polymerization method of dissolving monomer species and an initiator in a solvent and heating the solution, thereby carrying out the polymerization, and a dropping polymerization method of adding dropwise a solution containing monomer species and an initiator to a heated solvent for 1 hour to 10 hours, with the dropping polymerization method being preferable.

The reaction solvent, the polymerization initiator, the reaction conditions temperature, a concentration, and the like) and the method for purification after reaction are the same as ones described for the resin (A), but in the synthesis of the hydrophobic resin (D), the concentration at the reaction is preferably 30% by mass to 50% by mass.

Specific examples of the hydrophobic resin (D) are shown below. Further, the molar ratio of the repeating units (corresponding to the respective repeating units in order from the left side), the weight-average molecular weight, and the dispersity with respect to the respective resins are shown in the following Table.

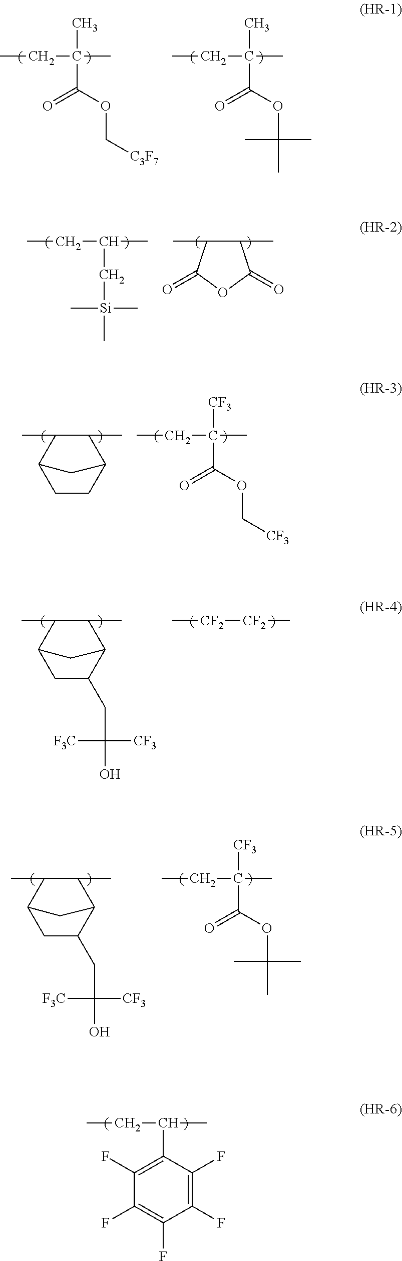

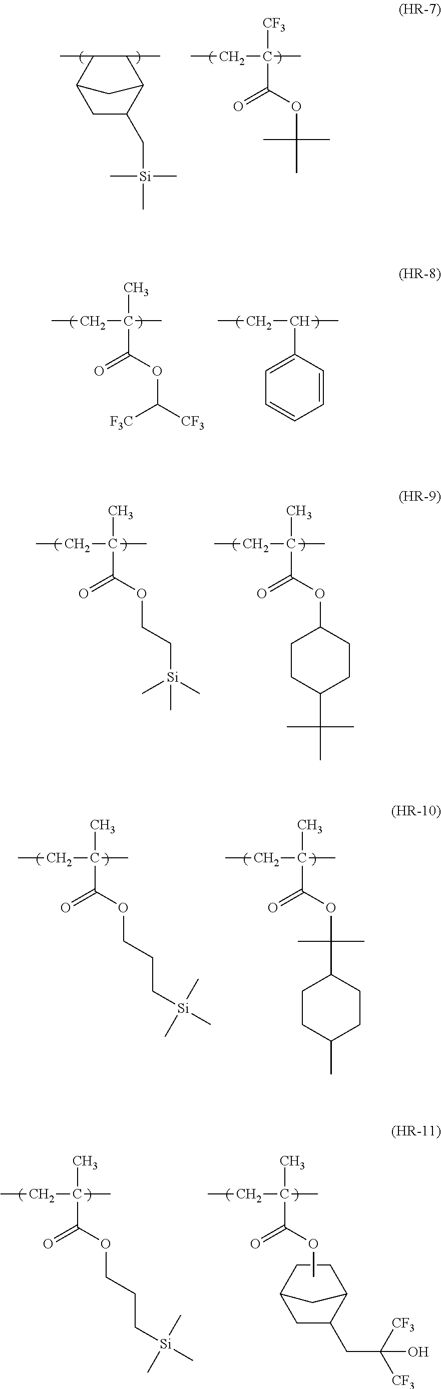

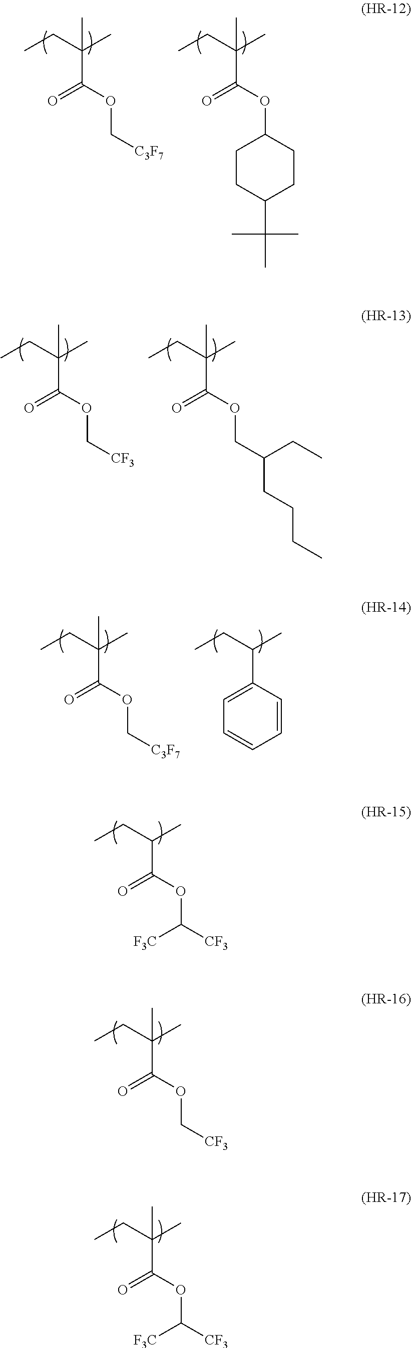

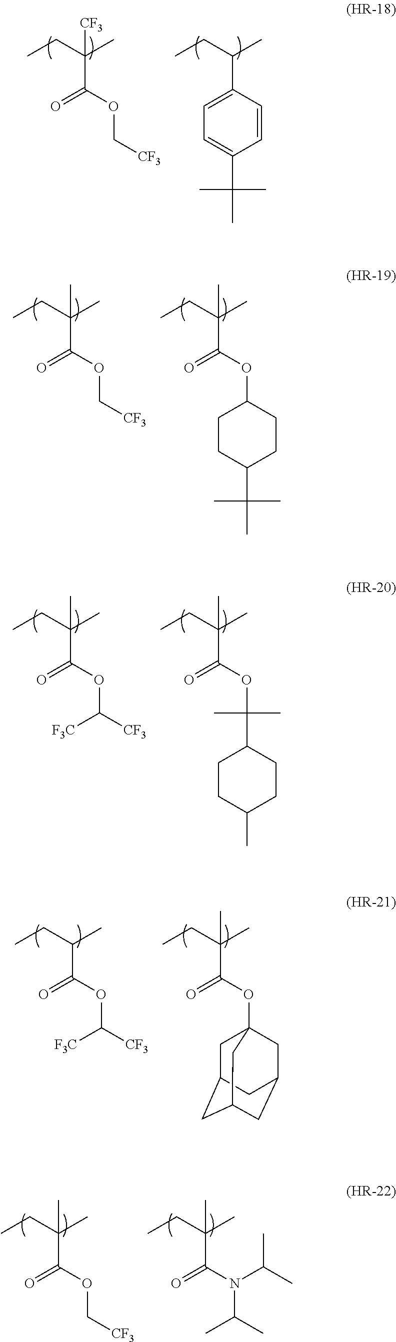

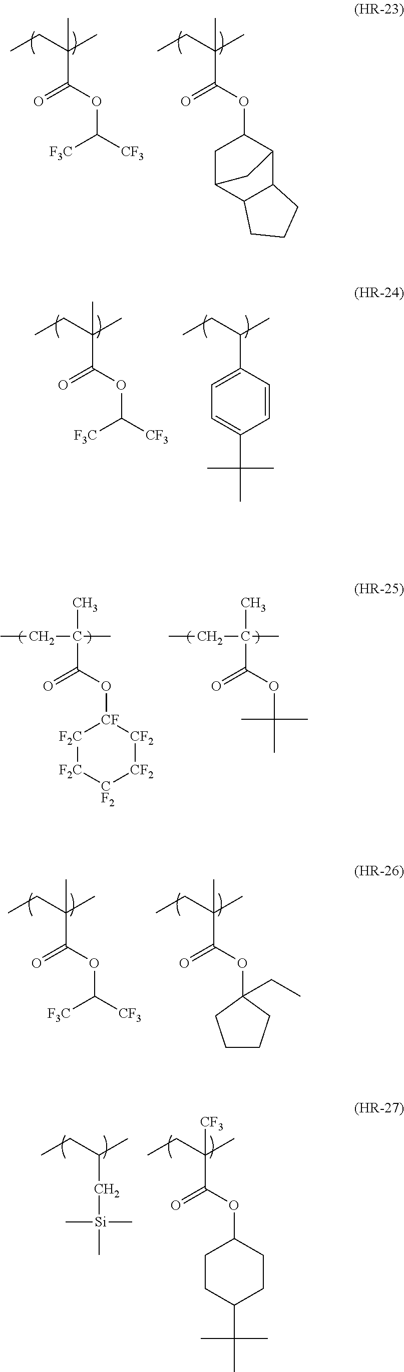

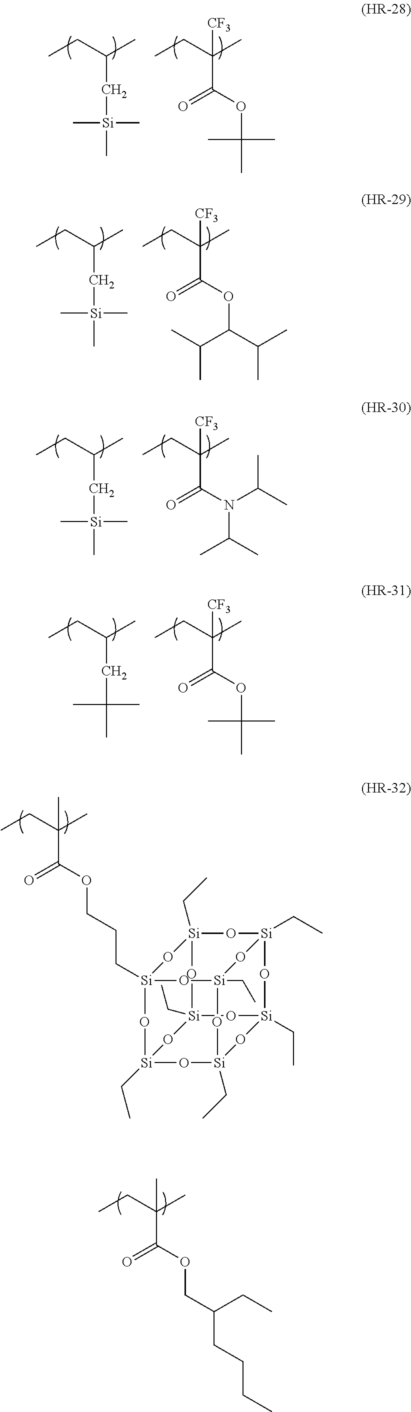

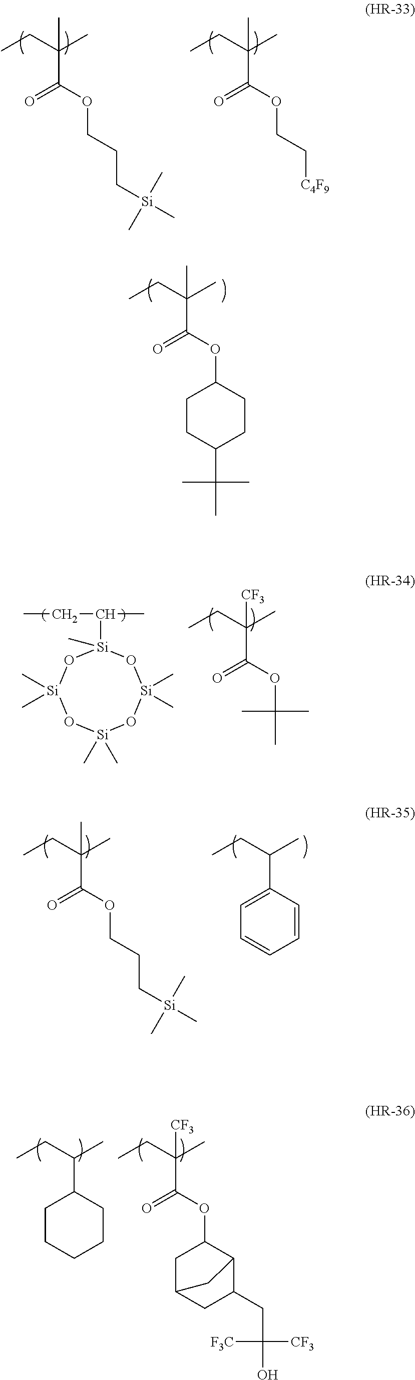

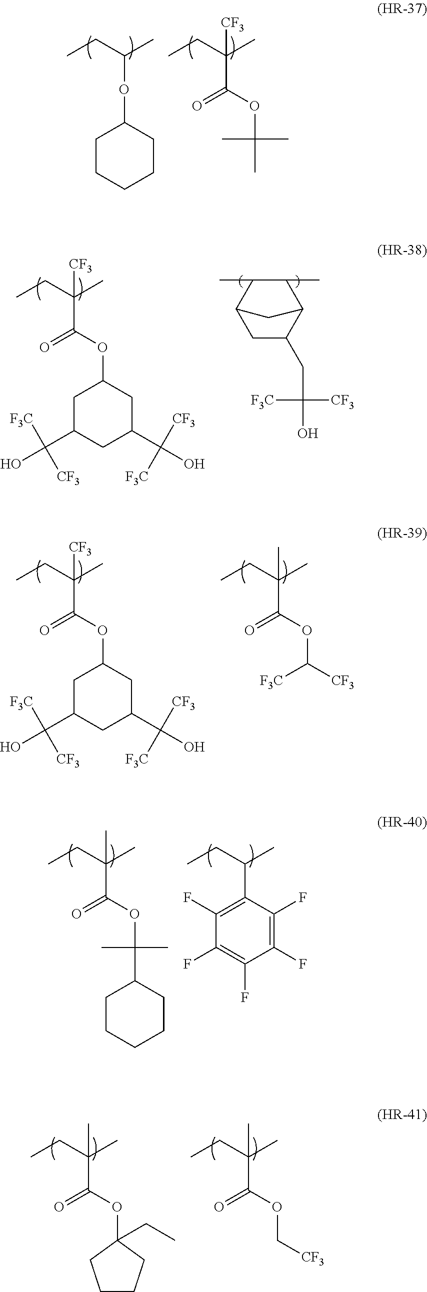

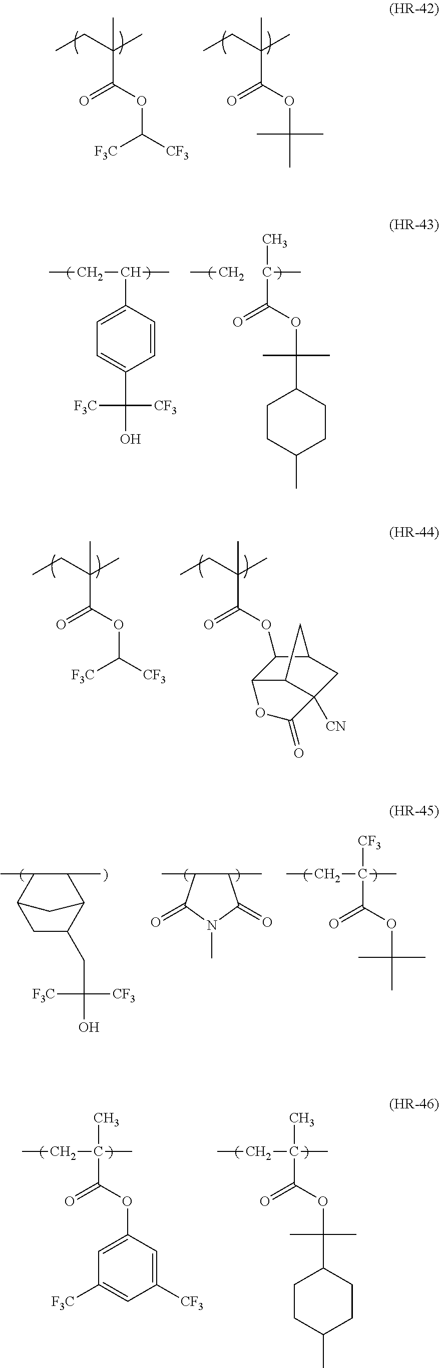

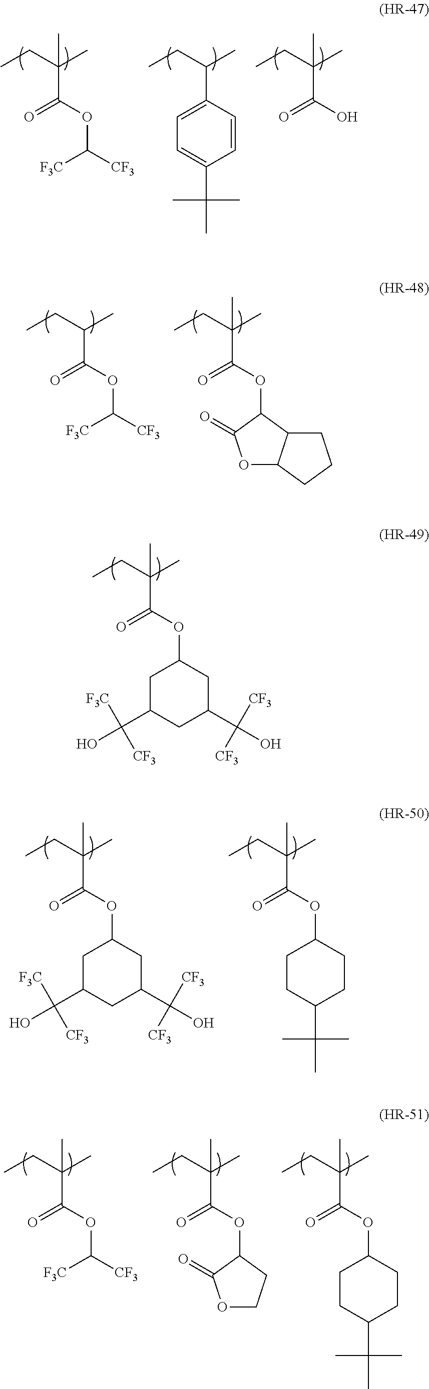

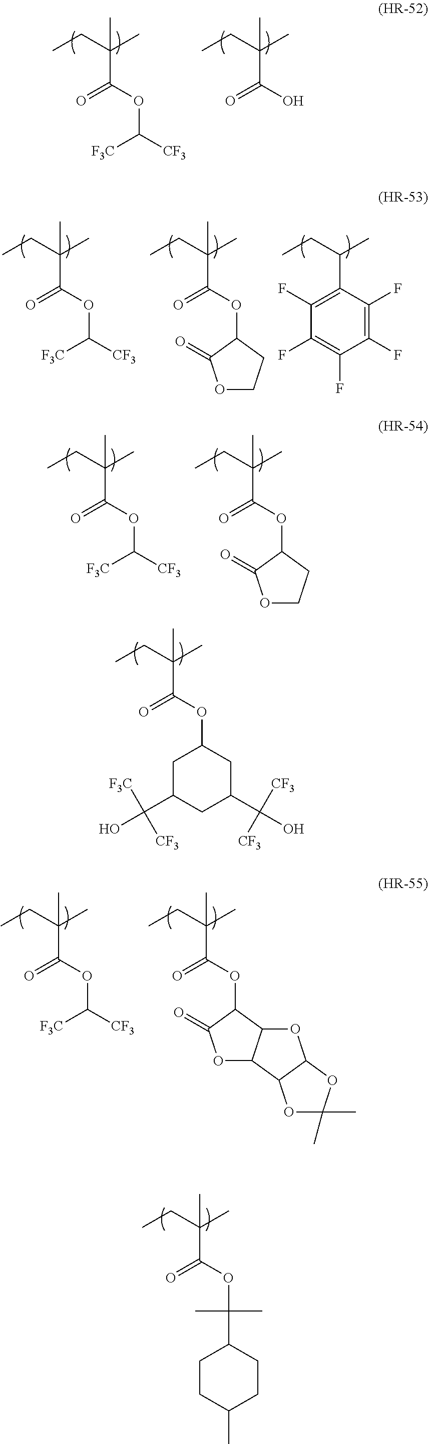

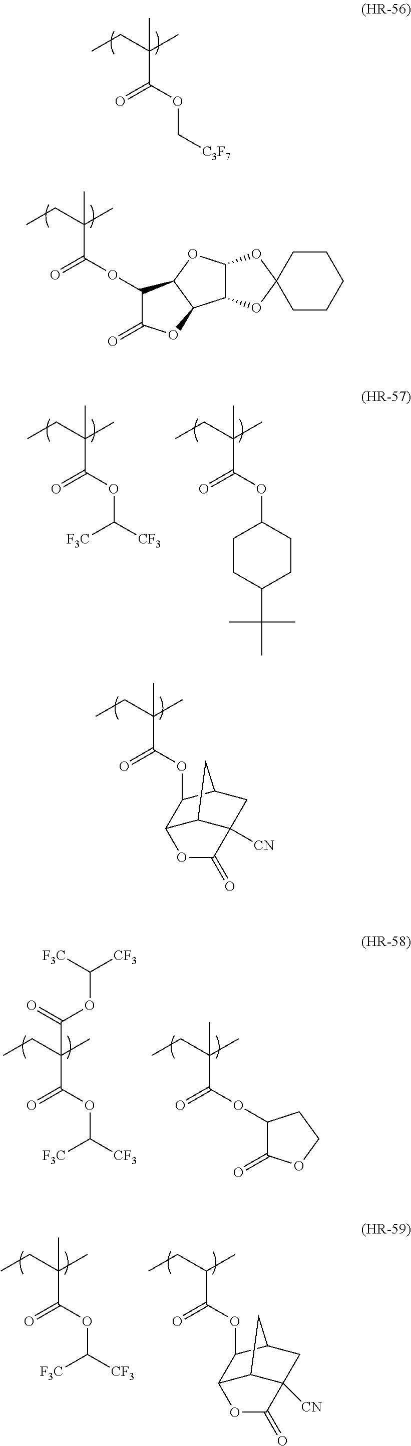

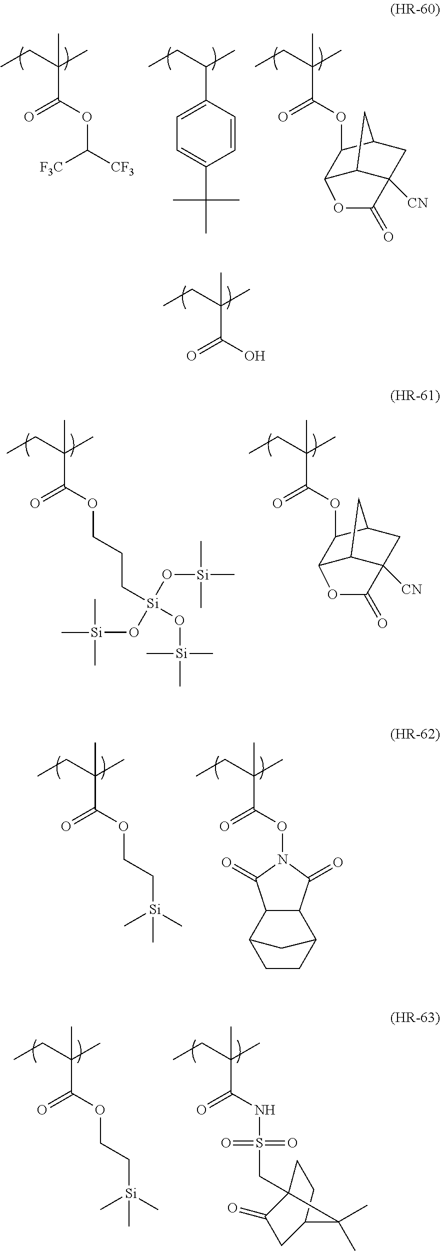

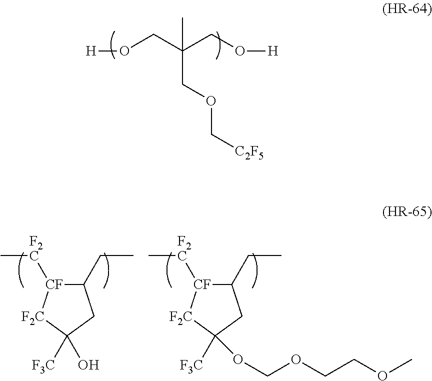

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR:13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

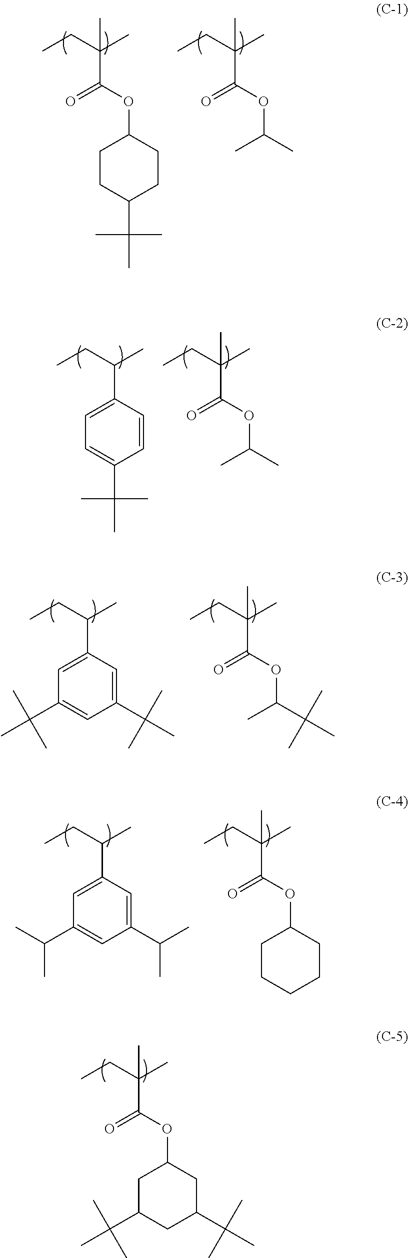

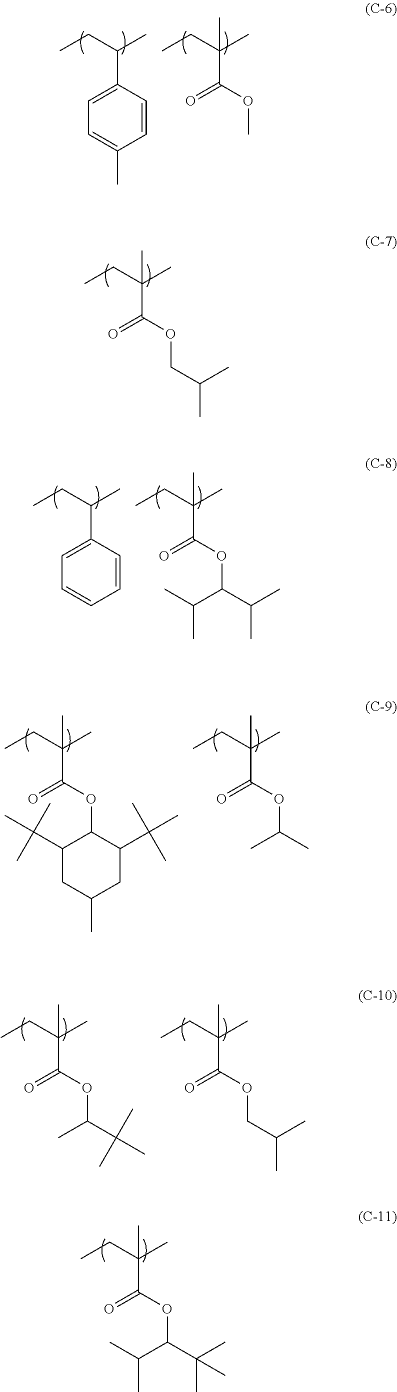

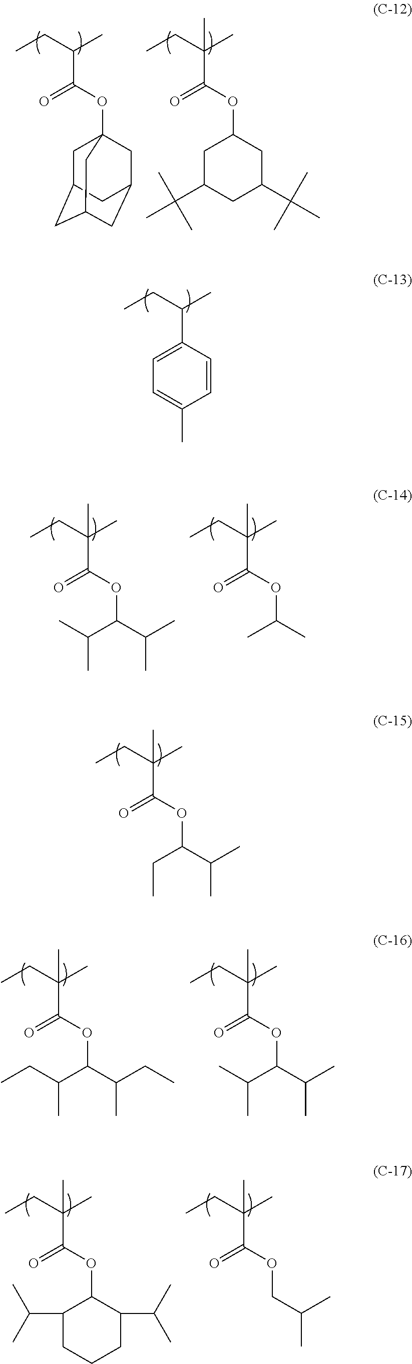

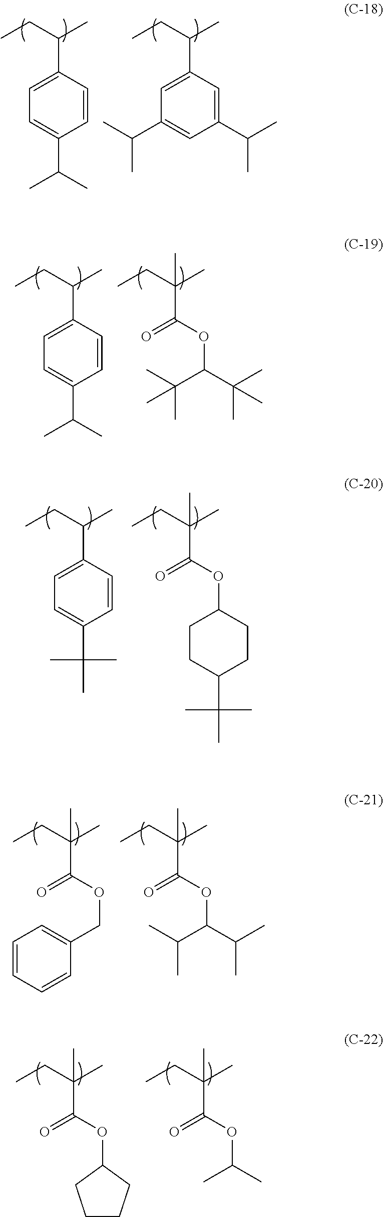

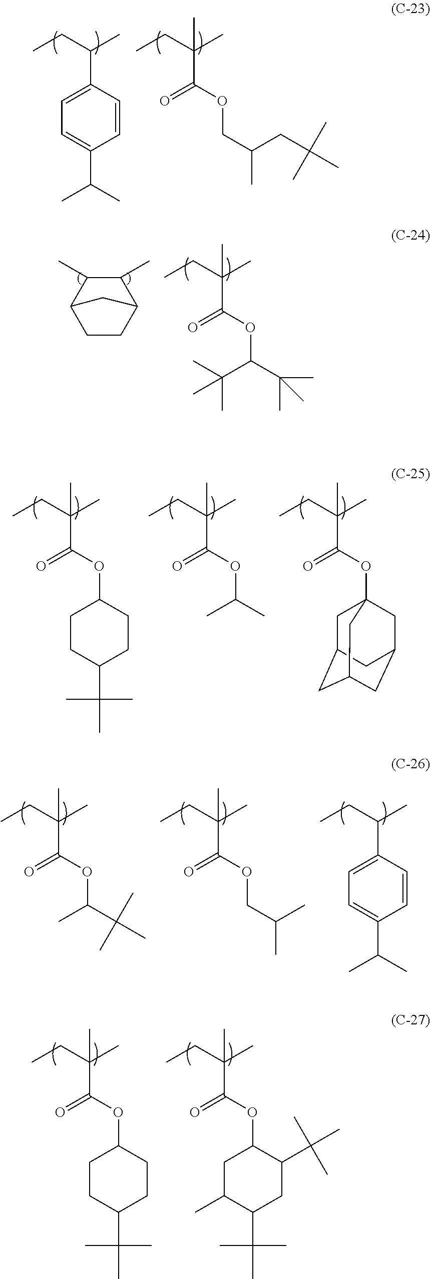

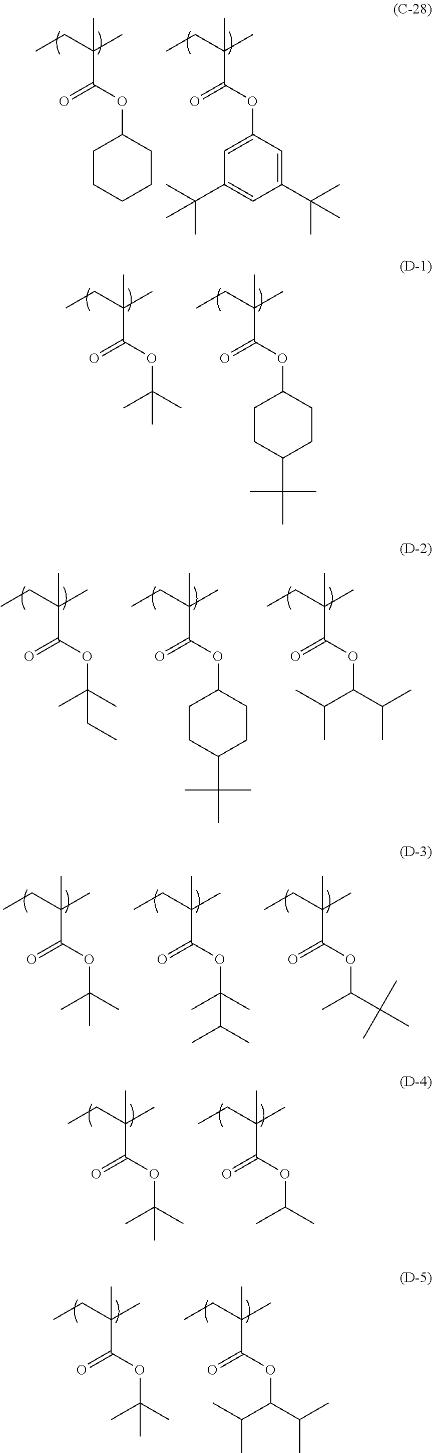

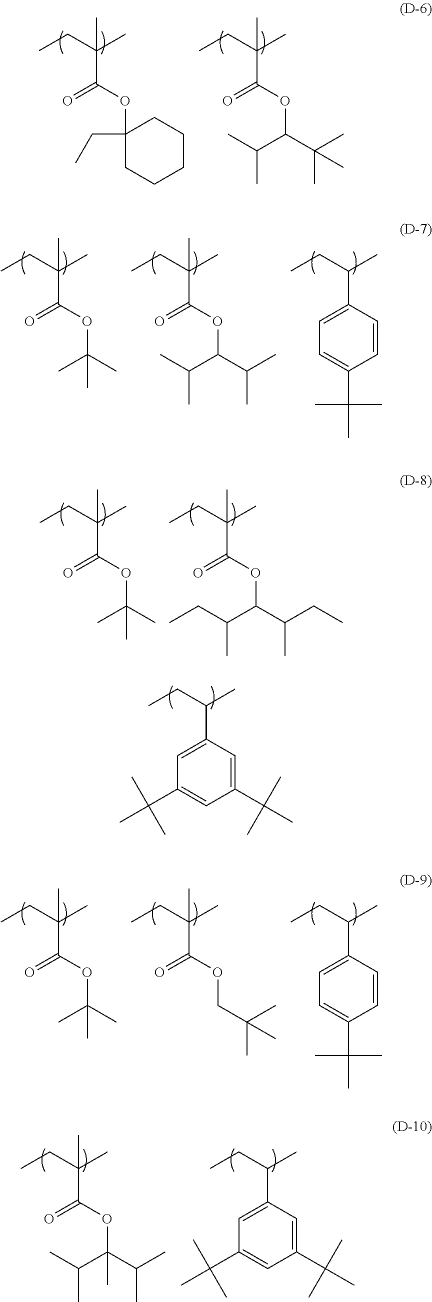

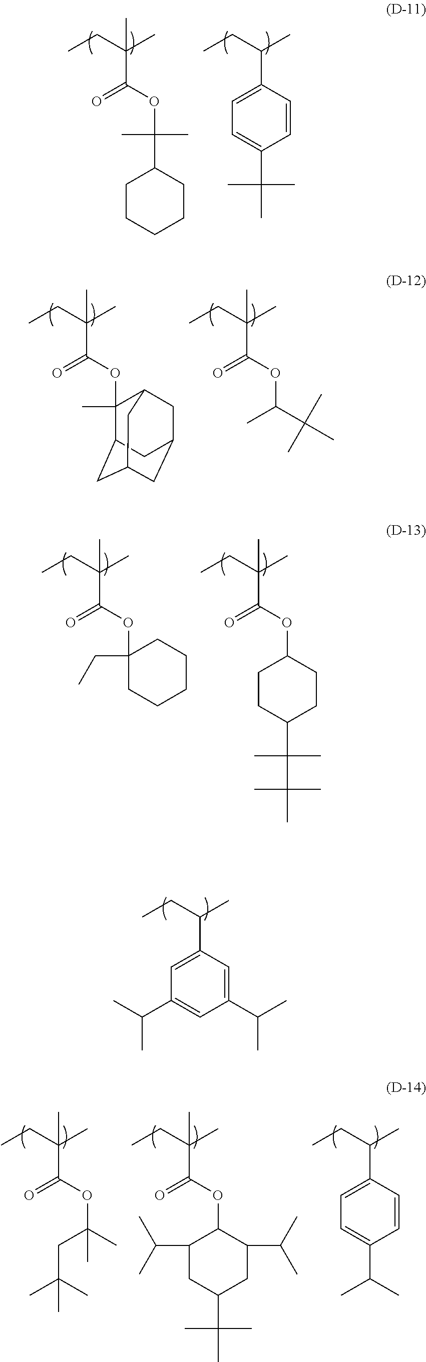

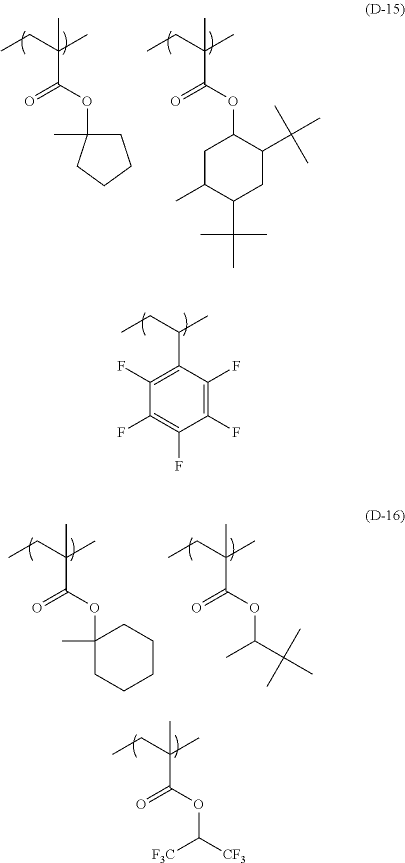

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 3

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | l.79 |
| D-5 | 10/90 | 24700 | 1.83 |
| D-6 | 10/90 | l5700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[6] Basic Compound (N)

The active-light-sensitive or radiation-sensitive resin composition in the present invention may contain a basic compound (N) in order to reduce the change in performance with aging from exposure to heating.

Preferred examples of the basic compound (N) include compounds having structures represented by the following Formulae (A′) to (E′).

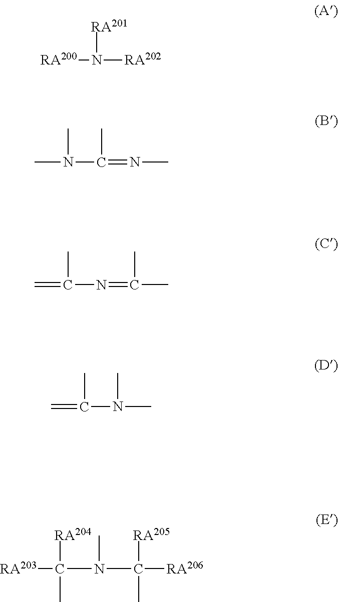

In General Formulae (A′) and (E′),

RA²⁰⁰, RA²⁰¹, and RA²⁰², which may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and RA²⁰¹ and RA²⁰² may be bonded to each other to form a ring. RA²⁰³, RA₂₀₄, R²⁰⁵, and RA²⁰⁶ may be the same as or different from each other, and each represent an alkyl group (preferably having 1 to 20 carbon atoms).

The alkyl group may have a substituent, and as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

It is more preferable that the alkyl groups in General Formulae (A′) and (E′) is unsubstituted.

Preferred examples of the basic compound (N) include guanidine, aminopyrrolidine, pyrazole, pyrazoline, piperazine, aminomorpholine, aminoalkylmorpholine, and piperidine. More preferred specific examples thereof include compounds having an imidazole structure, a diazabicyclo structure, an onium hydroxide structure, an onium carboxylate structure, a trialkylamine structure, an aniline structure, or a pyridine structure; alkylamine derivatives having a hydroxyl group and/or an ether bond; and aniline derivatives having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]nona-5-ene, and 1,8-diazabicyclo[5,4,0]undeca-7-ene. Examples of the compound having an onium hydroxide structure include triarylsulfonium hydroxide, phenacylsulfonium hydroxide, sulfonium hydroxide having 2-oxoalkyl group, specifically triphenylsulthnium hydroxide, tris(t-butyl phenyl)sulfonium hydroxide, bis(t-butyl phenyl)iodonium hydroxide, phenacylthiophenium hydroxide, and 2-oxopropylthiophenium hydroxide. The compound having an onium carboxylate structure is a compound in which the anion moiety of the compound having an onium hydroxide structure becomes a carboxylate, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Preferred examples of the basic compound include an amine compound further having a phenoxy group, an ammonium salt compound having a phenoxy group, an amine compound having a sulfonic acid ester group, and an ammonium salt compound having a sulfonic acid ester group.

In the amine compound having a phenoxy group, the ammonium salt compound having a phenoxy group, the amine compound having a sulfonic acid ester group, and the ammonium salt compound having a sulfonic acid ester group, at least one alkyl group is preferably bonded to the nitrogen atom. In addition, it is preferable that an oxygen atom is included and an oxyalkylene group is formed in the alkyl chain. The number of oxyalkylene groups is 1 or more, preferably 3 to 9, and more preferably 4 to 6, in the molecule. Among the oxyalkylene groups, a structure of —CH₂CH₂O—, —CH(CH₃)CH₂O—, or —CH₂CH₂CH₂O— is preferable.

Specific examples of the amine compound having a phenoxy group, the ammonium salt compound having a phenoxy group, the amine compound having a sulfonic acid ester group, and the ammonium salt compound having a sulfonic acid ester group include, but are not limited to, the compounds (C1-1) to (C3-3) exemplified in paragraph “0066” of US Patent App. No. 2007/0224539.

Furthermore, as one kind of the basic compound, a nitrogen-containing organic compound having a group which leaves by the action of an acid can also be used. Examples of this compound may include a compound represented by the following General Formula (F). Further, a compound represented by the following General Formula (F) exhibits effective basicity in the system when a group capable of leaving by an action of an acid leaves.

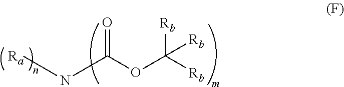

In General Formula (F), Rₐ's each independently represent a hydrogen atom, an alkyl group, a cycloalkyl group, an aryl group, or an aralkyl group. In addition, when n=2, the two Rₐ's may be the same as or different from each other, two of Rₐ's may be bonded to each other to form a divalent heterocyclic hydrocarbon group (preferably having 20 or less carbon atoms) or a derivative thereof.

R_{b}'s each independently represent a hydrogen atom, an alkyl group, a cycloalkyl group, an aryl group or an aralkyl group. However, in —C(R_{b})(R_{b})(R_{b}), when one or more of R_{b}'s are a hydrogen atom, at least one of the rest R_{b}'s is a cyclopropyl group or a 1-alkoxyalkyl group.

At least two of R_{b}'s may be bonded to each other and form an alicyclic hydrocarbon group, an aromatic hydrocarbon group, a heterocyclic hydrocarbon group, or a derivative thereof.

n represents an integer of 0 to 2, in represents an integer of 1 to 3, respectively, and n+m=3.

Specific examples of the compound represented by General Formula (F) are shown below.

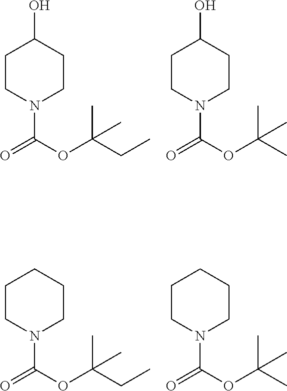

The compound represented by General Formula (F) can be synthesized in accordance with the method disclosed in, for example, JP2009-199021A.

Furthermore, as the basic compound (N), a compound having an amine oxide structure can also be used. As the specific examples of this compound, triethylaminepyridine N-oxide, tributyl amine N-oxide, triethanolamine N-oxide, tris(methoxyethyl)amine N-oxide, tris(2-(methoxymethoxy)ethyl)amine=oxide, 2,2′,2″-nitrilotriethylpropionate N-oxide, N-2-(2-methoxyethoxy)methoxyethylmorpholine N-oxide, and the amine oxide compounds exemplified in JP2008-102383A in addition to these can also be used.

Further, as the basic compound (N), compounds capable of decomposing upon irradiation with active light or radiation to generate an acid anion having a basic structure in the molecule, such as the compounds (A-1) to (A-44) of US2010/0233629A and the compounds (A-1) to (A-23) of US2012/0156617A, can also be used. The compounds which are particularly preferably used among these compounds are shown below.

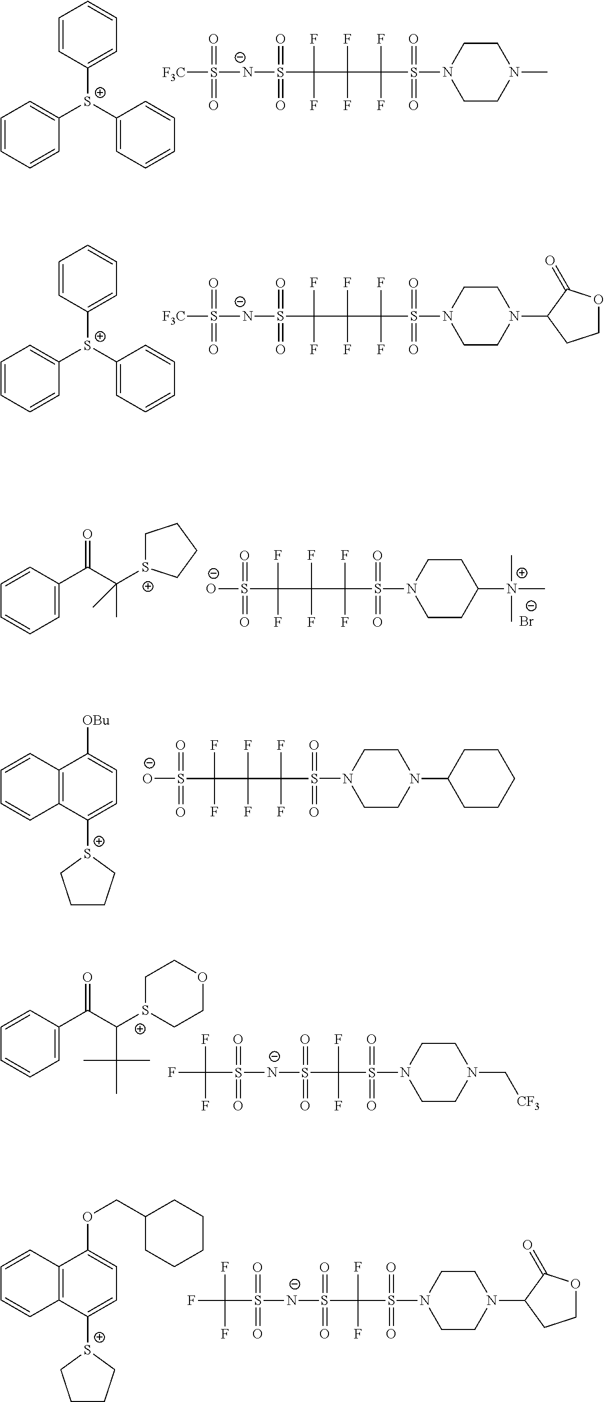

The molecular weight of the basic compound (N) is preferably 250 to 2,000, and more preferably 400 to 1,000. From the viewpoints of further reduction in LWR and local pattern dimensional uniformity, the molecular weight of the basic compound is preferably 400 or more, more preferably 500 or more, and still more preferably 600 or more.

This basic compound (N) may be used alone or in combination of two or more kinds thereof.

The active-light-sensitive or radiation-sensitive resin composition in the present invention may or may not contain the basic compound (N), but in the case where the composition contains the basic compound (N), the amount of the basic compound (N) used is usually 0.001% by mass to 10% by mass, and preferably 0.01% by mass to 5% by mass, with respect to the solid content of the active-light-sensitive or radiation-sensitive resin composition.

[7] Surfactant (F)

The active-light-sensitive or radiation-sensitive resin composition in the present invention may or may not further contain a surfactant, but in the case where a surfactant is contained, it is preferable to contain any one of fluorine- and/or silicon-based surfactants (a fluorine-based surfactant, a silicon-based surfactant, and a surfactant having both a fluorine atom and a silicon atom), or two or more kinds thereof.

By incorporating the surfactant into the active-light-sensitive or radiation-sensitive resin composition in the present invention, it becomes possible to provide a resist pattern which is improved in adhesion and decreased in development defects with good sensitivity and resolution when an exposure light source of 250 nm or less, and particularly 220 nm or less, is used.

Examples of the fluorine- and/or silicon-based surfactants include the surfactants described in “0276” of US2008/0248425A, and examples thereof include EFtop EF301 and EF303 (manufactured by Shin-Akita Kasei K.K.); Florad FC430, 431, and 4430 (manufactured by Sumitomo 3M Inc.); Megaface F171, F173, F176, F189, F113, F110, F177, F120, and R08 (manufactured by DIC Corp.); Surflon S-382, SC101, 102, 103, 104, 105, and 106, and KH-20 (manufactured by Asahi Glass Co., Ltd.); Troysol S-366 (manufactured by Troy Chemical); GF-300 and GF-150 (manufactured by Thagosei Chemical Industry Co., Ltd.); Surflon S-393 (manufactured by Seimi Chemical Co., Ltd.); EFtop EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA); and FTX-204G, 208G 218G, 230G, 204D, 208D, 212D, 218D, and 222D (manufactured by NEOS Co., Ltd.). In addition, Polysiloxane Polymer KP-341 (manufactured by Shin-Etsu Chemical Co., Ltd.) can also be used as the silicon-based surfactant.

In addition to those known surfactants as described above, a surfactant using a polymer having a fluoro-aliphatic group derived from a fluoro-aliphatic compound which is produced by a telomerization method (also referred to as a telomer method) or an oligomerization method (also referred to as an oligomer method), can be used. The fluoro-aliphatic compound can be synthesized in accordance with the method described in JP2002-90991A.

Examples of the surfactant corresponding to the above include Megaface F178, F-470, F-473, F-475, F-476, and F-472 (manufactured by DIC Corp.); a copolymer of an acrylate (or methacrylate) having a C₆F₁₃ group with a (poly(oxyalkylene))acrylate (or methacrylate); and a copolymer of an acrylate (or methacrylate) having a C₃F₇ group with a (poly(oxyethylene))acrylate (or methacrylate) and a (poly(oxypropylene))acrylate (or methacrylate).

In addition, in the present invention, a surfactant other than the fluorine- and/or silicon-based surfactants described in “0280” of US2008/0248425A can also be used.

These surfactants may be used alone or in combination of some kinds thereof.

In the ease where the active-light-sensitive or radiation-sensitive resin composition contains the surfactant, the amount of the surfactant used is preferably 0.0001% by mass to 2% by mass, and more preferably 0.0005% by mass to 1% by mass, with respect to the total amount (excluding the solvent) of the active-light-sensitive or radiation-sensitive resin composition.

On the other hand, by setting the amount of the surfactant added to 10 ppm or less with respect to the total amount (excluding the solvent) of the active-light-sensitive or radiation-sensitive resin composition, the hydrophobic resin is more unevenly distributed to the surface, so that the resist film surface can be made more hydrophobic, which can enhance the water tracking properties during the immersion exposure.

[8] Other Additives (G)

The active-light-sensitive or radiation-sensitive resin composition in the present invention may or may not contain an onium carboxylate salt. Examples of such an onium carboxylate salt include those described in “0605” to “0606” of US2008/0187860A.

The onium carboxylate salt can be synthesized by reacting sulfonium hydroxide, iodonium hydroxide, ammonium hydroxide and carboxylic acid with silver oxide in an appropriate solvent.

When the active-light-sensitive or radiation-sensitive resin composition contains the onium carboxylate salt, the content is generally 0.1% by mass to 20% by mass, preferably 0.5% by mass to 10% by mass, and more preferably 1% by mass to 7% by mass, with respect to the total solids of the composition.

The active-light-sensitive or radiation-sensitive resin composition of the present invention may further contain, if necessary, across-linking agent, a dye, a plasticizer, a light sensitizer, a light absorbent, an alkali-soluble resin, a dissolution inhibitor, a compound promoting solubility in a developer (for example, a phenol compound with a molecular weight of 1,000 or less, an alicyclic compound or aliphatic compound having a carboxyl group), and the like.

The phenol compound with a molecular weight of 1,000 or less may be readily synthesized by those skilled in the art with reference to the method disclosed in, for example, JP 1992-122938A (JP-H04-122938A), JP1990-28531A (JP-H02-28531A), U.S. Pat. No. 4,916,210, EP219294B, and the like.

Specific examples of the alicyclic compound or aliphatic compound having a carboxyl group may include a carboxylic acid derivative having a steroid structure such as a cholic acid, a deoxycholic acid or a lithocholic acid, an adamantane carboxylic acid derivative, an adamantane dicarboxylic acid, a cyclohexane carboxylic acid, a cyclohexane dicarboxylic acid, or the like, however, are not limited to these.

The active-light-sensitive or radiation-sensitive resin composition in the present invention is preferably used at a film thickness of 30 to 250 nm, and more preferably used at a film thickness of 30 to 200 nm from the viewpoint of improving resolution. This film thickness is possible by improving coating properties and film formability through setting the solid concentration in the composition being in an appropriate range to have a moderate viscosity.

The active-light-sensitive or radiation-sensitive resin composition in the present invention is generally 1.0% by mass to 10% by mass, preferably 2.0% by mass to 5.7% by mass, and more preferably 2.0% by mass to 5.3% by mass. By having a solid concentration in this range, the resist solution may be uniformly applied on the substrate, and forming a resist pattern with excellent line width roughness is possible. The reason for this is not clear, however, it is believed that, by having the solid concentration at 10% by mass or less and preferably 5.7% by mass or less, aggregation of materials in the resist solution, particularly, the photoacid generator is suppressed and as a result, a uniform resist film may be formed.

The solid concentration is a weight percentage of the weight of other resist components except for the solvent with regard to the total weight of the active-light-sensitive or radiation-sensitive resin composition of the present invention.

The active-light-sensitive or radiation-sensitive resin composition in the present invention is prepared by dissolving the components as described above in a predetermined organic solvent, and preferably a mixed solvent.

Furthermore, the preparation may include a step of reducing metal impurities in the composition to a ppb level by means of an ion exchange membrane, a step of filtering impurities such as various particles using of a suitable filter, a step of deaeration, or the like. Details of these steps are described in for example, JP2012-88574A, JP2010-189563A, JP2001-12529A, JP2001-350266A, JP2002-99076A, JP1993-307263A (JP-H05-307263A), JP2010-164980A, WO2006/121162A, JP2010-243866A, JP2010-020297A, and the like.

In particular, the pore size of the suitable filter used in the filtration step is preferably 0.1 μm or less, more preferably 0.05 μm or less, and still more preferably 0.03 μm or less made of polytetrafluoroethylene, polyethylene, or nylon.

Furthermore, the composition of present invention preferably has a low water content. Specifically, the water content is preferably 2.5% by mass or less, more preferably 1.0% by mass or less, and still more preferably 0.3% by mass or less, with respect to the total weight of the composition.

<Other Steps in Pattern Formation Method of the Invention>

The light source wavelength used in the exposure device in the present invention is not particularly limited, and examples thereof include infrared rays, visible light, ultraviolet rays, far ultraviolet rays, extreme ultraviolet rays, X-rays, and electron beams, for example, far ultraviolet rays at a wavelength of preferably 250 nm or less, more preferably 220 nm or less, and particularly preferably 1 nm to 200 nm, specifically, a KrF excimer laser (248 nm), ArF excimer laser (193 nm), an F₂ excimer laser (157 nm), X-rays, EUV (13 nm), electron beams, and the like, with the KrF excimer laser, the ArF excimer laser, EUV, or the electron beams being preferable, and the ArF excimer laser being more preferable.

It is preferable that the pattern formation method of the present invention includes the (v) heating step after the (ii) exposing step.

In the pattern formation method of the present invention, the (ii) exposing step can be carried out multiple times.

In the pattern formation method of the present invention, the (v) heating step con be carried out multiple times.

It is also preferable that the method includes a pre-heating step (PB; Prebake) after forming a film and before the exposing step.

In addition, it is also preferable that the method includes a heating treatment after exposure (PEB: Post Exposure Bake), after the exposing step and before the development step.

For both PB and PEB, the heating is preferably carried out at a heating temperature of 70° C. to 130° C., and more preferably 80° C. to 120° C.

The heating time is preferably 30 seconds to 300 seconds, more preferably 30 seconds to 180 seconds, and still more preferably 30 seconds to 90 seconds.

The heating may be carried out using a device installed in an ordinary exposure-and-development machine, or may also be carried out using a hot plate or the like.

The baking accelerates the reaction in the exposed areas, and thus, the sensitivity and the pattern profile are enhanced.

Furthermore, a liquid immersion exposure method can be applied to the exposing step. It is possible to combine the liquid immersion exposure method with super-resolution technology such as a phase shift method and a modified illumination method.

In the case of carrying out the liquid immersion exposure, a step of cleaning the surface of a film with an aqueous chemical liquid may be carried out (1) after forming a film on a substrate and before an exposing step, and/or (2) after a step of subjecting the film to exposure through an immersion liquid and before heating the film.

The immersion liquid is preferably a liquid which is transparent to exposure wavelength and has a minimum temperature coefficient of refractive index so as to minimize the distortion of an optical image projected on the resist film. In particular, in the case where the exposure light source is an ArF excimer laser (wavelength: 193 nm), water is preferably used in terms of easy availability and easy handling, in addition to the above-described viewpoints.

In the case of using water, an additive (liquid) that decreases the surface tension of water while increasing the interfacial activity may be added at a slight proportion. It is preferable that this additive does not dissolve the resist film, and gives a negligible effect on the optical coat at the undersurface of a lens element.

Such an additive is preferably, for example, an aliphatic alcohol having a refractive index substantially equal to that of water, and specific examples thereof include methyl alcohol, ethyl alcohol, and isopropyl alcohol. By adding an alcohol having a refractive index substantially equal to that of water, even when the alcohol component in water is evaporated and its content concentration is changed, an advantage in that the change in the refractive index of the liquid as a whole can be advantageously made very small is obtained.

On the other hand, in the case where materials opaque to light at 193 nm or impurities having a great difference in the refractive index from water are incorporated, the distortion of an optical image projected on a resist is caused. Therefore, the water to be used is preferably distilled water. Further, pure water after filtration through an ion exchange filter or the like may also be used.

The electrical resistance of water used as the immersion liquid is preferably 18.3 MQcm or more, and Total Organic Concentration (TOC) is preferably 20 ppb or less. The water is preferably one which has been subjected to a deaeration treatment.

In addition, the lithography performance can be enhanced by increasing the refractive index of the immersion liquid. From such a viewpoint, an additive for increasing the refractive index, for example, may be added to water, or heavy water (D₂O) may be used in place of water.

The receding contact angle of the resist film formed using the active-light-sensitive or radiation-sensitive resin composition in the present invention is preferably 70° or more at 23±3° C. at a humidity of 45±5%, which is appropriate in the case of the exposure through a liquid immersion medium. The receding contact angle is more preferably 75° or more, and still more preferably 75° to 85°.

When the receding contact angle is extremely small, the resist film cannot be appropriately used in the case of the exposure through the liquid immersion medium. For the realization of a desirable receding contact angle, it is preferable to incorporate the hydrophobic resin (D) into the active-light-sensitive or radiation-sensitive resin composition. Alternatively, the receding contact angle may be increased by forming a coating layer (known as a “top coat”) from the hydrophobic resin composition on the resist film. The applicable top coat is not particularly limited, and known top coats in the present technical field can be appropriately applied. In addition, it can also be considered to provide an auxiliary function for shape adjustment of patterns by applying a top coat including a basic compound (quencher) as well as a resin, as described in OC-5 to OC-11 of JP2013-61647A, particularly Table 3 of Examples of the publication.

In the liquid immersion exposing step, it is necessary for the immersion liquid to move on the wafer while tracking the movement of an exposure head involving high-speed scanning on the wafer and thus forming an exposure pattern. Therefore, the contact angle of the immersion liquid with respect to the resist film in a dynamic condition is important, and it is required for the resist to have no residual liquid droplets and be capable of tracking the high-speed scanning of the exposure head.

The developer of the pattern formation method of the present invention is an organic developer including an organic solvent in the amount of 80% by mass or more with respect to the total amount of the developer.

In particular, the organic developer is preferably a developer containing at least one organic solvent selected from the group consisting of a ketone-based solvent, an ester-based solvent, an alcohol-based solvent, an amide-based solvent, and an ether-based solvent, more preferably a developer containing at least one organic solvent selected from the group consisting of a ketone-based solvent and an ester-based solvent, and particularly preferably a developer containing butyl acetate as the ester-based solvent or methyl amyl ketone (2-heptanone) as the ketone-based solvent.

The organic developer may consist of at least one organic solvent or two or more kinds of solvents. Further, the organic developer may include water in addition to the organic solvent.

However, in order to exhibit the effects of the present invention sufficiently, the water content of the entire developer is preferably less than 10% by mass, and it is more preferable that the developer does not substantially include the water content.

That is, the amount of the organic solvent used with respect to the organic developer is preferably 90% by mass to 100% by mass, and more pr ferably 95% by mass to 100% by mass, with respect to the total amount of the developer.

The vapor pressure of the organic developer is preferably 5 kPa or less, more preferably 3 kPa or less, and particularly preferably 2 kPa or less, at 20° C. By setting the vapor pressure of the organic developer to 5 kPa or less, the evaporation of the developer on a substrate or in a development cup is inhibited, and the temperature uniformity within a wafer plane is improved, whereby the dimensional uniformity within a wafer plane is enhanced.

An appropriate amount of a surfactant may be added to the organic developer, if desired.

The surfactant is not particularly limited, and for example, an ionic or nonionic fluorine- and/or silicon-based surfactant can be used. Examples of such a fluorine- and/or silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540), JP1995-230165A (JP-H07-230165A), JP1996-62834A (JP-H08-62834A), JP1997-54432A (JP-H09-54432A), JP1997-5988A (JP-H09-5988A), and U.S. Pat. No. 5,405,720, U.S. Pat. No. 5,360,692, U.S. Pat. No. 5,529,881, U.S. Pat. No. 5,296,330, U.S. Pat. No. 5,436,098, U.S. Pat. No. 5,576,143, U.S. Pat. No. 5,294,511, and U.S. Pat. No. 5,824,451, with the nonionic surfactant being preferable. The nonionic surfactant is not particularly limited, but the fluorine-based surfactant or the silicon-based surfactant is more preferably used.

The amount of the surfactant used is usually 0.001% by mass to 5% by mass, preferably 0.005% by mass to 2% by mass, and more preferably 0.01% by mass to 0.5% by mass, with respect to the total amount of the developer.

In addition, the organic developer may contain a nitrogen-containing a compound as described in paragraphs “0041” to “0063” of JP5056974B.

As the developing method, for example, a method in which a substrate is immersed in a tank filled with a developer for a certain period of time (a dip method), a method in which a developer is heaped up to the surface of a substrate by surface tension and developed by resting for a certain period of time (a paddle method), a method in which a developer is sprayed on the surface of a substrate (a spray method), a method in which a developer is continuously discharged on a substrate spun at a constant rate while scanning a developer discharging nozzle at a constant rate (a dynamic dispense method), or the like, can be applied.

If a variety of developing methods as described above include a step in which a developer is discharged from a development nozzle of a development apparatus toward a resist film, the discharge pressure of the developer discharged (a flow rate per unit area of the developer discharged) is preferably 2 mL/sec/mm² or less, more preferably 1.5 mL/sec/mm² or less, and still more preferably 1 mL/sec/mm² or less. The lower limit of the flow rate is not particularly limited, but is preferably 0.2 mL/sec/mm² or more, taking consideration of throughput. The details of this are particularly described in paragraphs “0022” to “0029” of JP2010-232550A, and the like.

Furthermore, a step of discontinuing the development while replacement with another solvent may be carried out after a step of developing with a developer containing an organic solvent.

The pattern formation method of the present invention may include (vi) a step of developing using an alkali developer.

As the alkali developer, a 2.38%-by-mass aqueous tetramethylammonium hydroxide solution is used, but solutions at other concentrations (for example, lower concentrations) can also be used. Further, appropriate amounts of an alcohol and a surfactant can be added to an alkaline aqueous solution before the use thereof.

The alkali concentration of the alkali developer is generally in the range of 0.1% by mass to 20% by mass.

Pure water is preferably used as the rinsing liquid in the rinse treatment which is carried out after the alkali development, and an appropriate amount of a surfactant may be added thereto before the use.

In addition, a step of removing the developer or the rinsing liquid adhering onto the pattern can be carried out by a supercritical fluid after the development treatment or the rinse treatment.

The resist film of the present invention is a film formed by the active-light-sensitive or radiation-sensitive resin composition, and is, for example, a film formed by applying the active-light-sensitive or radiation-sensitive resin composition onto the substrate. In the pattern formation method of the present invention, the step of forming a film from the active-light-sensitive or radiation-sensitive resin composition on the substrate, the step of exposing the film, and the developing step can be carried out by generally known methods.

The substrate on which the film in the present invention is formed is not particularly limited, and a substrate generally used in a process for manufacturing an inorganic substrate such as silicon, SiN, and SiO₂ an application-based inorganic substrate such as an SOG, or a semiconductor such as an IC, or a process for manufacturing a liquid crystal, a circuit board for a thermal head or the like, and for lithographic processes in photofabrication in addition to these can be used. In addition, if desired, an antireflection film may be formed on the substrate between the resist film and the substrate. As the antireflection film, known organic or inorganic antireflection films can be appropriately used.

It is preferable that the method includes a step of carrying out the cleaning using a (iv) rinsing liquid after carrying out the development using a developer containing an organic solvent. The rinsing liquid is not particularly limited as long as it does not dissolve the resist pattern and a solution containing an ordinary organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same as those described for the developer containing an organic solvent as described above.

After the developing step using a developer containing an organic solvent, it is more preferable to carry out a step of cleaning using a rinsing liquid containing at least one organic solvent selected from the group consisting of a ketone-based solvent, an ester-based solvent, an alcohol-based solvent, and an amide-based solvent; it is still more preferable to carry out a step of cleaning using a rinsing liquid containing an alcohol-based solvent or an ester-based solvent; it is particularly preferable to carry out a step of cleaning using a rinsing liquid containing a monohydric alcohol; and it is most preferable to carry out a step of cleaning using a rinsing liquid containing a monohydric alcohol having 5 or more carbon atoms.

Examples of the monohydric alcohol used in the rinsing step include linear, branched, or cyclic monohydric alcohols, and specifically, 1-hexanol, 2-hexanol, 4-methyl-2-pentanol, 1-pentanol, 3-methyl-1-butanol, or the like can be used.

A plurality of these respective solvents may be mixed or the solvent may be used by mixing it with an organic solvent other than ones described above.

The water content of the rinsing liquid is preferably 10% by mass or less, more preferably 5% by mass or less, and particularly preferably 3% by mass or less. By setting the water content to 10% by mass or less, good developing characteristics can be obtained.

The vapor pressure of the rinsing liquid which is used after the step of carrying out development using a developer containing an organic solvent is preferably 0.05 kPa to 5 kPa, more preferably from 0.1 kPa to 5 kPa, and most preferably from 0.12 kPa to 3 kPa, at 20° C. By setting the vapor pressure of the rinsing liquid to a range from 0.05 kPa to 5 kPa, the temperature uniformity within a wafer plane is improved, and further, the dimensional uniformity within a wafer plane is enhanced by inhibition of swelling due to the penetration of the rinsing liquid.

The rinsing liquid can also be used after adding an appropriate amount of a surfactant thereto.

In the rinsing step, the wafer which has been subjected to development using a developer containing an organic solvent is subjected to a cleaning treatment using the rinsing liquid containing an organic solvent. A method for the cleaning treatment is not particularly limited, and for example, a method in which a rinsing liquid is continuously ejected on a substrate rotated at a constant rate (a rotation application method), a method in which a substrate is immersed in a bath filled with a rinsing liquid for a certain period of time (a dip method), a method in which a rinsing liquid is sprayed on a substrate surface (a spray method), or the like, can be applied. Among these, a method in which a cleaning treatment is carried out using the rotation application method, and a substrate is rotated at a rotational speed of 2,000 rpm to 4,000 rpm after cleaning, thereby removing the rinsing liquid from the substrate, is preferable. Further, it is preferable that a heating step (Post Bake) is included after the rinsing step. The residual developer and the rinsing liquid between and inside the patterns are removed by the baking. The heating step after the rinsing step is carried out at typically 40° C. to 160° C., and preferably at 70° C. to 95° C., and typically for 10 seconds to 3 minutes, and preferably for 30 seconds to 90 seconds.

The pattern which is consequently obtained by the pattern formation method of the present invention is typically used in “mask” applications in a so-called etching process or an ion implantation process. However, it is not intended to exclude uses in other applications. Examples of other such applications include applications for guide pattern formation in Directed Self-Assembly (DSA) (see, for example, ACS Nano, Vol. 4, No. 8, pp. 4815-4823), that is, a so-called core material (core) in a spacer process (see, for example, JP1991-270227A (JP-H03-270227A) and JP2013-164509A).

The present invention further relates to a method for manufacturing an electronic device, including the pattern formation method of the present invention as described above, and an electronic device manufactured by the manufacturing method.

The electronic device of the present invention is suitably mounted on electric or electronic equipment (home electronics, OA/media-related equipment, optical equipment, telecommunication equipment, and the like).

### EXAMPLES

### Synthetic Example (Synthesis of Resin A-1)

102.3 parts by mass of cyclohexanone was heated to 80° C. under a nitrogen gas stream. While stirring the liquid, a mixed solution of 22.2 parts by mass of a monomer represented by the following Structural Formula M-1, 19.7 parts by mass of a monomer represented by the following Structural Formula M-2, 2.4 parts by mass of a monomer represented by the following Structural Formula M-3, 189.9 parts by mass of cyclohexanone, and 0.9 parts by mass of dimethyl 2,2′-azobisiso butyrate [V-601, manufactured by Wako Pure Chemical Industries, Ltd.] was added dropwise for 5 hours. After completion of the dropwise addition, the solution was further stirred at 80° C. for 2 hours. After leaving the reaction liquid to cool, 40.1 parts by mass of a resin (A-1) of the present invention was obtained by re-precipitating and filtering with a large quantity of hexane/ethyl acetate (mass ratio 9:1), and vacuum-drying the obtained solid.

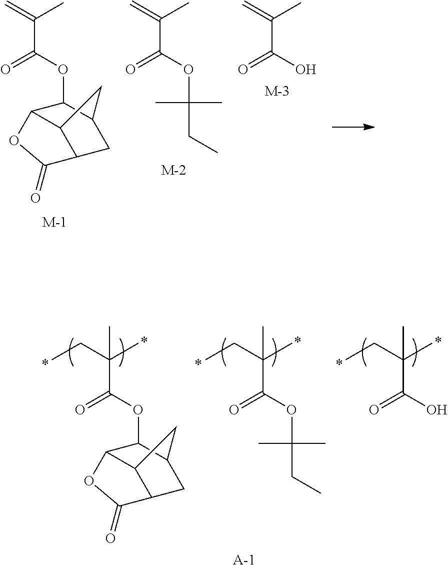

The weight-average molecular weight (Mw: polystyrene conversion) determined from the GPC (carrier: tetrahydrofuran (THF)) of the obtained resin was Mw=19,558, and the dispersity was Mw/Mn=1.90. The compositional ratio (molar ratio) measured by ¹³C-NMR was 40/50/10.

### Synthetic Example (Synthesis of Resin A-5)

102.3 parts by mass of cyclohexanone was heated to 80° C. under a nitrogen gas stream. While stirring the liquid, a mixed solution of 22.2 parts by mass of a monomer represented by the following Structural Formula M-1, 21.6 parts by mass of a monomer represented by the following Structural Formula M-4, 1.2 parts by mass of a monomer represented by the following Structural Formula M-3, 189.9 parts by mass of cyclohexanone, and 1.3 parts by mass of dimethyl 2,2′-azobisiso butyrate [V-601, manufactured by Wako Pure Chemical Industries, Ltd.] was added dropwise for 5 hours. After completion of the dropwise addition, the solution was further stirred at 80° C. for 2 hours. After leaving the reaction liquid to cool, 41.3 parts by mass of a resin was obtained by re-precipitating and filtering with 1,000 parts by mass of hexane/ethyl acetate (mass ratio 9:1), and vacuum-drying the obtained solid. To this obtained resin were added 62 parts by mass of cyclohexanone and 62 parts by mass of pure water under a nitrogen gas stream. While stirring the liquid, 5.1 parts by mass of NaHCO₃ (manufactured by TCI) and 5.1 parts by mass of tetrabutylammonium bromide (manufactured by Aldrich) were added thereto, and the mixed liquid was stirred for 4 hours. 41.7 parts by mass of a resin (A-5) of the present invention was obtained by re-precipitating and filtering the reaction solution with 1,000 parts by mass of water, and vacuum-drying the obtained solid.

The weight-average molecular weight (Mw: polystyrene conversion) determined from the GPC (carrier: tetrahydrofuran (THF)) of the obtained resin was Mw=12,344, and the dispersity was Mw/Mn=1.97. The compositional ratio (molar ratio) measured by ¹³C-NMR was 40/55/5.

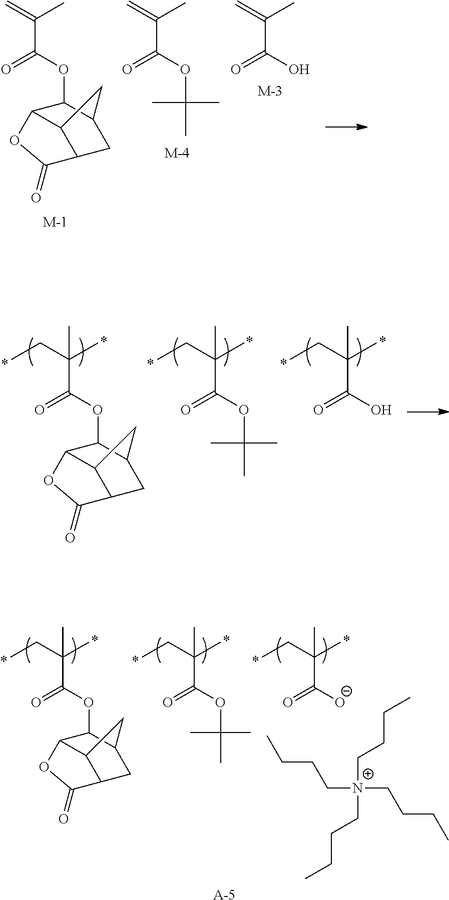

<Resin (A)>

Hereinafter, resins A-2 to A-4 and A-6 to A-8 were synthesized in the same manner as above. The synthesized resins A-2 to A-4 and A-6 to A-8 together with resins A-1 and A-5 are described below.

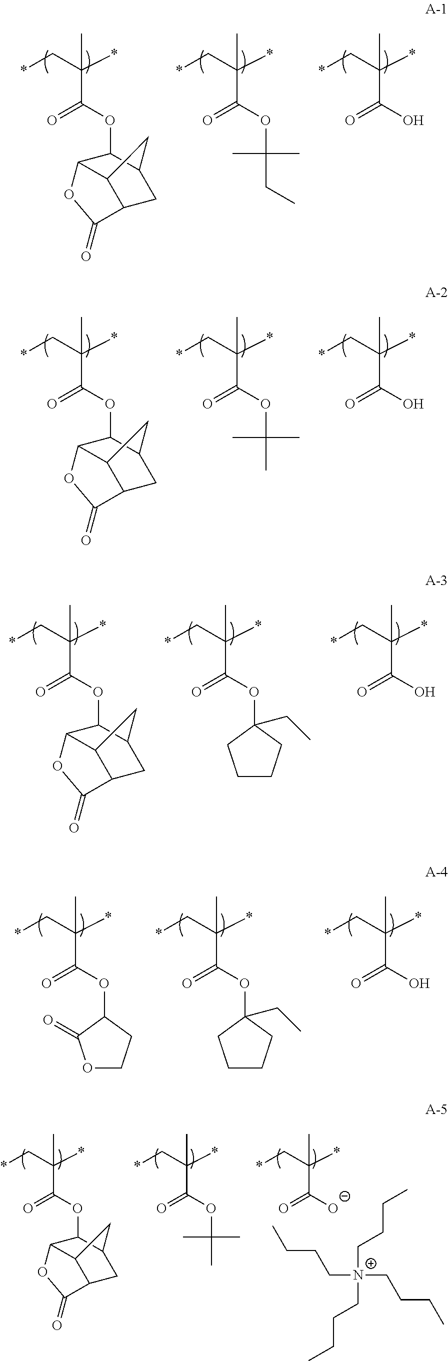

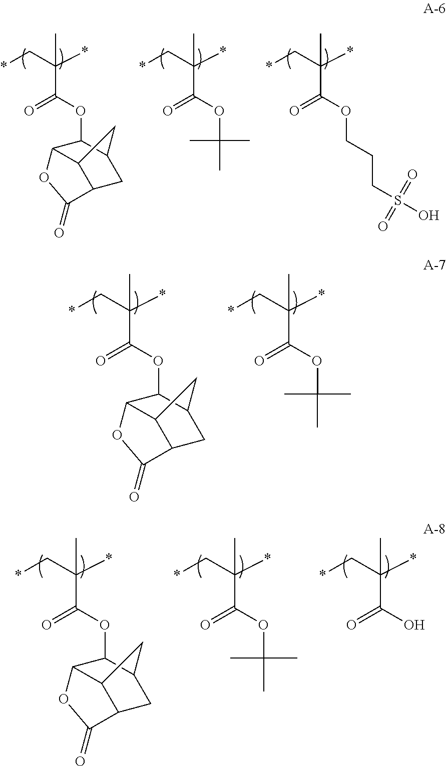

Further, the compositional ratios (molar ratios; corresponding in order starting from the left side), the weight-average molecular weight (Mw), and the dispersity (Mw/Mn) of the respective repeating units are shown in the following table.

TABLE 4

| | Compositional | | |
|---|---|---|---|
| | ratio | | |
| Resin | (% by mole) | Mw | Mw/Mn |
| A-1 | 40/50/10 | 19558 | 1.90 |
| A-2 | 40/50/10 | 21650 | 1.64 |
| A-3 | 50/40/10 | 11818 | 1.53 |
| A-4 | 50/40/10 | 11592 | 1.49 |
| A-5 | 40/55/5 | 12344 | 1.97 |
| A-6 | 40/50/10 | 9938 | 1.92 |
| A-7 | 40/60 | 22128 | 1.52 |
| A-8 | 40/50/10 | 20964 | 1.59 |

<Hydrophobic Resin>

Hereinafter, resins D-1 and D-2 were synthesized in the same manner as above. Hereinafter, the synthesized resins D-1 and D-2 are described below.

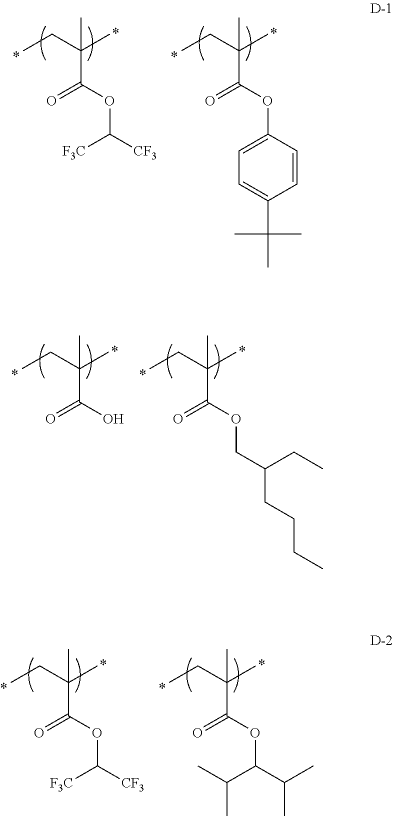

Further, the compositional ratios (molar ratios; corresponding in order starting from the left side), the weight-average molecular weight (Mw), and the dispersity (Mw/Mn) of the repeating units in the resins D-1 and D-2 are shown in the following table.

TABLE 5

| | Compositional ratio | | |
|---|---|---|---|
| Hydrophobic resin | (% by mole) | Mw | Mw/Mn |
| D-1 | 39/57/2/2 | 4200 | 1.38 |
| D-2 | 140/60 | 18531 | 1.68 |

<Ionic Compound (S) Containing Anionic Moiety Having pKa of 0.0 to 10.0>

As the ionic compound (S) containing an anionic moiety having a pKa of 0.0 to 10.0, S-1 to S-4 above were used.

Furthermore, as the compounds for Comparative Examples, S-a to S-c below were used.

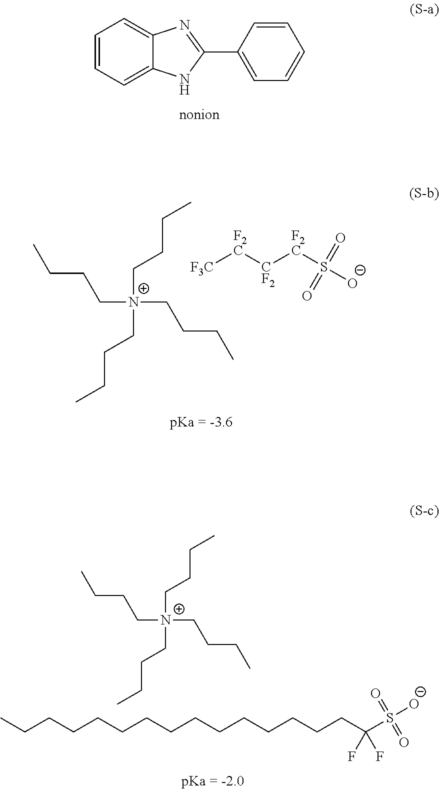 [SMILES: c1ccc(-c2nc3ccccc3[nH]2)cc1 ; CCCC[N+](CCCC)(CCCC)CCCC ; O=S(=O)([O-])C(F)(F)C(F)(F)C(F)(F)C(F)(F)F ; CCCCCCCCCCCCCCCC(F)(F)S(=O)(=O)[O-] ; CCCC[N+](CCCC)(CCCC)CCCC]

<Acid Generator>

As the acid generator, the following compounds were used.

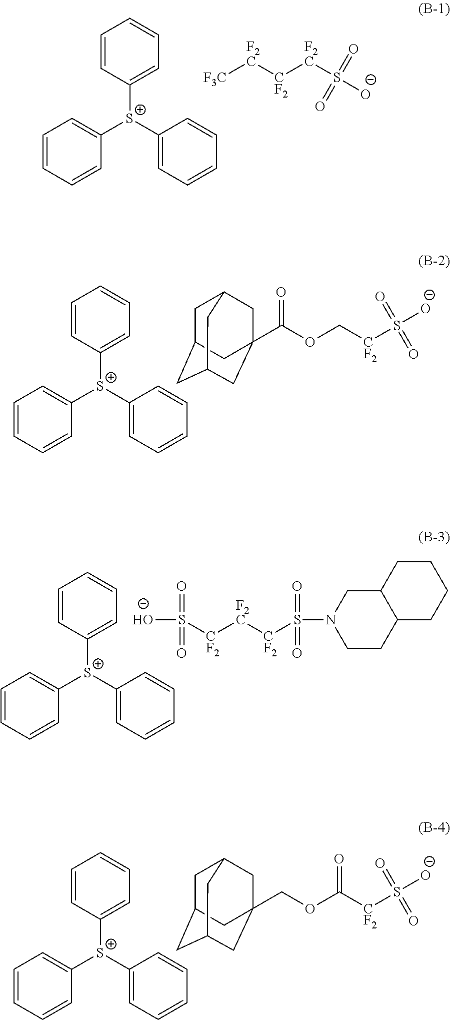

<Solvent>

As the solvent, the following ones were used.

PGMEA: propylene glycol monomethyletheracetate

PGME: propylene glycol monomethylether

CyHz: cyclohexanone

γBL: γ-butyrolactone

### Examples 1 to 30 and Comparative Examples 1 to 31

<1. Preparation of Resist Composition>

The components shown in Table 6 described below were dissolved in the solvents shown in the same table to prepare solutions for each components, and the solutions were filtered through a polyethylene filter having a pore size of 0.03 μm to prepare active-light-sensitive or radiation-sensitive resin compositions (resist compositions).

TABLE 6

| | | | | | | Mass | | | Mass | | | Mass |
|---|---|---|---|---|---|---|---|---|---|---|---|---|
| | Ionic | | Mass ratio | | | ratio | | | ratio | | | ratio |
| | com- | | in total | Acid | | in total | | | in total | Hydro- | | in total |
| | pound | | solid | gen- | | solid | Resin | Mass | solid | phobic | | solid |
| | (S) | Mass ratio | content | erator | Mass ratio | content | (A) | ratio | content | resin | Mass ratio | content |
| Example 1 | S-1 | 0.00074 | 0.02801 | B-1 | 0.0040329 | 0.15219 | A-1 | 0.02157 | 0.81380 | D-1 | 0.000159 | 0.00600 |
| Example 2 | S-1 | 0.00074 | 0.02801 | B-2 | 0.0042067 | 0.15875 | A-1 | 0.02139 | 0.80724 | D-1 | 0.000159 | 0.00600 |
| Example 3 | S-1 | 0.00074 | 0.02801 | B-3 | 0.0049886 | 0.18825 | A-1 | 0.02061 | 0.77774 | D-1 | 0.000159 | 0.00600 |
| Example 4 | S-1 | 0.00074 | 0.02801 | B-4 | 0.0042067 | 0.15875 | A-1 | 0.02139 | 0.80724 | D-1 | 0.000159 | 0.00600 |
| Example 5 | S-2 | 0.00082 | 0.03080 | B-1 | 0.0040329 | 0.15219 | A-1 | 0.02149 | 0.81101 | D-1 | 0.000159 | 0.00600 |
| Example 6 | S-2 | 0.00082 | 0.03080 | B-3 | 0.0049886 | 0.18825 | A-1 | 0.02054 | 0.77495 | D-1 | 0.000159 | 0.00600 |
| Example 7 | S-2 | 0.00082 | 0.03080 | B-3 | 0.0049886 | 0.18825 | A-2 | 0.02054 | 0.77495 | D-1 | 0.000159 | 0.00600 |
| Example 8 | 8-2 | 0.00082 | 0.03080 | B-3 | 0.0049886 | 0.18825 | A-3 | 0.02054 | 0.77495 | D-1 | 0.000159 | 0.00600 |
| Example 9 | S-2 | 0.00082 | 0.03080 | B-3 | 0.0049886 | 0.18825 | A-4 | 0.02054 | 0.77495 | D-1 | 0.000159 | 0.00600 |
| Example 10 | S-3 | 0.00090 | 0.03378 | B-1 | 0.0040329 | 0.15219 | A-1 | 0.02141 | 0.80803 | D-1 | 0.000159 | 0.00600 |
| Example 11 | S-3 | 0.00090 | 0.03378 | B-3 | 0.0049886 | 0.18825 | A-1 | 0.02045 | 0.77197 | D-1 | 0.000159 | 0.00600 |
| Example 12 | S-3 | 0.00142 | 0.05351 | B-3 | 0.0049886 | 0.18825 | A-2 | 0.01993 | 0.75224 | D-1 | 0.000159 | 0.00600 |
| Example 13 | S-3 | 0.00090 | 0.03378 | B-3 | 0.0064602 | 0.24378 | A-2 | 0.01899 | 0.71644 | D-1 | 0.000159 | 0.00600 |
| Example 14 | S-3 | 0.00142 | 0.05351 | B-1 | 0.0052226 | 0.19708 | A-2 | 0.01970 | 0.74341 | D-I | 0.000159 | 0.00600 |
| Example 15 | S-3 | 0.00142 | 0.05351 | B-3 | 0.0064602 | 0.24378 | A-2 | 0.01846 | 0.69671 | D-1 | 0.000159 | 0.00600 |
| Example 16 | S-3 | 0.00142 | 0.05351 | B-1 | 0.0052226 | 0.19708 | A-4 | 0.01970 | 0.74341 | D-1 | 0.000159 | 0.00600 |
| Example 17 | S-3 | 0.00142 | 0.05351 | B-3 | 0.0064602 | 0.24378 | A-4 | 0.01846 | 0.69671 | D-1 | 0.000159 | 0.00600 |
| Example 18 | None | | | B-3 | 0.0098001 | 0.36981 | A-5 | 0.01654 | 0.62419 | D-1 | 0.000159 | 0.00600 |
| Example 19 | S-3 | 0.00142 | 0.05351 | B-3 | 0.0064602 | 0.24378 | A-6 | 0.01846 | 0.69671 | D-1 | 0.000159 | 0.00600 |
| Example 20 | S-3 | 0.00142 | 0.05351 | B-3 | 0.0064602 | 0.24378 | A-6 | 0.01862 | 0.70271 | None | | |
| Example 21 | S-4 | 0.00084 | 0.03168 | B-3 | 0.0064602 | 0.24378 | A-2 | 0.01904 | 0.71854 | D-1 | 0.000159 | 0.00600 |
| Example 22 | S-3 | 0.00142 | 0.05351 | B-3 | 0.0064602 | 0.24378 | A-2 | 0.01846 | 0.69671 | D-2 | 0.000159 | 0.00600 |
| Example 23 | S-3 | 0.00142 | 0.05351 | B-3 | 0.0064602 | 0.24378 | A-2 | 0.01846 | 0.69671 | D-1 | 0.000159 | 0.00600 |
| Example 24 | S-3 | 0.00142 | 0.05351 | B-3 | 0.0064602 | 0.24378 | A-2 | 0.01846 | 0.69671 | D-1 | 0.000159 | 0.00600 |
| Example 25 | S-3 | 0.00316 | 0.11923 | B-3 | 0.010077 | 0.38027 | A-7 | 0.01310 | 0.49451 | D-1 | 0.000159 | 0.00600 |
| Example 26 | S-3 | 0.00142 | 0.05351 | B-3 | 0.0064602 | 0.24378 | A-8 | 0.01846 | 0.69671 | | | |
| Example 27 | S-3 | 0.00142 | 0.05351 | B-2 | 0.0027238 | 0.1028 | A-2 | 0.01897 | 0.71581 | D-1 | 0.000159 | 0.00600 |
| | | | | B-3 | 0.0032301 | 0.12189 | | | | | | |
| Example 28 | S-1 | 0.000588 | 0.0222 | B-3 | 0.0064602 | 0.24378 | A-2 | 0.01857 | 0.70086 | D-2 | 0.000159 | 0.00600 |
| | S-3 | 0.00072 | 0.0272 | | | | | | | | | |
| Example 29 | S-3 | 0.00142 | 0.05351 | B-3 | 0.0064602 | 0.24378 | A-3 | 0.00929 | 0.3507 | D-1 | 0.000159 | 0.00600 |
| | | | | | | | A-4 | 0.00929 | 0.3506 | | | |
| Example 30 | S-3 | 0.00072 | 0.0272 | B-3 | 0.0064602 | 0.24378 | A-2 | 0.01873 | 0.70697 | D-2 | 0.000159 | 0.00600 |
| | S-4 | 0.000426 | 0.0161 | | | | | | | | | |
| Comparative | S-a | 0.00048 | 0.01805 | B-3 | 0.0049886 | 0.18825 | A-1 | 0.02087 | 0.78770 | D-1 | 0.000159 | 0.00600 |
| Example 1 | | | | | | | | | | | | |
| Comparative | S-b | 0.00133 | 0.05032 | B-3 | 0.0049886 | 0.18825 | A-1 | 0.02002 | 0.75543 | D-1 | 0.000159 | 0.00600 |
| Example 2 | | | | | | | | | | | | |
| Comparative | S-c | 0.00196 | 0.07414 | B-3 | 0.0049886 | 0.18825 | A-1 | 0.01939 | 0.73161 | D-1 | 0.000159 | 0.00600 |
| Example 3 | | | | | | | | | | | | |

| | | | | | | | Ionic | Resin (A) | Ionic Compound(S) | |
|---|---|---|---|---|---|---|---|---|---|---|
| | | | | | | | compound | pKa of | Mass ratio % | mmol % |
| | | PGMEA | PGME | CyHx | γBL | | (S) pKa of | repeating | per total | per |
| | | Mass | Mass | Mass | Mass | | anionic | unit having | solid | total solid |
| | Solvent | ratio | ratio | ratio | ratio | Sum | moiety | acid group | content | content |
| Example 1 | PGMEA/PGME/CyHx | 0.5841 | 0.1947 | 0.1947 | | 1.0 | 4.8 | 4.8 | 2.801% | 0.0929 |
| Example 2 | PGMEA/PGME/CyHx | 0.5841 | 0.1947 | 01947 | | 1.0 | 4.8 | 4.8 | 2.801% | 0.0929 |
| Example 3 | PGMEA/PGME/CyHx | 0.5841 | 0.1947 | 0.1947 | | 1.0 | 4.8 | 4.8 | 2.801% | 0.0929 |
| Example 4 | PGMEA/PGME/CyHx | 0.5841 | 0.1947 | 0.1947 | | 1.0 | 4.8 | 4.8 | 2.801% | 0.0929 |
| Example 5 | PGMEA/PGME/CyHx | 0.5841 | 0.1947 | 0.1947 | | 1.0 | 3.9 | 4.8 | 3.080% | 0.0929 |
| Example 6 | PGMEA/PGME/CyHx | 0.5841 | 0.1947 | 0.1947 | | 1.0 | 3.9 | 4.8 | 3.080% | 0.0929 |
| Example 7 | PGMEA/PGME/CyHx | 0.5841 | 0.1947 | 0.1947 | | 1.0 | 3.9 | 4.8 | 3.080% | 0.0929 |
| Example 8 | PGMEA/PGME/CyHx | 0.5841 | 0.1947 | 0.1947 | | 1.0 | 3.9 | 4.8 | 3.080% | 0.0929 |
| Example 9 | PGMEA/PGME/CyHx | 0.5841 | 0.1947 | 0.1947 | | 1.0 | 3.9 | 4.8 | 3.080% | 0.0929 |
| Example 10 | PGMEA/PGME/CyHx | 0.5841 | 0.1947 | 0.1947 | | 1.0 | 4.2 | 4.8 | 3.378% | 0.0929 |
| Example 11 | PGMEA/PGME/CyHx | 0.5841 | 0.1947 | 0.1947 | | 1.0 | 4.2 | 4.8 | 3.378% | 0.0929 |
| Example 12 | PGMEA/PGME/CyHx | 0.5841 | 0.1947 | 0.1947 | | 1.0 | 4.2 | 4.8 | 5.351% | 0.1472 |
| Example 13 | PGMEA/PGME/CyHx | 0.5841 | 0.1947 | 0.1947 | | 1.0 | 4.2 | 4.8 | 3.378% | 0.0929 |
| Example 14 | PGMEA/PGME/CyHx | 0.5841 | 0.1947 | 0.1947 | | 1.0 | 4.2 | 4.8 | 5.351% | 0.1472 |
| Example 15 | PGMEA/PGME/CyHx | 0.5841 | 0.1947 | 0.1947 | | 1.0 | 4.2 | 4.8 | 5.351% | 0.1472 |
| Example 16 | PGMEA/PGME/CyHx | 0.5841 | 0.1947 | 0.1947 | | 1.0 | 4.2 | 4.8 | 5.351% | 0.1472 |
| Example 17 | PGMEA/PGME/CyHx | 0.5841 | 0.1947 | 0.1947 | | 1.0 | 4.2 | 4.8 | 5.351% | 0.1472 |
| Example 18 | PGMEA/PGME/CyHx | 0.5841 | 0.1947 | 0.1947 | | 1.0 | | 4.8 | | |
| Example 19 | PGMEA/PGME/CyHx | 0.5841 | 0.1947 | 0.1947 | | 1.0 | 4.2 | 2.0 | 5.351% | 0.1472 |
| Example 20 | PGMEA/PGME/CyHx | 0.5841 | 0.1947 | 0.1947 | | 1.0 | 4.2 | 2.0 | 5.351% | 0.1472 |
| Example 21 | PGMEA/PGME/CyHx | 0.5841 | 0.1947 | 0.1947 | | 1.0 | 4.2 | 4.8 | 3.168% | 0.1472 |
| Example 22 | PGMEA/PGME/CyHx | 0.5841 | 0.1947 | 0.1947 | | 1.0 | 4.2 | 4.8 | 5.351% | 0.1472 |
| Example 23 | PGMEA/CyHx | 0.6815 | | 0.2921 | | 1.0 | 4.2 | 4.8 | 5.351% | 0.1472 |
| Example 24 | PGMEA/γBL | 0.9248 | | | 0.0487 | 1.0 | 4.2 | 4.8 | 5.351% | 0.1472 |
| Example 25 | PGMEA/γBL | 0.8762 | | | 0.0974 | 1.0 | 4.2 | None | 11.923% | 0.3279 |
| Example 26 | PGMEA/PGME/CyHx | 0.5841 | 0.1947 | 0.1947 | | 1.0 | 4.2 | 4.8 | 5.351% | 0.1472 |
| Example 27 | PGMEA/PGME/CyHx | 0.5841 | 0.1947 | 0.1947 | | 1.0 | 4.2 | 4.8 | 5.351% | 0.1472 |
| Example 28 | PGMEA/PGME/CyHx | 0.5841 | 0.1947 | 0.1947 | | 1.0 | 4.8 | 4.8 | 2.22% | 0.0736 |
| | | | | | | | 4.2 | | 2.72% | 0.0748 |
| Example 29 | PGMEA/PGME/CyHx | 0.5841 | 0.1947 | 0.1947 | | 1.0 | 4.2 | 4.8 | 3.378% | 0.0929 |
| Example 30 | PGMEA/PGME/CyHx | 0.5841 | 0.1947 | 0.1947 | | 1.0 | 4.2 | 4.8 | 2.72% | 0.0748 |
| | | | | | | | 4.2 | | 1.61% | 0.0748 |
| Comparative | PGMEA/PGMEiCyHx | 0.5841 | 0.1947 | 0.1947 | | 1.0 | | 4.8 | 1.805% | 0.0929 |
| Example 1 | | | | | | | | | | |
| ComparLve | PGMEA/PGME/CyHx | 0.5841 | 0.1947 | 0.1947 | | 1.0 | −3.6 | 4.8 | 5.032% | 0.0929 |
| Example 2 | | | | | | | | | | |
| Comparative | PGMEA/PGME/CyHx | 0.5841 | 0.1947 | 0.1947 | | 1.0 | −2.0 | 4.8 | 7.414% | 0.1353 |
| Example 3 | | | | | | | | | | |

(Calculation of pKa in Table)

ACD/ChemSketch (manufactured by Advanced Chemistry Development Inc., ACD/Labs ver 8.08) was used to perform calculation. Further, the values were obtained by performing calculation of pKa for the monomers corresponding to the repeating units with respect to the repeating unit containing an acid group in the resin (A).

<2. Residual Film Test of Resist Films and Evaluations Thereof>

An organic antireflection film ARC29A (manufactured by Nissan Chemical Industries, Ltd.) was applied onto a silicon wafer and baked at 205° C. for 60 seconds to form an antireflection film having a film thickness of 86 nm. The active-light-sensitive or radiation-sensitive resin composition was applied (with a rotational speed being appropriately adjusted depending on the viscosity of a resist) thereonto and baked (Prebake: PB) at 100° C. for 60 seconds to form a resist film having a film thickness of 65 nm.

The obtained wafer was exposed with a 0.3-mJ step at an exposure dose ranging from mJ to 30.4 mJ while changing the exposure position on the wafer, not via a mask, using an ArF excimer laser scanner (PAS5500/1100, manufactured by ASML, NA=0.75, Conventional, σo=0.89). Thereafter, the wafer was heated (Post Exposure Bake: PEB) at 95° C. for 60 seconds, and then developed by paddling a developer (butyl acetate) for 30 seconds. Subsequently, the wafer was spun at a rotational speed of 2,000 rpm for 5 seconds and then spun at a rotational speed of 4,000 rpm for 20 seconds to shake off the developer. Further, the developer was completely dried off by heating (Post Bake) at 90° C. for 60 seconds. The film thickness of the exposed area was measured, a graph having the exposure doses on the horizontal axis and the thickness of the resist film on the vertical axis was constructed, and the residual film (nm) of the resist film at each exposure dose (mJ/cm²) was tested and evaluated.

(Evaluation)

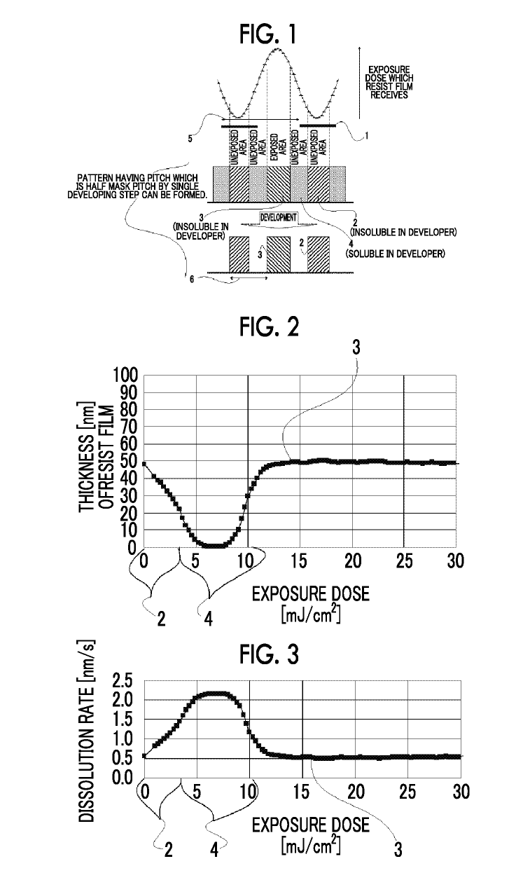

FIG. 2 is a view showing a graph of the test results of the resist film using the resist composition of Example 3 corresponding to the first embodiment. FIG. 3 is a view showing a graph of the dissolution rate (nm/sec, solubility) relative to the exposure dose using the resist composition of Example 3 corresponding to the first embodiment.

As clearly shown in FIGS. 2 and 3, it can be seen that a film whose solubility in the organic developer decreases in an unexposed state is formed at an exposure dose of around 0 mJ/cm² to 5 mJ/cm², which can be considered to correspond to the resist film 2 of the unexposed area shown in FIG. 1.

Next, it could be seen that a film whose solubility increases as the exposure dose increases the solubility reaches an inflection point at a predetermined exposure dose (around 6 mJ/cm²) is formed at an exposure dose of around 5 mJ/cm² to 10 mJ/cm². It can be considered that a film having the solubility at the inflection point and a film having the solubility at around the inflection point correspond to the resist film 4 of the semi-exposed area, which is removed by development by a developer, as shown in FIG. 1.

Further, it can be seen that acid decomposition of the acid-decomposable group contained in the resin (A) proceeds due to an increase in generation of protons by an acid generator at an exposure dose of at least around 10 mJ/cm², and further, the acid generation by the acid decomposition is chemically amplified, thereby accelerating reduction in the solubility. This can be considered to correspond to a resist film of the exposed area 3 in FIG. 1.

The same graphs as in Example 3 were also obtained in the residual film tests using the resist compositions of Examples 1, 2, 4 to 17, 19 to 24, and 26 to 30 corresponding to the first embodiment, and a resist film whose solubility in the developer increases as the exposure dose increases from an unexposed state and the solubility decreases once a predetermined exposure dose has been reached was obtained.

The same graph as in Example 3 was also obtained in the residual film test using the resist composition of Example 18 corresponding to the second embodiment, and a resist film whose solubility in the developer increases as the exposure dose increases from an unexposed state and the solubility decreases once a predetermined exposure dose has been reached was obtained.

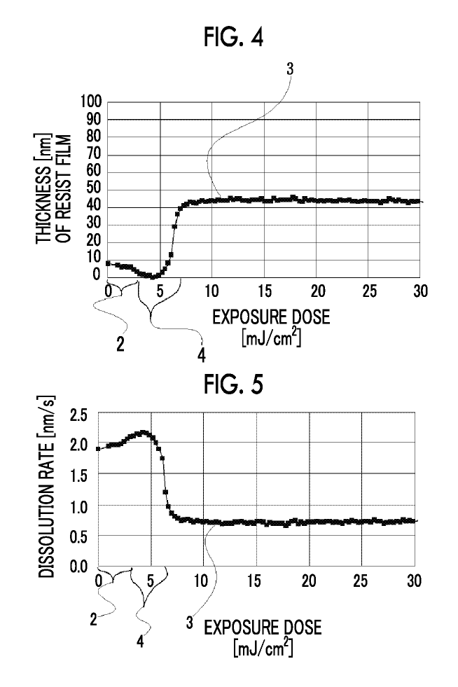

FIG. 4 is a view showing a graph of the test results of the resist film using the resist composition of Example 25 corresponding to the third embodiment. FIG. 5 is a view showing a graph of the dissolution rate (nm/sec, solubility) relative to the exposure dose using the resist composition of Example 25 corresponding to the third embodiment.

As clearly shown in FIGS. 4 and 5, it can be seen that a film in which the residual film is smaller than that of Example 3 as described with reference to FIG. 2 but the solubility in the developer decreases in an unexposed state is formed at an exposure dose of around 0 mJ/cm² to 3 mJ/cm². This can be considered to the resist film 2 of the unexposed area shown in FIG. 1, and further, it is thought that it is possible to enlarge the residual film as in Example 3 by investing the conditions.

Next, it can be seen that a film whose solubility increases as the exposure dose increases the solubility reaches an inflection point at a predetermined exposure dose (around 5 mJ/cm²) is formed at an exposure dose of around 3 mJ/cm² to 6 mJ/cm². It can be considered that a film having the solubility at the inflection point and a film having the solubility at around the inflection point correspond to the resist film 4 of the semi-exposed area, which is removed by development by a developer, as shown in FIG. 1.

Further, it can be seen that acid decomposition of the acid-decomposable group contained in the resin (A) proceeds due to an increase in generation of protons by an acid generator at an exposure dose of at least around 6 mJ/cm², and further, the acid generation by the acid decomposition is chemically amplified, thereby accelerating reduction in the solubility. This can be considered to correspond to a resist film of the exposed area 3 in FIG. 1.

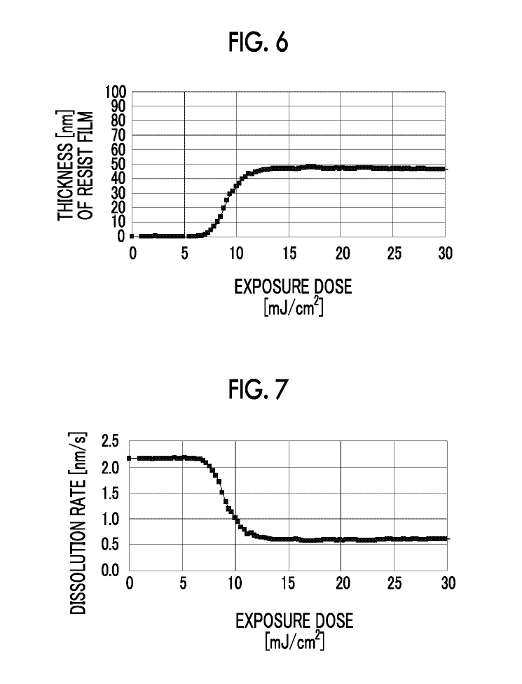

FIG. 6 is a view showing a graph of the residual film test results of the resist film using the resist composition of Comparative Example 1. FIG. 7 is a view showing a graph of the dissolution rate (nm/sec, solubility) relative to the exposure dose using the resist composition of Comparative Example 1.

As clearly shown in FIGS. 6 and 7, it could be seen that a film in which the residual film of the resist film is 0 nm, the dissolution rate is as high as around 2.2 nm/sec, and the solubility decreases in the unexposed state is not formed at an exposure dose of around 0 mJ/cm² to 7 mJ/cm². Further, it can be seen that there is no case where as the solubility in the organic developer increases as the exposure dose increases from an unexposed state, and the resist film of the unexposed area above is not distinguished from the resist film of the semi-exposed area. However, a resist film of the exposed area is formed at an exposure dose of around 8 mJ/cm² or more.

Accordingly, it can be seen that even though the resist composition of Comparative Example 1 is used, a resist film whose solubility in the developer increases as the exposure dose increases from an unexposed state and the solubility decreases once a predetermined exposure dose has been reached is not obtained.

With respect to Comparative Examples 2 and 3, the same graph as in Comparative Example 1 was obtained, and with respect to Comparative Examples 2 and 3, a resist film whose solubility in the developer increases as the exposure dose increases from an unexposed state and the solubility decreases once a predetermined exposure dose has been reached was not obtained.

<3. Resist Pattern Formation Test and Evaluation Thereof>

An organic antireflection film ARC29A (manufactured by Nissan Chemical Industries, Ltd.) was applied onto a silicon wafer and baked at 205° C. for 60 seconds to form an antireflection film having a film thickness of 86 nm. The active-light-sensitive or radiation-sensitive resin composition was applied (with a rotational speed being appropriately adjusted depending on the viscosity of a resist) thereonto and baked (Prebake: PB) at 100° C. for 60 seconds to form a resist film having a film thickness of 65 nm.

The obtained wafer was exposed to a line-and-space pattern via a 6% half-tone mask having a pitch of 240 nm and a line width ratio of line:space of 1:1, using an ArF excimer laser scanner (PAS5500/1100, manufactured by ASML, NA=0.75, DiPole, σo/σi=0.89/0.65). Thereafter, the wafer was heated (Post Exposure Bake: PEB) at 95° C. for 60 seconds, and then developed by paddling a developer (butyl acetate) for 30 seconds. Subsequently, the wafer was spun at a rotational speed of 2,000 rpm for 5 seconds and then spun at a rotational speed of 4,000 rpm for 20 seconds to shake off the developer. Further, the developer was completely dried by heating (Post Bake) at 90° C. for 60 seconds.

(Evaluation)

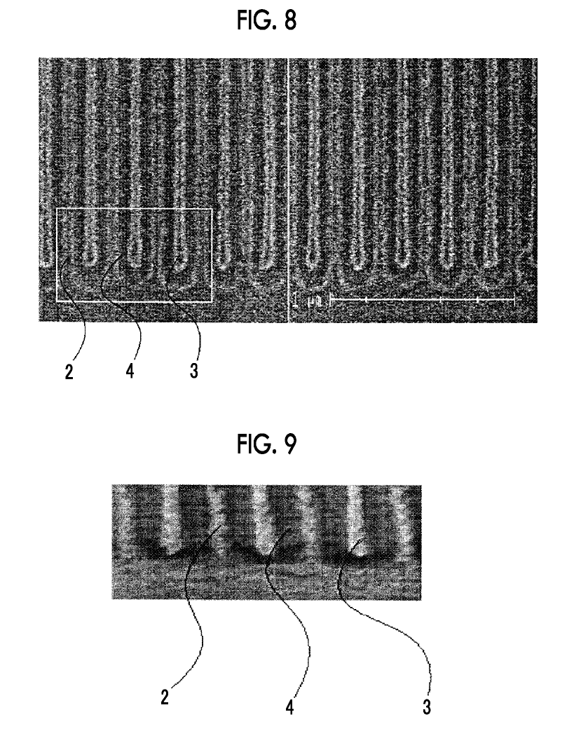

FIG. 8 is a view showing the results of observation of a pattern using the resist composition of Example 3 corresponding to the first embodiment by means of a scanning electron microscopic (SEM) image. FIG. 9 is a partially enlarged view of the range represented by a white solid line in FIG. 8.

As clearly shown in FIGS. 8 and 9, it can be seen that a pattern formed of a line corresponding to the unexposed area 2, a line corresponding to the exposed area 3, and a space (groove) corresponding to the semi-exposed area 4 is formed.

In particular, as seen from the reference to the scale bar in FIG. 9, it could be seen that a pattern having a pattern pitch of 120 nm and a line width of 60 nm is formed.

As described above, it can be seen that a pattern having a pitch of 120 nm which is half the pitch (240 nm) of the mask is formed by a single exposing step and a single developing step, which cannot be accomplished by the pattern formation method in the related art. It is also thought that the line width of 60 nm by a single exposing step and a single developing step cannot be accomplished by the pattern formation method in the related art.

The same resist pattern as in Example 3 was obtained in the resist pattern formation tests using the resist compositions of Examples 1, 2, 4 to 17, 19 to 24 and 26 to 30 corresponding to the first embodiment.

The same resist pattern as in Example 3 was obtained in the resist pattern formation tests using the resist compositions of Example 18 corresponding to the second embodiment and Example 25 corresponding to the third embodiment.

It can be seen that a line-and-space pattern having a pitch of 120 nm and a space width of 60 nm, which is half the pitch of the exposed mask, can be obtained by a single exposing step and a single developing step with respect to all the compositions of Examples 1 to 30, as described above.

<Dot Pattern Formation>

An organic antireflection film ARC29A (manufactured by Nissan Chemical Industries, Ltd.) was applied onto a silicon wafer and baked at 205° C. for 60 seconds to form an antireflection film having a film thickness of 86 nm. The active-light-sensitive or radiation-sensitive resin composition used in Example 3 as described above was applied (with a rotational speed being appropriately adjusted depending on the viscosity of a resist) thereonto and baked (Prebake: PB) at 100° C. for 60 seconds to form a resist film having a film thickness of 65 nm.

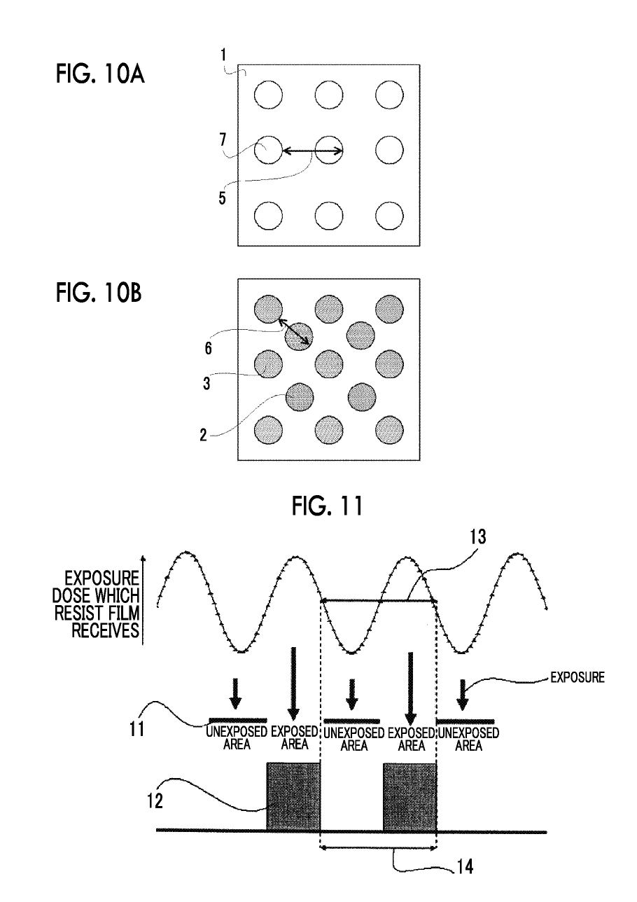

The obtained wafer was exposed to a dot pattern via a 6% half-tone mask having a pitch 5 of a mask 1 of 240 nm and a diameter of the dot pattern of a transparent pattern 7 of 120 nm, as shown in FIG. 10A, using an ArF excimer laser scanner (PAS5500/1100, manufactured by ASML, NA=0.75, Annular, σo/σi=0.89/0.60). Thereafter, the wafer was heated (Post Exposure Bake: PEB) at 95° C. for 60 seconds, and then developed by paddling a developer (butyl acetate) for 30 seconds. Subsequently, the wafer was spun at a rotational speed of 2,000 rpm for 5 seconds and then spun at a rotational speed of 4,000 rpm for 20 seconds to shake off the developer. Further, the developer was completely dried by heating (Post Bake) at 90° C. for 60 seconds. Thus, only the semi-exposed area was removed by development, and a dot pattern which includes a dot pattern derived from the resist film of the unexposed area 2 and a dot pattern derived from the resist film of the unexposed area 3, as shown in FIG. 10B, was obtained. A pattern in which the pattern pitch 6 is 170 nm and the diameter of the dot pattern is 85 nm was obtained.

It can be seen that a dot pattern which is smaller by about 0.7 times the diameter of the dot pattern in the mask 1 is formed, and a pattern pitch 6 which is narrower by about 0.7 times the pitch 5 of the mask 1 is formed.

### INDUSTRIAL APPLICABILITY

According to the present invention, it is possible to provide a novel pattern formation method, completely different from the double patterning methods in the related art, which can provide a fine pattern pitch using a single exposing step and a single developing step; an active-light-sensitive or radiation-sensitive resin composition used for the pattern formation method; a resist film; a method for manufacturing an electronic device; and an electronic device. In particular, it is possible to provide a pattern formation method, in which in the case of using a mask, a pattern having a pitch which is half the pitch of the mask or less can be formed; an active-light-sensitive or radiation-sensitive resin composition used for the pattern formation method; a resist film; a method for manufacturing an electronic device; and an electronic device.

The present invention has been described in detail with reference to specific aspects, but it is obvious to those skilled in the art that various changes or modifications can be made without departing from the spirit and scope of the present invention.

The present application is based on the Japanese Patent Application (JP2013-161643A) filed on Aug. 2, 2013, the contents of which are incorporated herein by reference.

### EXPLANATION OF REFERENCES

1 Mask

2 Unexposed area

3 Exposed area

4 Semi-exposed area

5 Pitch of the mask

6 Pattern pitch

What is claimed is:

1. A pattern formation method comprising the following steps (i) to (iii):
(i) a step of forming a film whose solubility in a developer increases as the exposure dose increases from an unexposed state but then decreases once a predetermined exposure dose has been reached by using an active-light-sensitive or radiation-sensitive resin composition;
(ii) a step of exposing the film; and
(iii) a step of developing the exposed film by using a developer containing an organic solvent in the amount of 80% by mass or more with respect to the total amount of the developer.

2. The pattern formation method according to claim 1,
wherein the exposure is carried out through a mask to form a pattern having a narrower pitch than the pitch of the mask.

3. The pattern formation method according to claim 2,
wherein the pitch of the pattern is half the pitch of the mask or less.

4. The pattern formation method according to claim 1,
wherein the active-light-sensitive or radiation-sensitive resin composition includes a resin (A) having a repeating unit (P1) containing a group capable of decomposing by an action of an acid to generate a polar group, and a compound (B) capable of generating an acid upon irradiation with active light or radiation.

5. The pattern formation method according to claim 4,
wherein the active-light-sensitive or radiation-sensitive resin composition further includes an ionic compound (S) containing an anionic moiety having a pKa of 0.0 to 10.0.

6. The pattern formation method according to claim 5,
wherein the resin (A) is a resin further having a repeating unit (P2) containing an acid group.

7. The pattern formation method according to claim 6,
wherein the pKa of the repeating unit (P2) is 0.0 to 10.0, and when the pKa of the repeating unit (P2) is higher than the pKa of the anionic moiety of the ionic compound (S), the difference between the pKa of the repeating unit (P2) and the pKa of the anionic moiety of the ionic compound (S) is 2.0 or less.

8. The pattern formation method according to claim 4,
wherein the resin (A) is a resin further having a repeating unit (P3) containing an ionic group obtained by forming a salt with an acid group.

9. The pattern formation method according to claim 5,
wherein the anionic moiety is represented by any one of the following General Formulae (a1) to (a5): 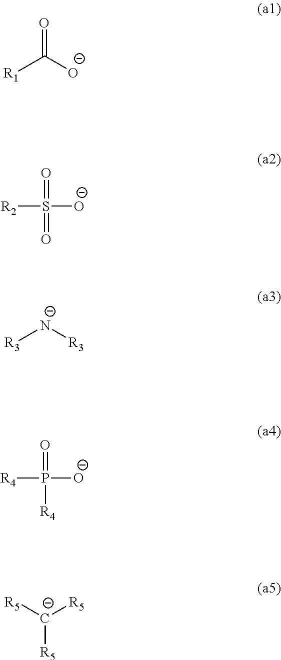
in the general formulae,
R₁, R₂, R₃, R₄, and R₅ each independently represent a hydrogen atom or an organic group,
R₃'s, which are present in plural numbers, may be the same as or different from each other and R₃'s may be bonded to each other to form a ring,
R₄'s, which are present in plural numbers, may be the same as or different from each other and R₄'s may be bonded to each other to form a ring, and
R₅'s, which are present in plural numbers, may be the same as or different from each other and R₅'s may be bonded to each other to form a ring.

10. The pattern formation method according to claim 5,
wherein the cationic moiety contained in the ionic compound (S) is represented by any one of the following General Formulae (b1) to (b7): 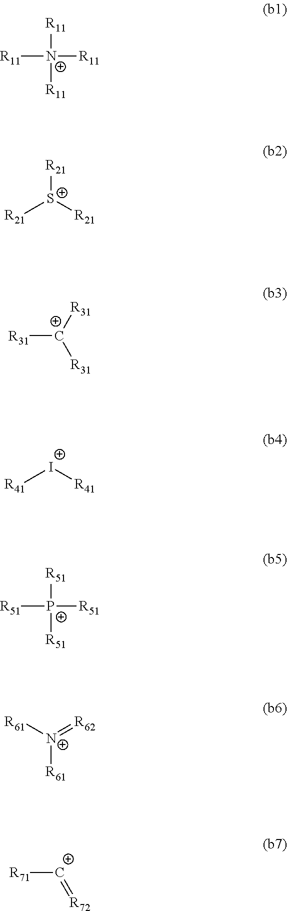
in the general formulae,
R₁₁, R₂₁, R₃₁, R₄₁, R₅₁, R₆₁, R₇₁, and R₇₂ each independently represent a hydrogen atom or an organic group,
R₁₁'s, which are present in plural numbers, may be the same as or different from each other and R₁₁'s may be bonded to each other to form a ring,
R₂₁'s, which are present in plural numbers, may be the same as or different from each other and R₂₁'s may be bonded to each other to form a ring,
R₃₁'s, which are present in plural numbers, may be the same as or different from each other and R₃₁'s may be bonded to each other to form a ring,
R₄₁'s, which are present in plural numbers, may be the same as or different from each other and R₄₁'s may be bonded to each other to form a ring,
R₅₁'s, which are present in plural numbers, may be the same as or different from each other and R₅₁'s may be bonded to each other to form a ring, and
R₆₁'s, which are present in plural numbers, may be the same as or different from each other and R₆₁'s may be bonded to each other to form a ring.

11. The pattern formation method according to claim 1,
wherein the exposure is liquid immersion exposure.

12. An active-light-sensitive or radiation-sensitive resin composition, which forms a film whose solubility in a developer increases as the exposure dose increases from an unexposed state but then decreases once a predetermined exposure dose has been reached.

13. The active-light-sensitive or radiation-sensitive resin composition according to claim 12, comprising a resin (A) having a repeating unit (P1) containing a group capable of decomposing by an action of an acid to generate a polar group, and a compound (B) capable of generating an acid upon irradiation with active light or radiation.

14. The active-light-sensitive or radiation-sensitive resin composition according to claim 13, further comprising an ionic compound (S) containing an anionic moiety having a pKa of 0.0 to 10.0.

15. The active-light-sensitive or radiation-sensitive resin composition according to claim 13,
wherein the resin (A) is a resin further having a repeating unit (P2) containing an acid group.

16. The active-light-sensitive or radiation-sensitive resin composition according to claim 15,
wherein the pKa of the repeating unit (P2) is 0.0 to 10.0, and when the pKa of the repeating unit (P2) is higher than the pKa of the anionic moiety of the ionic compound (S), the difference between the pKa of the repeating unit (P2) and the pKa of the anionic moiety of the ionic compound (S) is 2.0 or less.

17. The active-light-sensitive or radiation-sensitive resin composition according to claim 13,
wherein the resin (A) is a resin further having a repeating unit (P3) containing an ionic group obtained by forming a salt with an acid group.

18. A resist film formed by using the active-light-sensitive or radiation-sensitive resin composition according to claim 12.

19. A method for manufacturing an electronic device, comprising the pattern formation method according to claim 1.

20. An electronic device manufactured by the method for manufacturing an electronic device according to claim 19.
